(19) United States
(12) Patent Application Publication
(10) Pub. No.: US 2023/0309403 A1
(43) Pub. Date: Sep. 28, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: MINJUNG JUNG, Hongcheon-gun (KR); TAEIL KIM, Hwaseong-si (KR); SERAN KIM, Suwon-si (KR); JUNHA PARK, Gwacheon-si (KR); JANG YEOL BAEK, Yongin-si (KR); MinJae SUNG, Hwaseong-si (KR)

(21) Appl. No.: 18/121,517

(22) Filed: Mar. 14, 2023

(30) Foreign Application Priority Data
Mar. 23, 2022 (KR) 10-2022-0036019

(51) Int. Cl. H10K 85/60; C07F 5/02; C07F 7/08; H10K 85/30; C09K 11/06

(52) U.S. Cl. CPC H10K 85/658; C07F 5/027; C07F 7/0812; H10K 85/6572; H10K 85/654; H10K 85/346; C09K 11/06; H10K 50/11

(57) ABSTRACT

A light emitting element including: a first electrode; a second electrode facing the first electrode; and at least one functional layer between the first electrode and the second electrode is provided. The at least one functional layer includes: a first compound represented by Formula 1; and at least one of a second compound represented by Formula HT-1, a third compound represented by Formula ET-1, or a fourth compound represented by Formula M-b.

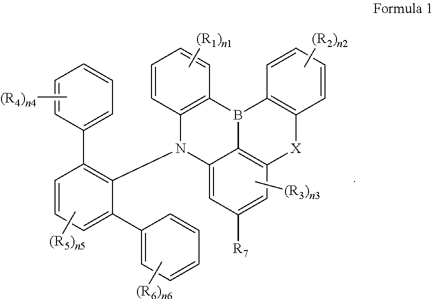

### CROSS-REFERENCE TO RELATED APPLICATION

This application claims priority to and the benefit of Korean Patent Application No. 10-2022-0036019, filed on Mar. 23, 2022, in the Korean Intellectual Property Office, the entire content of which is hereby incorporated by reference.

### BACKGROUND

### 1. Field

Aspects of one or more embodiments of the present disclosure relate to a polycyclic compound and a light emitting element including the same, and for example, to a light emitting element including a polycyclic compound in an emission layer.

### 2. Description of Related Art

As image display devices, organic electroluminescence display devices and/or the like have recently been actively developed. The organic electroluminescence display devices and/or the like are display devices including self-luminescent light emitting elements in which holes and electrons injected from a first electrode and a second electrode recombine in an emission layer, and thus a luminescent material in the emission layer emits light to accomplish display (e.g., to display an image).

For application of light emitting elements to display devices, there is a demand or desired for light emitting elements having a low driving voltage, a high luminous efficiency, and/or a long life, and development of materials, for light emitting elements, capable of stably attaining one or more of such characteristics is being continuously required (sought).

### SUMMARY

An aspect of one or more embodiments of the present disclosure is directed toward a light emitting element exhibiting a long lifespan.

An aspect of one or more embodiments of the present is directed toward a polycyclic compound as a material for a light emitting element having long lifespan.

Additional aspects will be set forth in part in the description which follows and, in part, will be apparent from the description, or may be learned by practice of the presented embodiments of the disclosure.

An embodiment of the present disclosure provides a light emitting element including: a first electrode; a second electrode facing the first electrode; and at least one functional layer between the first electrode and the second electrode, wherein the at least one functional layer includes: a first compound represented by Formula 1; and at least one of a second compound represented by Formula HT-1, a third compound represented by Formula ET-1, or a fourth compound represented by Formula M-b.

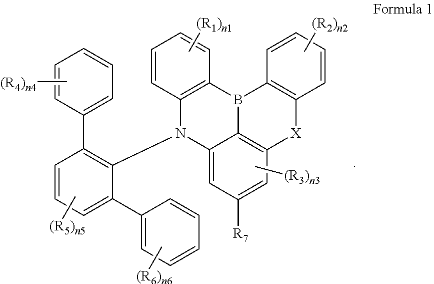

In Formula 1, X may be CR₈R₉ or SiR₁₀R₁₁, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, R₈ to R₁₁ may each independently be a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring, n1 and n2 may each independently be an integer from 0 to 4, n3 may be an integer from 0 to 2, n4 may be an integer from 0 to 5, n5 may be an integer from 0 to 3, and n6 may be an integer from 0 to 5.

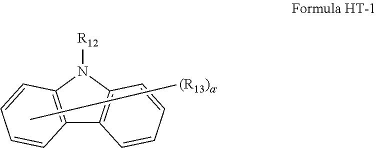

In Formula HT-1, R₁₂ and R₁₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and a may be an integer from 0 to 8.

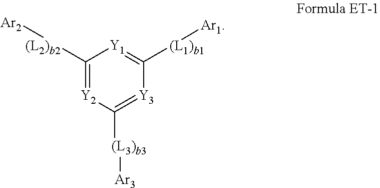

In Formula ET-1 above, Y₁ to Y₃ may each independently be N or CRₐ, at least one of Y₁ to Y₃ may be N, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and b1 to b3 may each independently be an integer from 0 to 10.

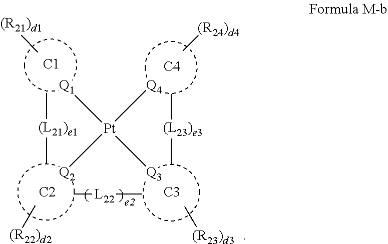

In Formula M-b above, Q₁ to Q₄ may each independently be C or N, C1 to C4 may each independently be a substituted or unsubstituted hydrocarbon ring group having 5 to 30 ring-forming carbon atoms, or a substituted or unsubstituted heterocycle having 2 to 30 ring-forming carbon atoms, L₂₁ to L₂₃ may each independently be a direct linkage,

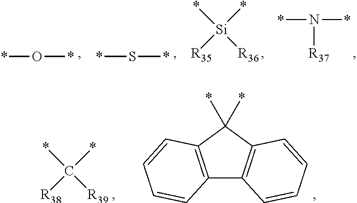

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, d1 to d4 may each independently be an integer from 0 to 4, e1 to e3 may each independently be 0 or 1, and R₂₁ to R₂₄, and R₃₅ to R₃₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

In an embodiment, the at least one functional layer may include an emission layer, a hole transport region between the first electrode and the emission layer, and an electron transport region between the emission layer and the second electrode, wherein the emission layer may include the first compound, and at least one of the second compound, the third compound, or the fourth compound.

In an embodiment, the emission layer may emit delayed fluorescence.

In an embodiment, the emission layer may emit light having a maximum emission wavelength of about 430 nm to about 490 nm.

In an embodiment, the at least one functional layer may include the first compound, the second compound, and the third compound.

In an embodiment, the at least one functional layer may include the first compound, the second compound, the third compound, and the fourth compound.

In an embodiment, the first compound represented by Formula 1 above may be represented by any one among Formulas 1-1a to 1-1e.

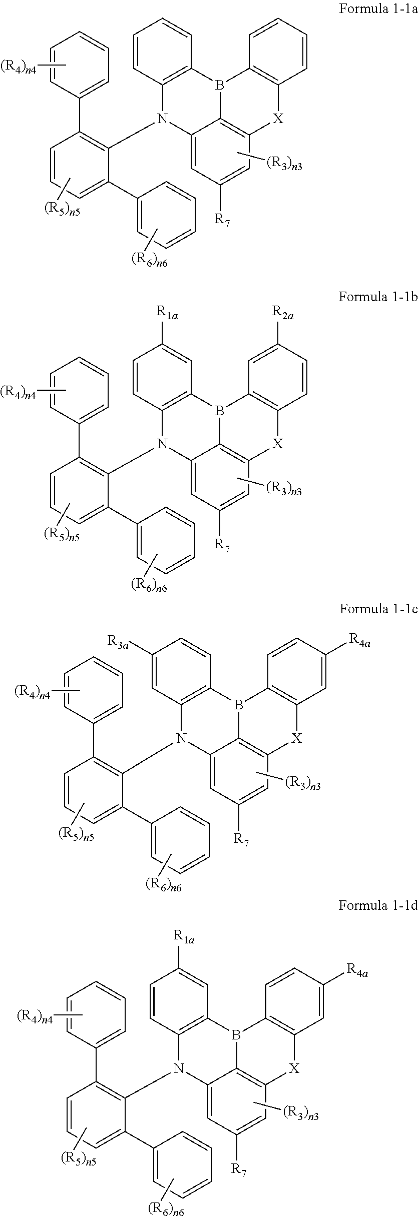

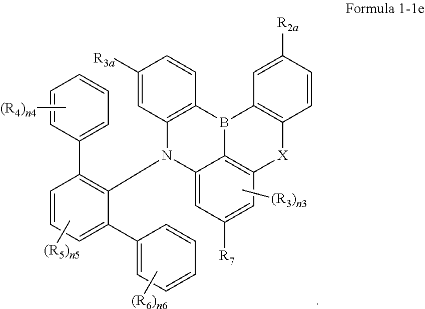

In Formulas 1-1a to 1-1e, R₁ₐ to R₄ₐ may each independently be a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and R₃ to R₇, X, and n3 to n6 may each independently be the same as defined in Formula 1.

In an embodiment, R₁ₐ to R₄ₐ may each independently be a substituted or unsubstituted diphenylamine group, a substituted or unsubstituted phenyl group, or a substituted or unsubstituted carbazole group.

In an embodiment, R₁ and R₂ may each independently be a hydrogen atom, a substituted or unsubstituted diphenylamine group, a substituted or unsubstituted phenyl group, or a substituted or unsubstituted carbazole group.

In an embodiment, R₃ may be a hydrogen atom.

In an embodiment, R₄ and R₆ may each independently be a hydrogen atom, a deuterium atom, a halogen atom, a cyano group, and/or bonded to an adjacent group to form a ring.

In an embodiment, R₅ may be a hydrogen atom.

In an embodiment, R₇ may be a hydrogen atom, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted carbazole group, a substituted or unsubstituted dibenzofuran group, a substituted or unsubstituted dibenzothiophene group, or a substituted or unsubstituted dibenzoselenophene group.

In an embodiment, R₈ to Ru may each independently be a substituted or unsubstituted phenyl group, and/or bonded to an adjacent group to form an aromatic ring.

In an embodiment of the present disclosure, a light emitting element includes a first electrode, a second electrode on the first electrode, and an emission layer between the first electrode and the second electrode and including a polycyclic compound represented by Formula 1.

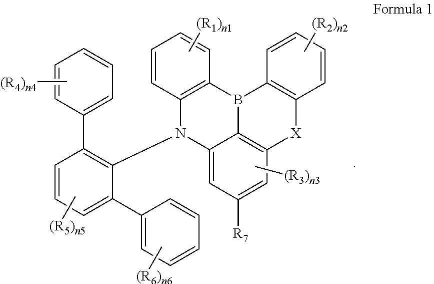

In Formula 1, X may be CR₈R₉ or SiR₁₀R₁₁, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, R₈ to R₁₁ may each independently be a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring, n1 and n2 may each independently be an integer from 0 to 4, n3 is an integer from 0 to 2, n4 is an integer from 0 to 5, n5 is an integer from 0 to 3, and n6 is an integer from 0 to 5.

In an embodiment of the present disclosure, a polycyclic compound may be represented by Formula 1.

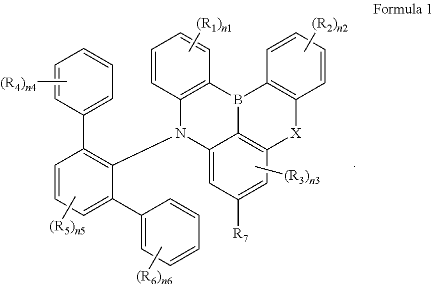

In Formula 1, X may be CR₈R₉ or SiR₁₀R₁₁, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, R₈ to R₁₁ may each independently be a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring, n1 and n2 may each independently be an integer from 0 to 4, n3 may be an integer from 0 to 2, n4 may be an integer from 0 to 5, n5 may be an integer from 0 to 3, and n6 may be an integer from 0 to 5.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view of a display device according to an embodiment;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view of a display device according to an embodiment;

FIG. 8 is a cross-sectional view of a display device according to an embodiment;

FIG. 9 is a cross-sectional view showing a display device according to an embodiment; and

FIG. 10 is a cross-sectional view showing a display device according to an embodiment.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In describing the drawings, like reference numerals are utilized for like elements. In the drawings, the sizes of elements may be exaggerated for clarity. It will be understood that, although the terms “first”, “second”, etc. may be utilized herein to describe one or more suitable elements, these elements should not be limited by these terms. These terms are only utilized to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise. As used herein, the singular forms “a”, “an” and “the” are intended to include the plural forms as well, unless the context clearly indicates otherwise.

In the present disclosure, it should be understood that the terms “comprise”, “include”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

In the present disclosure, it should be understood that when an element such as a layer, a film, a region, or a substrate is referred to as being “on” or “above” another element, it may be “directly on” the other element or intervening elements may also be present. In contrast, it should be understood that when an element such as a layer, a film, a region, or a substrate is referred to as being “beneath” or “under” another element, it may be “directly under” the other element or intervening elements may also be present. In some embodiments, in the present disclosure, it should be understood that when an element is referred to as being “on”, it may be as being “above” or “under” the other element.

In the present disclosure, the term “substituted or unsubstituted” may indicate that one is substituted or unsubstituted with at least one substituent selected from the group including (e.g., consisting of) a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or as a phenyl group substituted with a phenyl group.

In the present disclosure, the term “linked to an adjacent group to form a ring” may indicate that one is linked to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In some embodiments, the rings formed by being linked to each other may be connected to another ring to form a spiro structure.

In the present disclosure, the term “an adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In some embodiments, two methyl groups in 4,5-dimethylphenanthrene may be interpreted as mutually “adjacent groups”.

In the present disclosure, examples of a halogen atom may include a fluorine atom, a chlorine atom, a bromine atom, and an iodine atom.

In the present disclosure, an alkyl group may be a linear, branched or cyclic type or kind. The number of carbon atoms in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but are not limited thereto.

In the present disclosure, an alkenyl group refers to a hydrocarbon group including at least one carbon double bond in the middle (i.e., not on the end/terminus) or end of an alkyl group having 2 or more carbon atoms. The alkenyl group may be linear or branched. The number of carbon atoms is not limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but are not limited thereto.

In the present disclosure, an alkynyl group refers to a hydrocarbon group including at least one carbon triple bond in the middle (i.e., not on the end/terminus) or end of an alkyl group having 2 or more carbon atoms. The alkynyl group may be linear or branched. The number of carbon atoms is not limited, but may be 2 to 30, 2 to 20, or 2 to 10. Examples of the alkynyl group may include an ethynyl group, a propynyl group, etc., but are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the present disclosure, a fluorenyl group may be substituted, and two substituents may be bonded to each other to form a spiro structure. An example that the fluorenyl group is substituted is as follows. However, the embodiment of the present disclosure is not limited thereto.

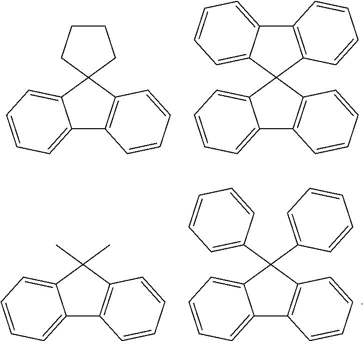

In the present disclosure, a heterocyclic group refers to any functional group or substituent derived from a ring containing at least one of B, O, N, P, Si, S, or Se as a hetero atom. The heterocyclic group may include an aliphatic heterocyclic group and/or an aromatic heterocyclic group. The aromatic heterocyclic group may be a heteroaryl group. The aliphatic heterocycle and the aromatic heterocycle may be monocyclic or polycyclic.

When the heterocyclic group contains two or more hetero atoms, the two or more hetero atoms may be the same as or different from each other. In the present disclosure, the heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the present disclosure, the aliphatic heterocyclic group may contain at least one of B, O, N, P, Si, S, or Se as a hetero atom. The number of ring-forming carbon atoms in the aliphatic heterocyclic group may be 2 to 30, 2 to 20, or 2 to 10. Examples of the aliphatic heterocyclic group include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but are not limited to thereto

In the present disclosure, the heteroaryl group may contain at least one of B, O, N, P, Si, S, or Se as a hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but are not limited thereto.

In the present disclosure, the above description of the aryl group may be applied to an arylene group, except that the arylene group is a divalent group. The above description of the heteroaryl group may be applied to a heteroarylene group, except that the heteroarylene group is a divalent group.

In the present disclosure, the boron group includes an alkyl boron group and/or an aryl boron group. Examples of the boron group include a dimethyl boron group, a diethyl boron group, a t-butylmethyl boron group, a diphenyl boron group, a phenyl boron group, etc., but are not limited thereto. For example, the alkyl group in the alkyl boron group is the same as the examples of the alkyl group described above, and the aryl group in the aryl boron group is the same as the examples of the aryl group described above.

In the present disclosure, a silyl group includes an alkyl silyl group and/or an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but are not limited thereto.

In the present disclosure, the number of carbon atoms in a carbonyl group is not limited, but may be 1 to 40, 1 to 30, or 1 to 20. For example, the carbonyl group may have the following structure, but is not limited thereto.

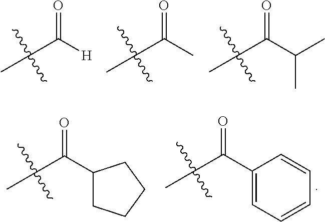

In the present disclosure, the number of carbon atoms in a sulfinyl group and/or a sulfonyl group is not limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkyl thio group and/or an aryl thio group. The thio group may refer to a sulfur atom that is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but are not limited to thereto.

In the present disclosure, an oxy group may refer to an oxygen atom that is bonded to an alkyl group or aryl group as defined above. The oxy group may include an alkoxy group and/or an aryl oxy group. The alkoxy group may be linear, branched or cyclic. The number of carbon atoms in the alkoxy group is not limited, but may be, for example, 1 to 20, or 1 to 10. Examples of the oxy group include methoxy, ethoxy, n-propoxy, isopropoxy, butoxy, pentyloxy, hexyloxy, octyloxy, nonyloxy, decyloxy, benzyloxy, etc., but are not limited thereto.

In the present disclosure, the number of carbon atoms in an amine group is not limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, etc., but are not limited thereto.

In the present disclosure, examples of the alkyl group include an alkylthio group, an alkyl sulfoxy group, an alkylaryl group, an alkylamino group, an alkyl boron group, an alkyl silyl group, and/or an alkyl amine group.

In the present disclosure, examples of the aryl group include an aryloxy group, an arylthio group, an aryl sulfoxy group, an arylamino group, an aryl boron group, an aryl silyl group, and/or an aryl amine group.

In the present disclosure, a direct linkage may refer to a single bond.

In some embodiments, in the present disclosure,

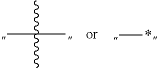

refers to a site to be connected.

Hereinafter, embodiments of the present disclosure will be described with reference to the accompanying drawings.

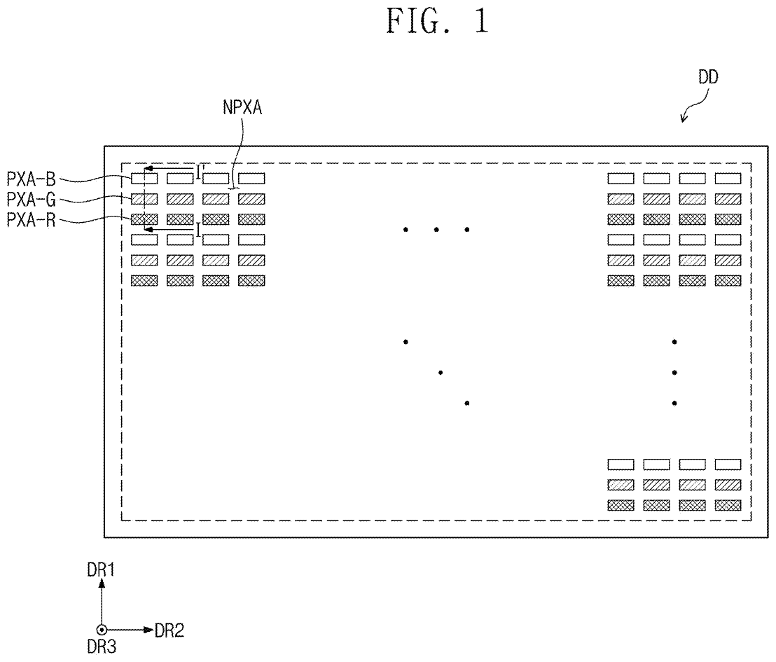

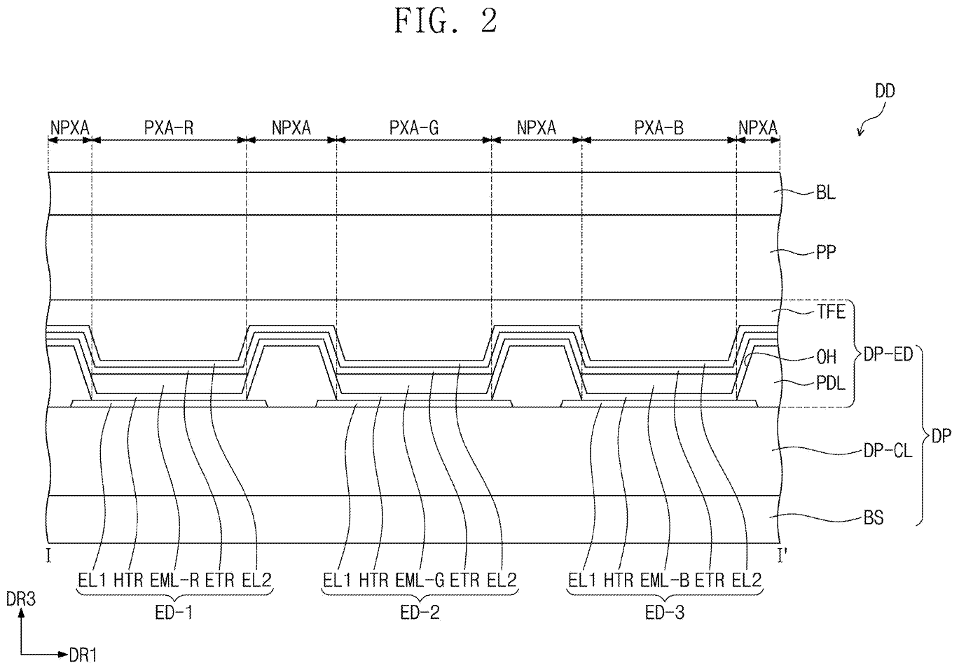

FIG. 1 is a plan view showing an embodiment of a display device DD. FIG. 2 is a cross-sectional view of a display device DD of an embodiment. FIG. 2 is a cross-sectional view showing a portion corresponding to line I-I′ of FIG. 1.

The display device DD may include a display panel DP and an optical layer PP on the display panel DP. The display panel DP includes light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarizing layer or a color filter layer. In some embodiments, the optical layer PP may not be provided in the display device DD.

A base substrate BL may be on the optical layer PP. The base substrate BL may be a member providing a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one selected from among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE on the plurality of light emitting elements ED-1, ED-2, and ED-3.

The base layer BS may be a member providing a base surface in which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

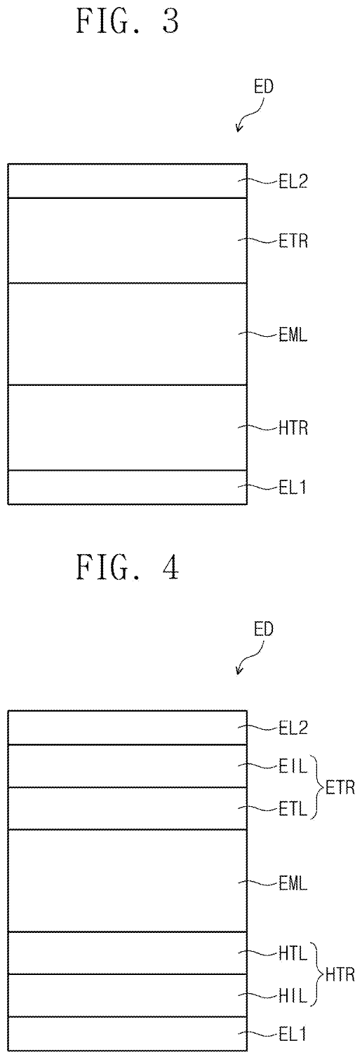

The light emitting elements ED-1, ED-2, and ED-3 may each have a structure of a light emitting element ED of an embodiment of FIGS. 3 to 6, which will be described in more detail. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided as a common layer throughout the light emitting elements ED-1, ED-2, and ED-3. However, the embodiment of the present disclosure is not limited thereto, and in an embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, and the electron transport region ETR, etc., of the light emitting elements ED-1, ED-2, and ED-3 may be patterned and provided through an inkjet printing method.

An encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be a single layer or a laminated layer of a plurality of layers. The encapsulation layer TFE includes at least one insulating layer. The encapsulation layer TFE according to an embodiment may include at least one inorganic film (hereinafter, an encapsulation inorganic film). In some embodiments, the encapsulation layer TFE according to an embodiment may include at least one organic film (hereinafter, an encapsulation organic film) and at least one encapsulation inorganic film.

The encapsulation inorganic film protects (or reduces exposure to moisture/oxygen) the display element layer DP-ED from moisture/oxygen, and the encapsulation organic film protects (or reduces exposure to foreign substances) the display element layer DP-ED from foreign substances such as dust particles. The encapsulation inorganic film may include silicon nitride, silicon oxy nitride, silicon oxide, titanium oxide, aluminum oxide, etc., but is not limited thereto. The encapsulation organic layer may include an acrylic compound, an epoxy-based compound, etc. The encapsulation organic layer may include a photopolymerizable organic material, but is not limited thereto.

The encapsulation layer TFE may be on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from a corresponding one of the light emitting elements ED-1, ED-2, and ED-3. The light emitting regions PXA-R, PXA-G, and PXA-B may be spaced apart from (separated from) each other when viewed on a plane (e.g., in a plan view).

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In some embodiments, in the present disclosure, the light emitting regions PXA-R, PXA-G, and PXA-B may each correspond to a pixel. The pixel defining films PDL may separate the light emitting elements ED-1, ED-2 and ED-3. The emission layers EML-R, EML-G, and EML-B of the light emitting elements ED-1, ED-2 and ED-3 may be disposed and separated in openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are presented as an example. For example, the display device DD of an embodiment may include a red light emitting region PXA-R, a green light emitting region PXA-G, and a blue light emitting region PXA-B, which are distinct from one another.

In the display device DD according to an embodiment, the plurality of light emitting elements ED-1, ED-2, and ED-3 may emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2 and ED-3 may be to emit light in substantially the same wavelength range or emit light in at least one different wavelength range. For example, the first to third light emitting elements ED-1, ED-2, and ED-3 all may be to emit blue light.

The light emitting regions PXA-R, PXA-G, and PXA-B in the display device DD according to an embodiment may be arranged in the form of a stripe. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may each be arranged with each other along the second direction axis DR2. In some embodiments, the red light emitting region PXA-R, the green light emitting region PXA-G, and the blue light emitting region PXA-B may be alternately arranged in turn along a first direction axis DR1. (DR3 is a third direction which is normal or perpendicular to the plane defined by the first direction DR1 and the second direction DR2).

FIGS. 1 and 2 show that the light emitting regions PXA-R, PXA-G, and PXA-B are all similar in size, but the embodiment of the present disclosure is not limited thereto, and the light emitting regions PXA-R, PXA-G and PXA-B may be different in size from each other according to wavelength range of emitted light. In some embodiments, the areas of the light emitting regions PXA-R, PXA-G, and PXA-B may refer to areas when viewed on a plane defined by the first direction axis DR1 and the second direction axis DR2 (e.g., when viewed in a plan view).

In some embodiments, the arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged with one or more suitable combinations according to display quality characteristics required for the display device DD. For example, the light emitting regions PXA-R, PXA-G, and PXA-B may be arranged in the form of a pentile (PENTILE®) (for example, an RGBG matrix, an RGBG structure, or RGBG matrix structure) or a diamond (Diamond Pixel™) (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung Display Co., Ltd.

In some embodiments, areas of each of the light emitting regions PXA-R, PXA-G, and PXA-B may be different in size from one another. For example, in an embodiment, the green light emitting region PXA-G may be smaller than the blue light emitting region PXA-B in size, but the embodiment of the present disclosure is not limited thereto.

In the display device DD according to an embodiment which is shown in FIG. 2, at least one of the first to third light emitting elements ED-1, ED-2, and ED-3 may include a polycyclic compound according to an embodiment.

Hereinafter, FIGS. 3 to 6 are cross-sectional views schematically showing a light emitting element according to an embodiment. The light emitting element ED according to an embodiment may include a first electrode EL1, a second electrode EL2 facing the first electrode EL1, and at least one functional layer between the first electrode EU and the second electrode EL2. The light emitting element ED of an embodiment may include a polycyclic compound of an embodiment, which will be described in more detail, in at least one functional layer. In some embodiments, the polycyclic compound of an embodiment may be referred to as a first compound herein.

The light emitting element ED may include a hole transport region HTR, an emission layer EML, and an electron transport region ETR, which are sequentially stacked (in the sated order), as at least one functional layer. Referring to FIG. 3, the light emitting element ED according to an embodiment may include a first electrode EL1, a hole transport region HTR, an emission layer EML, an electron transport region ETR, and a second electrode EL2. In some embodiments, the light emitting element ED according to an embodiment may include a polycyclic compound of an embodiment, which will be described in more detail, in the emission layer EML.

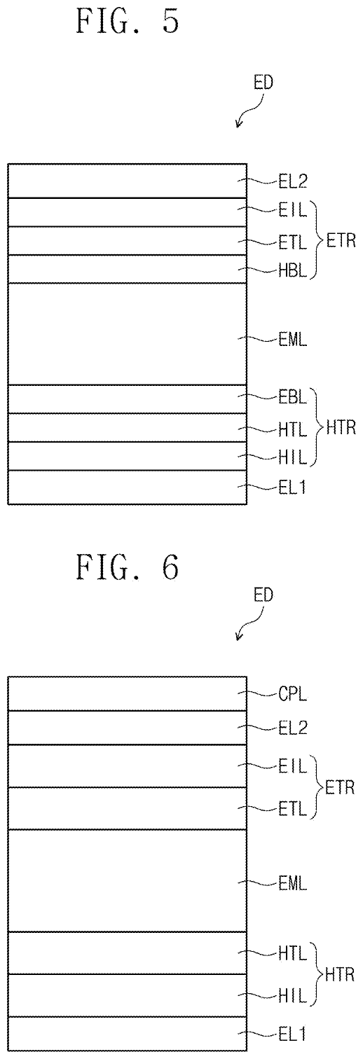

FIG. 4 shows, compared with FIG. 3, a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In some embodiments, FIG. 5 shows, compared with FIG. 3, a cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 4, a cross-sectional view of a light emitting element ED of an embodiment, in which a capping layer CPL on the second electrode EL2 is provided.

In an embodiment, the emission layer EML may include a first compound containing: a fused ring having carbon atoms, silicon atoms, boron atoms, and nitrogen atoms as ring-forming atoms; and a terphenyl group connected to the fused ring. In some embodiments, the emission layer EML may include at least one of a second compound, a third compound, or a fourth compound. The second compound may include a substituted or unsubstituted carbazole. The third compound may include a hexagonal ring containing at least one nitrogen atom as a ring-forming atom. The fourth compound may be a compound containing platinum.

In the light emitting element ED according to an embodiment, the first electrode EU has conductivity (e.g., is a conductor). The first electrode EL1 may be formed of a metal material, a metal alloy or a conductive compound. The first electrode EU may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or one or more oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EU is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, one or more compounds thereof, or one or more mixtures thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but is not limited thereto. For example, the first electrode EL1 may include the above-described metal materials, a combination of two or more metal materials selected from the above-described metal materials, or one or more oxides of the above-described metal materials. The first electrode EU may have a thickness of about 700 Å to about 10000 Å. For example, the first electrode EL1 may have a thickness of 1000 Å to about 3000 Å.

The hole transport region HTR is provided on the first electrode EL1. The hole transport region HTR may have a single layer formed of a single material, a single layer formed of a plurality of different materials, or a multilayer structure having a plurality of layers formed of a plurality of different materials.

The hole transport region HTR may include at least one selected from among a hole injection layer HIL, a hole transport layer HTL, and an electron blocking layer EBL. In some embodiments, the hole transport region HTR may include a plurality of hole transport layers that are stacked.

In some embodiments, alternatively, the hole transport region HTR may have a single-layer structure formed of the hole injection layer HIL or the hole transport layer HTL, or a single-layer structure formed of a hole injection material or a hole transport material. In an embodiment, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, or a hole transport layer HTL/buffer layer are stacked in order from the first electrode EL1, but the embodiment of the present disclosure is not limited thereto.

The hole transport region HTR may have, for example, a thickness of about 50 Å to about 15000 Å. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

In the light emitting element ED according to an embodiment, the hole transport region HTR may include a compound represented by Formula H-1.

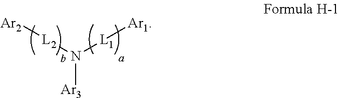

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer from 0 to 10. In some embodiments, when a or b is an integer of 2 or greater, a plurality of Lis and Les may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may each independently be a substituted or unsubstituted aryl group having 6 to 30 ring-forming carbon atoms.

A compound represented by Formula H-1 may be a monoamine compound. In some embodiments, the compound represented by Formula H-1 may be a diamine compound in which at least one of Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂ or a substituted or unsubstituted fluorene-based group in at least one of Ar₁ or Ar₂.

The compound represented by Formula H-1 may be represented by any one selected from among compounds from Compound Group H. However, the compounds listed in Compound Group H are presented merely as an example, and the compound represented by Formula H-1 is not limited to the those listed in Compound Group H.

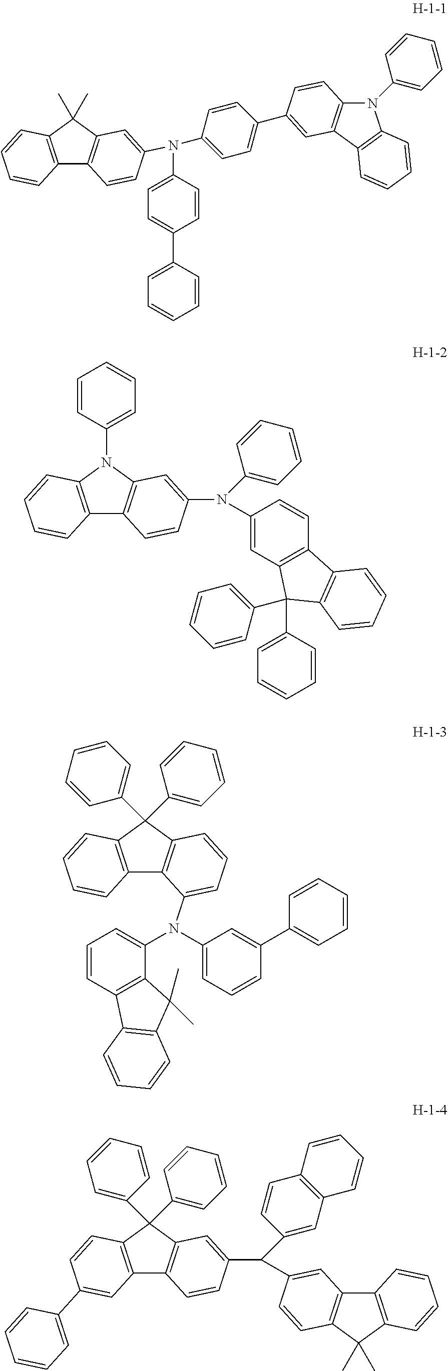

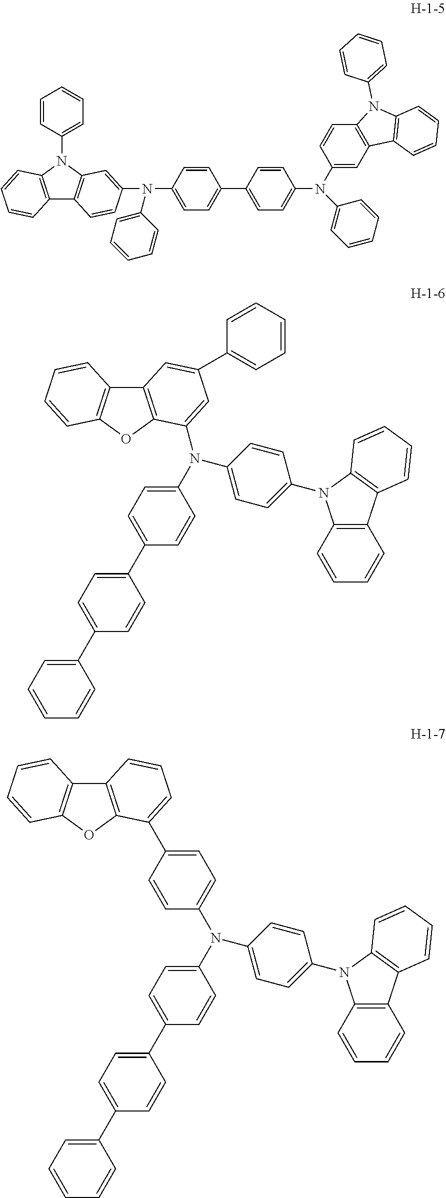

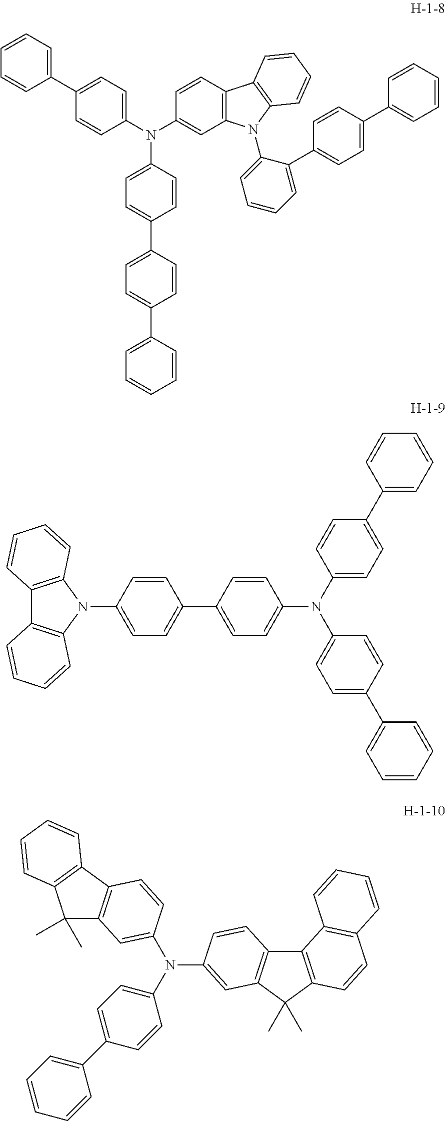 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

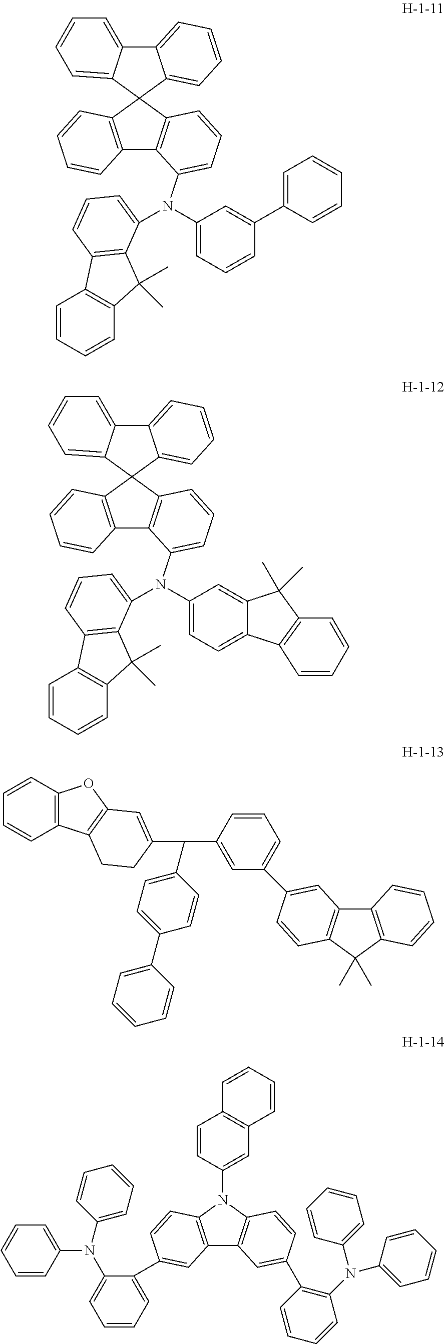

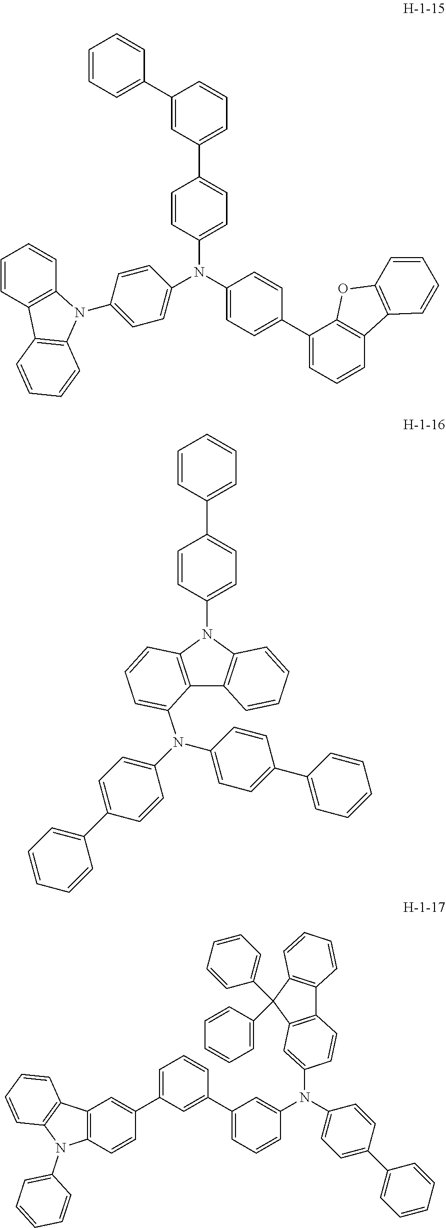 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

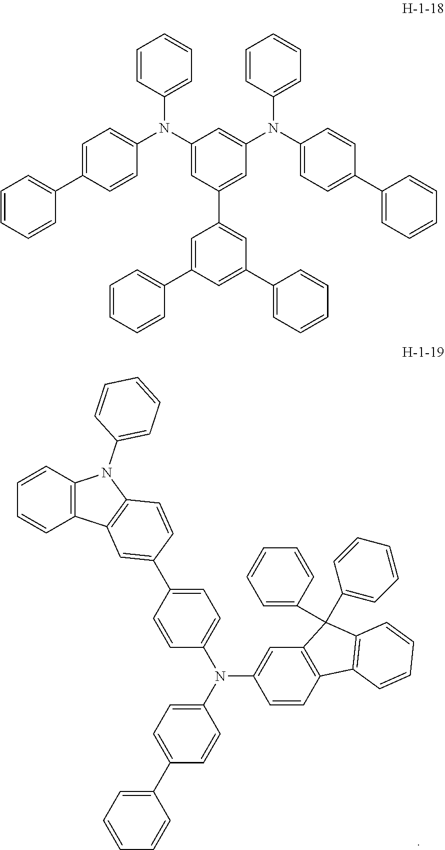

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), 20 polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB or NPD, α-NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HATCN), etc.

The hole transport region HTR may include carbazole-based derivatives such as N-phenyl carbazole and polyvinyl carbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region described above in at least one selected from among the hole injection layer HIL, the hole transport layer HTL, and the electron blocking layer EBL.

The hole transport region HTR may have a thickness of about 100 Å to about 10000 Å, for example, about 100 Å to about 5000 Å. When the hole transport region HTR includes the hole injection layer HIL, the hole injection layer HIL may have a thickness of, for example, about 30 Å to about 1000 Å. When the hole transport region HTR includes the hole transport layer HTL, the hole transport layer HTL may have a thickness of about 30 Å to about 1000 Å. When the hole transport region HTR includes the electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory (suitable) hole transport properties may be obtained without a substantial increase in driving voltage.

The hole transport region HTR may further include, in addition to the above-described materials, a charge generation material to increase conductivity. The charge generation material may be substantially uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but is not limited thereto. For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f:2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but is not limited thereto.

As described above, the hole transport region HTR may further include at least one of a buffer layer or an electron blocking layer EBL in addition to the hole injection layer HIL and the hole transport layer HTL. The buffer layer may compensate for a resonance distance according to wavelengths of light emitted from an emission layer EML, and may thus increase light emitting efficiency. Materials which may be included in the hole transport region HTR may be utilized as materials included in the buffer layer. The electron blocking layer EBL is a layer that serves to prevent or reduce electrons from being injected from the electron transport region ETR to the hole transport region HTR.

The emission layer EML is provided on the hole transport region HTR. The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

In an embodiment, the emission layer EML may include a first compound represented by Formula 1. The first compound corresponds to a polycyclic compound according to an embodiment.

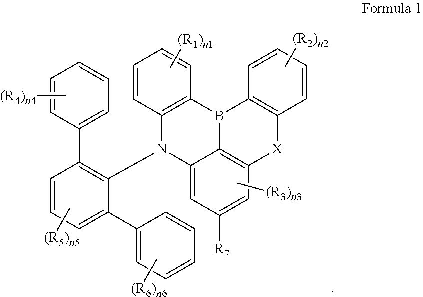

In Formula 1, X may be CR₈R₉ or SiR₁₀R₁₁. For example, the polycyclic compound of the present disclosure includes a C—C bond or a C—Si bond in molecules which may cause an increase in bond dissociation energy (BDE) of the molecules, resulting in greater material stability. When the polycyclic compound of the present disclosure is applied to a light emitting element, the element may have an increased lifespan and an increased luminous efficiency.

The polycyclic compound of the present disclosure includes CR₈R₉ or SiR₁₀R₁₁ in the skeleton of a fused ring containing boron atoms to increase intermolecular distance and reduce intermolecular interactions, resulting in greater material stability and thermal stability.

R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,

For example, R₁ and R₂ may each independently be a hydrogen atom, a substituted or unsubstituted diphenylamine group, a substituted or unsubstituted phenyl group, or a substituted or unsubstituted carbazole group.

For example, R₃ may be a hydrogen atom.

For example, R₄ and R₆ may each independently be a hydrogen atom, a deuterium atom, a halogen atom, a cyano group, and/or bonded to an adjacent group to form a ring. For example, when R₄ and R₆ may each independently be a halogen atom, R₄ and R₆ may each be a fluorine atom. For example, when R₄ and R₆ may each independently be bonded to an adjacent group to form a ring, R₄ and R₆ may each independently be bonded to an adjacent group to form substituted or unsubstituted naphthalene. However, the embodiment of the present disclosure is not limited thereto.

For example, R₅ may be a hydrogen atom. However, the embodiment of the present disclosure is not limited thereto.

For example, R₇ may be a hydrogen atom, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted carbazole group, a substituted or unsubstituted dibenzofuran group, a substituted or unsubstituted dibenzothiophene group, or a substituted or unsubstituted dibenzoselenophene group.

R₈ to R₁₁ may each independently be a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring. For example, R₈ to R₁₁ may each independently be a substituted or unsubstituted phenyl group, and for example, may be an unsubstituted phenyl group. For example, R₈ to R₁₁ may each independently be bonded to an adjacent group to form an aromatic ring and may for example, form substituted or unsubstituted fluorene. However, the embodiment of the present disclosure is not limited thereto.

In the polycyclic compound of the present disclosure, R₈ to R₁₁ may each independently be a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring to increase intermolecular distance and reduce intermolecular interactions, resulting in greater thermal stability.

n1 and n2 may each independently be an integer from 0 to 4. For example, n1 and n2 may each independently be 0 or 1. The embodiment in which n1 is 0 may be the same as the embodiment in which n1 is 4 and R₁ is a hydrogen atom. When n1 is 0, it may be understood that R₁ is not substituted in the polycyclic compound represented by Formula 1. The embodiment in which n2 is 0 may be the same as the embodiment in which n2 is 4 and R₂ is a hydrogen atom. When n2 is 0, it may be understood that R₂ is not substituted in the polycyclic compound represented by Formula 1.

n3 is an integer of 0 to 2. For example, n3 may be 0. The embodiment in which n3 is 0 may be the same as the embodiment in which n3 is 2 and R₃ is a hydrogen atom. When n3 is 0, it may be understood that R₃ is not substituted in the polycyclic compound represented by Formula 1.

n4 is an integer from 0 to 5. For example, n4 may be 0, 1, or 2. The embodiment in which n4 is 0 may be the same as the embodiment in which n4 is 5 and R₄ is a hydrogen atom. When n4 is 0, it may be understood that R₄ is not substituted in the polycyclic compound represented by Formula 1. When n4 is 2, two R₄s may be bonded to each other to form an aromatic ring.

n5 may be an integer from 0 to 3. For example, n5 may be 0. The embodiment in which n5 is 0 may be the same as the embodiment in which n5 is 3 and R₅ is a hydrogen atom. When n5 is 0, it may be understood that R₅ is not substituted in the polycyclic compound represented by Formula 1.

n6 is an integer from 0 to 5. For example, n6 may be 0, 1, or 2. The embodiment in which n6 is 0 may be the same as the embodiment in which n6 is 5 and R₆ is a hydrogen atom. When n6 is 0, it may be understood that R₆ is not substituted in the polycyclic compound represented by Formula 1. When n4 is 2, two Res may be bonded to each other to form an aromatic ring.

In an embodiment, the first compound represented by Formula 1 above may be represented by any one selected from among Formulas 1-1a to 1-1e.

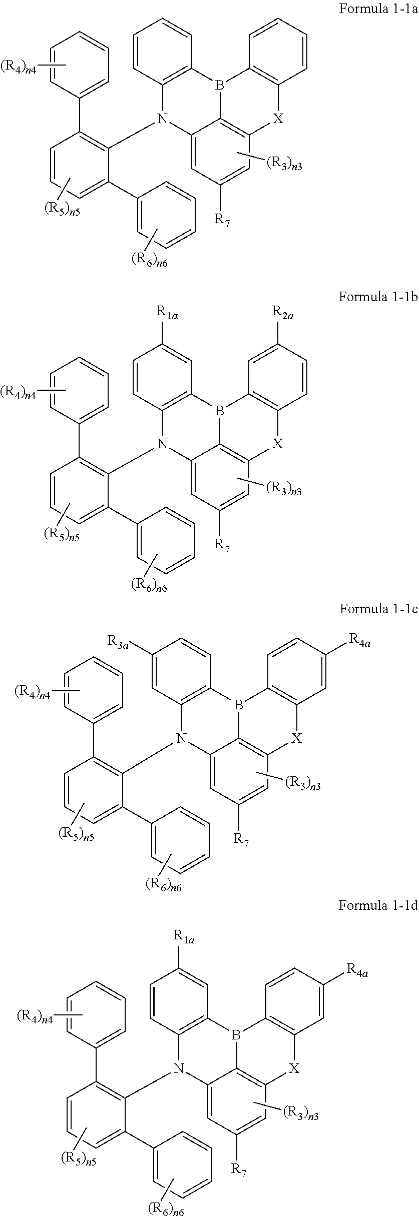

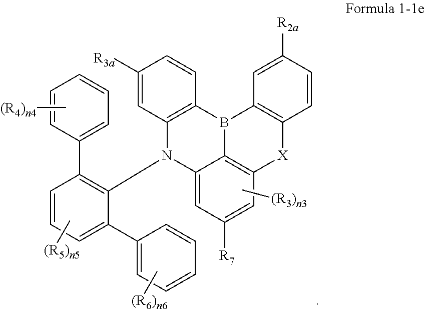

Each of Formulas 1-1a to 1-1 e indicates an embodiment in which in Formula 1, R₁ may be embodied as any one selected from among a hydrogen atom, R₁ₐ, and R₁ₐ, and R₂ may be embodied as any one selected from among a hydrogen atom, R₂ₐ, and R₄ₐ.

In Formulas 1-1a to 1-1e, R₁ₐ to R₄ₐ may each independently be a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, R₁ₐ to R₄ₐ may each independently be a substituted or unsubstituted diphenylamine group, a substituted or unsubstituted phenyl group, or a substituted or unsubstituted carbazole group. For example, R₁ₐ to R₄ₐ may each independently be an unsubstituted diphenylamine group, a diphenylamine group substituted with a t-butyl group, an unsubstituted phenyl group, a phenyl group substituted with a t-butyl group, an unsubstituted carbazole group, a carbazole group substituted with deuterium, or a carbazole group substituted with a t-butyl group. However, the embodiment of the present disclosure is not limited thereto.

In Formulas 1-1a to 1-1e, R₃ to R₇, X, and n3 to n6 may each independently be the same as defined in Formula 1.

In an embodiment, a polycyclic compound represented by Formula 1 may be represented by any one of Formula 2-1 or Formula 2-2.

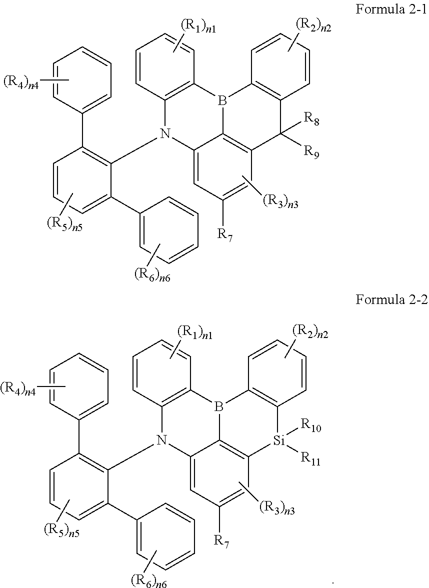

Formula 2-1 indicates an embodiment in which in Formula 1, X may be embodied as CR₈R₉, and Formula 2-2 indicates a embodiment in which in Formula 1, X may be embodied as SiR₁₀R₁₁.

In Formulas 2-1 and 2-2, R₁ to R₁₁, and n1 to n6 may each independently be the same as defined in Formula 1.

The polycyclic compound of the present disclosure, which is represented by Formula 1, may include a fused ring skeleton containing carbon atoms, silicon atoms, boron atoms, and nitrogen atoms, and an ortho-type or kind terphenyl group connected to the nitrogen atoms of the fused ring skeleton. The polycyclic compound of the present disclosure, which is represented by Formula 1, may include a C—C bond or a C—Si bond in molecules which may cause an increase in bond dissociation energy (BDE) of the molecules, resulting in greater molecular stability. When the polycyclic compound of the present disclosure is utilized as a thermally activated delayed fluorescence (TADF) dopant material, greater material stability may be obtained.

In some embodiments, the ortho-type or kind terphenyl group included in the polycyclic compound protects the p orbital of the boron atoms, thereby preventing or reducing the trigonal bonding structure of the boron atoms from being deformed as the p orbital of the boron atoms are combined with external nucleophiles. The deformation of the trigonal bonding structure of the boron atoms may cause deterioration of an element, but the polycyclic compound of the present disclosure includes the ortho-type or kind terphenyl group to prevent or reduce the element deterioration when applied to the element, and achieve greater lifespan of the element.

Compared to a polycyclic compound without an ortho-type or kind terphenyl group, the polycyclic compound of the present disclosure includes an ortho-type or kind terphenyl group to relatively increase intermolecular distance and relatively reduce intermolecular interactions such as intermolecular aggregation, excimer formation, and exciplex formation, which may cause a decrease in luminous efficiency. The prevention of intermolecular aggregation allows the processes of sublimation and purification of the polycyclic compound of the present disclosure to be easily performed, and ensures stability against thermal decomposition upon the processes of sublimation and purification.

The polycyclic compound of the present disclosure has an equal wavelength in the emission spectrum measured in a solution state and the emission spectrum measured in a deposition film state, and may thus exhibit high color purity when applied to an emission layer of an element.

A polycyclic compound according to an embodiment may be represented by any one selected from among compounds of Compound Group 1. In Compound Group 1, D may be a deuterium atom, and Ph may be a phenyl group.

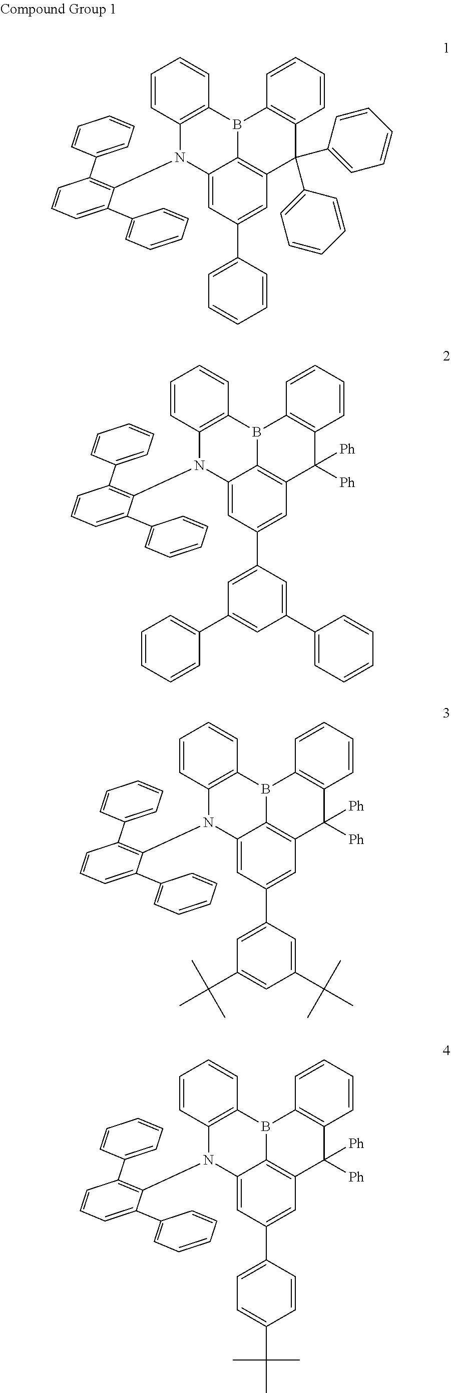

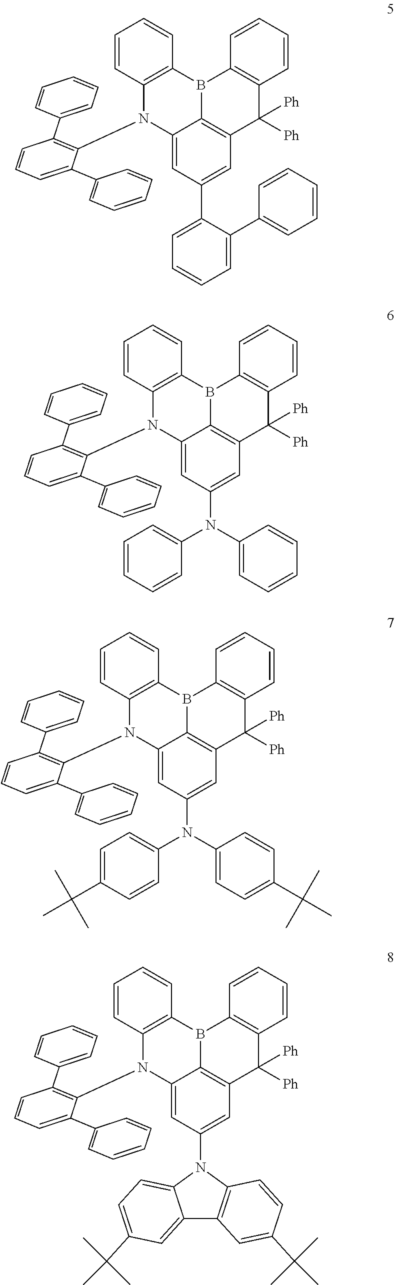 [SMILES: c1ccc(-c2ccccc2-c2cc3c4c(c2)C(c2ccccc2)(c2ccccc2)c2ccccc2B4c2ccccc2N3c2c(-c3ccccc3)cccc2-c2ccccc2)cc1 ; c1ccc(-c2cccc(-c3ccccc3)c2N2c3ccccc3B3c4ccccc4C(c4ccccc4)(c4ccccc4)c4cc(N(c5ccccc5)c5ccccc5)cc2c43)cc1 ; CC(C)(C)c1ccc(N(c2ccc(C(C)(C)C)cc2)c2cc3c4c(c2)C(c2ccccc2)(c2ccccc2)c2ccccc2B4c2ccccc2N3c2c(-c3ccccc3)cccc2-c2ccccc2)cc1 ; CC(C)(C)c1ccc2c(c1)c1cc(C(C)(C)C)ccc1n2-c1cc2c3c(c1)C(c1ccccc1)(c1ccccc1)c1ccccc1B3c1ccccc1N2c1c(-c2ccccc2)cccc1-c1ccccc1]

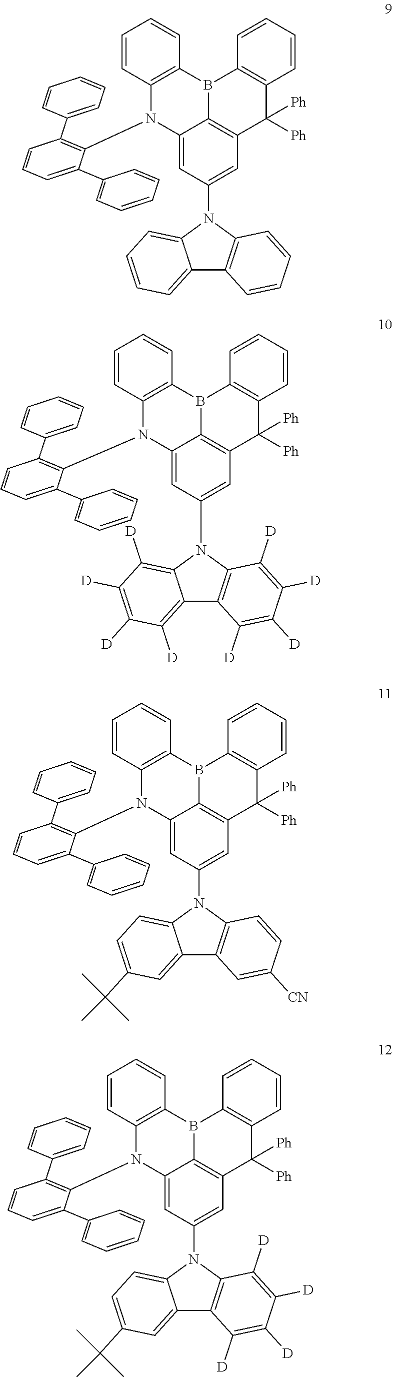

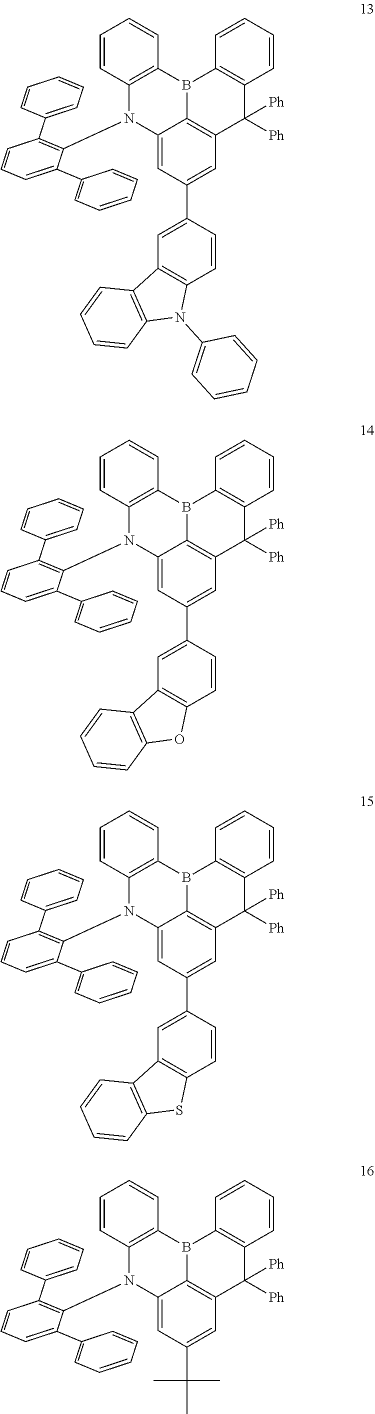

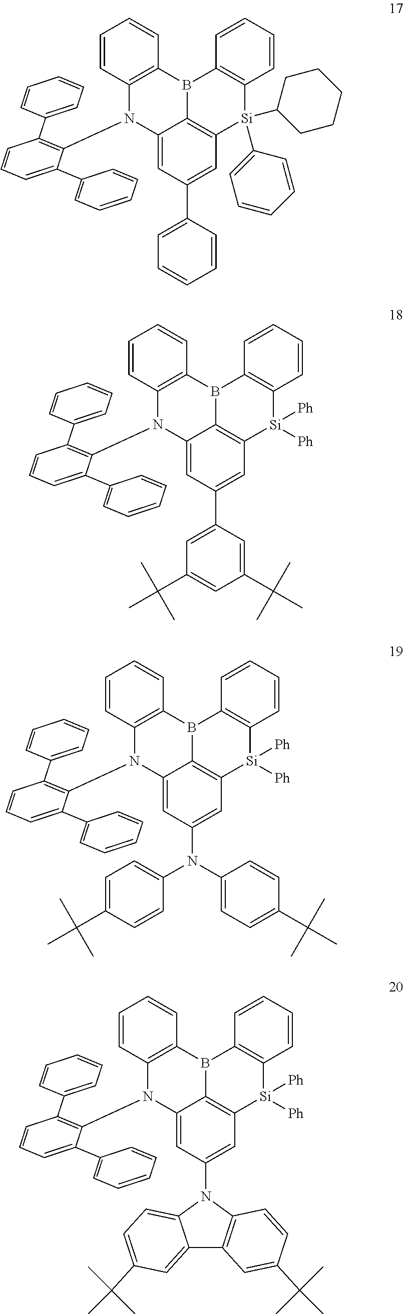

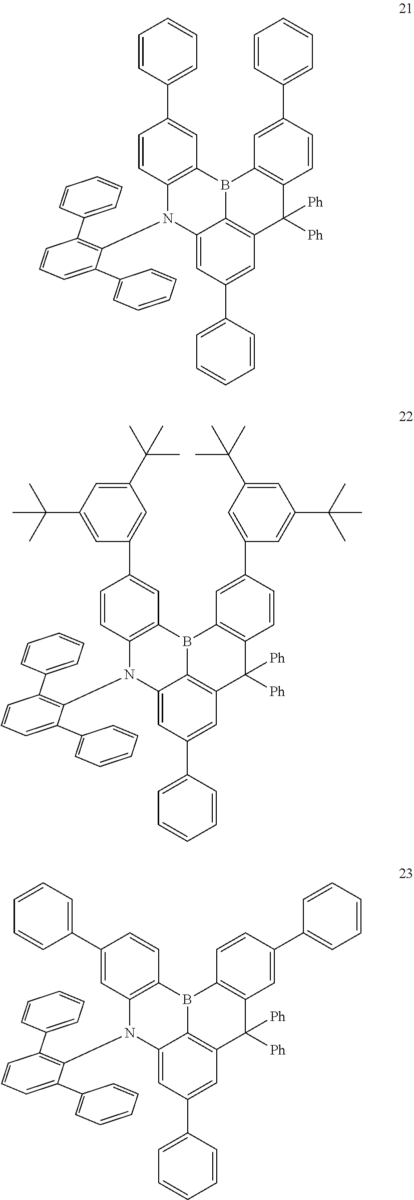

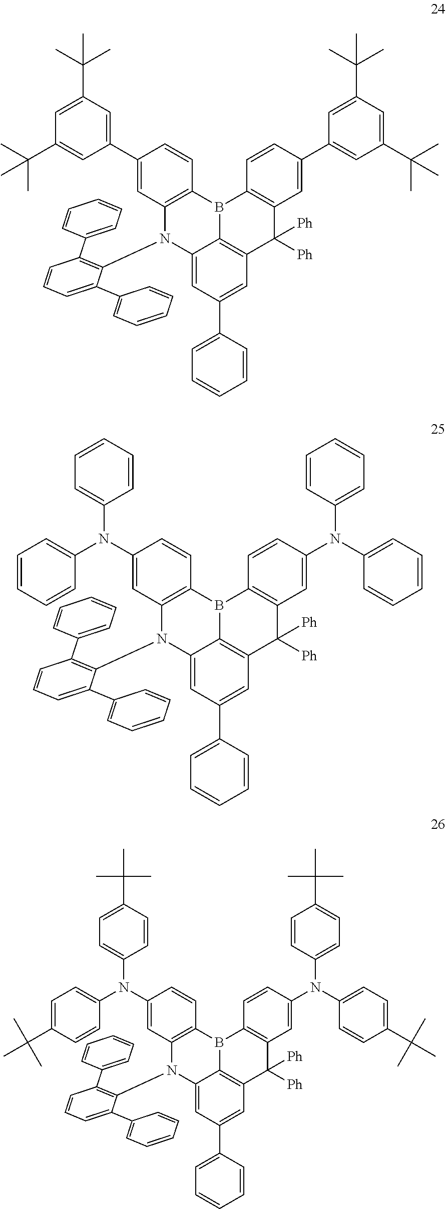

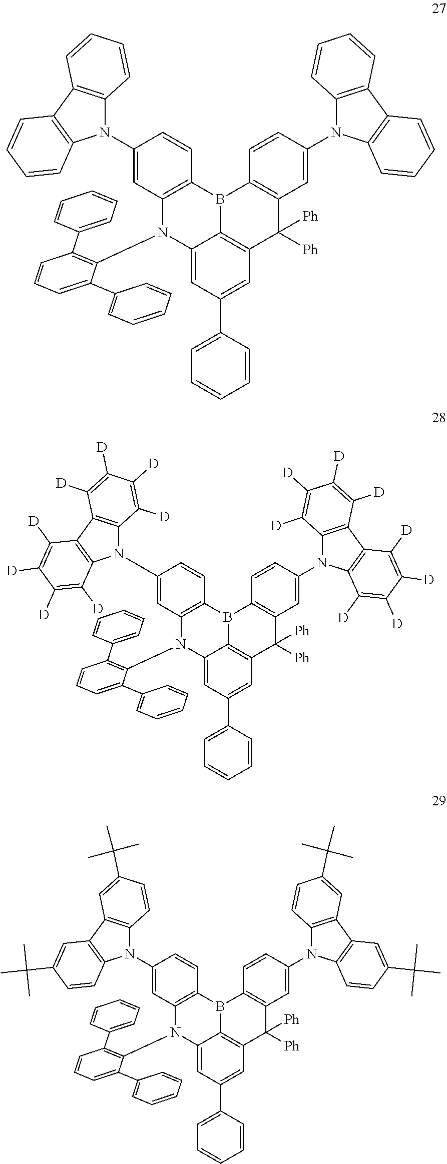

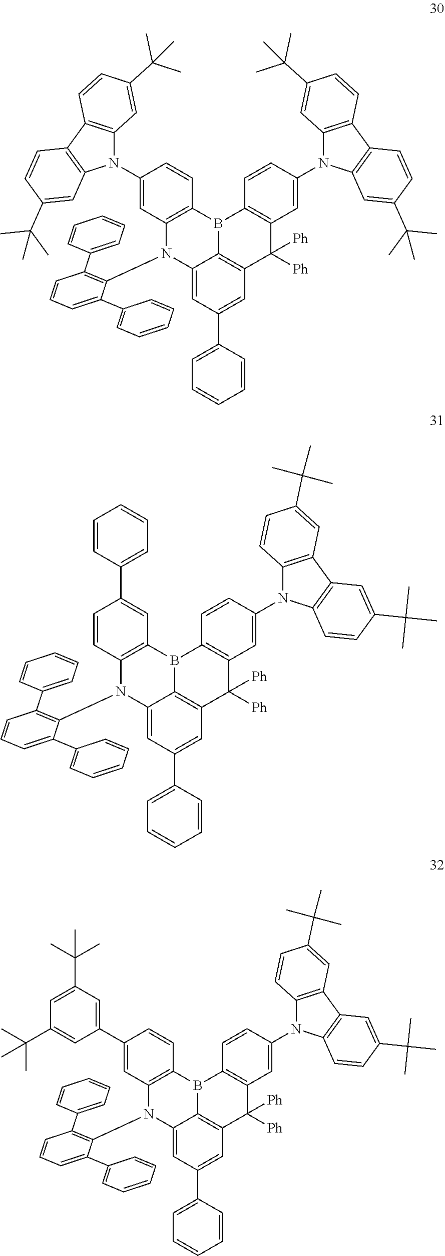

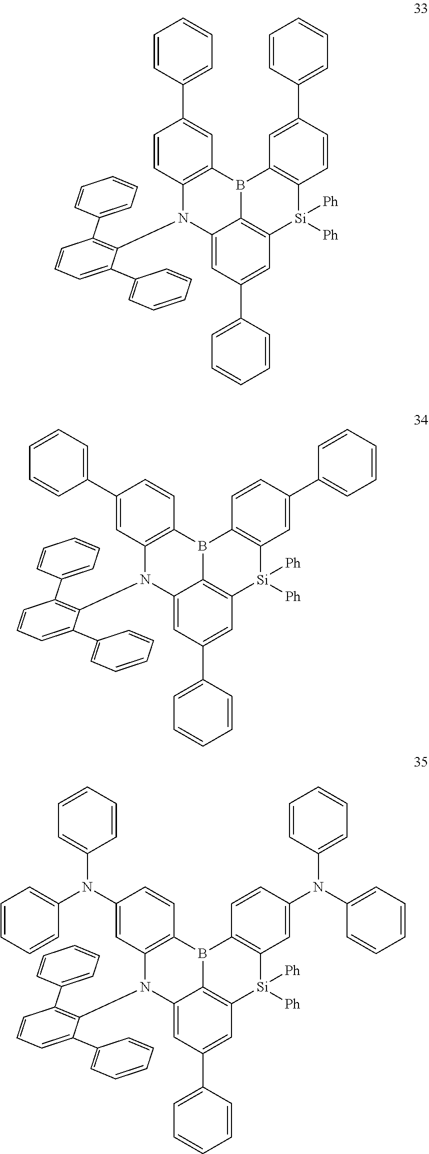 [SMILES: c1ccc(-c2ccc3c(c2)B2c4cc(-c5ccccc5)ccc4[Si](c4ccccc4)(c4ccccc4)c4cc(-c5ccccc5)cc(c42)N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc(-c3ccccc3)cc2[Si]4(c2ccccc2)c2ccccc2)cc1 ; c1ccc(-c2cc3c4c(c2)[Si](c2ccccc2)(c2ccccc2)c2cc(N(c5ccccc5)c5ccccc5)ccc2B4c2ccc(N(c4ccccc4)c4ccccc4)cc2N3c2c(-c3ccccc3)cccc2-c2ccccc2)cc1]

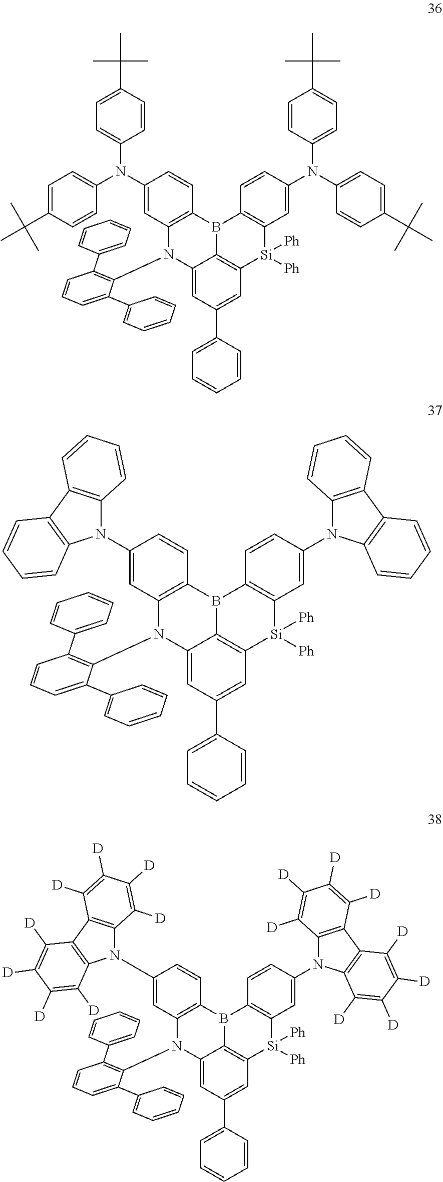

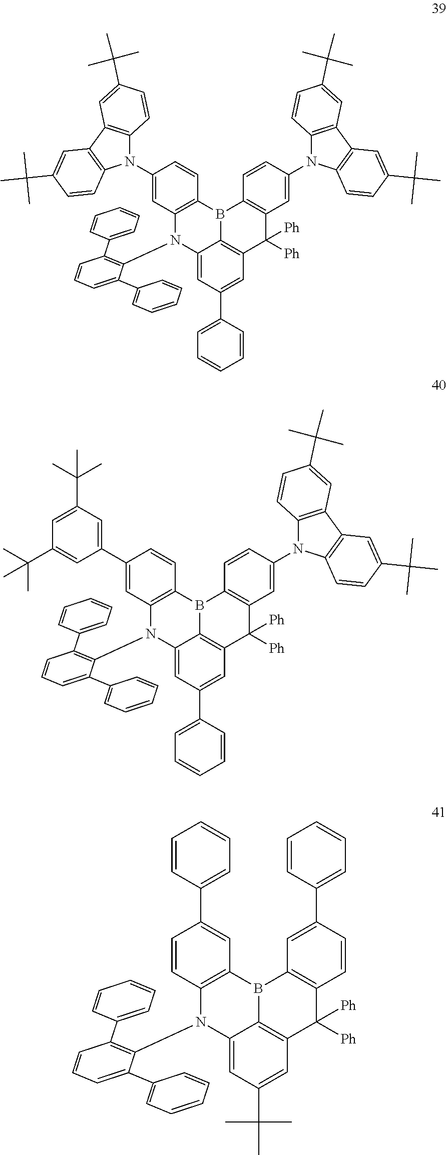

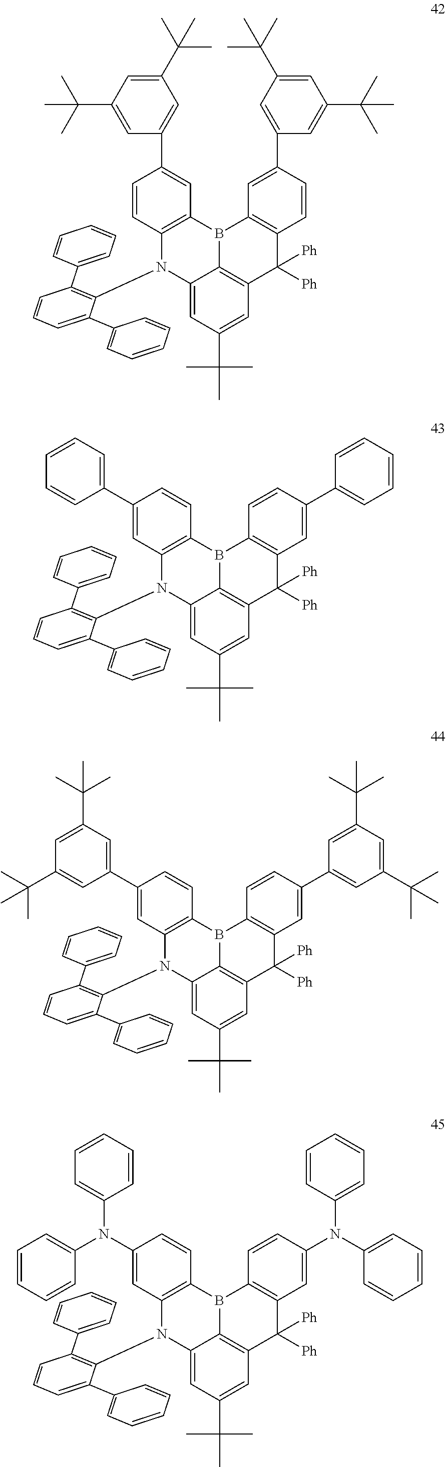

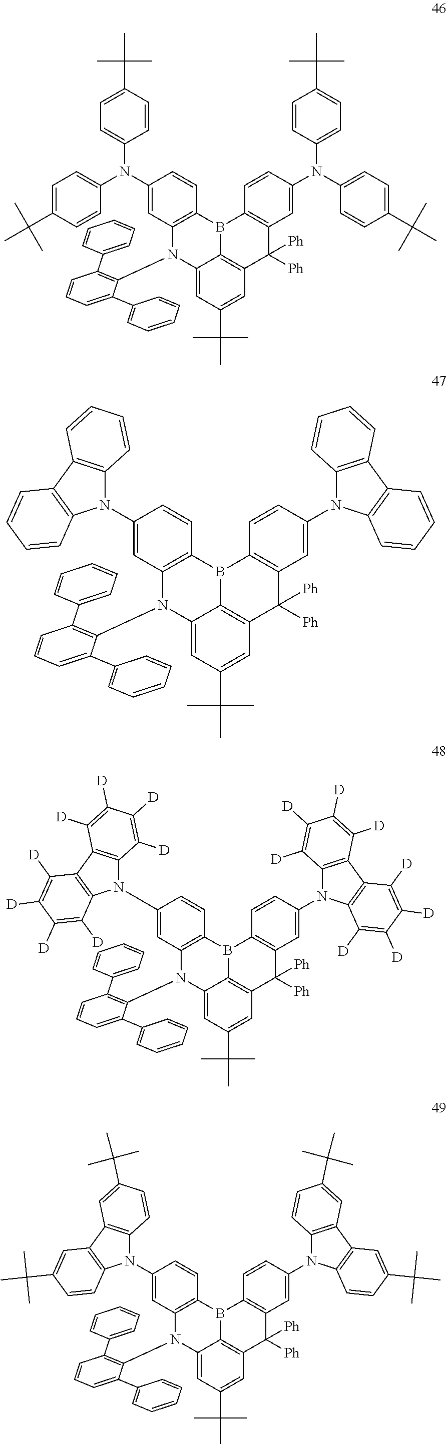

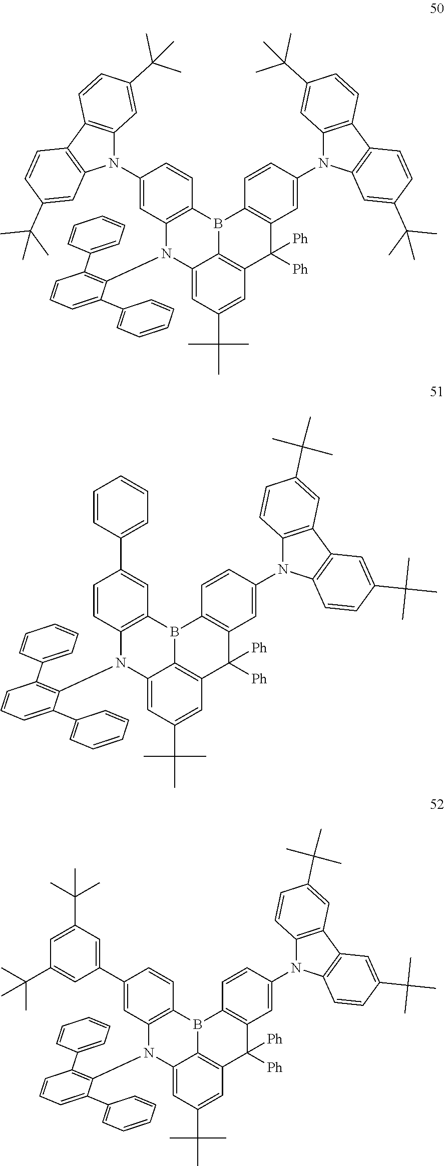

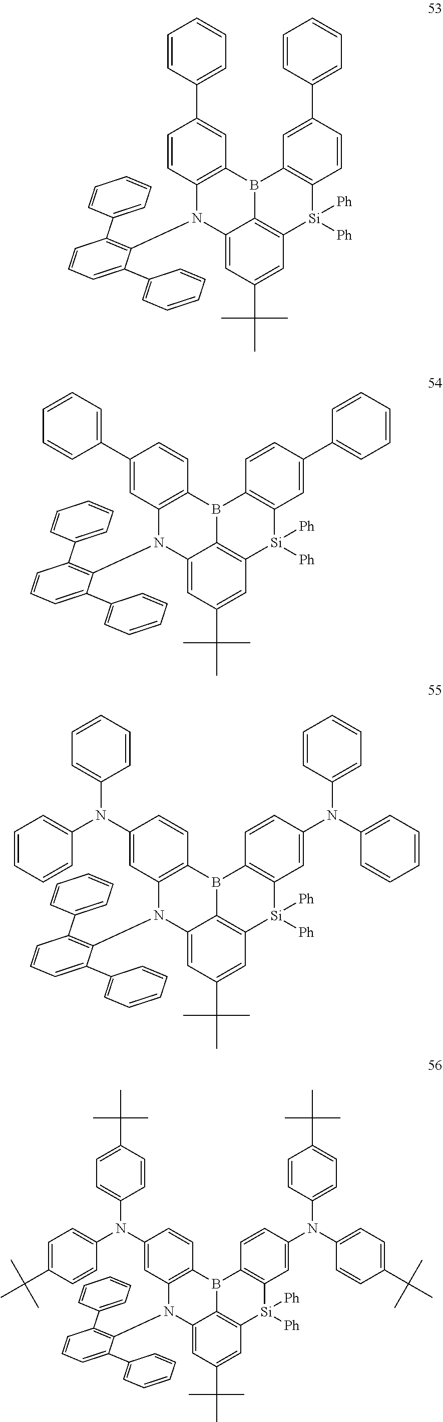

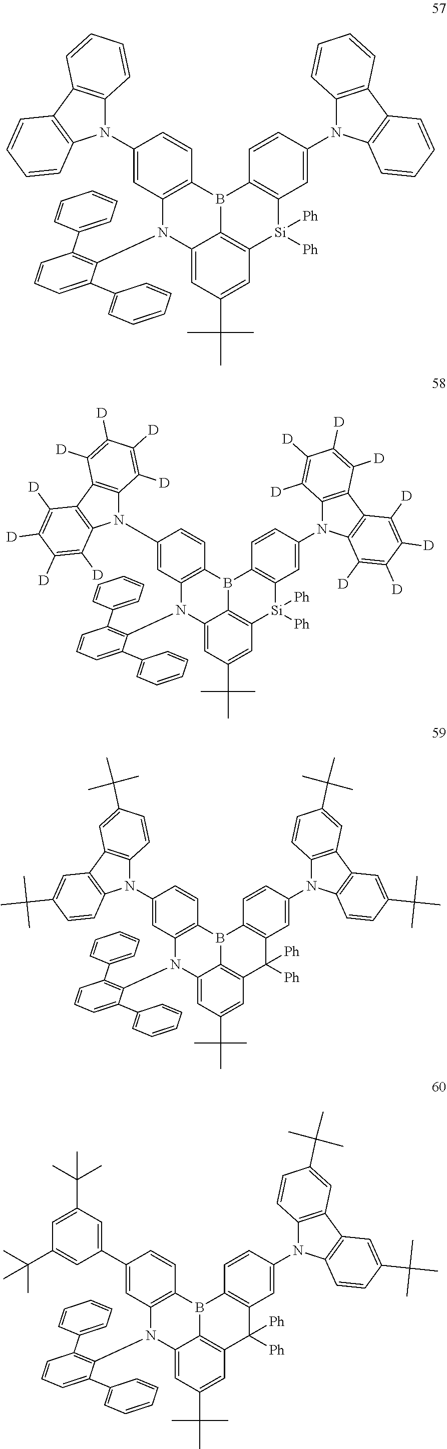

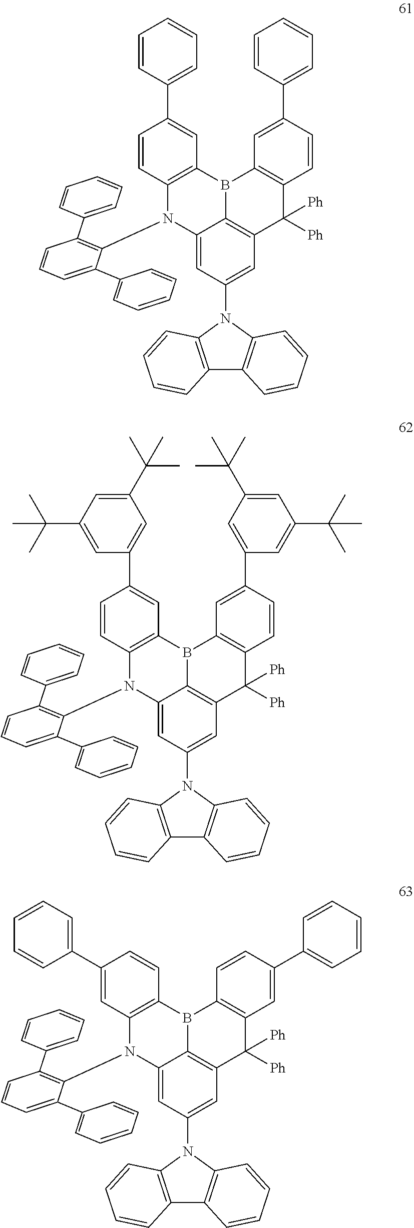

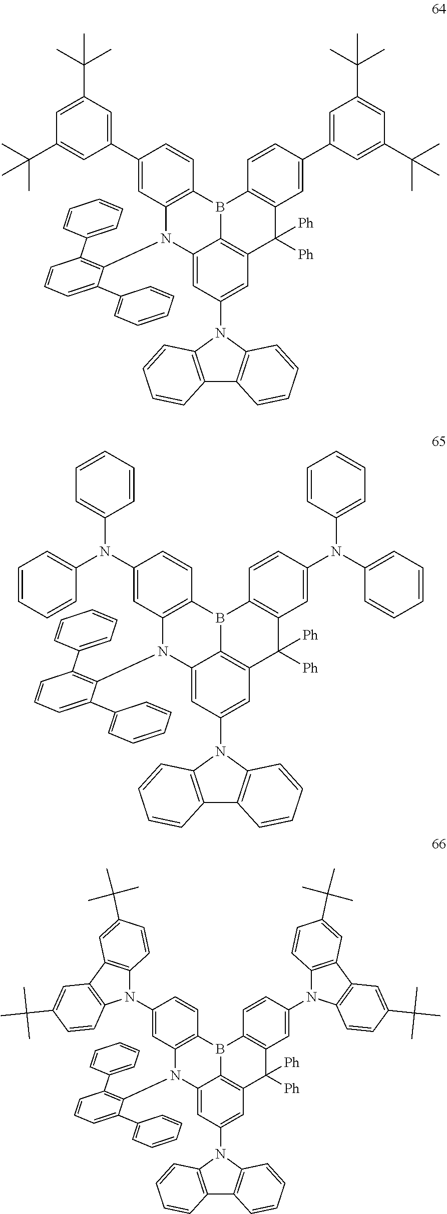

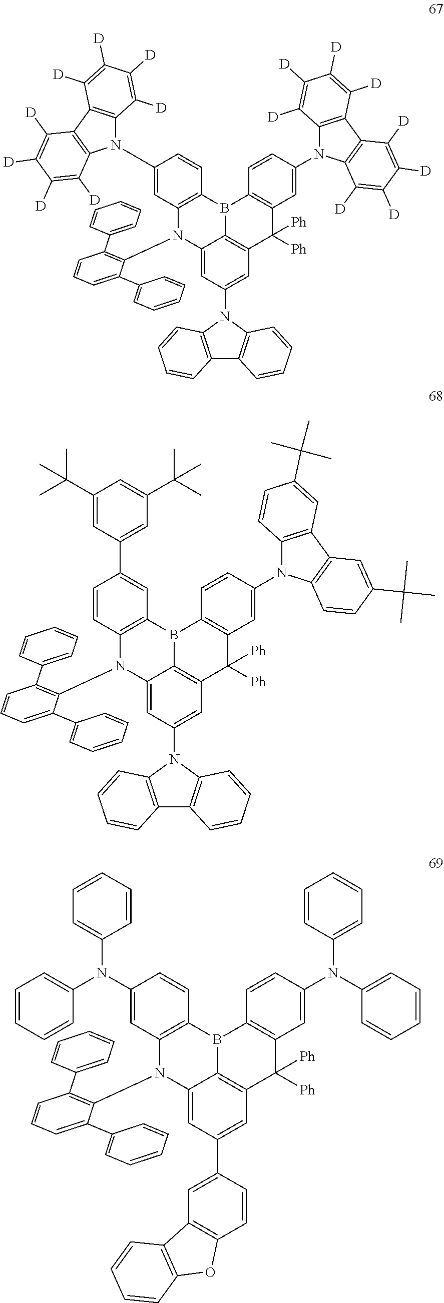

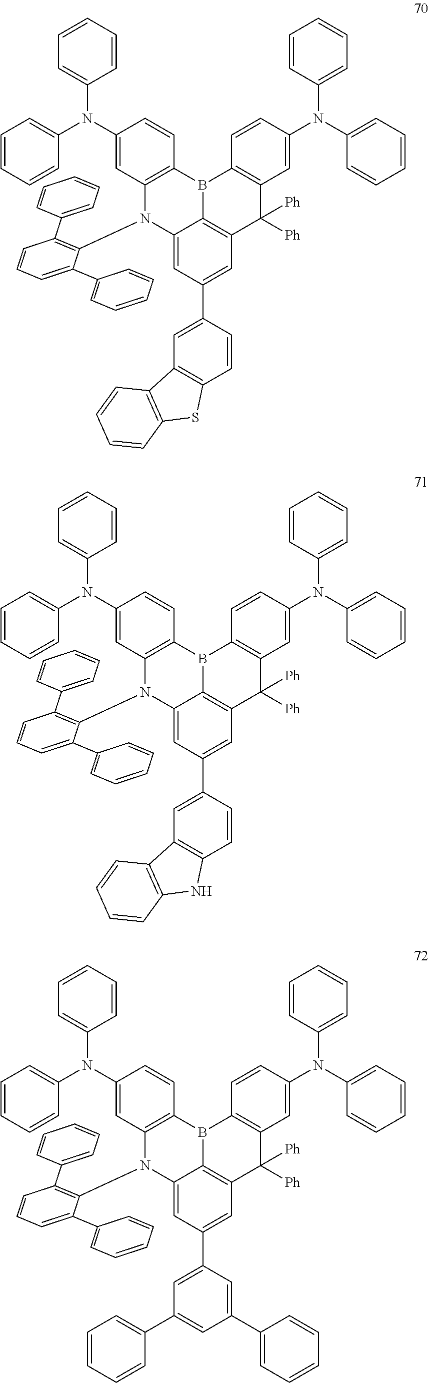 [SMILES: c1ccc(-c2cccc(-c3ccccc3)c2N2c3cc(N(c4ccccc4)c4ccccc4)ccc3B3c4ccc(N(c5ccccc5)c5ccccc5)cc4C(c4ccccc4)(c4ccccc4)c4cc(-c5ccc6sc7ccccc7c6c5)cc2c43)cc1 ; c1ccc(-c2cccc(-c3ccccc3)c2N2c3cc(N(c4ccccc4)c4ccccc4)ccc3B3c4ccc(N(c5ccccc5)c5ccccc5)cc4C(c4ccccc4)(c4ccccc4)c4cc(-c5ccc6[nH]c7ccccc7c6c5)cc2c43)cc1 ; c1ccc(-c2cc(-c3ccccc3)cc(-c3cc4c5c(c3)C(c3ccccc3)(c3ccccc3)c3cc(N(c6ccccc6)c6ccccc6)ccc3B5c3ccc(N(c5ccccc5)c5ccccc5)cc3N4c3c(-c4ccccc4)cccc3-c3ccccc3)c2)cc1]

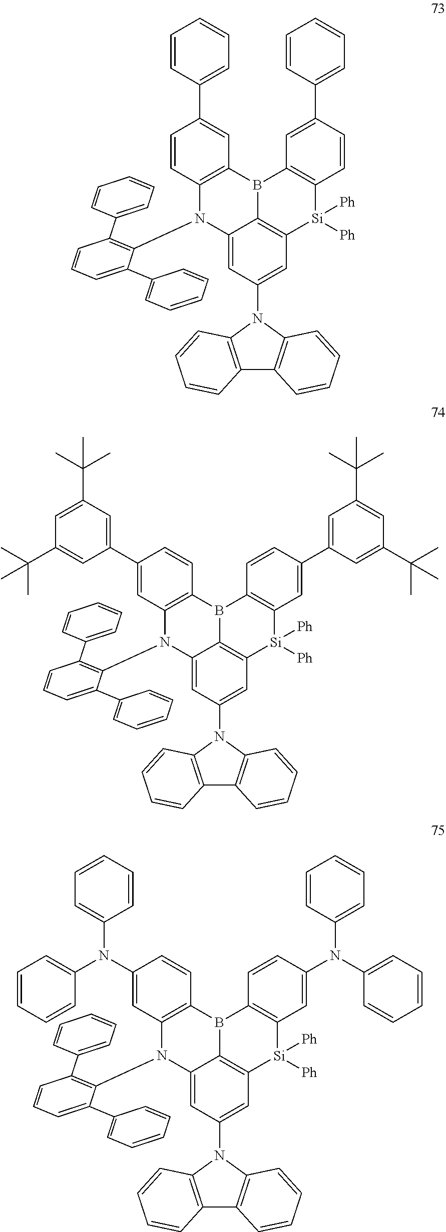 [SMILES: c1ccc(-c2ccc3c(c2)B2c4cc(-c5ccccc5)ccc4[Si](c4ccccc4)(c4ccccc4)c4cc(-n5c6ccccc6c6ccccc65)cc(c42)N3c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(-n4c5ccccc5c5ccccc54)cc4c2B3c2ccc(-c3cc(C(C)(C)C)cc(C(C)(C)C)c3)cc2[Si]4(c2ccccc2)c2ccccc2)cc(C(C)(C)C)c1 ; c1ccc(-c2cccc(-c3ccccc3)c2N2c3cc(N(c4ccccc4)c4ccccc4)ccc3B3c4ccc(N(c5ccccc5)c5ccccc5)cc4[Si](c4ccccc4)(c4ccccc4)c4cc(-n5c6ccccc6c6ccccc65)cc2c43)cc1]

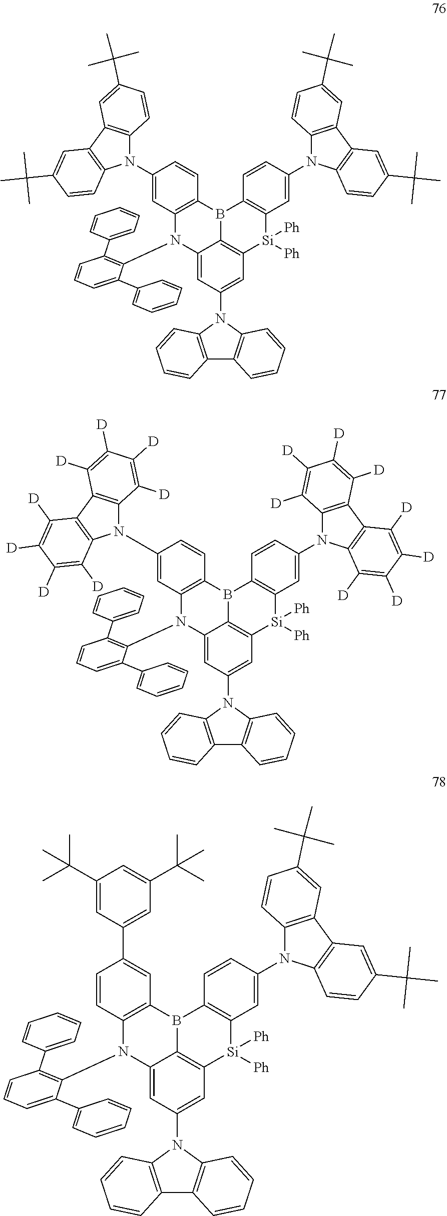

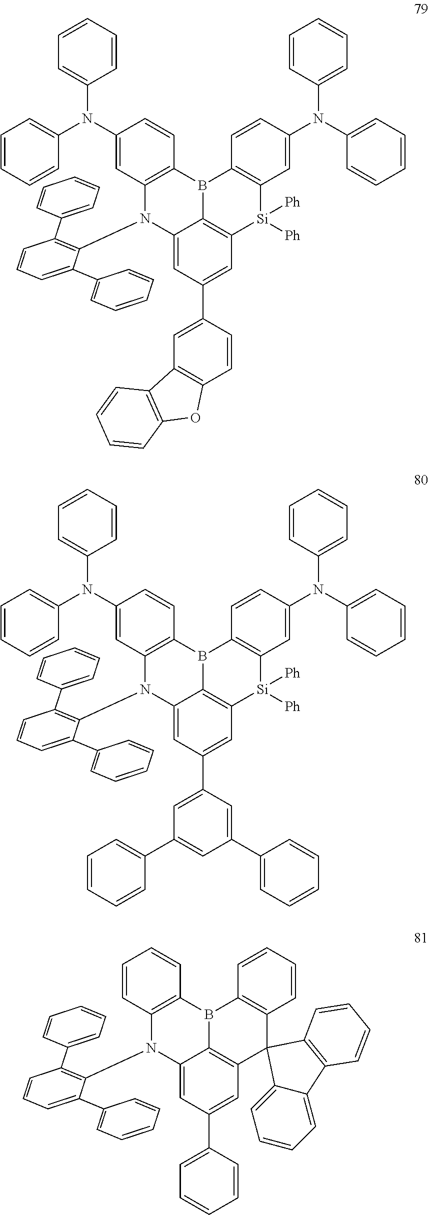 [SMILES: c1ccc(-c2cccc(-c3ccccc3)c2N2c3cc(N(c4ccccc4)c4ccccc4)ccc3B3c4ccc(N(c5ccccc5)c5ccccc5)cc4[Si](c4ccccc4)(c4ccccc4)c4cc(-c5ccc6oc7ccccc7c6c5)cc2c43)cc1 ; c1ccc(-c2cc(-c3ccccc3)cc(-c3cc4c5c(c3)[Si](c3ccccc3)(c3ccccc3)c3cc(N(c6ccccc6)c6ccccc6)ccc3B5c3ccc(N(c5ccccc5)c5ccccc5)cc3N4c3c(-c4ccccc4)cccc3-c3ccccc3)c2)cc1 ; c1ccc(-c2cc3c4c(c2)C2(c5ccccc5B4c4ccccc4N3c3c(-c4ccccc4)cccc3-c3ccccc3)c3ccccc3-c3ccccc32)cc1]

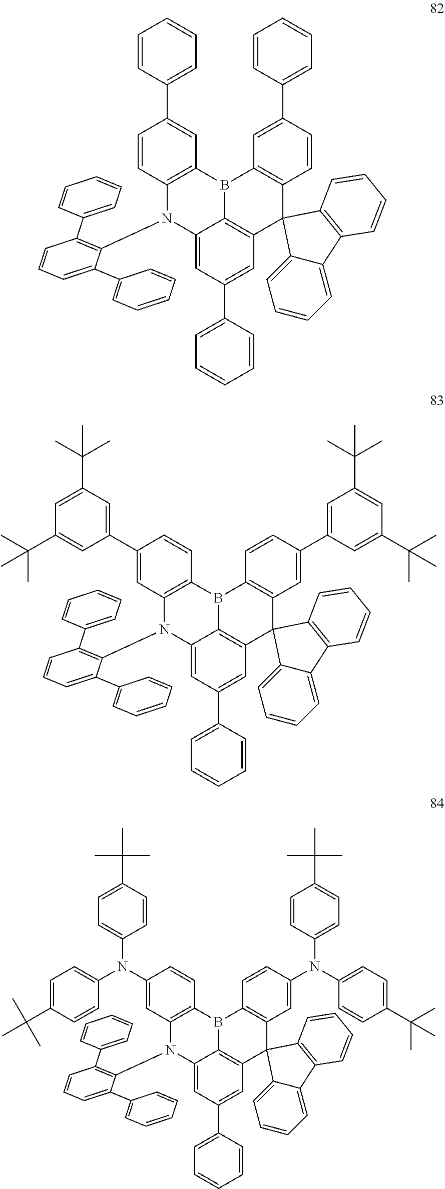

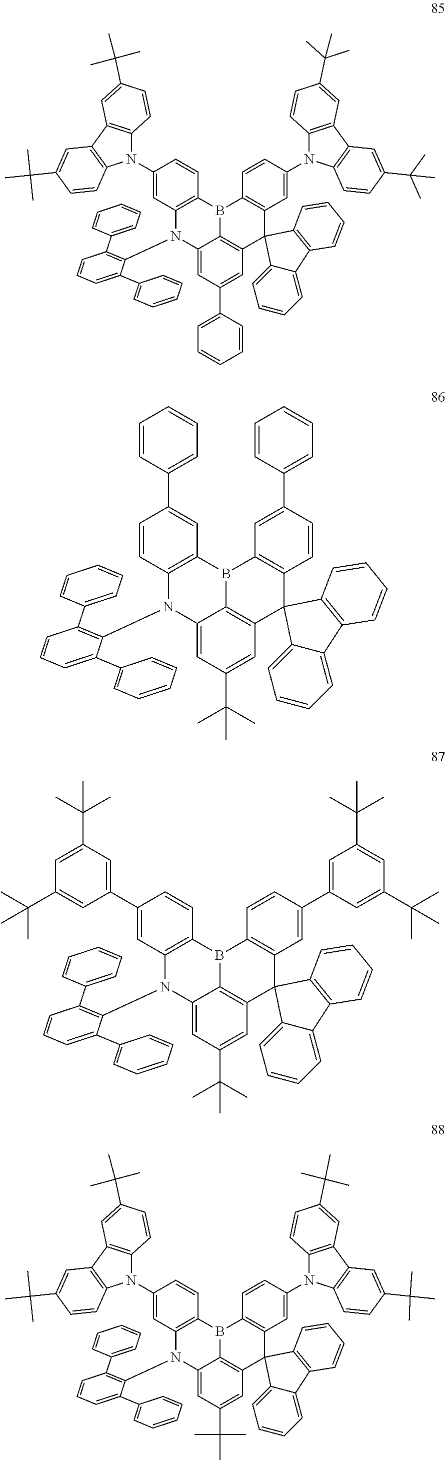

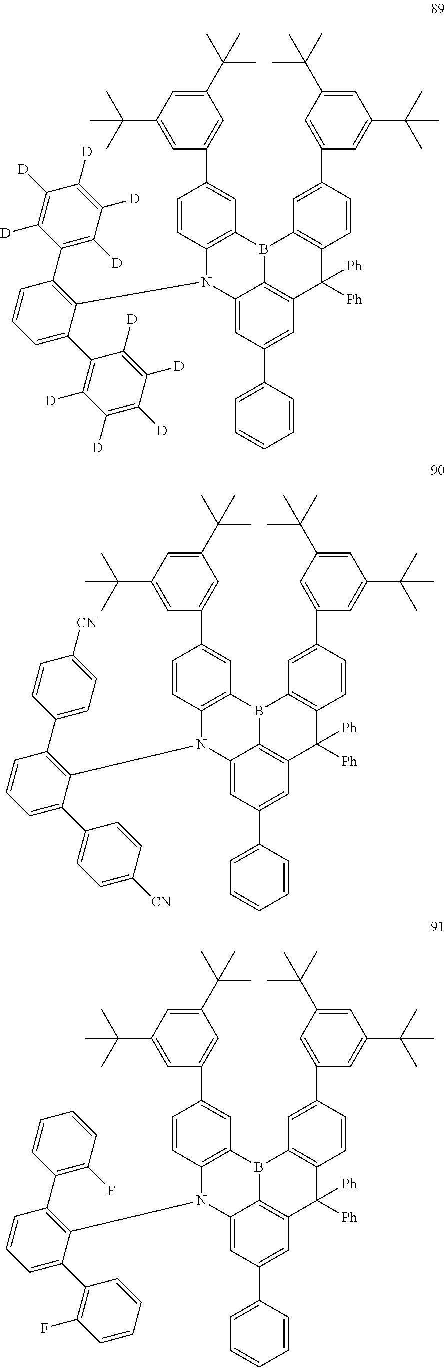

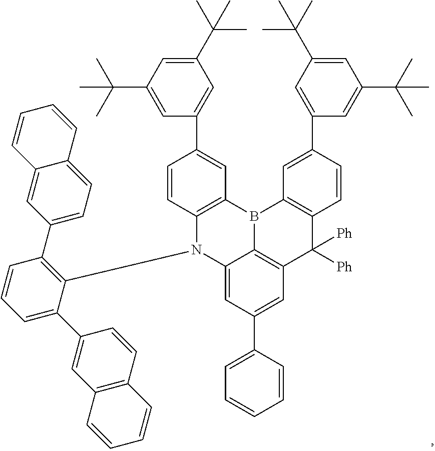 [SMILES: CC(C)(C)c1cc(-c2ccc3c(c2)B2c4cc(-c5cc(C(C)(C)C)cc(C(C)(C)C)c5)ccc4C(c4ccccc4)(c4ccccc4)c4cc(-c5ccccc5)cc(c42)N3c2c(-c3ccc4ccccc4c3)cccc2-c2ccc3ccccc3c2)cc(C(C)(C)C)c1]

The polycyclic compound of an embodiment may include a fused ring skeleton containing one or more selected from carbon atoms, silicon atoms, boron atoms, and nitrogen atoms as ring-forming atoms, and an ortho-type or kind terphenyl group connected to the nitrogen atom(s), and may thus secure a steric shielding effect to exhibit stable compound properties. The polycyclic compound of an embodiment may be utilized as a material of a light emitting element to increase lifespan of the light emitting element.

The polycyclic compound according to an embodiment may be included in an emission layer EML. The polycyclic compound according to an embodiment may be included in the emission layer EML as a dopant material. The polycyclic compound according to an embodiment may be a thermally activated delayed fluorescent material. The polycyclic compound according to an embodiment may be utilized as a thermally activated delayed fluorescent dopant. For example, in the light emitting element ED of an embodiment, the emission layer EML may include at least one of the polycyclic compounds shown in Compound Group 1 above as a thermally activated delayed fluorescent dopant. However, the use of the polycyclic compound according to an embodiment is not limited thereto.

The polycyclic compound of an embodiment may emit blue light, and may emit light having a maximum emission wavelength of about 430 nm to about 490 nm. For example, the polycyclic compound of an embodiment may emit pure blue having a maximum emission wavelength in the vicinity of about 450 nm to about 460 nm.

In the light emitting element ED of an embodiment, the emission layer EML may include a first compound, and may further include at least one of a second compound, a third compound, or a fourth compound. For example, the emission layer EML may include the first compound, the second compound, and the third compound. The second compound may be a hole transporting host, and the third compound may be an electron transporting host. In the emission layer EML, the second compound and the third compound form an exciplex, and energy may be transferred from the exciplex to the first compound to emit light.

The triplet energy of the exciplex formed by the second compound and the third compound corresponds to a difference between Lowest Unoccupied Molecular Orbital (LUMO) energy level of the electron transporting host and Highest Occupied Molecular Orbital (HOMO) energy level of the hole transporting host. For example, the triplet energy level (T1) of the exciplex formed by the hole transporting host and the electron transporting host may have an absolute value of about 2.4 eV to about 3.0 eV. In some embodiments, the triplet energy of the exciplex may have a value smaller than the energy gap of each host material. The exciplex may have a triplet energy of 3.0 eV or less, which is an energy gap between the hole transporting host and the electron transporting host.

In an embodiment, the emission layer EML may include the first compound, the second compound, the third compound, and the fourth compound. In the emission layer EML, the second compound and the third compound form an exciplex, and energy may be transferred from the exciplex to the fourth compound and from the fourth compound to the first compound to emit light.

In an embodiment, the fourth compound may be a sensitizer. In the light emitting element ED of an embodiment, the fourth compound included in the emission layer EML may serve as a sensitizer to transfer energy from a host to the first compound, which is a light emitting dopant. For example, the fourth compound serving as an auxiliary dopant may accelerate the energy transfer to the first compound serving as the light emitting dopant, thereby increasing the light emitting ratio of the first compound. Accordingly, the emission layer EML of an embodiment may have increased luminous efficiency. In some embodiments, when the energy transfer to the first compound is increased, excitons formed in the emission layer EML do not accumulate in the emission layer EML and emit light quickly, resulting in less deterioration of an element. Accordingly, the light emitting element ED of an embodiment may have an increased lifespan.

The light emitting element ED of an embodiment may include a first compound, a second compound, a third compound, and a fourth compound, and the emission layer EML may thus include a combination of two host materials and two dopant materials. In the light emitting element ED of an embodiment, the emission layer EML includes two different hosts, a first compound emitting delayed fluorescence, and a fourth compound containing an organometallic complex, and may thus exhibit excellent or suitable luminous efficiency.

In some embodiments, the light emitting element ED of an embodiment may include a plurality of emission layers. The plurality of emission layers may be sequentially stacked and provided, and for example, the light emitting element ED including the plurality of emission layers may emit white light. The light emitting element including the plurality of emission layers may be a light emitting element having a tandem structure. When the light emitting element ED includes the plurality of emission layers, at least one emission layer EML may include all of the first compound, the second compound, the third compound, and the fourth compound as described above.

In the light emitting element ED of an embodiment, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED of an embodiment shown in FIGS. 3 to 6, the emission layer EML may further include a generally utilized/generally available host and dopant in addition to the host and dopant described above, and the emission layer EML may include a compound represented by Formula E-1. The compound represented by Formula E-1 may be utilized as a fluorescent host material.

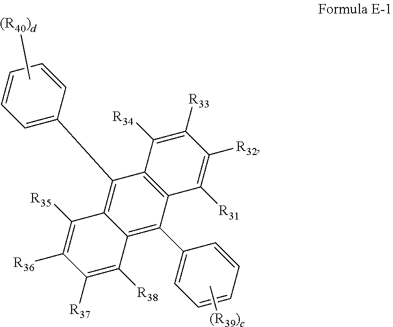

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. In some embodiments, R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

Formula E-1 may be represented by any one selected from among compounds E1 to E19.

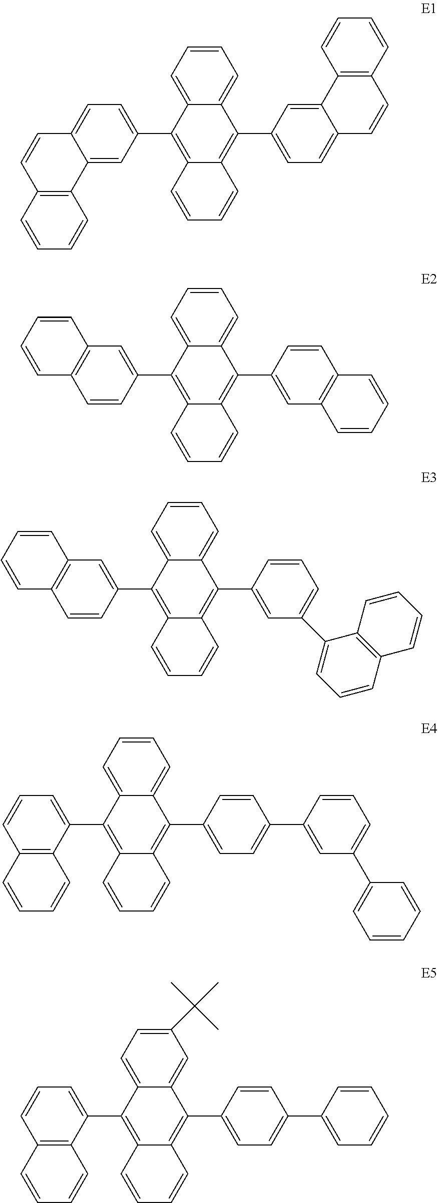

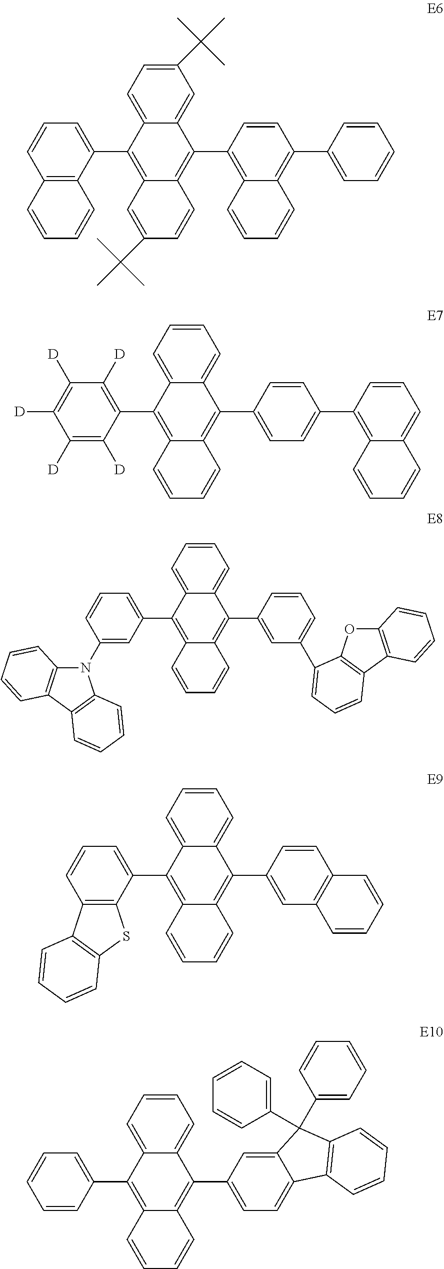

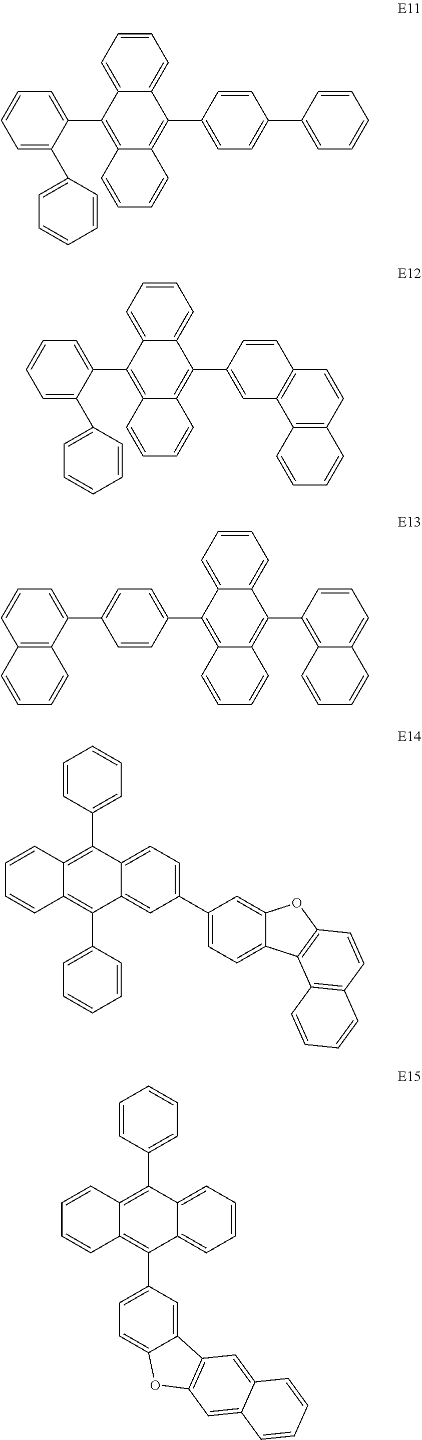

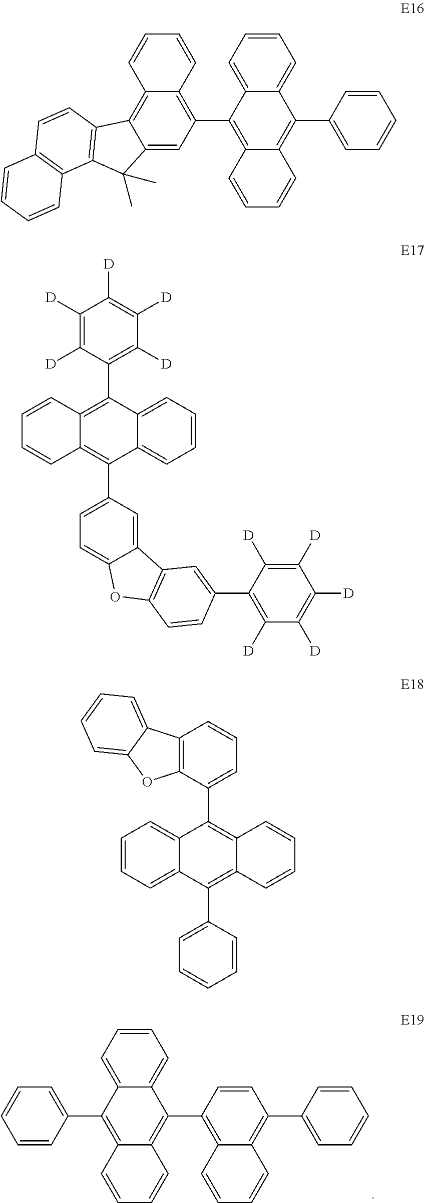

In an embodiment, the emission layer EML may include a first compound represented by Formula 1, and at least one of a second compound represented by Formula HT-1, a third compound represented by Formula ET-1, or a fourth compound represented by Formula M-b.

In an embodiment, the second compound may be utilized as a hole transporting host material of the emission layer EML.

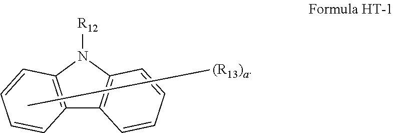

In Formula HT-1, R₁₂ and R₁₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, R₁₂ may be a substituted or unsubstituted aryl group having 6 to 60 ring-forming carbon atoms, or a substituted or unsubstituted heteroaryl group having 2 to 60 ring-forming carbon atoms, and for example, R₁₂ may be a substituted phenyl group, an unsubstituted dibenzofuran group, or a substituted fluorenyl group. For example, R₁₃ may be a substituted or unsubstituted aryl group having 6 to 60 ring-forming carbon atoms, or a substituted or unsubstituted heteroaryl group having 2 to 60 ring-forming carbon atoms, and for example, R₁₃ may be a substituted or unsubstituted carbazole group.

a may be an integer from 0 to 8. When a is an integer of 2 or greater, a plurality of R₁₃s may all be the same or at least one may be different from the others.

The second compound may be represented by any one selected from among compounds of Compound Group 2. In Compound Group 2, D is a deuterium atom.

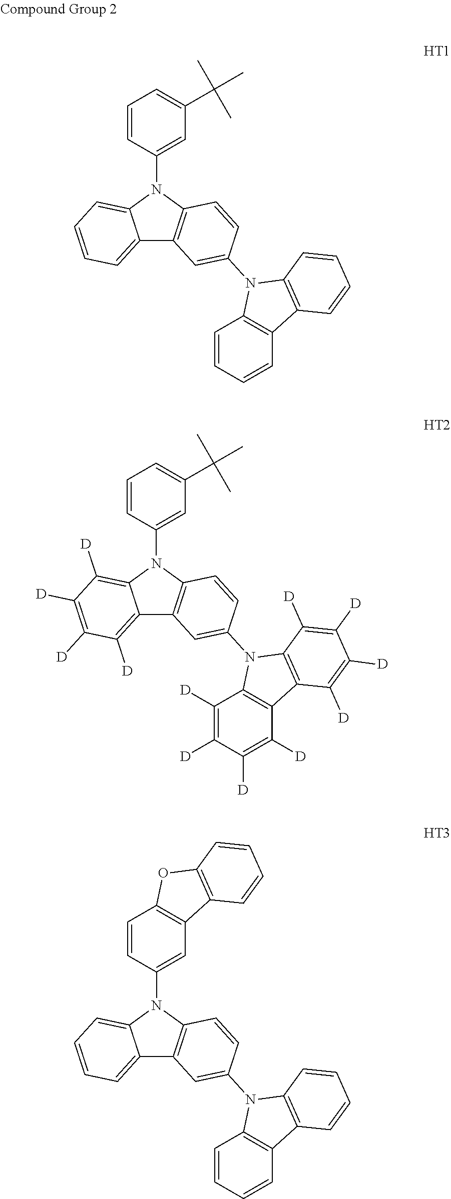 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

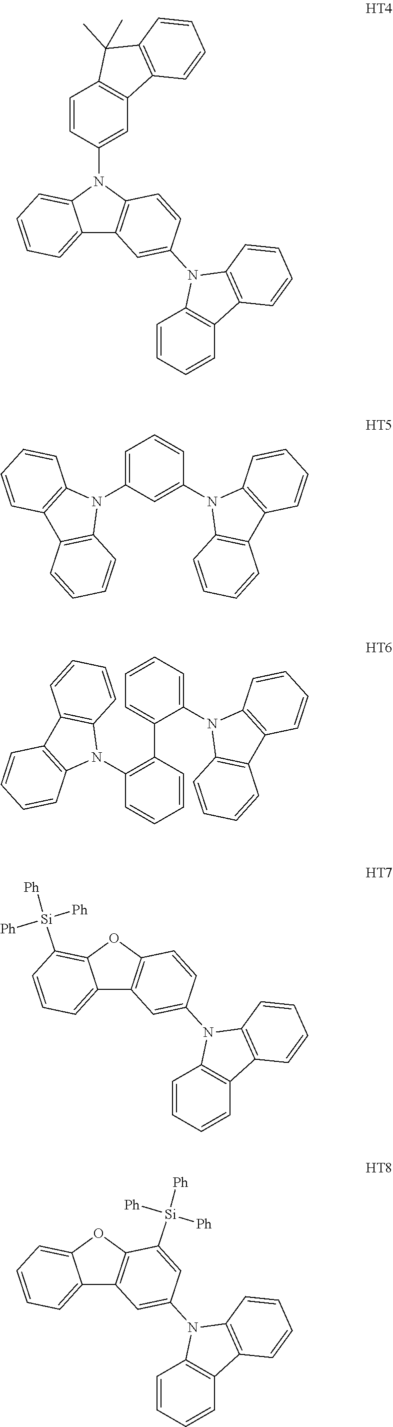 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

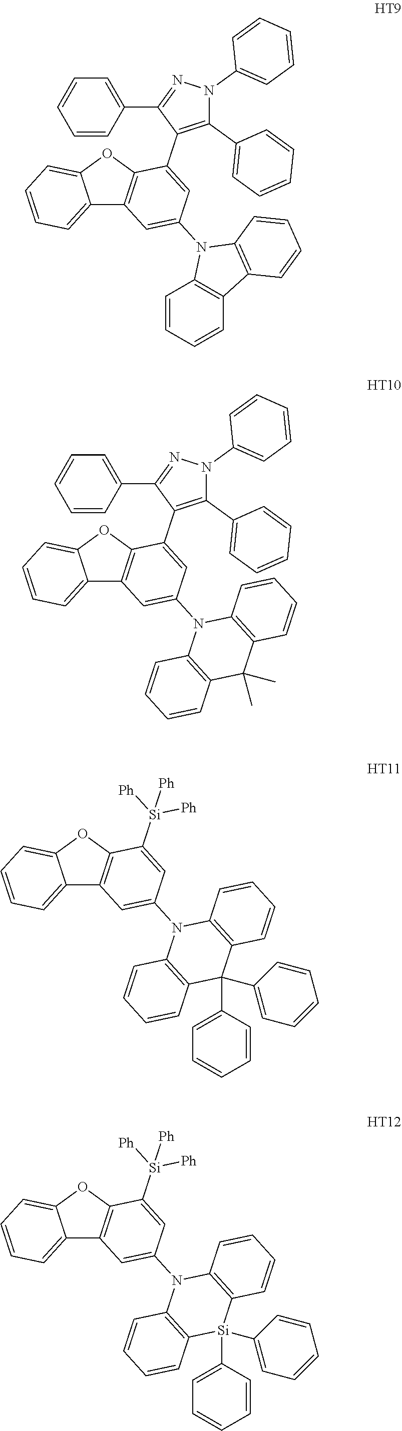 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

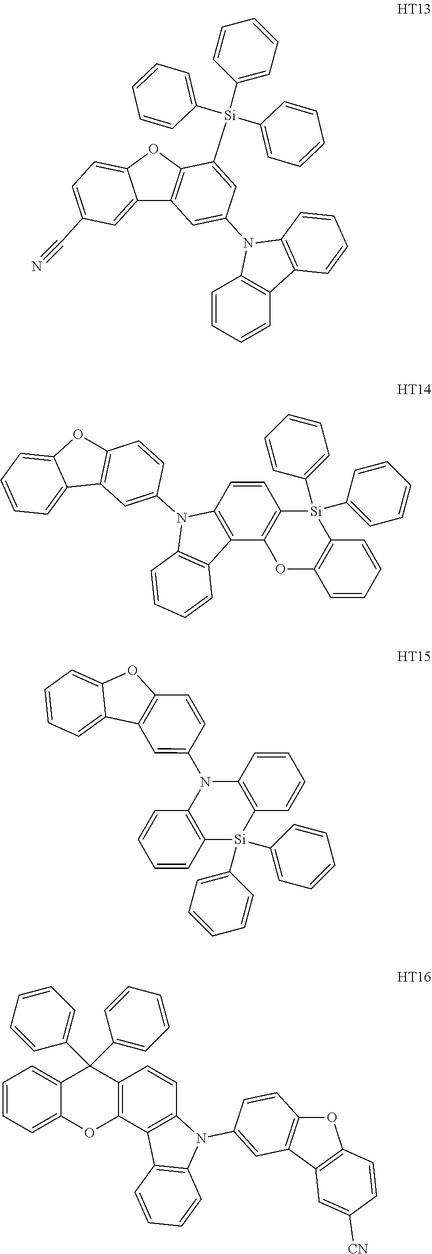 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)C(c4ccccc4)(c4ccccc4)c4ccccc4O6)cc3c2c1]

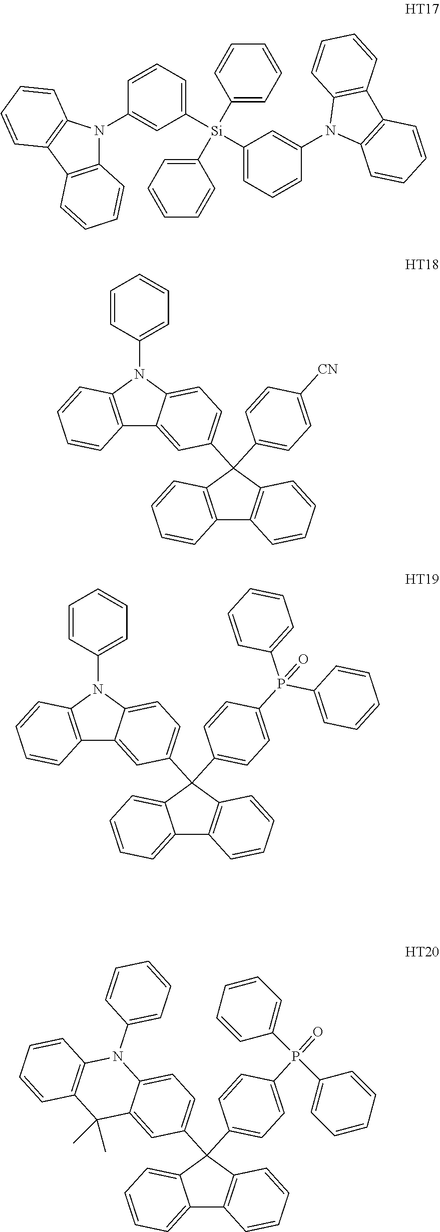 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

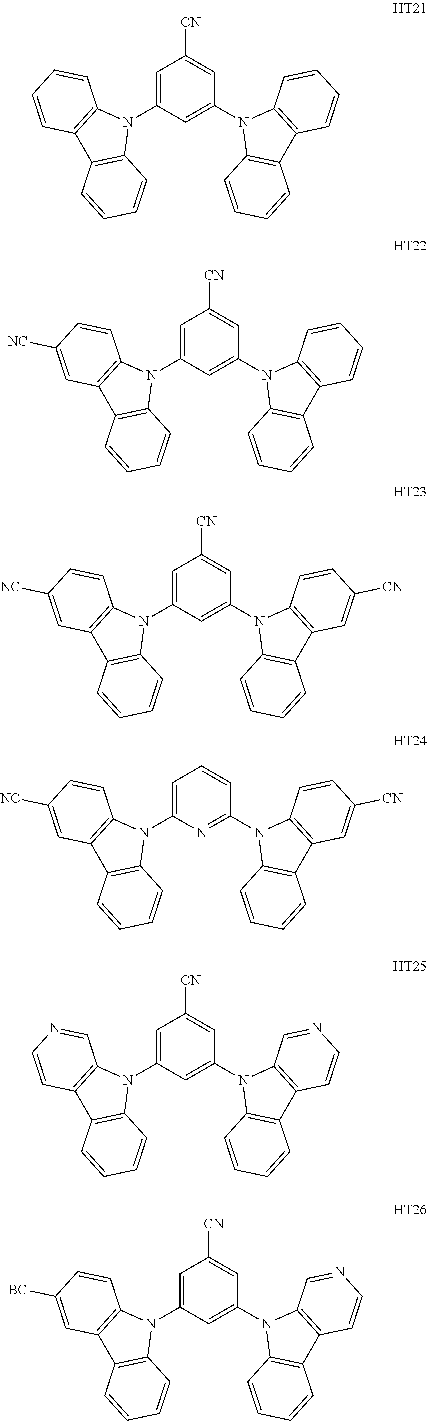

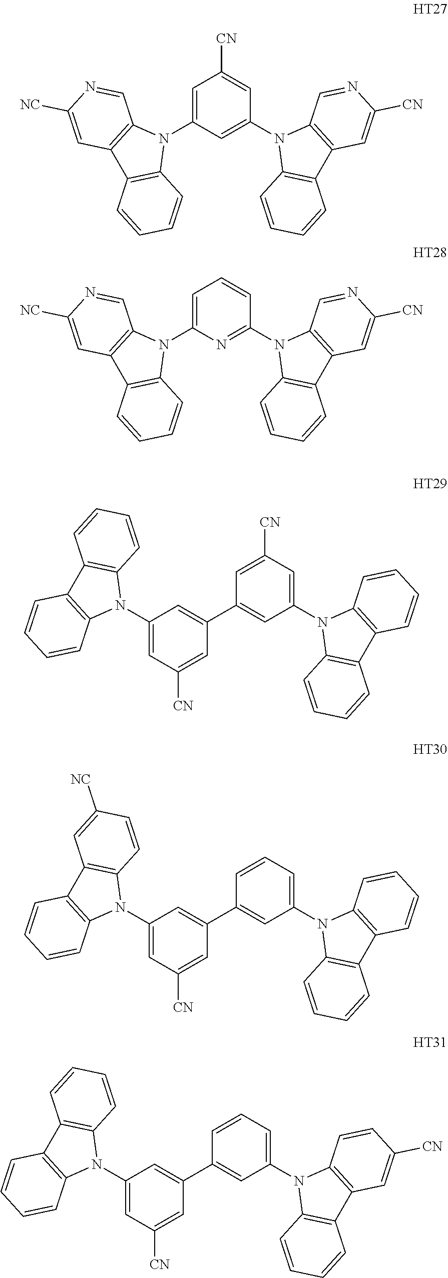 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

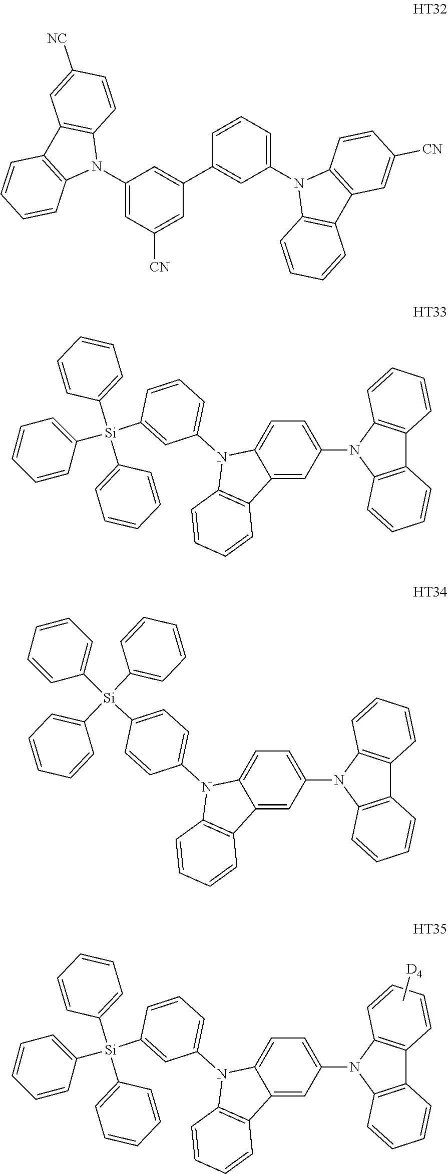

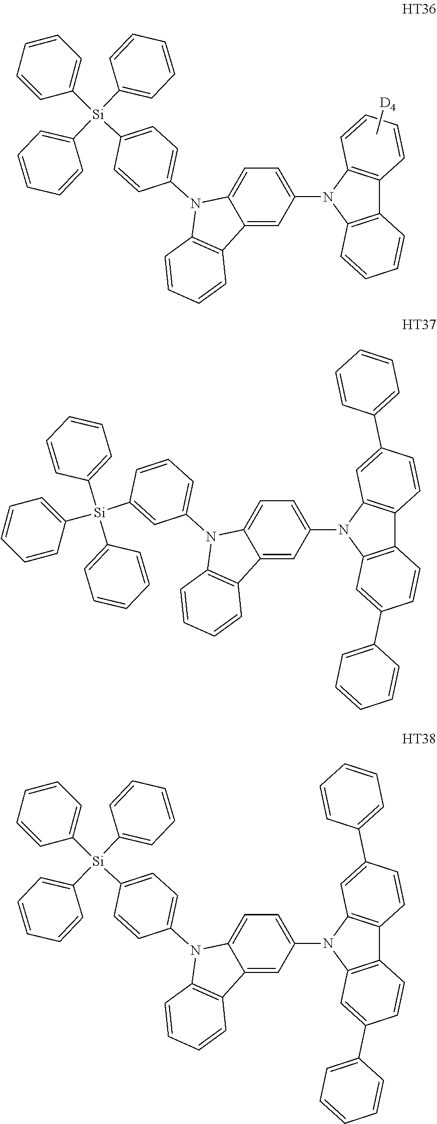

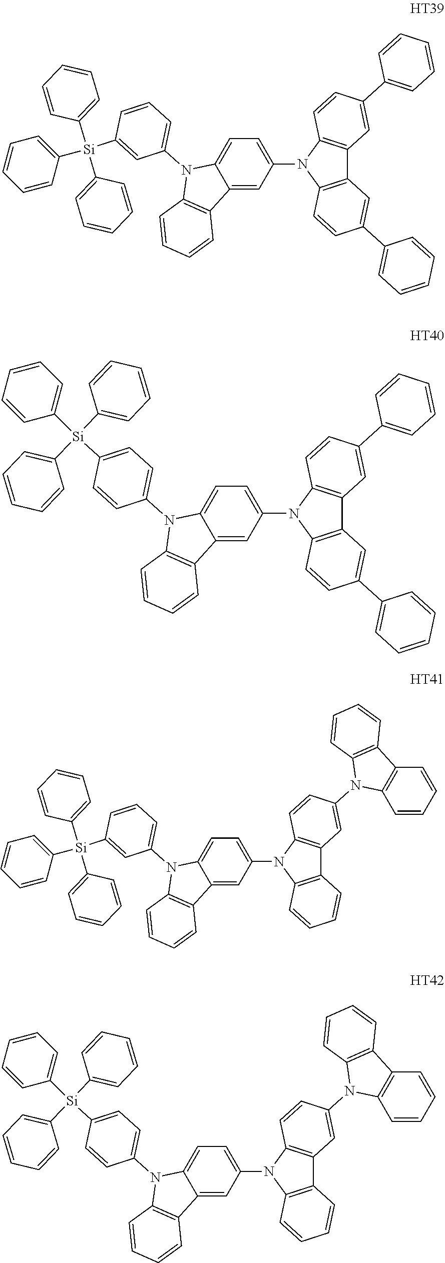 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

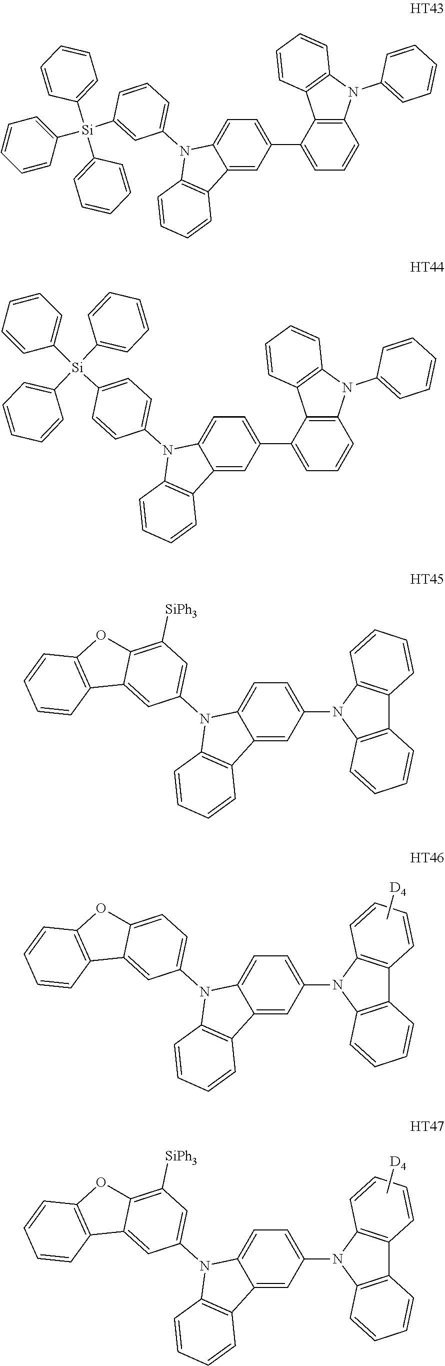

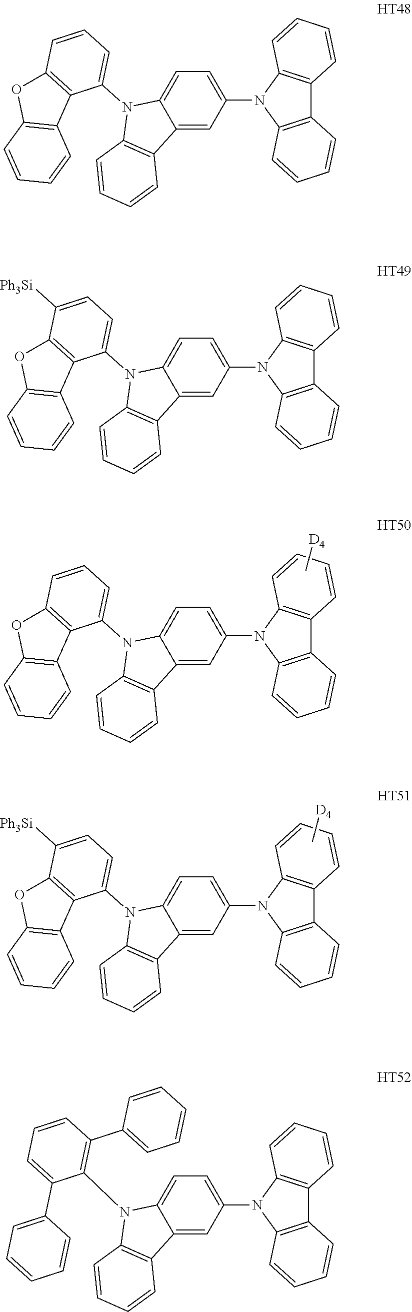

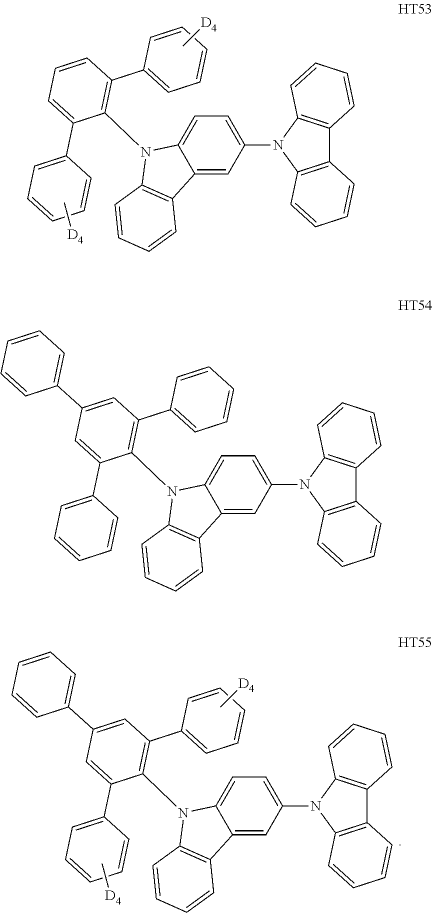

In an embodiment, the emission layer EML may include a third compound represented by Formula ET-1. For example, the third compound may be utilized as an electron transporting host material of the emission layer EML.

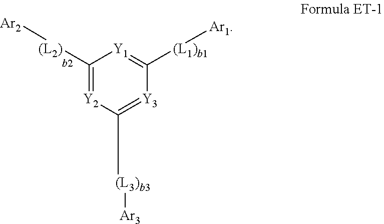

In Formula ET-1, Y₁ to Y₃ may each independently be N or CRₐ, and at least one of Y₁ to Y₃ may be N.

Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may be a substituted or unsubstituted phenyl group or a substituted or unsubstituted carbazole group.

L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

b1 to b3 may each independently be an integer from 0 to 10. In some embodiments, when b1 to b3 are each an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The third compound may be represented by any one selected from among compounds of Compound Group 3. The light emitting element ED of an embodiment may include any one selected from among compounds of Compound Group 3. In Compound Group 3, D is a deuterium atom.

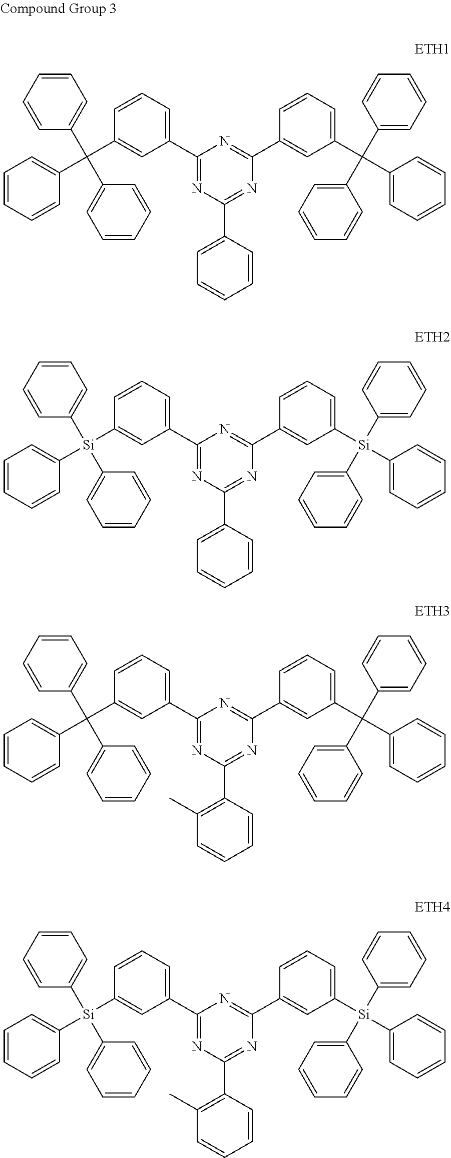 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

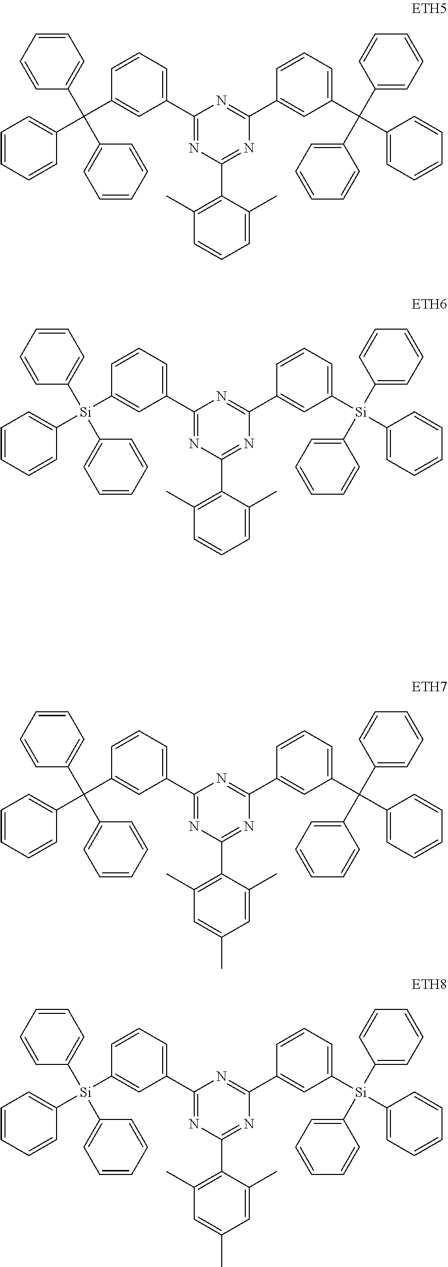 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

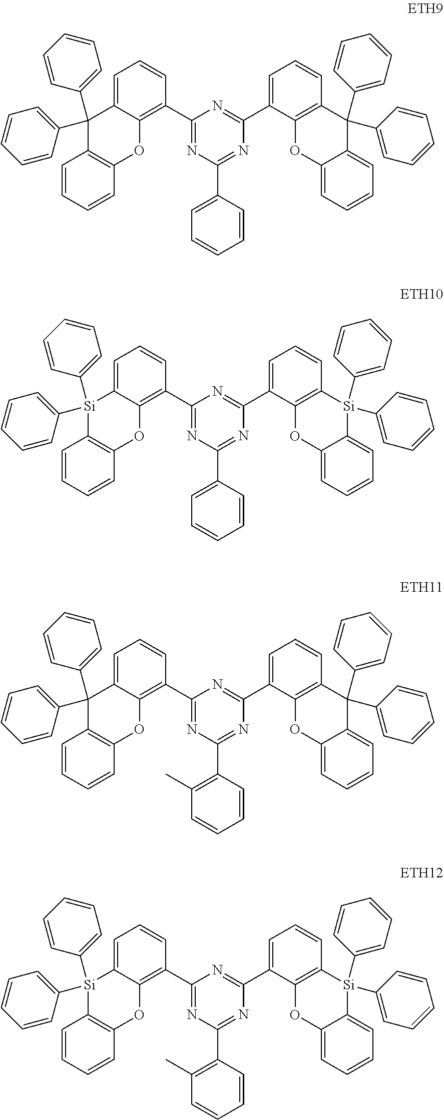 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

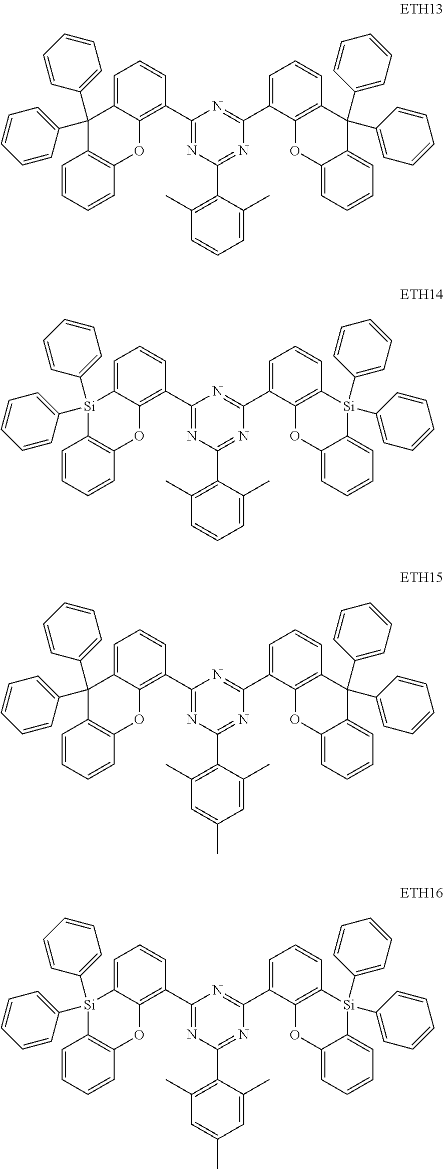 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

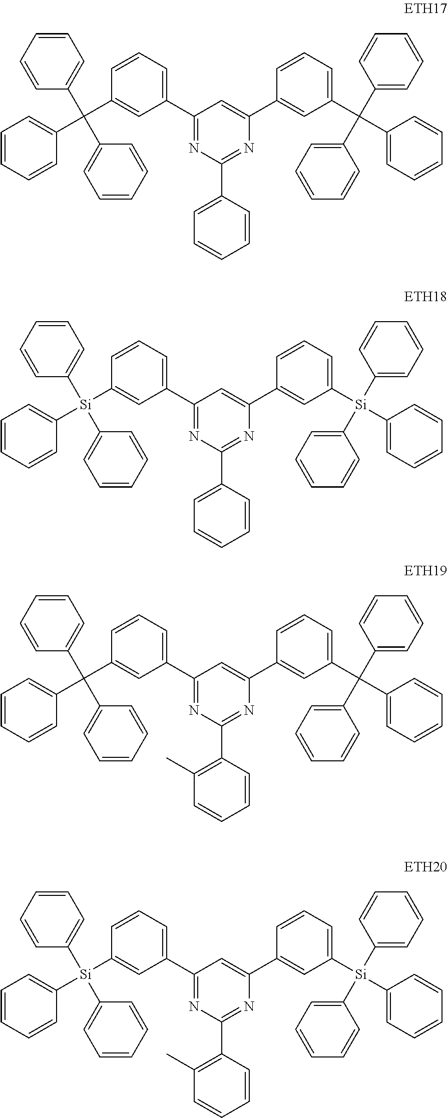 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

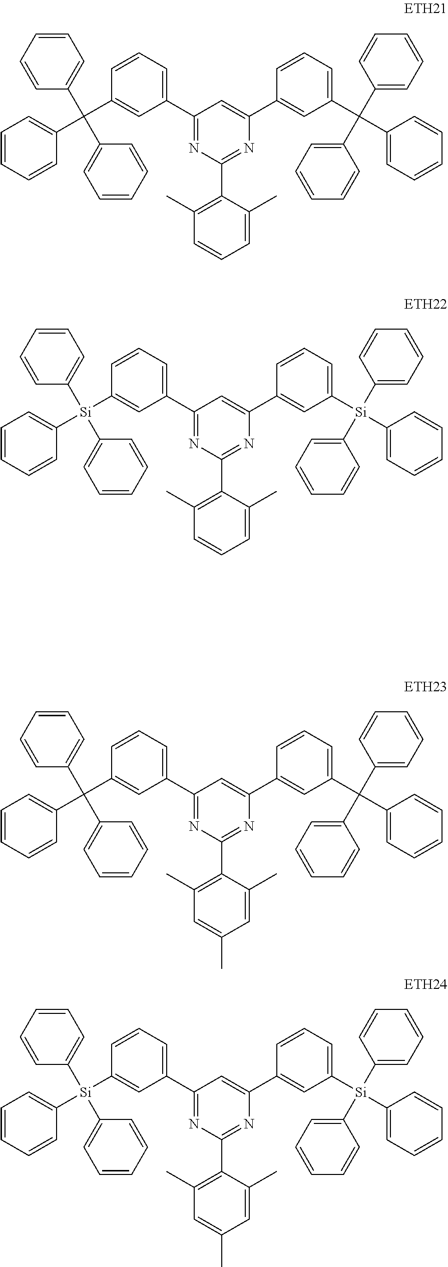 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

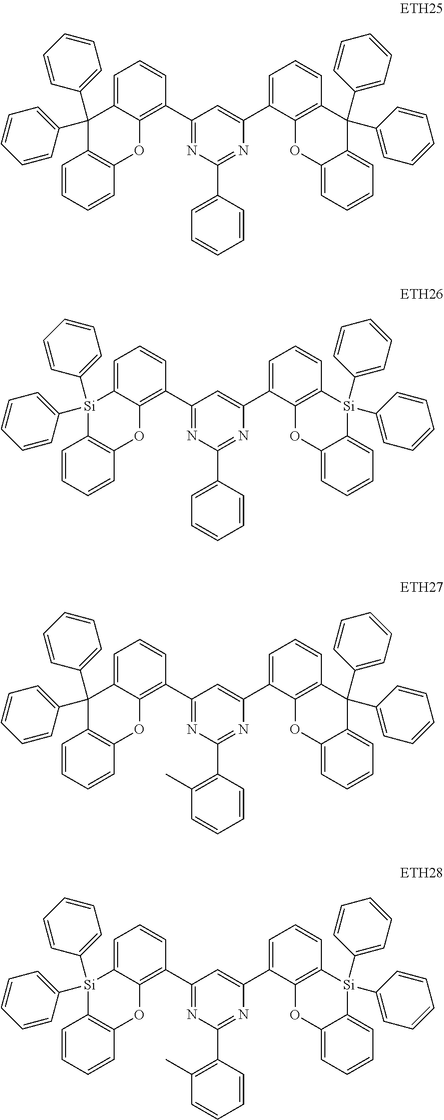 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

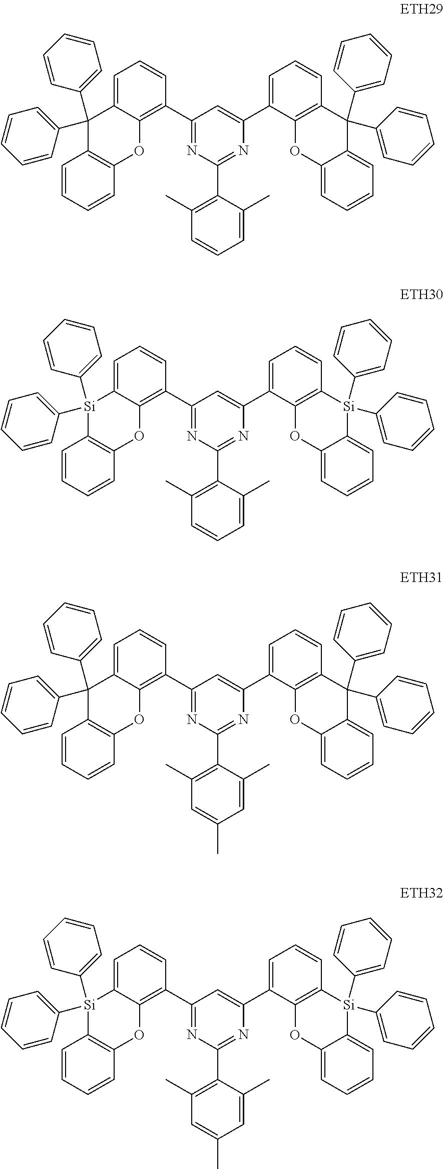 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

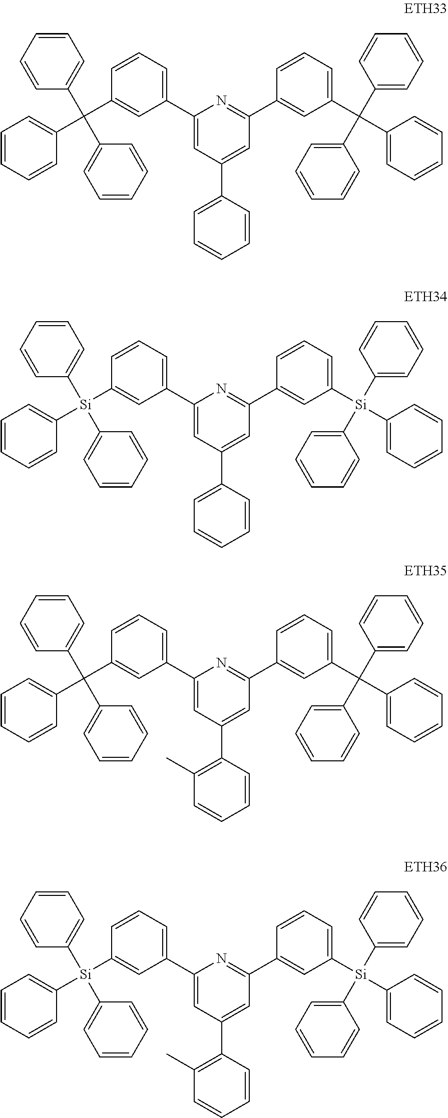 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

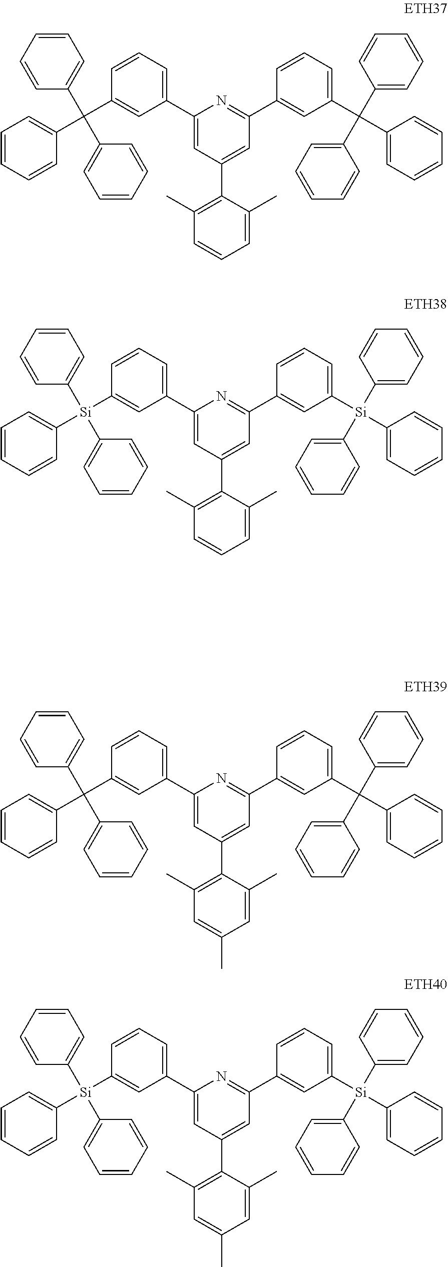 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

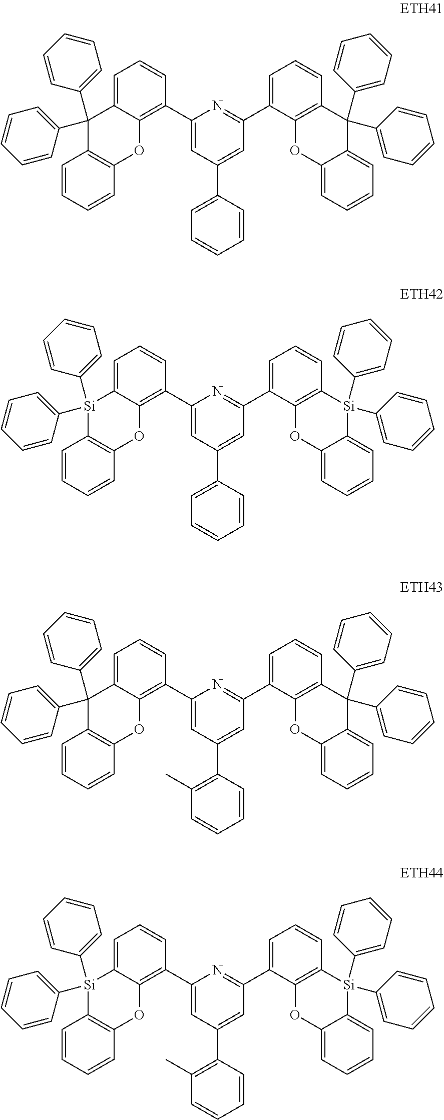 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

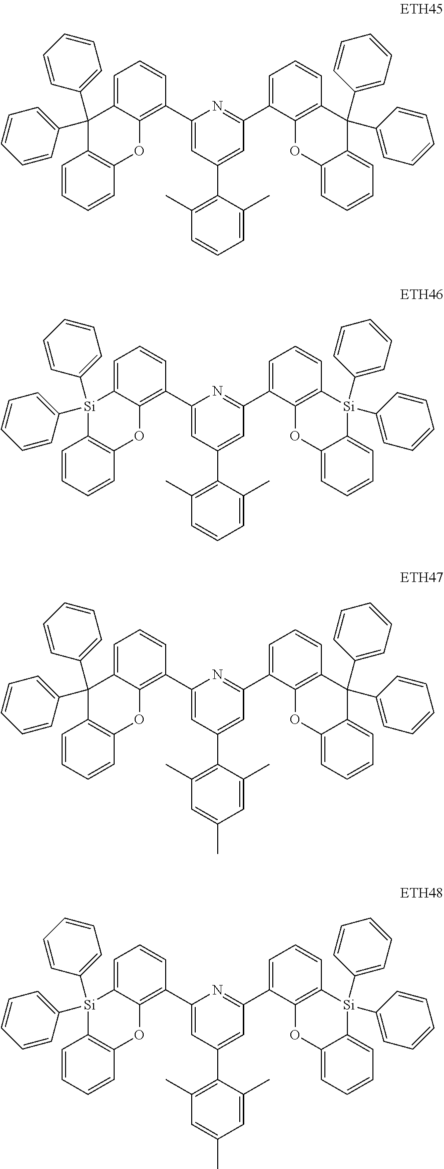 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

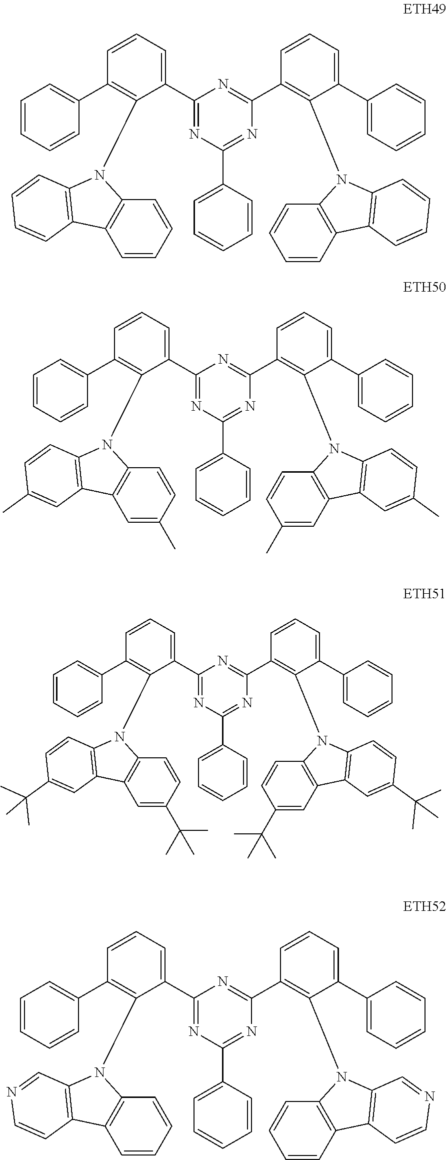

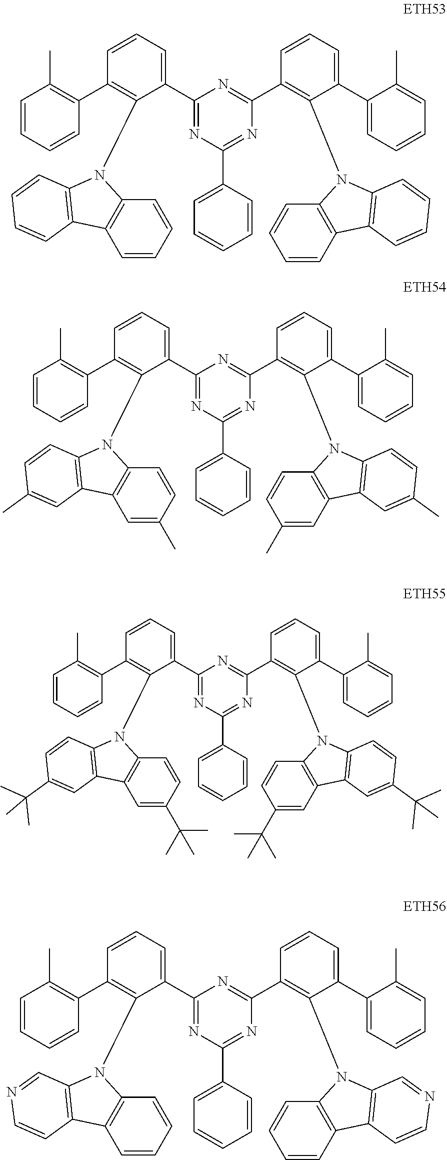

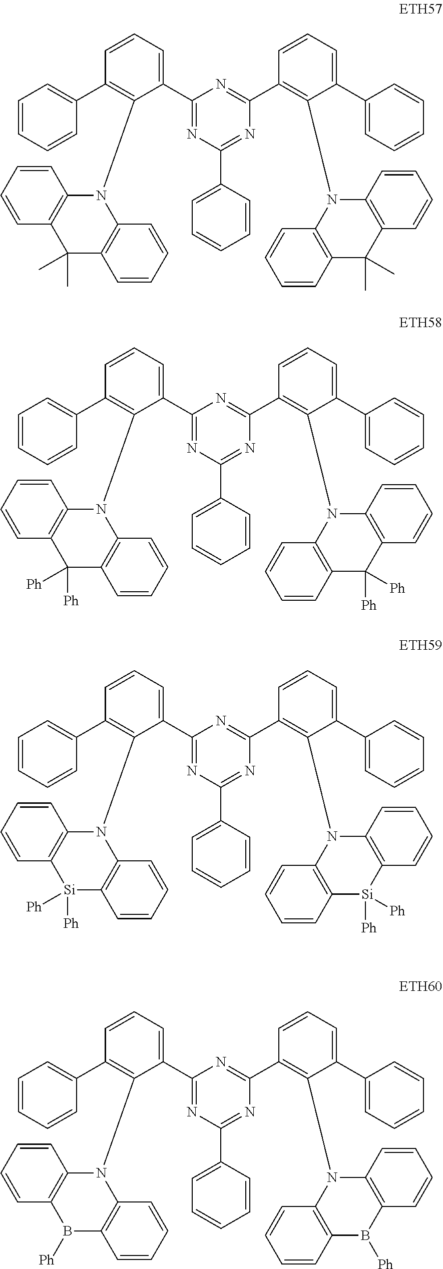

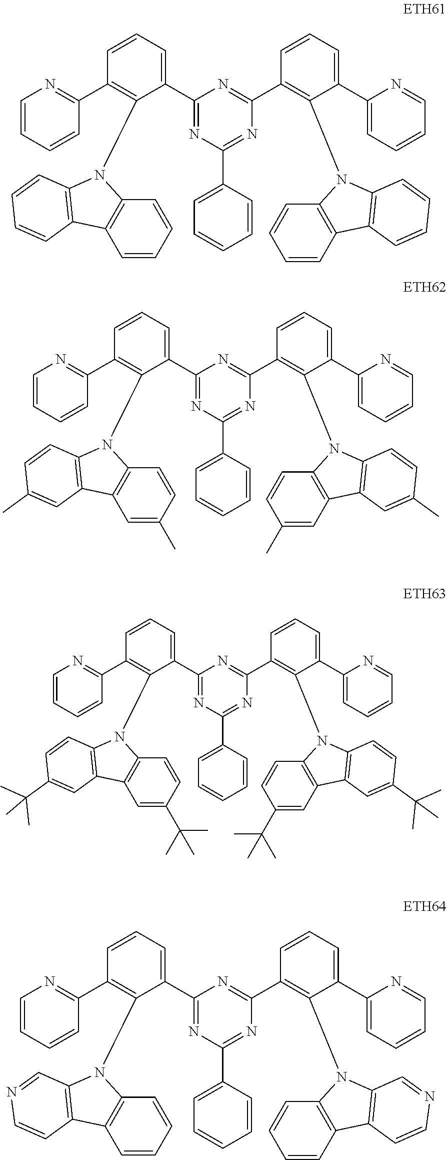

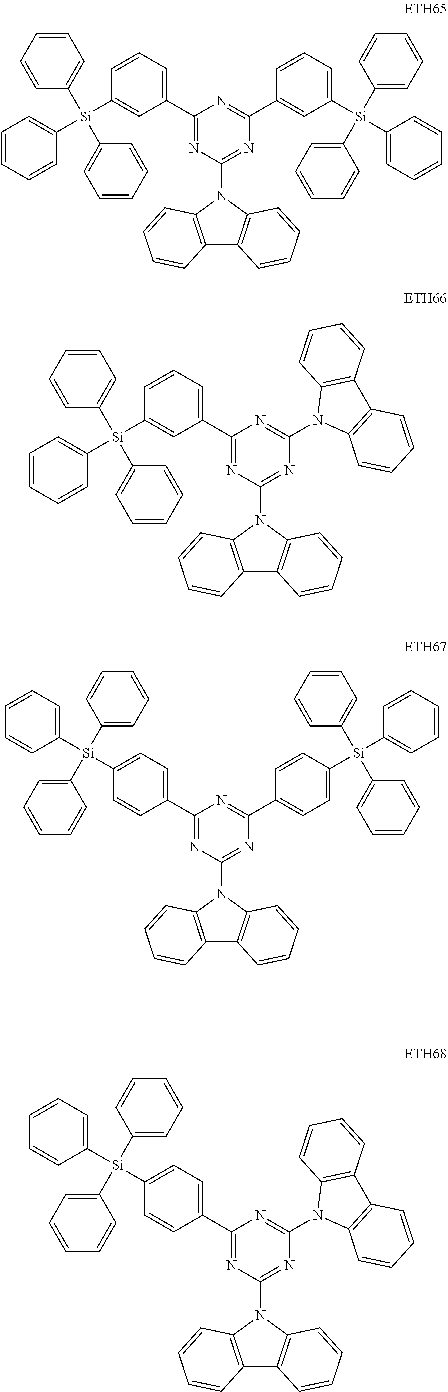 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

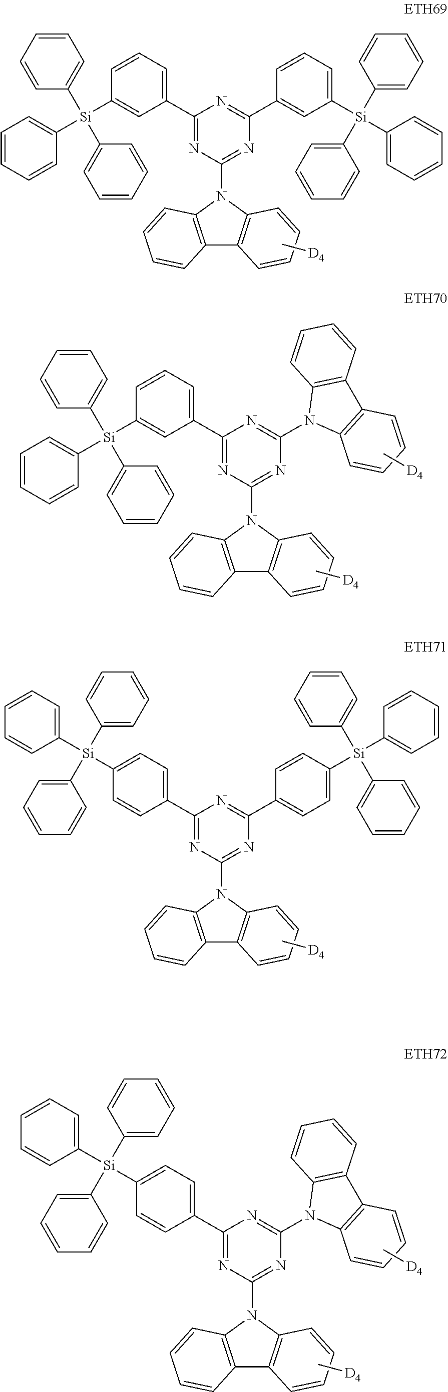

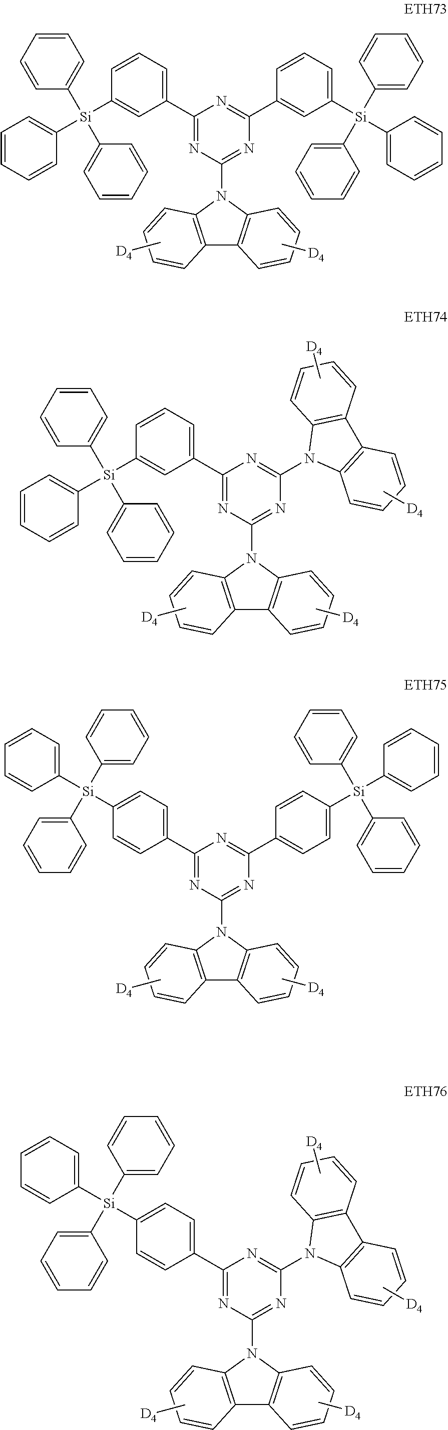

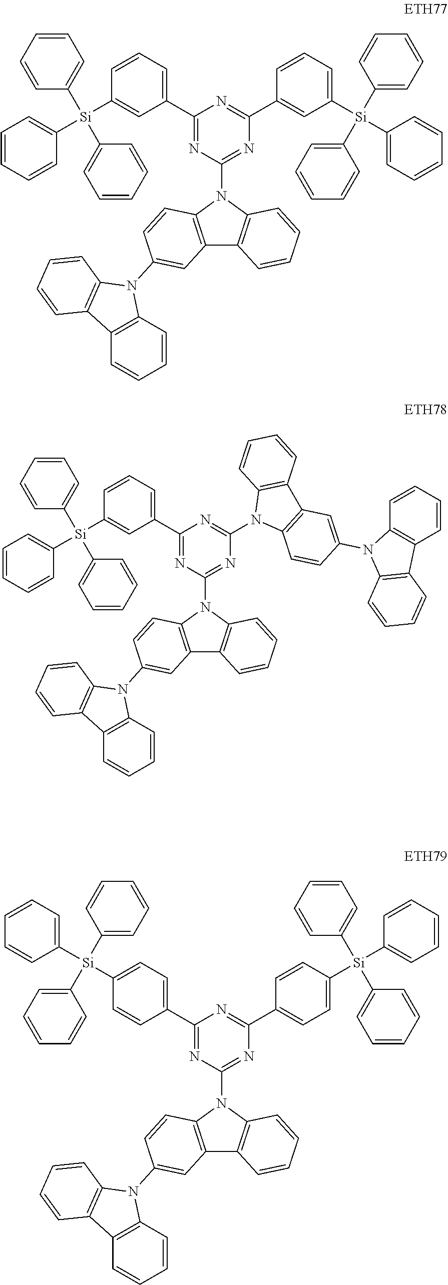 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

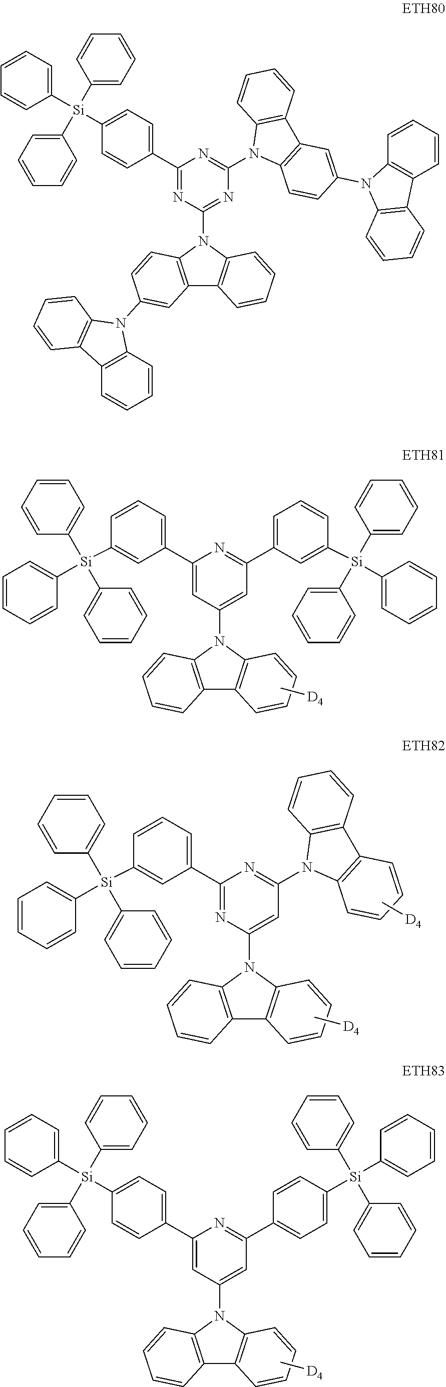

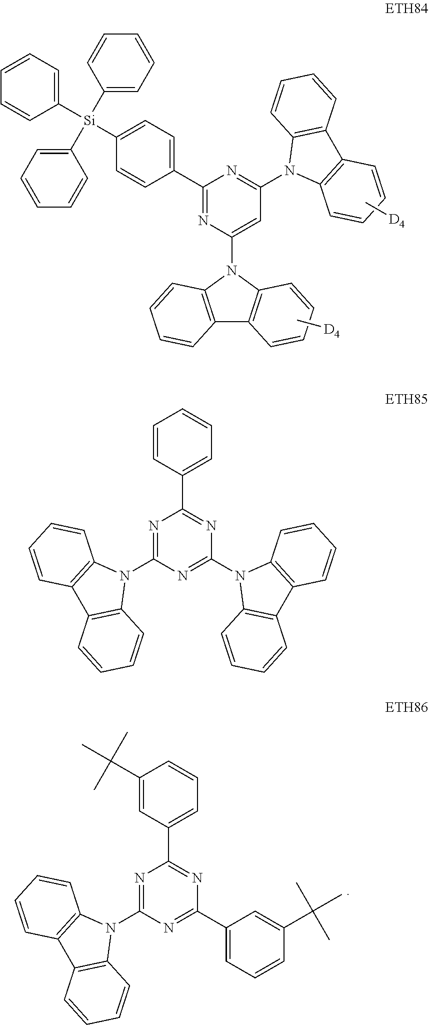

In an embodiment, the emission layer EML may include a compound represented by Formula E-2a or Formula E-2b. The compound represented by Formula E-2a or Formula E-2b may be utilized as a phosphorescent host material.

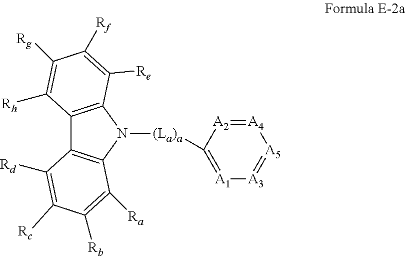

In Formula E-2a, a may be an integer from 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Las may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A5 may be N or Crᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or linked to an adjacent group to form a ring. Rₐ to Rᵢ may be linked to an adjacent group to form a hydrocarbon ring or a heterocycle containing N, O, S, etc. as a ring-forming atom.

In some embodiments, in Formula E-2a, two or three selected from A₁ to A₅ may be N, and the rest may be Crᵢ.

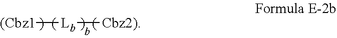

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer from 0 to 10, and when b is an integer of 2 or greater, a plurality of L_{b}s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among Compound E-2-1 to Compound E-2-24 of Compound Group E-2. However, Compounds E-2-1 to E-2-24 are presented merely as examples, and the compound represented by Formula E-2a or Formula E-2b is not limited to Compounds E-2-1 to E-2-24.

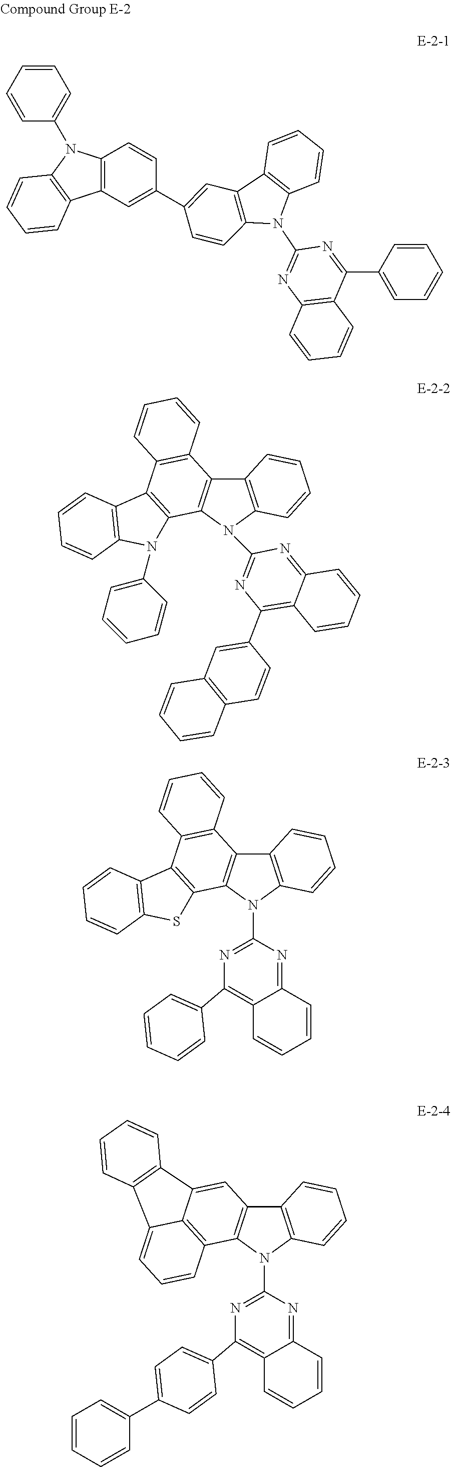

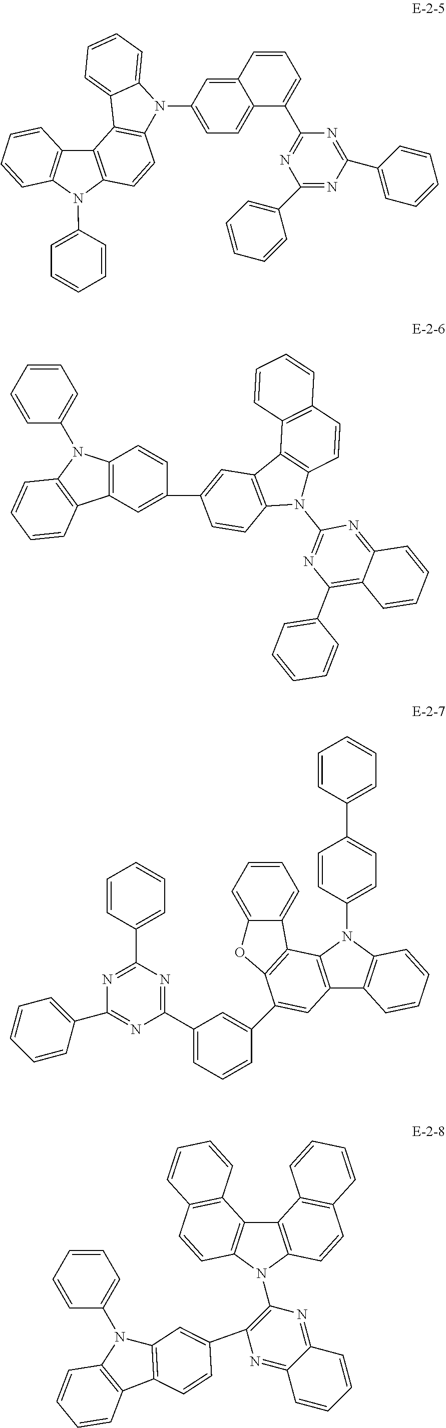 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

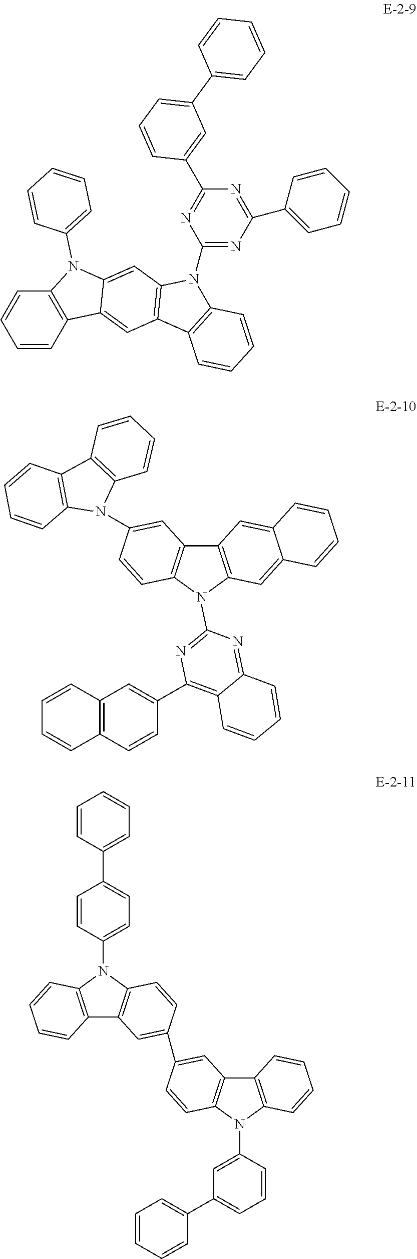 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

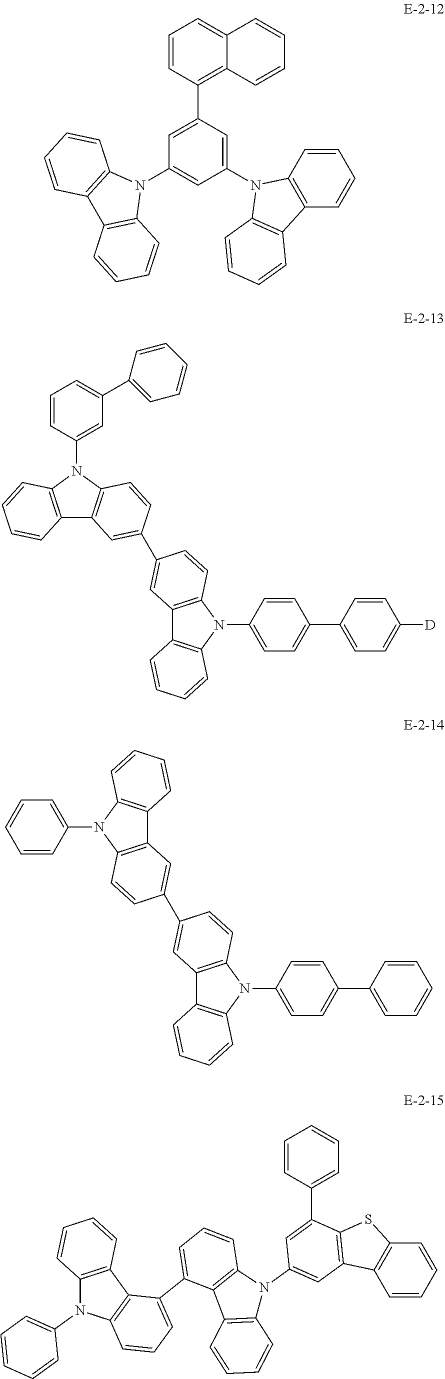 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

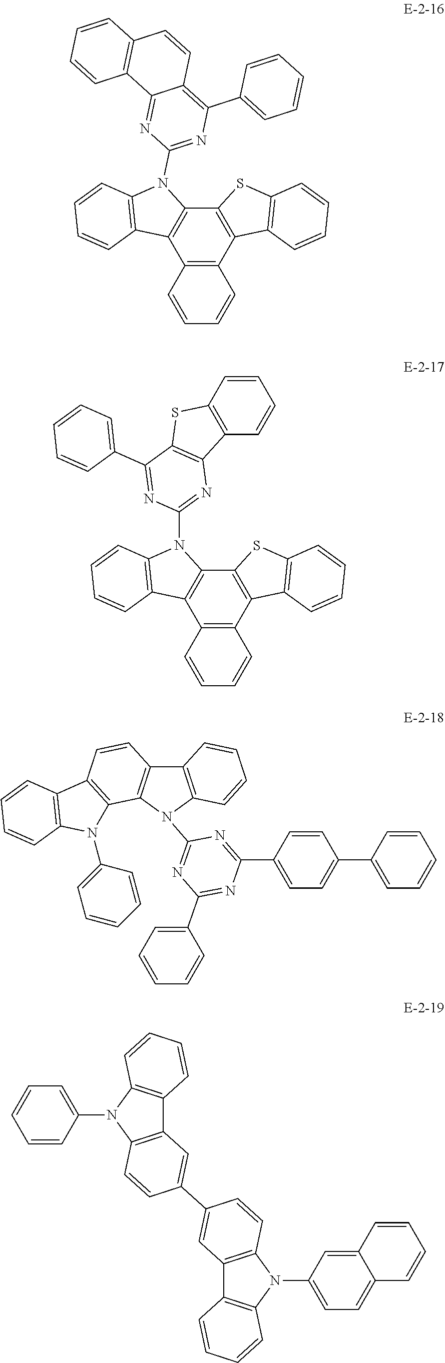 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

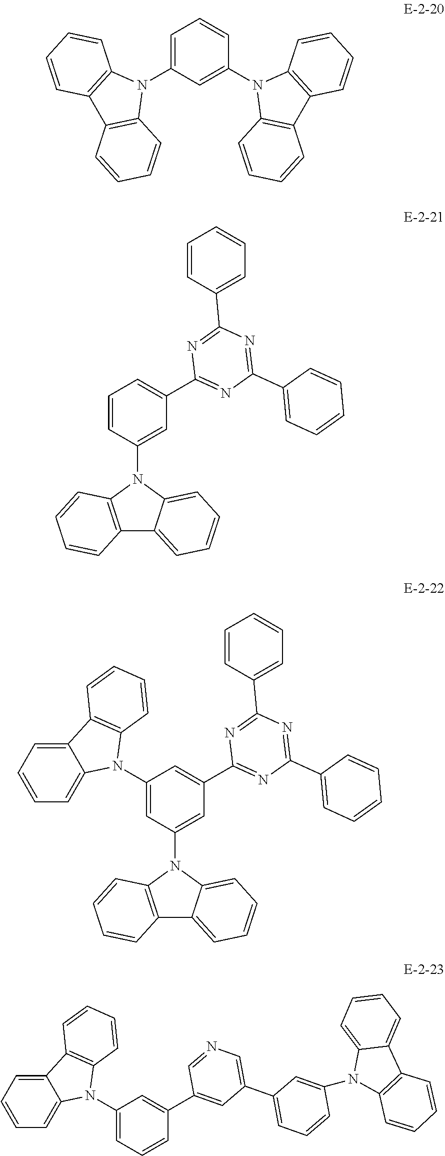 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

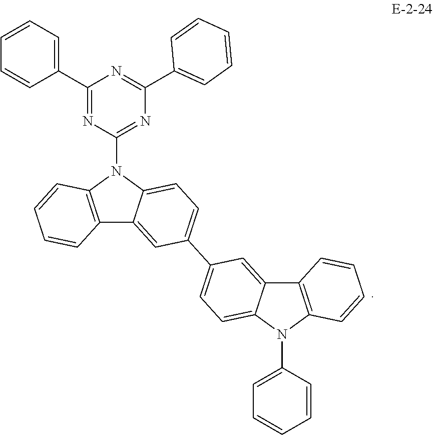 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a generally utilized/generally available material known in the art as a host material. For example, the emission layer EML may include, as a host material, at least one selected from among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the embodiment of the present disclosure is not limited thereto, and for example, tris(8-hydroxyquinolinato)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include a compound represented by Formula M-a. The compound represented by Formula M-a may be utilized as a phosphorescent dopant material. In some embodiments, the compound represented by Formula M-a may be utilized as an assistant dopant material.

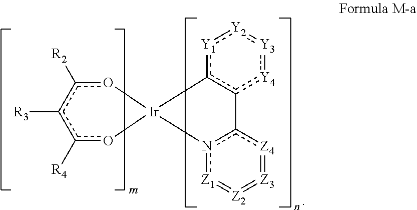

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected framong compounds M-a1 to M-a25. However, the compounds M-a1 to M-a25 are presented merely as examples, and the compound represented by Formula M-a is not limited to those represented by the compounds M-a1 to M-a25.

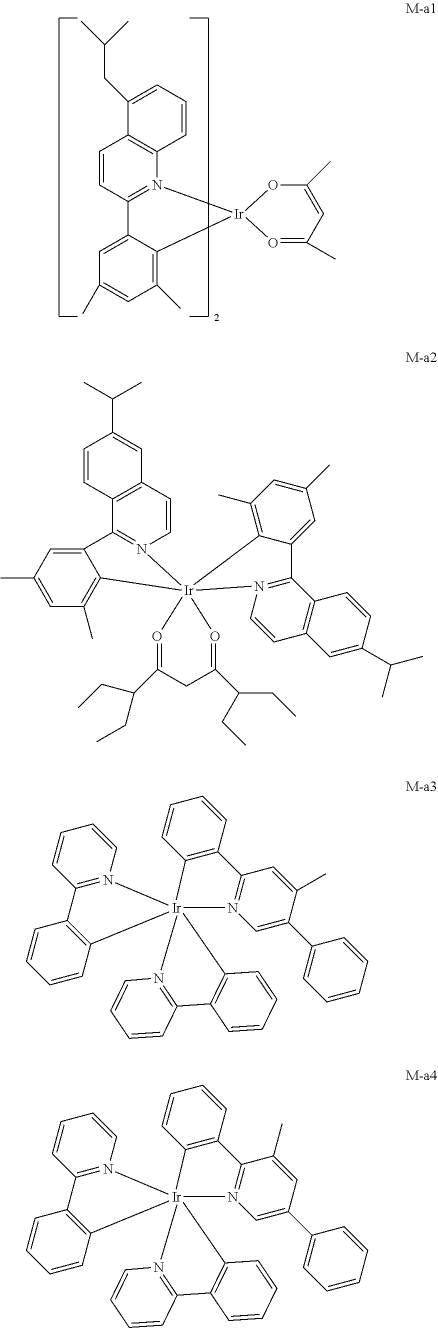

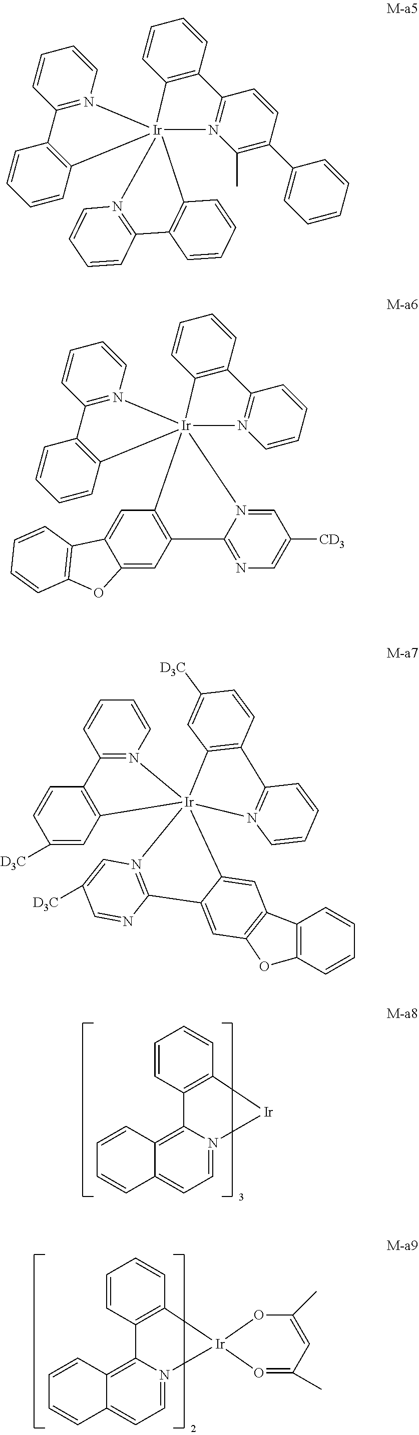

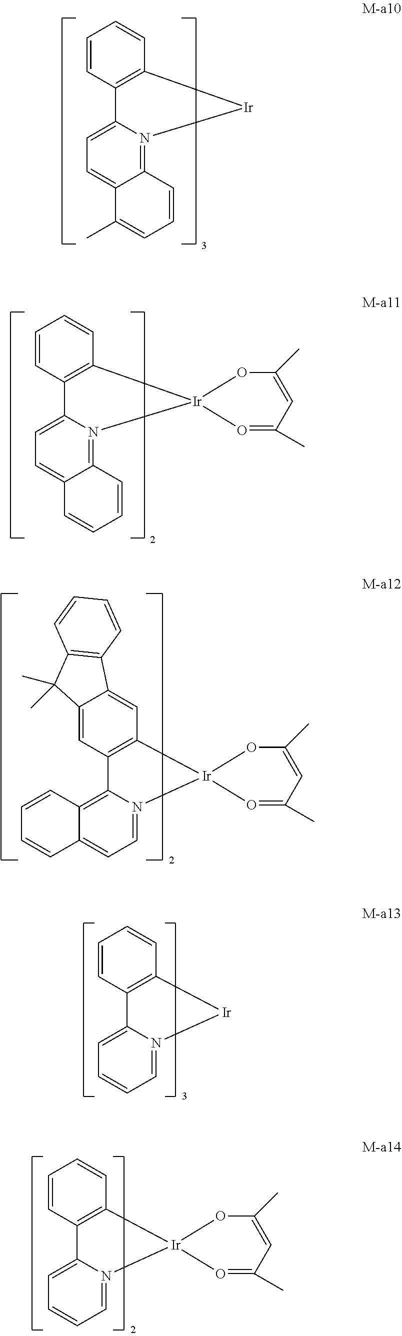

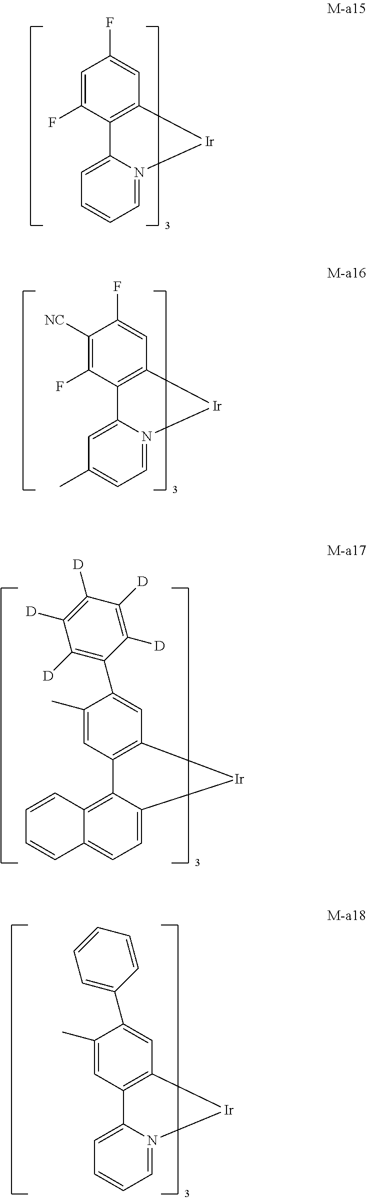

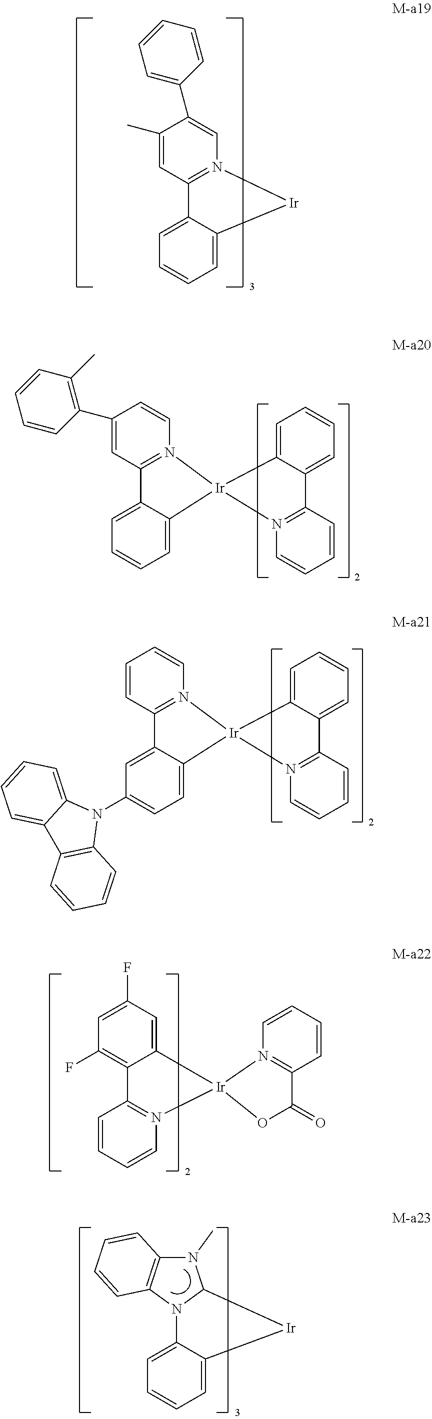

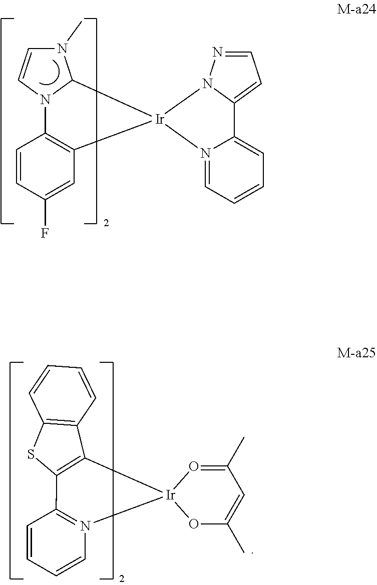

The compounds M-a1 and M-a2 may be utilized as a red dopant material, and the compounds M-a3 to M-a7 may be utilized as a green dopant material.

The emission layer EML may include Pt (platinum) as a central metal atom and an organometallic complex containing ligands bonded to the central metal atom as the fourth compound. In the light emitting element ED of an embodiment, the emission layer EML may include a compound represented by Formula M-b as the fourth compound.

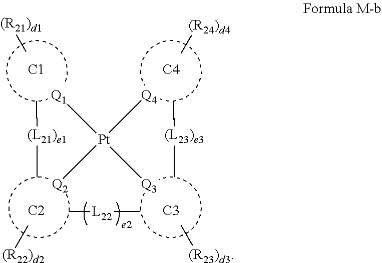

In Formula M-b, Q₁ to Q₄ may each independently be C or N.

C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

L₂₁ to L₂₄ may each independently be a direct linkage,

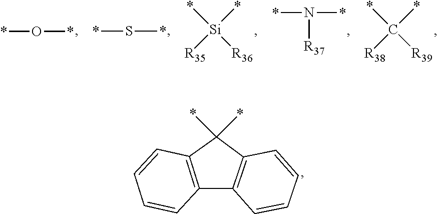

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₂₁ to L₂₃,

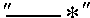

indicates a site connected to C1 to C4.

d1 to d4 may each independently be an integer from 0 to 4. When d1 to d4 are each an integer of 2 or greater, a plurality of R₂₁ to R₂₄ may all be the same or at least one may be different.

e1 to e3 may each independently be 0 or 1. When e1 is 0, C1 and C2 may not be connected. When e2 is 0, C2 and C3 may not be connected. When e3 is 0, C3 and C4 may not be connected.

R₂₁ to R₂₄, and R₃₅ to R₃₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, R₂₁ to R₂₄, and R₃₅ to R₃₉ may each independently be a substituted or unsubstituted methyl group, or a 10 substituted or unsubstituted t-butyl group.

In some embodiments, C1 to C4 may each independently be a substituted or unsubstituted hydrocarbon ring or a substituted or unsubstituted heterocycle, which is represented by any one among C-1 to C-3.

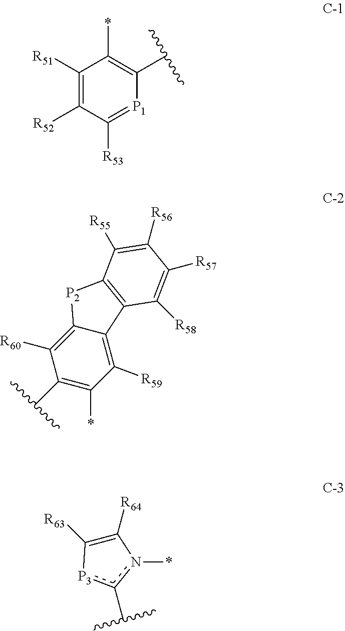

In C-1 to C-3, P₁— may be

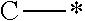 [SMILES: *C]

or CR₅₄, P₂ may be

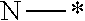 [SMILES: *N]

or NR₆₁, and P₃ may be

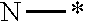 [SMILES: *N]

### or NR₆₂.

R₅₁ to R₆₄ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 6 to 30 ring-forming carbon atoms, and/or bonded to an adjacent group to form a ring.

In some embodiments, in C-1 to C-3,

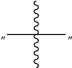

indicates a portion connected to the central metal atom, and

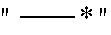 [SMILES: *C]

indicates a portion connected to neighboring ring groups (C1 to C4) or linkers (L₂₁ to L₂₄).

The compound represented by Formula M-b may be utilized as a blue phosphorescent dopant or a green phosphorescent dopant.

The compound represented by Formula M-b may be represented by any one selected from among compounds from Compound Group 4. The emission layer EML may include one or more of compounds selected from among Compound Group 4 as a sensitizer. However, the compounds are presented merely as examples, and the compound represented by Formula M-b is not limited to those represented by the compounds of Compound Group 4.

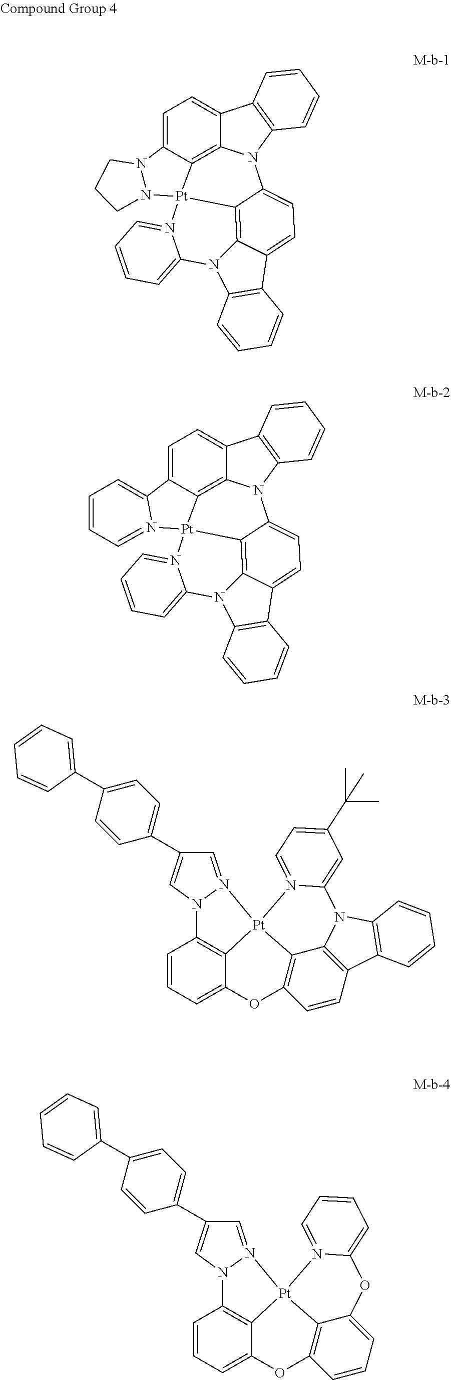

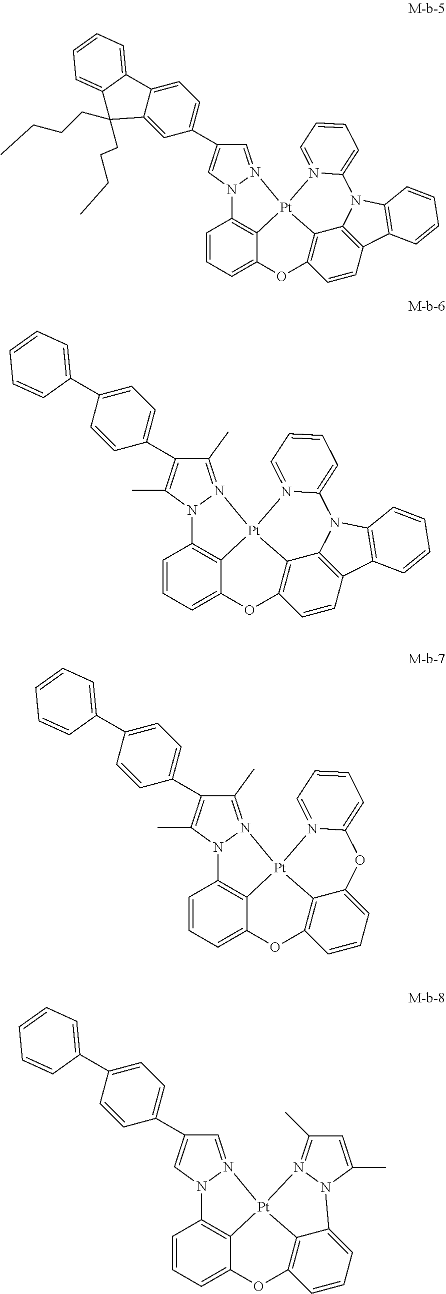

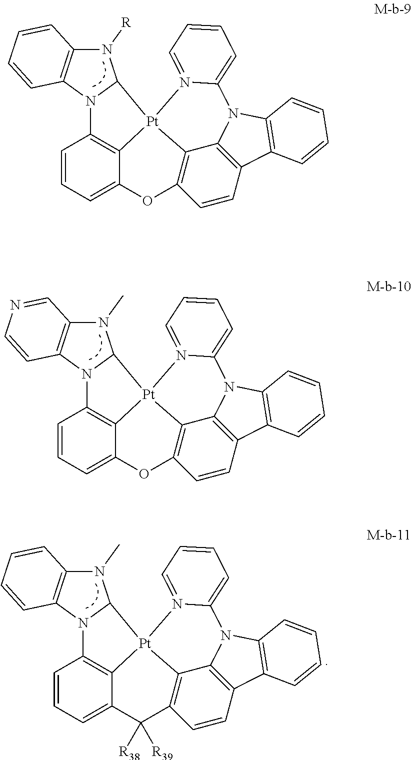

In the compounds above, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may further include a compound represented by any one of Formulas F-a to F-c. The compounds represented by Formulas F-a to F-c may be utilized as a fluorescent dopant material.

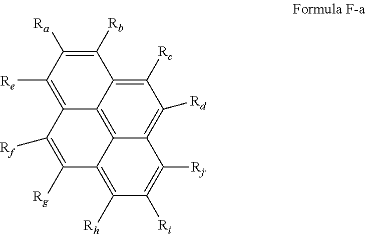

In Formula F-a, two selected from Rₐ to Rⱼ may each independently be substituted with

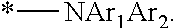

The others among Rₐ to Rⱼ which are not substituted with

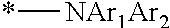

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In

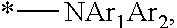

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing 0 or S as a ring-forming atom.

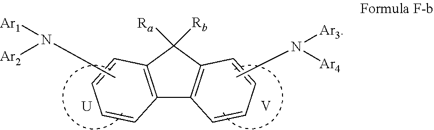

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or linked to an adjacent group to form a ring.

In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, In Formula F-b, when the number of U or V is 1, one ring forms a fused ring in a portion indicated by U or V, and when the number of U or V is 0, it refers to no ring indicated by U or V being present. For example, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are 0, the fused ring of Formula F-b may be a cyclic compound having three rings. In some embodiments, when both (e.g., simultaneously) U and V are 1, the fused ring having a fluorene core of Formula F-b may be a cyclic compound having five rings.

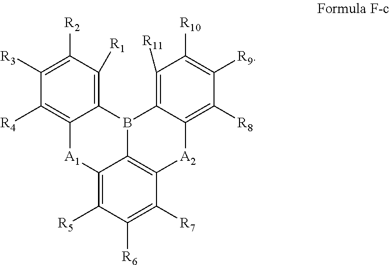

In Formula F-c, A₁ and A₂ may each independently be 0, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring.

In Formula F-c, A₁ and A₂ may each independently be bonded to substituents of neighboring rings to form a fused ring. For example, when A₁ and A₂ are each independently NRₘ, A₁ may be bonded to R₄ or R₅ to form a ring. In some embodiments, A2 may be bonded to R₇ or R₈ to form a ring.

The emission layer EML may include, as a generally utilized/generally available dopant material, styryl derivatives (e.g., 1,4-bis[2-(3-N-ethylcarbazolyl)vinyl]benzene (BCzVB), 4-(di-p-tolylamino)-4″-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), perylene and/or derivatives thereof (e.g., 2,5,8,11-tetra-t-butylperylene (TBP)), pyrene and/or derivatives thereof (e.g., 1,1′-dipyrene, 1,4-dipyrenylbenzene, 1,4-bis(N,N-diphenylamino)pyrene), etc.

The emission layer EML may include a generally utilized/generally available phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be utilized. For example, bis(4,6-difluorophenylpyridinato-C², N)(picolinate) iridium(III) (Flrpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

The emission layer EML may include a quantum dot material. The core of a quantum dot may be selected from among a Group II-VI compound, a Group III-VI compound, a Group I-III-VI compound, a Group III-V compound, a Group III-II-V compound, a Group IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The Group III-VI compound may include a binary compound such as In₂S₃ and In₂Se₃, a ternary compound such as InGaS₃ and InGaSe₃, or one or more combinations thereof.

The Group compound may include a ternary compound selected from the group including (e.g., consisting of) AgInS, AgInS₂, CuInS, CuInS₂, AgGaS₂, CuGaS₂ CuGaO₂, AgGaO₂, AgAlO₂, or one or more compounds or mixtures thereof, and/or a quaternary compound such as AgInGaS₂ and CuInGaS₂ (the quaternary compound may be used alone or in combination with any of the foregoing compounds or mixtures; and the quaternary compound may also be combined with other quaternary compounds).

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and a mixture thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and a quaternary compound selected from the group including (e.g., consisting of) SnPbSSe, SnPbSeTe, SnPbSTe, and one or more compounds or mixtures thereof. The Group IV element may be selected from the group including (e.g., consisting of) Si, Ge, and one or more elements or mixtures thereof. The Group IV compound may be a binary compound selected from the group including (e.g., consisting of) SiC, SiGe, and one or more compounds or mixtures thereof.

In this embodiment, the binary compound, the ternary compound, or the quaternary compound may be present in a particle form having a substantially uniform concentration distribution, or may be present in substantially the same particle form having a partially different concentration distribution. In some embodiments, a core/shell structure in which one quantum dot surrounds another quantum dot may be present. The core/shell structure may have a concentration gradient in which the concentration of an element present in the shell decreases towards the core.

In some embodiments, a quantum dot may have the core/shell structure including a core having nano-crystals, and a shell around (e.g., surrounding) the core, which are described above. The shell of the quantum dot may serve as a protection layer to prevent or reduce the chemical deformation of the core so as to keep semiconductor properties, and/or a charging layer to impart electrophoresis properties to the quantum dot. The shell may be a single layer or a plurality of layers. Examples of the shell of the quantum dot may be a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

A quantum dot may have a full width of half maximum (FWHM) of a light emitting wavelength spectrum of about 45 nm or less, about 40 nm or less, or about 30 nm or less, and color purity or color reproducibility may be enhanced in the above ranges. In some embodiments, light emitted through such a quantum dot is emitted in all directions, and thus a wide viewing angle may be improved.

In some embodiments, the form of a quantum dot is not limited as long as it is a form generally utilized/generally available in the art, for example, a quantum dot in the form of substantially spherical, pyramidal, multi-arm, or cubic nanoparticles, nanotubes, nanowires, nanofibers, nanoplatelets, etc. may be utilized.

The quantum dot may control (select) the colors of emitted light according to the particle size thereof, and thus the quantum dot may have one or more suitable light emission colors such as blue, red, green, etc.

In the light emitting element ED of an embodiment shown in FIGS. 3 to 6, an electron transport region ETR is provided on the emission layer EML. The electron transport region ETR may include at least one selected from among a hole blocking layer HBL, an electron transport layer ETL, and an electron injection layer EIL, but the embodiment of the present disclosure is not limited thereto.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL, or an electron transport layer ETL/buffer layer/electron injection layer EIL are stacked in order (in the stated order) from the emission layer EML, but is not limited thereto. The electron transport region ETR may have a thickness of, for example, about 1000 Å to about 1500 Å.

The electron transport region ETR may be formed utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a third compound represented by Formula ET-1 described above.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or one or more compounds or mixtures thereof.

The electron transport region ETR may include one or more of compounds ET1 to ET36.

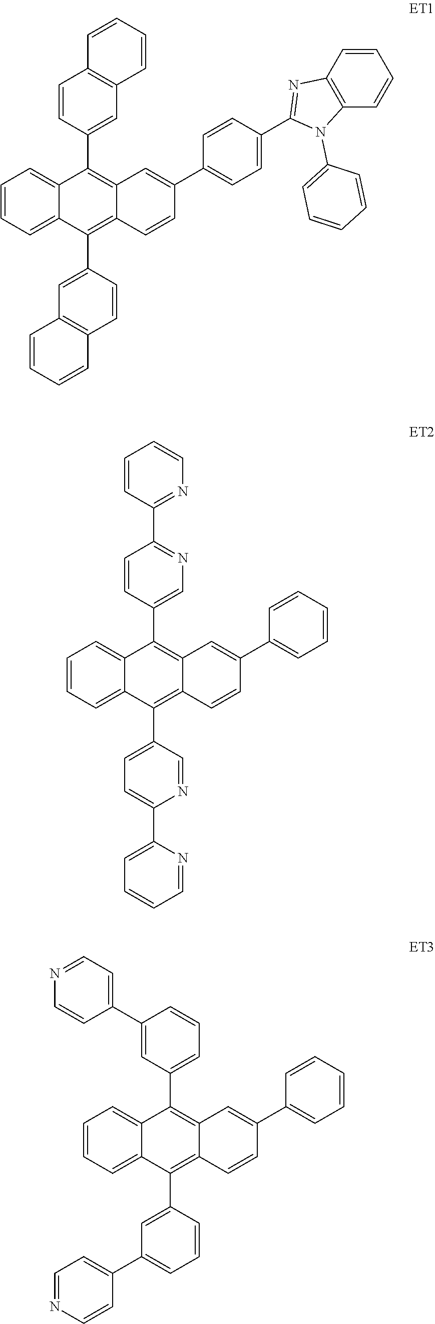 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

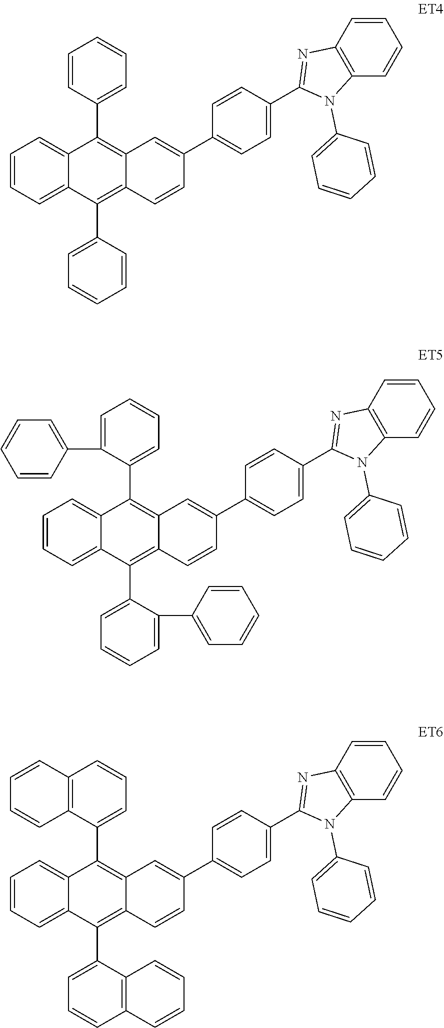 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

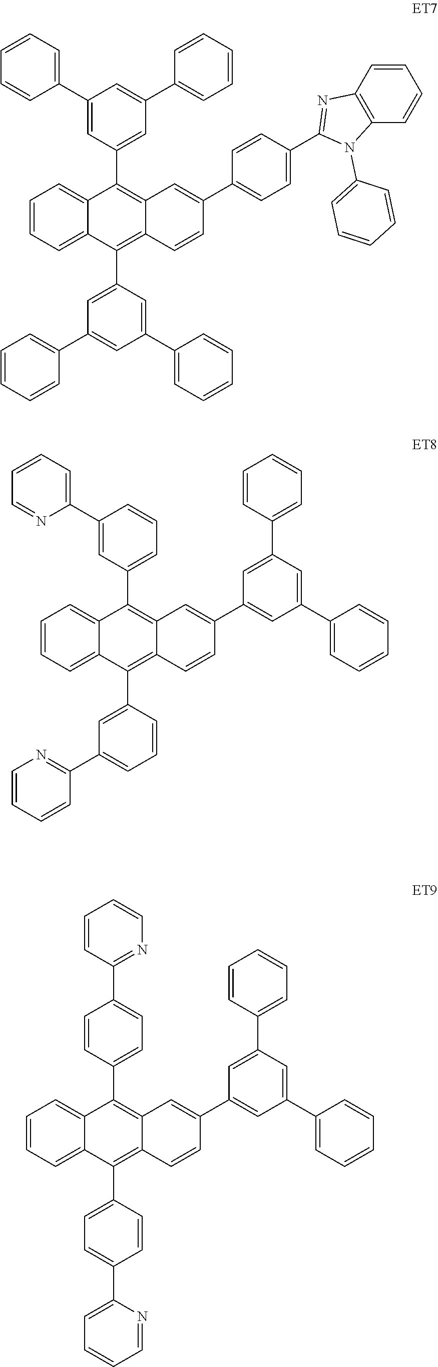 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

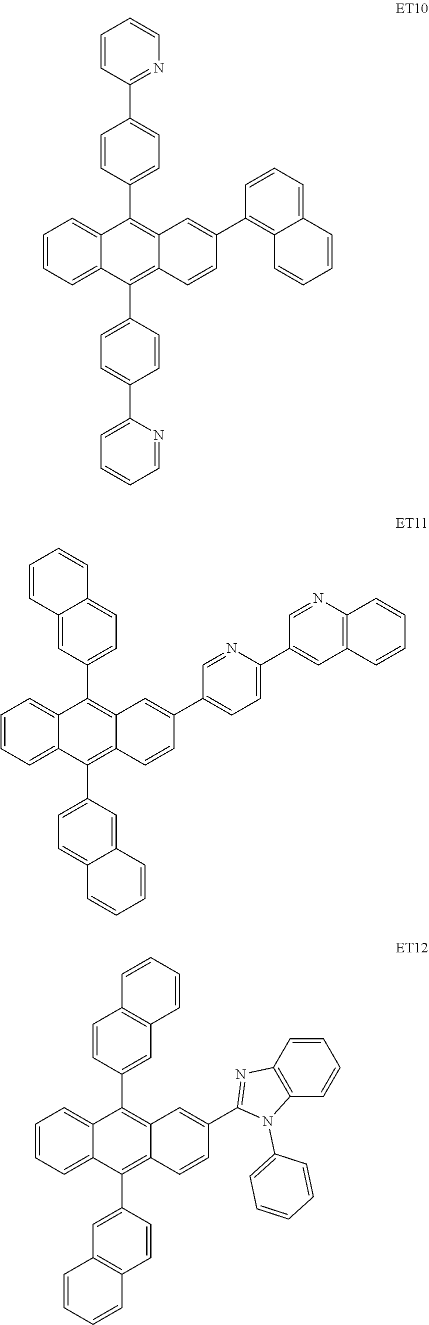 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

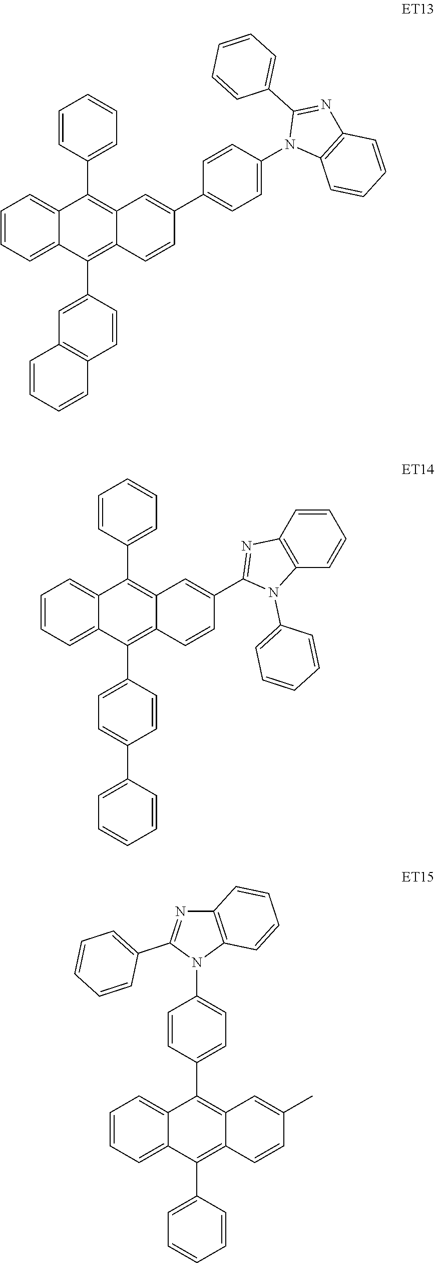 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

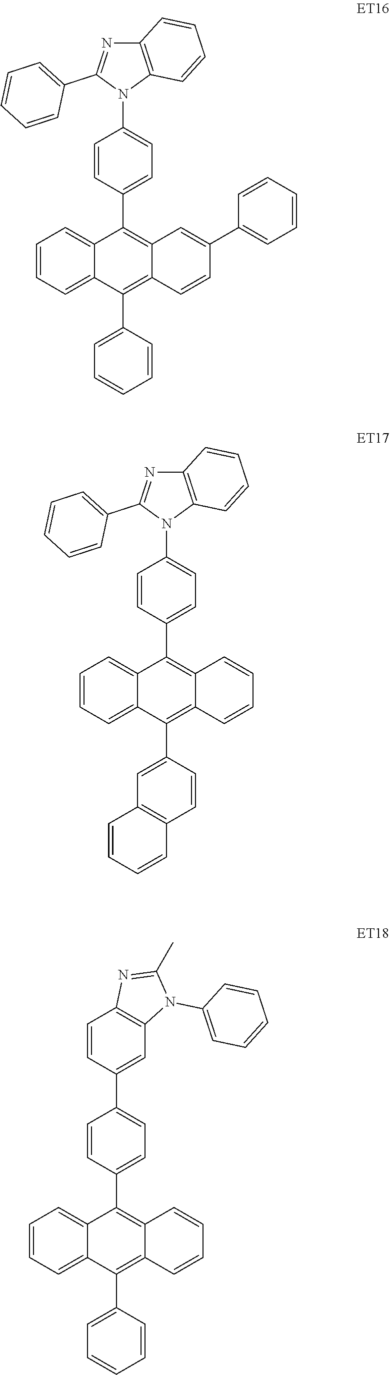 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

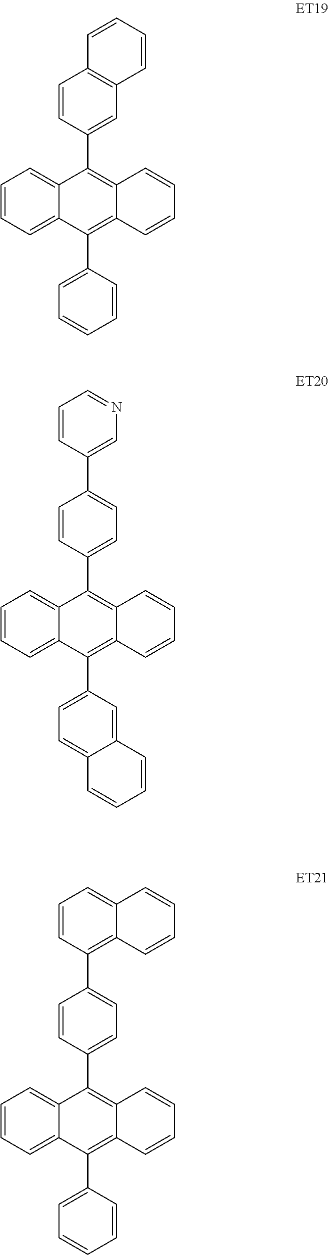

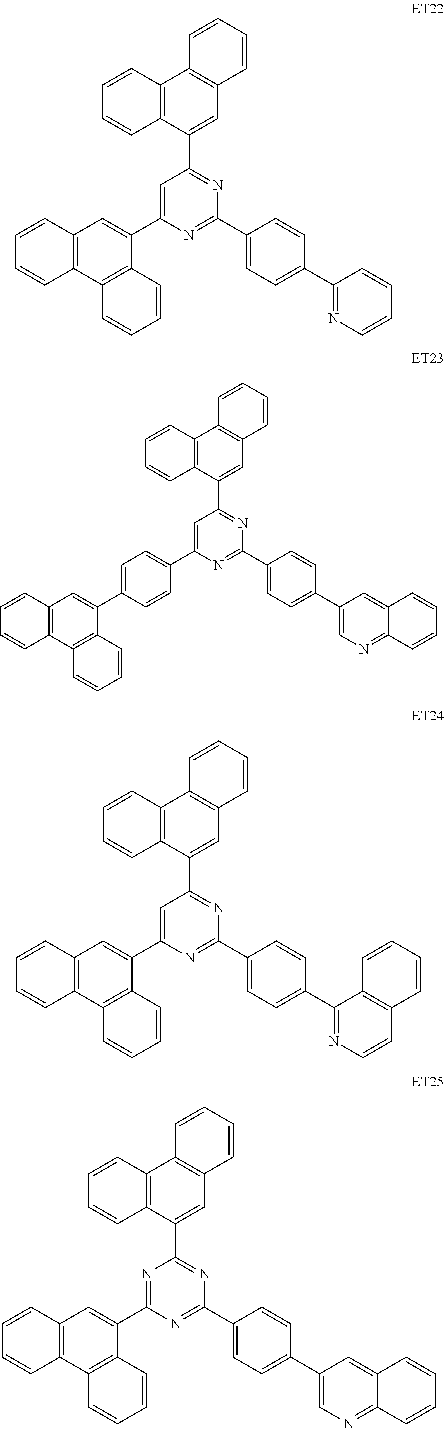 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

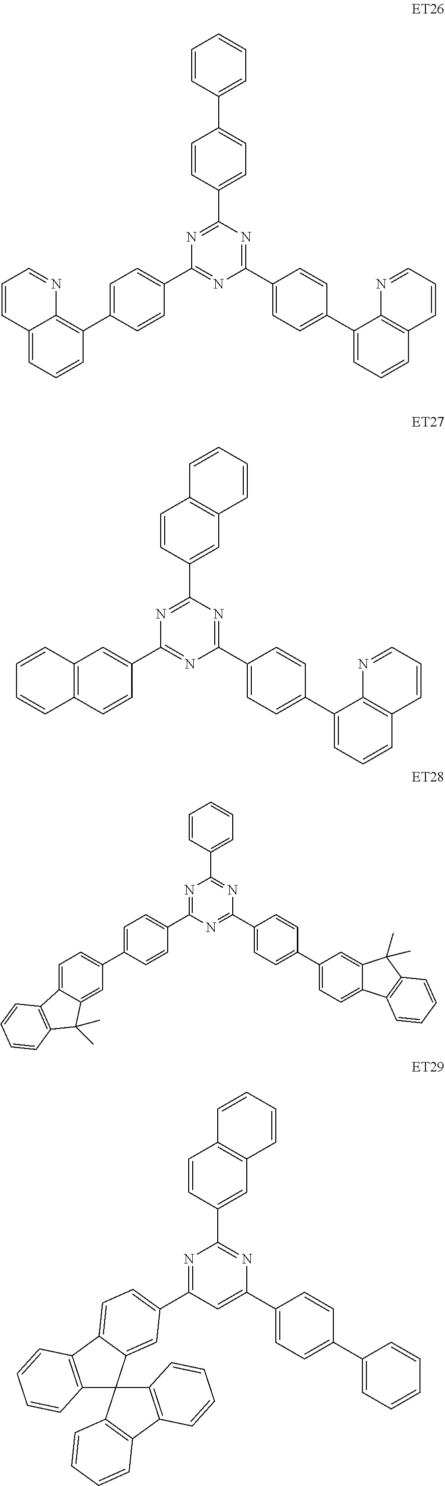 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

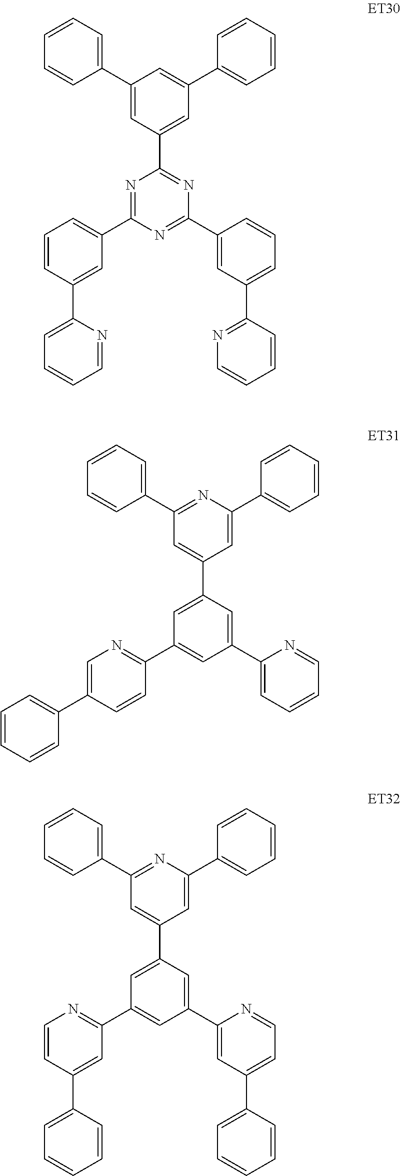 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

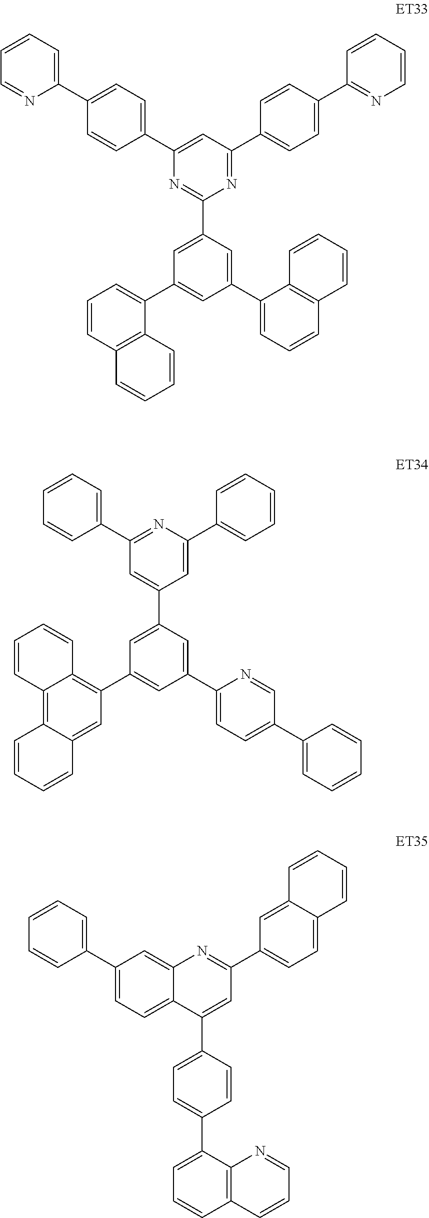 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

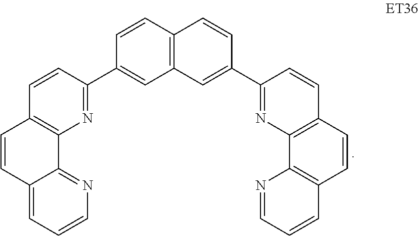 [SMILES: c1cnc2c(c1)ccc1ccc(-c3ccc4ccc(-c5ccc6ccc7cccnc7c6n5)cc4c3)nc12]

In some embodiments, the electron transport region ETR may include halogenated metals such as LiF, NaCl, CsF, RbCl, RbI, CuI, and/or KI, lanthanide metals such as Yb, co-deposition materials of a halogenated metal and/or a lanthanide metal. For example, the electron transport region ETR may include KI:Yb, RbI:Yb, LiF:Yb, etc. as a co-deposition material. In some embodiments, for the electron transport region ETR, a metal oxide such as Li₂O and BaO, or 8-hydroxyl-lithium quinolate (Liq), etc. may be utilized, but the embodiment of the present disclosure is limited thereto. The electron transport region ETR may also be formed of a mixture material of an electron transport material and an insulating organo-metal salt. The organo-metal salt may be a material having an energy band gap of about 4 eV or greater. For example, the organo-metal salt may include, for example, metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but the embodiment of the present disclosure is not limited thereto.

The electron transport region ETR may include the compounds of the electron transport region described above in at least one selected from among the electron injection layer EIL, the electron transport layer ETL, and the hole blocking layer HBL.

When the electron transport region ETR includes the electron transport layer ETL, the electron transport layer ETL may have a thickness of about 100 Å to about 1000 Å, for example, about 150 Å to about 500 Å. When the thickness of the electron transport layer ETL satisfies the above-described range, satisfactory (suitable) electron transport properties may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory (suitable) electron injection properties may be obtained without a substantial increase in driving voltage.

The second electrode EL2 is provided on the electron transport region ETR. The second electrode EL2 may be a common electrode. The second electrode EL2 may be a cathode or an anode but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or one or more oxides thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, compounds thereof, or mixtures thereof (e.g., AgMg, AgYb, or MgYb). In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or one or more oxides of the above-described metal materials.

The second electrode EL2 may be connected with an auxiliary electrode. When the second electrode EL2 is connected with the auxiliary electrode, the resistance of the second electrode EL2 may decrease.

In some embodiments, a capping layer CPL may be further disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., or may include one or more of epoxy resins or acrylates such as methacrylates. However, the embodiment of the present disclosure is not limited thereto, and the capping layer CPL may include one or more of compounds P1 to P5.

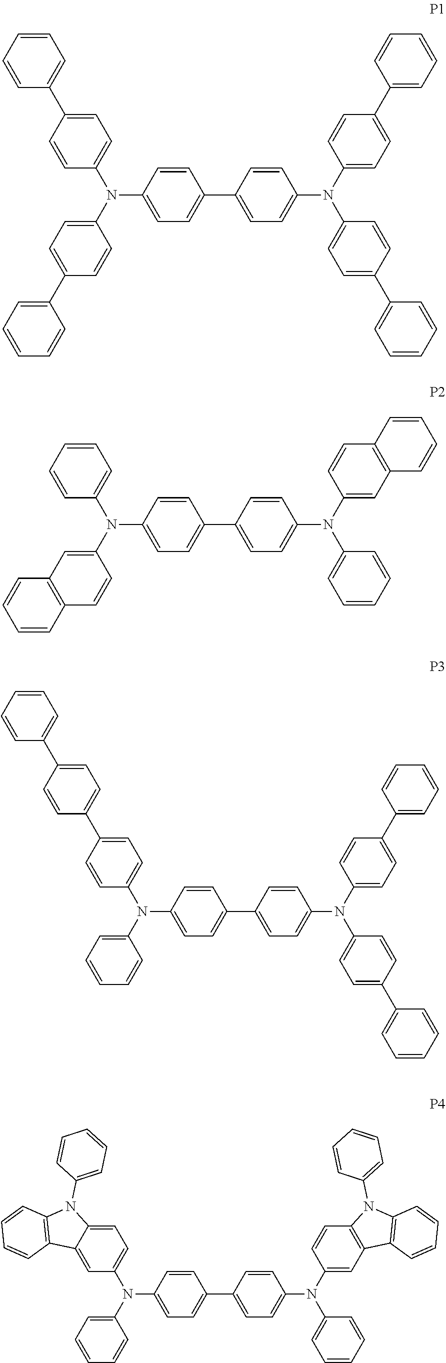 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

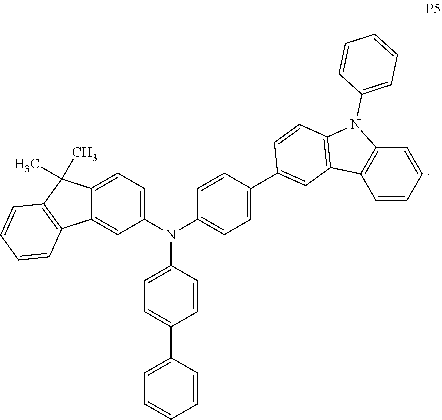 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or greater. For example, the capping layer CPL may have a refractive index of about 1.6 or greater in a wavelength range of about 550 nm to about 660 nm.

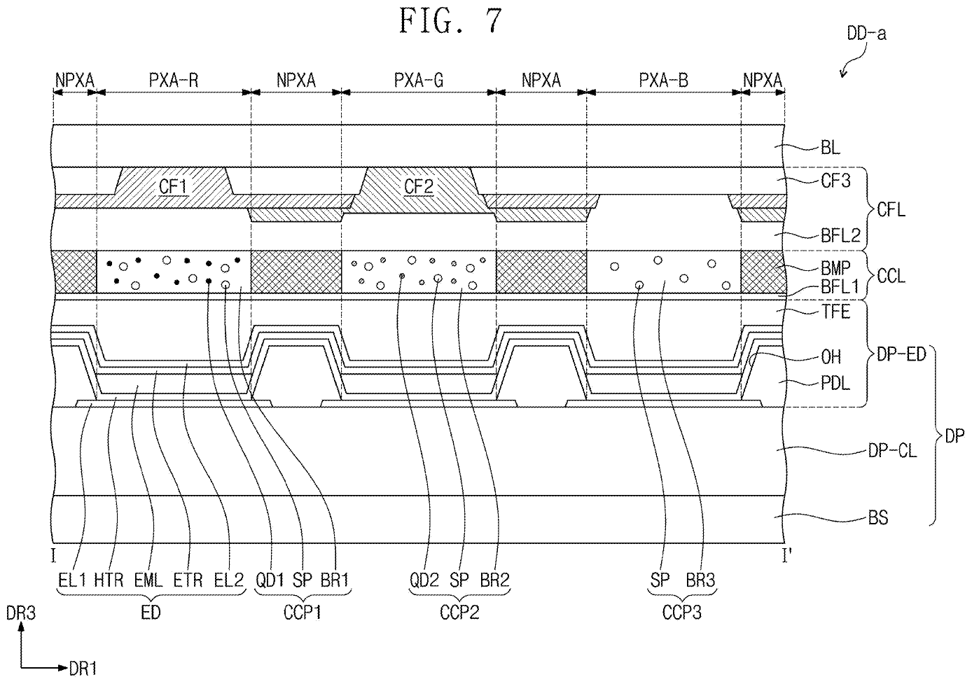

FIGS. 7 to 10 are each a cross-sectional view of a display device according to an embodiment. Hereinafter, in the description of the display device according to an embodiment with reference to FIGS. 7 and 10, content (e.g., amount) overlapping the one described above with reference to FIGS. 1 to 6 may not be described again, and the differences will be primarily described.

Referring to FIG. 7, a display device DD-a according to an embodiment may include a display panel DP having a display element layer DP-ED, a light control layer CCL on the display panel DP, and a color filter layer CFL.

In an embodiment shown in FIG. 7, the display panel DP may include a base layer BS, a circuit layer DP-CL provided on the base layer BS, and a display element layer DP-ED, and the element layer DP-ED may include a light emitting element ED.

The light emitting element ED may include a first electrode EL1, a hole transport region HTR on the first electrode EU, an emission layer EML on the hole transport region HTR, an electron transport region ETR on the emission layer EML, and a second electrode EL2 on the electron transport region ETR. In some embodiments, a structure of the light emitting element ED shown in FIG. 7 may be the same as the structure of the light emitting element of FIGS. 3 to 6 described above.

The emission layer EML of the light emitting element ED included in a display device DD-a according to an embodiment may include the polycyclic compound of an embodiment described above.

Referring to FIG. 7, the emission layer EML may be disposed in the openings OH defined in the pixel defining films PDL. For example, the emission layer EML separated by the pixel defining films PDL and provided corresponding to each of light emitting regions PXA-R, PXA-G, and PXA-B may emit light in substantially the same wavelength ranges. In the display device DD-a of an embodiment, the emission layer EML may emit blue light. In some embodiments, the emission layer EML may be provided as a common layer throughout the light emitting regions PXA-R, PXA-G, and PXA-B.

The light control layer CCL may be on the display panel DP. The light control layer CCL may include a light converter. The light converter may be a quantum dot or a phosphor. The light converter may wavelength-convert the provided light and emit the wavelength-converted light. For example, the light control layer CCL may be a layer containing quantum dots or phosphors.

The light control layer CCL may include a plurality of light control units CCP1, CCP2, and CCP3. The light control units CCP1, CCP2, and CCP3 may be spaced apart from (separated from) each other.

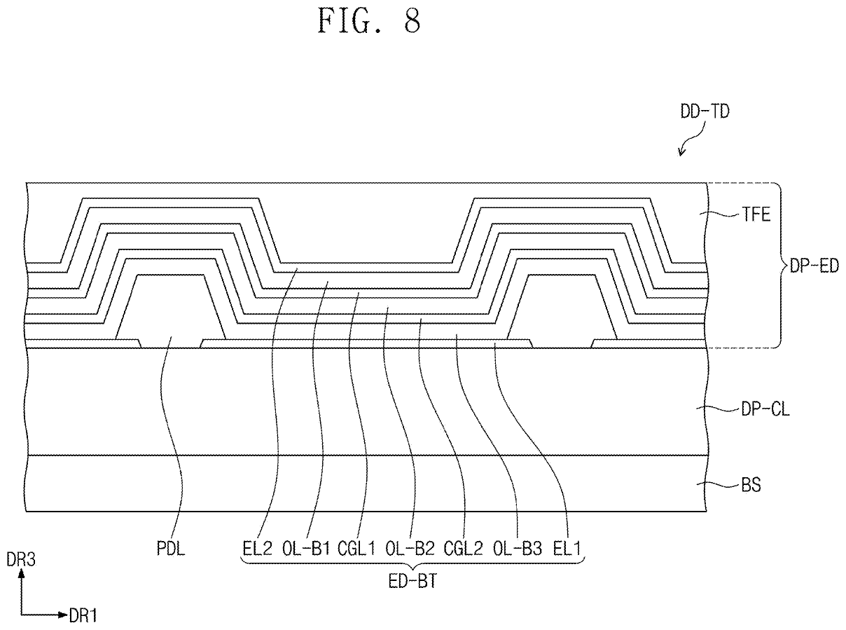

Referring to FIG. 7, a division pattern BMP may be disposed between the light control units CCP1, CCP2, and CCP3 spaced apart from (separated from) each other, but the embodiment of the present disclosure is not limited thereto. In FIG. 8, the division pattern BMP is shown to not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting first color light provided from the light emitting element ED into second color light, a second light control unit CCP2 including a second quantum dot QD2 for converting the first color light into third color light, and a third light control unit CCP3 transmitting the first color light.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot and the second quantum dot QD2 may be a green quantum dot. The same descriptions above may be applied to the quantum dots QD1 and QD2.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) a quantum dot but may include the scatterers SP.

The scatterers SP may be inorganic particles. For example, the scatterers SP may include at least one selected from among TiO₂, ZnO, Al₂O₃, SiO₂, and hollow silica. The scatterers SP may include any one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light control unit CCP1, the second light control unit CCP2, and the third light control unit CCP3 may include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include (e.g., may just include) the scatterers SP dispersed in the third base resin BR3. The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may be an acrylic resin, a urethane-based resin, a silicone-based resin, an epoxy-based resin, etc. The base resins BR1, BR2, and BR3 may be a transparent resin. In an embodiment, the first base resin BR1, the second base resin BR2, and the third base resin BR3 may each be the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may be disposed on the light control units CCP1, CCP2, and CCP3 to prevent or reduce the light control units CCP1, CCP2, and CCP3 from being exposed to moisture/oxygen. In some embodiments, the barrier layer BFL1 may cover the light control units CCP1, CCP2, and CCP3. In some embodiments, a barrier layer BFL2 may be provided between the light control units CCP1, CCP2, and CCP3 and filters CF1, CF2, and CF3.

The barrier layers BFL1 and BFL2 may include one or more inorganic layers. For example, the barrier layers BFL1 and BFL2 may be formed of an inorganic material. For example, the barrier layers BFL1 and BFL2 may be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly disposed on the light control layer CCL. In this embodiment, the barrier layer BFL2 may not be provided.

The color filter layer CFL may include filters CF1, CF2, and CF3. For example, the color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, a pigment and/or a dye. The first filter CF1 may include a red pigment and/or a red dye, the second filter CF2 may include a green pigment and/or a green dye, and the third filter CF3 may include a blue pigment and/or a blue dye. The embodiment of the present disclosure is not limited thereto, and the third filter CF3 may not include (e.g., may exclude) any pigment or dye. The third filter CF3 may include a polymer photosensitive resin, but not include any pigment or dye. The third filter CF3 may be transparent. The third filter CF3 may be formed of a transparent photosensitive resin.

In some embodiments, the first filter CF1 and the second filter CF2 may be yellow filters. The first filter CF1 and the second filter CF2 may not be separated and may be provided as a single body. The first to third filters CF1, CF2, and CF3 may be disposed corresponding to the red light emitting region PXA-R, the green light emitting region PXA-G, and the blue light emitting region PXA-B, respectively.

In some embodiments, the color filter layer CFL may include a light blocking unit. The color filter layer CFL may include the light blocking unit disposed to overlap the boundaries of the neighboring filters CF1, CF2, and CF3. The light blocking unit may be a black matrix. The light blocking unit may be formed including an organic light blocking material or an inorganic light blocking material, both (e.g., simultaneously) including a black pigment and/or a black dye. The light blocking unit may separate boundaries between the adjacent filters CF1, CF2, and CF3. In some embodiments, in an embodiment, the light blocking unit may be formed of a blue filter.

The base substrate BL may be on the color filter layer CFL. The base substrate BL may be a member providing a base surface on which the color filter layer CFL and the light control layer CCL are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In an embodiment, the base substrate BL may not be provided.

FIG. 8 is a cross-sectional view showing a portion of a display device according to an embodiment. FIG. 8 shows a cross-sectional view of a portion corresponding to the display panel DP of FIG. 7. In a display device DD-TD of an embodiment, a light emitting element ED-BT may include a plurality of light emitting structures OL-B1, OL-B2, and OL-B3. The light emitting element ED-BT may include the first electrode EL1 and the second electrode EL2 facing each other, and the plurality of light emitting structures OL-B1, OL-B2, and OL-B3 provided by being sequentially stacked in a thickness direction between the first electrode EL1 and the second electrode EL2. The light emitting structures OL-B1, OL-B2, and OL-B3 each may include the emission layer EML (FIG. 7), a hole transport region HTR and an electron transport region ETR disposed with the emission layer EML (FIG. 7) therebetween.

For example, the light emitting element ED-BT included in the display device DD-TD of an embodiment may be a light emitting element having a tandem structure including a plurality of emission layers.

In an embodiment shown in FIG. 8, light emitted from each of the light emitting structures OL-B1, OL-B2, and OL-B3 may all be blue light. However, the embodiment of the present disclosure is not limited thereto, and wavelength ranges of light emitted from each of the light emitting structures OL-B1, OL-B2, and OL-B3 may be different from each other. For example, the light emitting element ED-BT including the plurality of light emitting structures OL-B1, OL-B2, and OL-B3 emitting light in different wavelength ranges may emit white light.

Charge generation layers CGL1 and CGL2 may be disposed between neighboring light emitting structures OL-B1, OL-B2, and OL-B3. The charge generation layers CGL1 and CGL2 may include a p-type or kind charge generation layer (e.g., P-charge generation layer) and/or an n-type or kind charge generation layer (e.g., N-charge generation layer).

At least one of the light emitting structures selected from among OL-B1, OL-B2, and OL-B3 included in the display device DD-TD of an embodiment may include the polycyclic compound of an embodiment described above. For example, at least one of the plurality of emission layers included in the light emitting element ED-BT may include a polycyclic compound according to an embodiment.

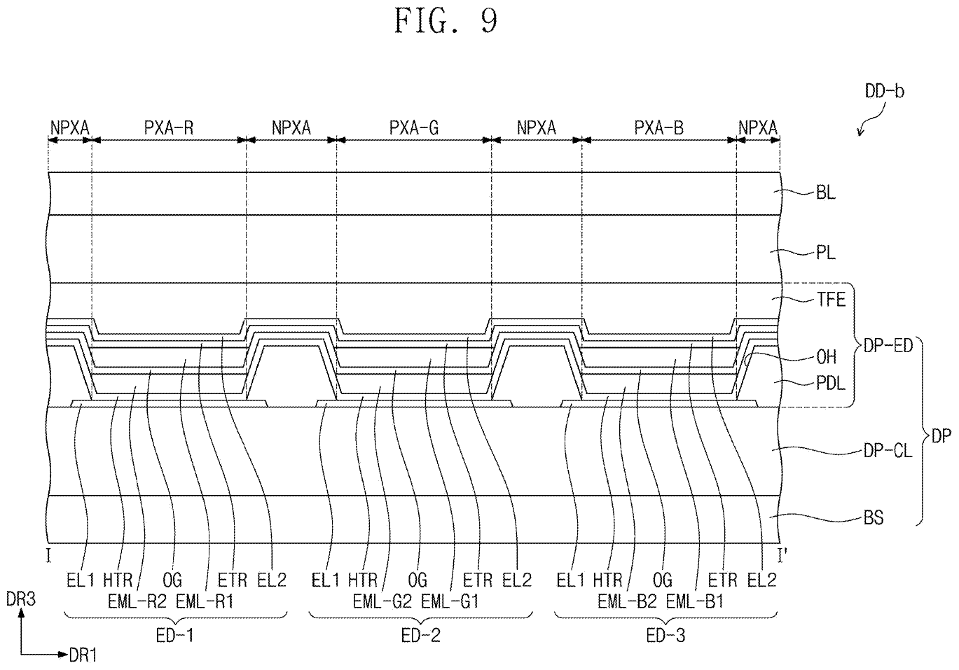

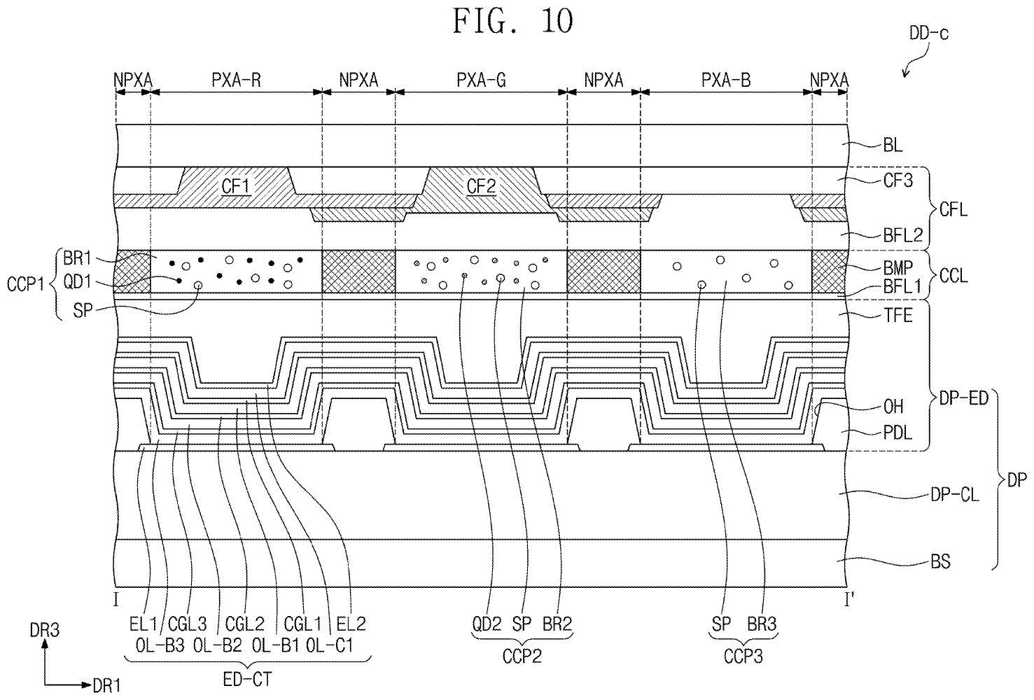

Referring to FIG. 9, a display device DD-b according to an embodiment may include light emitting elements ED-1, ED-2, and ED-3 in which two emission layers are stacked. Compared to the display device DD according to an embodiment shown in FIG. 2, a difference is that in an embodiment shown in FIG. 9, the first to third light emitting elements ED-1, ED-2, and ED-3 each include two emission layers stacked in a thickness direction. In each of the first to third light emitting elements ED-1, ED-2, and ED-3, the two emission layers may emit light in substantially the same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. A light emitting auxiliary portion OG may be between the first red emission layer EML-R₁ and the second red emission layer EML-R2 (along the thickness direction), between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. For example, the light emitting auxiliary portion OG may include an electron transport region, a charge generation layer, and a hole transport region that are sequentially stacked (in the stated order). The light emitting auxiliary portion OG may be provided as a common layer throughout the first to third light emitting elements ED-1, ED-2, and ED-3. However, the embodiment of the present disclosure is not limited thereto, and the light emitting auxiliary portion OG may be provided to be patterned inside the openings OH defined in the pixel defining films PDL.

The first red emission layer EML-R1, the first green emission layer EML-G1, and the first blue emission layer EML-B1 may be between the electron transport region ETR and the emission auxiliary portion OG. The second red emission layer EML-R2, the second green emission layer EML-G2, and the second blue emission layer EML-B2 may be between the emission auxiliary portion OG and the hole transport region HTR.

For example, the light emitting element ED-1 may include the first electrode EL1, the hole transport region HTR, the second red emission layer EML-R2, the emission auxiliary portion OG, the first red emission layer EML-R1, the electron transport region ETR, and the second electrode EL2, which are sequentially stacked (in the stated order). The second light emitting element ED-2 may include the first electrode EU, the hole transport region HTR, the second green emission layer EML-G2, the emission auxiliary portion OG, the first green emission layer EML-G1, the electron transport region ETR, and the second electrode EL2, which are sequentially stacked (in the stated order). The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, which are sequentially stacked (in the stated order).

In some embodiments, an optical auxiliary layer PL may be on the display element layer DP-ED. The optical auxiliary layer PL may include a polarizing layer. The optical auxiliary layer PL may be on the display panel DP to control reflected light in the display panel DP due to external light. The optical auxiliary layer PL may not be provided in the display device according to an embodiment.

At least one emission layer included in a display device DD-b according to an embodiment shown in FIG. 9 may include the polycyclic compound according to an embodiment, described above. For example, at least one of the first blue emission layer EML-B1 or the second blue emission layer EML-B2 may include the polycyclic compound according to an embodiment.

The display device DD-c of FIG. 10 is shown to include four light emitting structures OL-B1, OL-B2, OL-B3, and OL-C1. The light emitting element ED-BT may include the first electrode EL1 and the second electrode EL2 facing each other, and the first to fourth light emitting structures L-B1, OL-B2, OL-B3, and OL-C1 sequentially stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1, respectively. Among the four light emitting structures, the first to third light emitting structures OL-B1, OL-B2, and OL-B3 may emit blue light, and the fourth light emitting structure OL-C1 may emit green light. However, the embodiment of the present disclosure is not limited thereto, and the first to fourth light emitting structures OL-B1, OL-B2, OL-B3, and OL-C1 may emit light having different wavelength ranges.

The charge generation layers CGL1, CGL2 and CGL3 disposed between the neighboring light emitting structures OL-B1, OL-B2, OL-B3, and OL-C1 may include a p-type or kind charge generation layer and/or an n-type or kind charge generation layer.

One or more of the light emitting structures selected from among OL-B1, OL-B2, OL-B3, and OL-C1 included in the display device DD-c of an embodiment may include the polycyclic compound of an embodiment described above. For example, in an embodiment, one or more of the first to third light emitting structures selected from among OL-B1, OL-B2, and OL-B3 may include a polycyclic compound according to an embodiment, which is described above.

The light emitting element ED according to an embodiment of the present disclosure may include the polycyclic compound of an embodiment described above in at least one functional layer disposed between the first electrode EL1 and the second electrode EL2, and may thus exhibit improved lifespan characteristics. For example, the polycyclic compound according to an embodiment may be included in the emission layer EML of the light emitting element ED of an embodiment, and the light emitting element according to an embodiment may exhibit a long lifespan.

The polycyclic compound of an embodiment, which is described above includes a C—C bond or a C—Si bond, including a core containing carbon atoms, silicon atoms, boron atoms, and nitrogen atoms to increase bond dissociation energy of molecules, and may thus exhibit high material stability. In some embodiments, the polycyclic compound of an embodiment includes an ortho-type or kind terphenyl group (e.g., an ortho-terphenyl group) in the core to reduce intermolecular interactions, increase thermal stability of molecules, and/or reduce deterioration of an element, thereby increasing lifespan.

The light emitting element of the present disclosure includes the polycyclic compound of an embodiment in an emission layer to increase lifespan and luminous efficiency of an element.

Hereinafter, with reference to Examples and Comparative Examples, a polycyclic compound and a light emitting element according to an embodiment of the present disclosure will be described in more detail. In some embodiments, Examples shown below are presented primarily for the understanding of the present disclosure, and the scope of the present disclosure is not limited thereto.

### EXAMPLES

### 1. Synthesis of Polycyclic Compounds

First, a process of synthesizing polycyclic compounds according to an embodiment of the present disclosure will be described in more detail by providing a process of synthesizing Compound 1, Compound 24, Compound 29, Compound 39, Compound 41, Compound 49, Compound 61, and Compound 69 as examples. In some embodiments, a process of synthesizing polycyclic compounds, which will be described hereinafter, is provided merely as an example, and thus a process of synthesizing polycyclic compounds according to an embodiment of the present disclosure is not limited to the Examples.

### 1) Synthesis of Compound 1

Compound 1 according to an embodiment may be synthesized by, for example, a process of Reaction Formula 1.

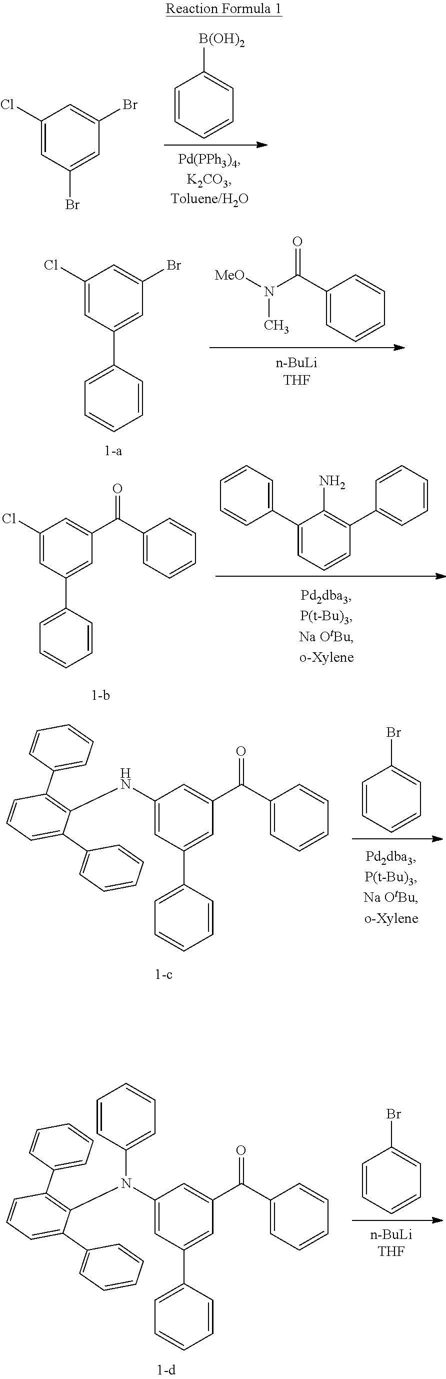

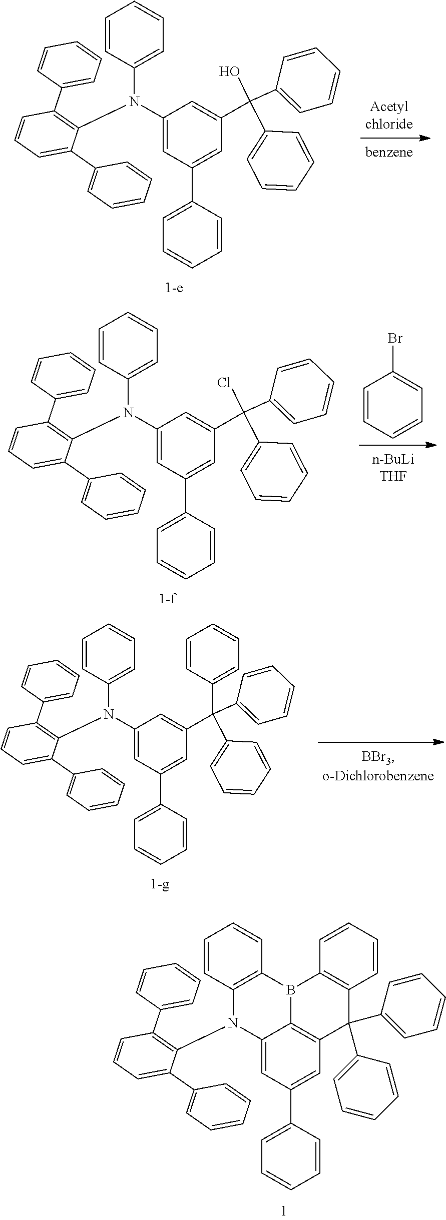

### (1) Synthesis of Intermediate 1-a

In an argon atmosphere, in a 2 L flask, phenyl boronic acid (1 eq), 1,3-dibromo-5-chlorobenzene (2.5 eq), Pd(PPh₃)₄ (0.03 eq), and potassium carbonate (2 eq) were added and dissolved in toluene:H₂O (3:1), and then the reaction solution was stirred at 100° C. for 12 hours. After cooling the resultant product, water (1 L) and ethyl acetate (300 mL) were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-a (yield: 60%). It was confirmed that the obtained compound was Intermediate 1-a through ESI-LCMS.

ESI-LCMS: [M]⁺: C₁₂H₈BrCl. 265.9498

### (2) Synthesis of Intermediate 1-b

In an argon atmosphere, in a 1 L flask, Intermediate 1-a (1 eq) was dissolved in THF. At −78° C., n-BuLi (2.5 M) in hexane (1 eq) was slowly added dropwise. After 1 hour, N-methoxy-N-methylbenzamide (0.8 eq) was added thereto and stirred. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-b (yield: 71%). It was confirmed that the obtained compound was Intermediate 1-b through ESI-LCMS.

ESI-LCMS: [M]⁺: C₁₉H₁₃C₁₀. 292.0655.

### (3) Synthesis of Intermediate 1-c

In an argon atmosphere, in a 1 L flask, Intermediate 1-b (1 eq), [1,1′:3′,1″-terphenyl]-2′-amine (1 eq), Pd₂dba₃ (0.05 eq), tris-tert-butyl phosphine (0.1 eq), and sodium tert-butoxide (3 eq) were added and dissolved in o-xylene, and then the reaction solution was stirred at 140° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-c (yield: 68%). It was confirmed that the obtained compound was Intermediate 1-c through ESI-LCMS.

ESI-LCMS: [M]⁺: C₃₇H₂₇NO. 501.2093.

### (4) Synthesis of Intermediate 1-d

In an argon atmosphere, in a 1 L flask, Intermediate 1-c (1 eq), bromobenzenee (1 eq), Pd₂dba₃ (0.05 eq), tris-tert-butyl phosphine (0.1 eq), and sodium tert-butoxide (3 eq) were added and dissolved in o-xylene, and then the reaction solution was stirred at 140° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-d (yield: 72%). It was confirmed that the obtained compound was Intermediate 1-d through ESI-LCMS.

ESI-LCMS: [M]⁺: C₄₃H₃₁ NO. 577.2406.

### (5) Synthesis of Intermediate 1-e

In an argon atmosphere, in a 1 L flask, bromobenzene (1 eq) was dissolved in THF. At −78° C., n-BuLi (2.5 M) in hexane (1 eq) was slowly added dropwise. After 1 20 hour, Intermediate 1-d (0.8 eq) was added thereto and stirred. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-e (yield: 59%). It was confirmed that the obtained compound was Intermediate 1-e through ESI-LCMS.

ESI-LCMS: [M]⁺: C₄₉H₃₇NO. 655.2875.

### (6) Synthesis of Intermediate 1-f

In an argon atmosphere, in a 1 L flask, Intermediate 1-e (1 eq) was dissolved in benzene. Acetyl chloride (2.5 eq) was added thereto and the mixture was heated and stirred. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 1-f (yield: 67%). It was confirmed that the obtained compound was Intermediate 1-f through ESI-LCMS.

ESI-LCMS: [M]⁺: C₄₉H₃₆ClN. 673.2576.

### (7) Synthesis of Intermediate 1-g

Intermediate 1-g was synthesized in substantially the same manner as in the synthesis of Intermediate 1-e, utilizing Intermediate 1-f instead of Intermediate 1-d. (Yield: 65%). It was confirmed that the obtained solid was Intermediate 1-g through ESI-LCMS.

ESI-LCMS: [M]⁺: C₅₅H₄₁N. 715.3239.

### (8) Synthesis of Compound 1

In an argon atmosphere, in a 500 mL flask, Intermediate 1-g (1 eq) was added, dissolved in o-dichlorobenzene, and cooled to 0° C. utilizing water and ice, and BBr₃ (5 eq.) was slowly added dropwise, and then the reaction solution was stirred at 180° C. for 12 hours. After cooling the resultant product, triethylamine (5 equiv.) was added thereto to terminate the reaction, and the organic layer was collected through extraction utilizing water and CH₂Cl₂, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Compound 1 (yellow solid, yield: 11%). It was confirmed that the obtained compound was Compound 1 through 1H-NMR and ESI-LCMS.

¹H-NMR (400 MHz, CDCl₃): d=9.10 (d, 2H), 8.12 (s, 2H), 7.84 (m, 2H), 7.78-7.68 (m, 6H), 7.64-7.57 (m, 6H), 7.56-7.46 (m, 10H), 7.40-7.24 (m, 6H), 7.11 (d, 2H), 6.95 (m, 2H).

ESI-LCMS: [M]⁺: C₅₅H₃₈BN. 723.3097.

### 2) Synthesis of Compound 24

Compound 24 according to an embodiment may be synthesized by, for example, a process of Reaction Formula 2.

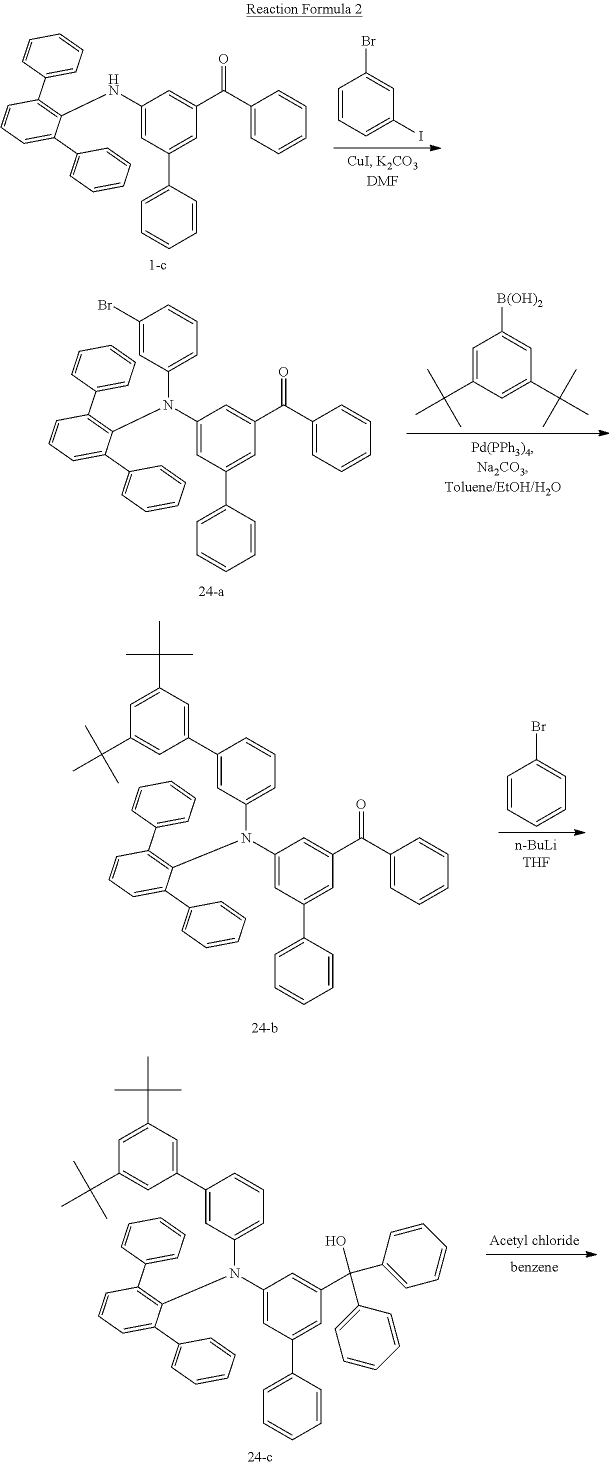

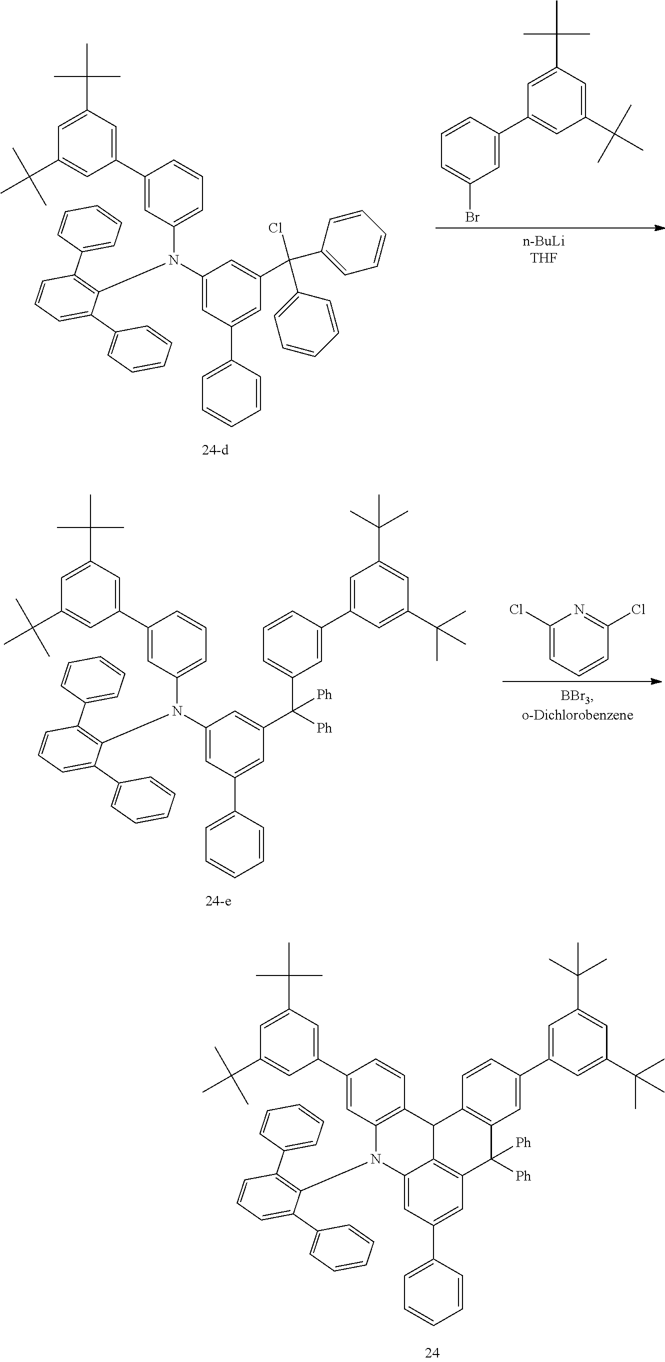

### (1) Synthesis of Intermediate 24-a

In an argon atmosphere, in a 1 L flask, Intermediate 1-c (1 eq), 1-bromo-3-iodobenzene (1 eq), copper iodide (1 eq), 1,10-phenanthroline (1 eq), and potassium carbonate (3 eq) were added and dissolved in DMF, and then the reaction solution was stirred at 160° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to synthesize Intermediate 24-a. (Yield: 47%). It was confirmed that the obtained solid was Intermediate 24-a through ESI-LCMS.

ESI-LCMS: [M]⁺: C₄₃H₃₀BrNO. 655.1511.

### (2) Synthesis of Intermediate 24-b

(3,5-di-tert-butylphenyl)boronic acid (1.5 eq), Intermediate 24-a (1 eq), tetrakis(triphenylphosphine)palladium(0) (0.05 eq), and sodium carbonate (3 eq) were dissolved in toluene, ethanol, and pure water (ratio of 1:1:3) and stirred at 100° C. for 12 hours in a nitrogen atmosphere. The resultant product was cooled and washed three times with ethyl acetate and water, and then the obtained organic layer was dried over magnesium sulfate, and dried under reduced pressure. The residue obtained by drying under reduced pressure was separated and purified through column chromatography to obtain Intermediate 24-b. (Yield: 68%). It was confirmed that the obtained solid was Intermediate 24-b through ESI-LCMS.

ESI-LCMS: [M]⁺: C₅₇H₅₁NO. 765.3971.

### (3) Synthesis of Intermediate 24-c

Intermediate 24-c was synthesized in substantially the same manner as in the synthesis of Intermediate 1-e, utilizing Intermediate 24-b instead of Intermediate 1-d. (Yield: 52%). It was confirmed that the obtained solid was Intermediate 24-c through ESI-LCMS.

ESI-LCMS: [M]⁺: C₆₃H₅₇NO. 843.4430

### (4) Synthesis of Intermediate 24-d

Intermediate 24-d was synthesized in substantially the same manner as in the synthesis of Intermediate 1-f, utilizing Intermediate 24-c instead of Intermediate 1-e. (Yield: 53%). It was confirmed that the obtained solid was Intermediate 24-d through ESI-LCMS.

ESI-LCMS: [M]⁺: C₆₃H₅₆ClN. 861.4101

### (5) Synthesis of Intermediate 24-e

Intermediate 24-e was synthesized in substantially the same manner as in the synthesis of Intermediate 1-g, utilizing Intermediate 24-d instead of Intermediate 1-f, and 3′-bromo-3,5-di-tert-butyl-1,1′-biphenyl instead of bromobenzene. (Yield: 42%). It was confirmed that the obtained solid was Intermediate 24-e through ESI-LCMS.

ESI-LCMS: [M]⁺: C₈₃H₈₁N. 1091.6369

### (5) Synthesis of Compound 24

In an argon atmosphere, Intermediate 24-e (1 eq) was added, dissolved in o-dichlorobenzene, and cooled to 0° C. utilizing water and ice, and BBr₃ (5 eq.) was slowly added dropwise, and then the mixture was stirred for 20 minutes before 2,6-dichloropyridine (3 eq.) was added dropwise. The mixture was stirred for 6 hours, and the reaction solution was stirred at 180° C. for 12 hours. After cooling the resultant product, triethylamine (5 equiv.) was added thereto to terminate the reaction, and the organic layer was collected through extraction utilizing water and CH₂Cl₂, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Compound 24. (Yellow solid, yield: 5%). It was confirmed that the obtained yellow solid was Compound 24 through ¹H-NMR and ESI-LCMS.

¹H-NMR (400 MHz, CDCl₃): d=9.34 (d, 2H), 8.20-8.01 (m, 4H), 7.84-7.70 (m, 4H), 7.65-7.50 (m, 6H), 7.50-7.42 (m, 6H), 7.38-7.25 (m, 4H), 7.18-7.10 (m, 6H), 7.08-7.01 (m, 4H), 6.89-6.81 (m, 6H), 1.32 (s, 36H).

ESI-LCMS: [M]⁺: C₈₃H₇₈BN. 1099.6227.

### 3) Synthesis of Compound 29

Compound 29 according to an embodiment may be synthesized by, for example, a process of Reaction Formula 3.

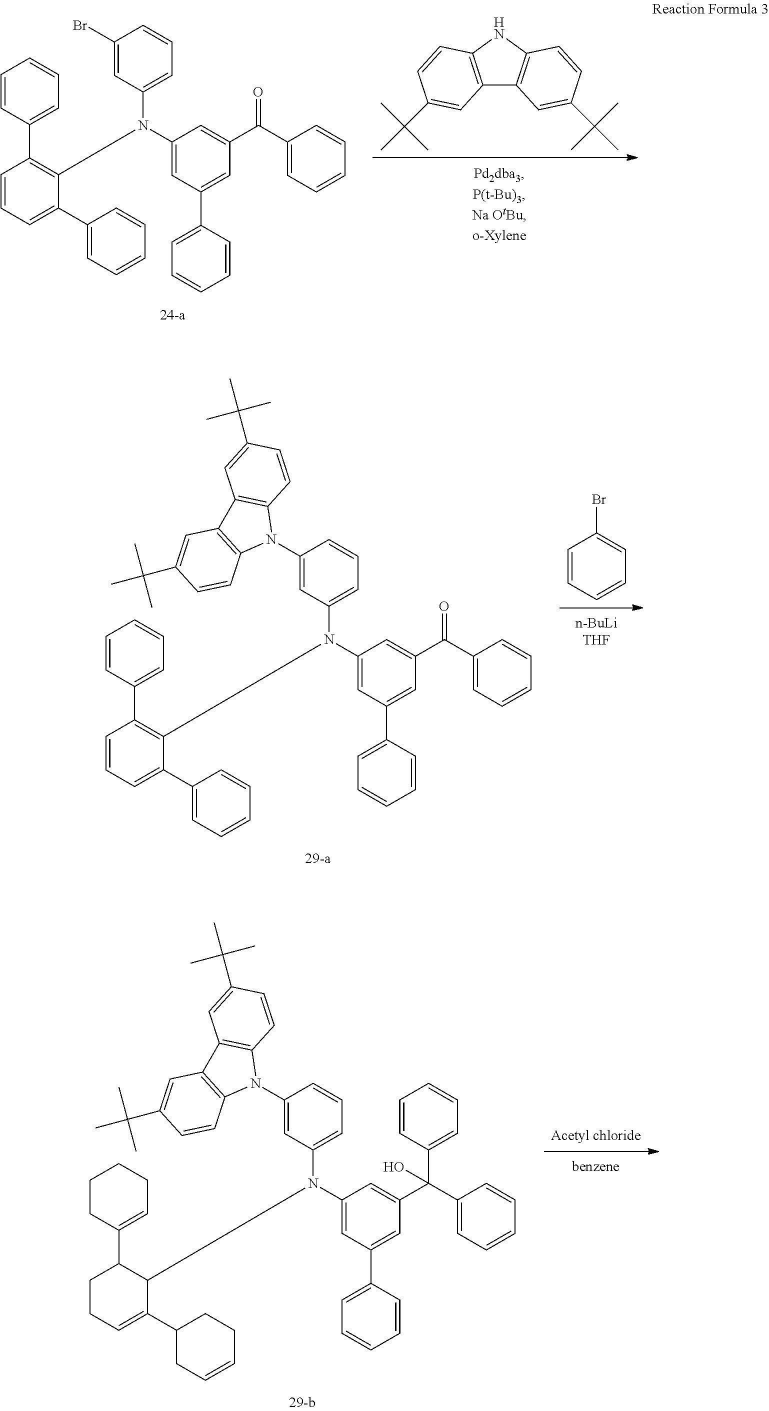

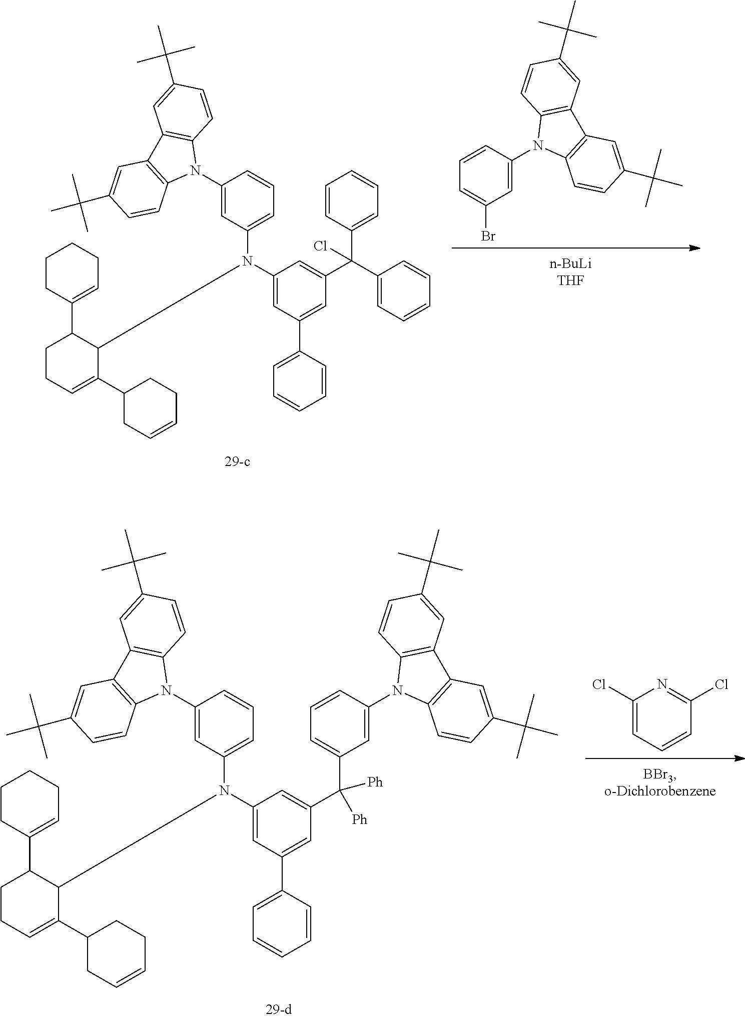 [SMILES: CC(C)(C)c1ccc2c(c1)c1cc(C(C)(C)C)ccc1n2-c1cccc(N(c2cc(-c3ccccc3)cc(C(Cl)(c3ccccc3)c3ccccc3)c2)C2C(C3CC=CCC3)=CCCC2C2=CCCCC2)c1 ; CC(C)(C)c1ccc2c(c1)c1cc(C(C)(C)C)ccc1n2-c1cccc(Br)c1 ; CC(C)(C)c1ccc2c(c1)c1cc(C(C)(C)C)ccc1n2-c1cccc(N(c2cc(-c3ccccc3)cc(C(c3ccccc3)(c3ccccc3)c3cccc(-n4c5ccc(C(C)(C)C)cc5c5cc(C(C)(C)C)ccc54)c3)c2)C2C(C3CC=CCC3)=CCCC2C2=CCCCC2)c1 ; Clc1cccc(Cl)n1]

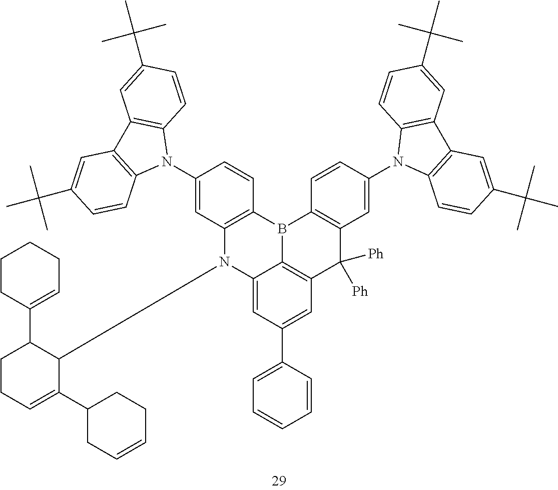 [SMILES: CC(C)(C)c1ccc2c(c1)c1cc(C(C)(C)C)ccc1n2-c1ccc2c(c1)N(C1C(C3CC=CCC3)=CCCC1C1=CCCCC1)c1cc(-c3ccccc3)cc3c1B2c1ccc(-n2c4ccc(C(C)(C)C)cc4c4cc(C(C)(C)C)ccc42)cc1C3(c1ccccc1)c1ccccc1]

### (1) Synthesis of Intermediate 29-a

Intermediate 29-a was synthesized in substantially the same manner as in the synthesis of Intermediate 1-c, utilizing Intermediate 24-a instead of Intermediate 1-b, and 3,6-di-tert-butyl-9H-carbazole instead of [1,1′:3′,1″-terphenyl]-2′-amine. (Yield: 78%). It was confirmed that the obtained solid was Intermediate 29-a through ESI-LCMS.

ESI-LCMS: [M]⁺: C₆₃H₅₄N₂O. 854.4237.

### (2) Synthesis of Intermediate 29-b

Intermediate 29-b was synthesized in substantially the same manner as in the synthesis of Intermediate 1-e, utilizing Intermediate 29-a instead of Intermediate 1-d. (Yield: 48%). It was confirmed that the obtained solid was Intermediate 29-b through ESI-LCMS.

ESI-LCMS: [M]⁺: C₆₉H₆₀N₂O. 932.4708.

### (3) Synthesis of Intermediate 29-c

Intermediate 29-c was synthesized in substantially the same manner as in the synthesis of Intermediate 1-f, utilizing Intermediate 29-b instead of Intermediate 1-e. (Yield: 45%). It was confirmed that the obtained solid was Intermediate 29-c through ESI-LCMS.

ESI-LCMS: [M]⁺: C₆₉H₅₉ClN₂. 950.4367.

### (4) Synthesis of Intermediate 29-d

Intermediate 29-d was synthesized in substantially the same manner as in the synthesis of Intermediate 1-g, utilizing Intermediate 29-c instead of Intermediate 1-f, and 9-(3-bromophenyl)-3,6-di-tert-butyl-9H-carbazole instead of bromobenzene. (Yield: 28%). It was confirmed that the obtained solid was Intermediate 29-d through ESI-LCMS.

ESI-LCMS: [M]⁺: C₉₅H₈₇N₃. 1269.6900.

### (5) Synthesis of Compound 29

Compound 29 was synthesized in substantially the same manner as in the synthesis of Compound 24, utilizing Intermediate 29-d instead of Intermediate 24-e. (Yellow solid, yield: 5%). It was confirmed that the obtained yellow solid was Compound 29 through ¹H-NMR and ESI-LCMS.

¹H-NMR (400 MHz, CDCl₃): d=9.24 (d, 2H), 8.54-8.45 (m, 8H), 8.40-8.34 (m, 6H), 8.28-8.19 (m, 6H), 7.95-7.86 (m, 5H), 7.77 (s, 2H), 7.54 (m, 4H), 7.43 (m, 4H), 7.19 (m, 5H), 7.08 (m, 4H), 6.89 (m, 2H), 1.42 (s, 36H).

ESI-LCMS: [M]⁺: C₉₅H₈₄BN₃. 1277.6758.

### 4) Synthesis of Compound 39

Compound 39 according to an embodiment may be synthesized by, for example, a process of Reaction Formula 4.

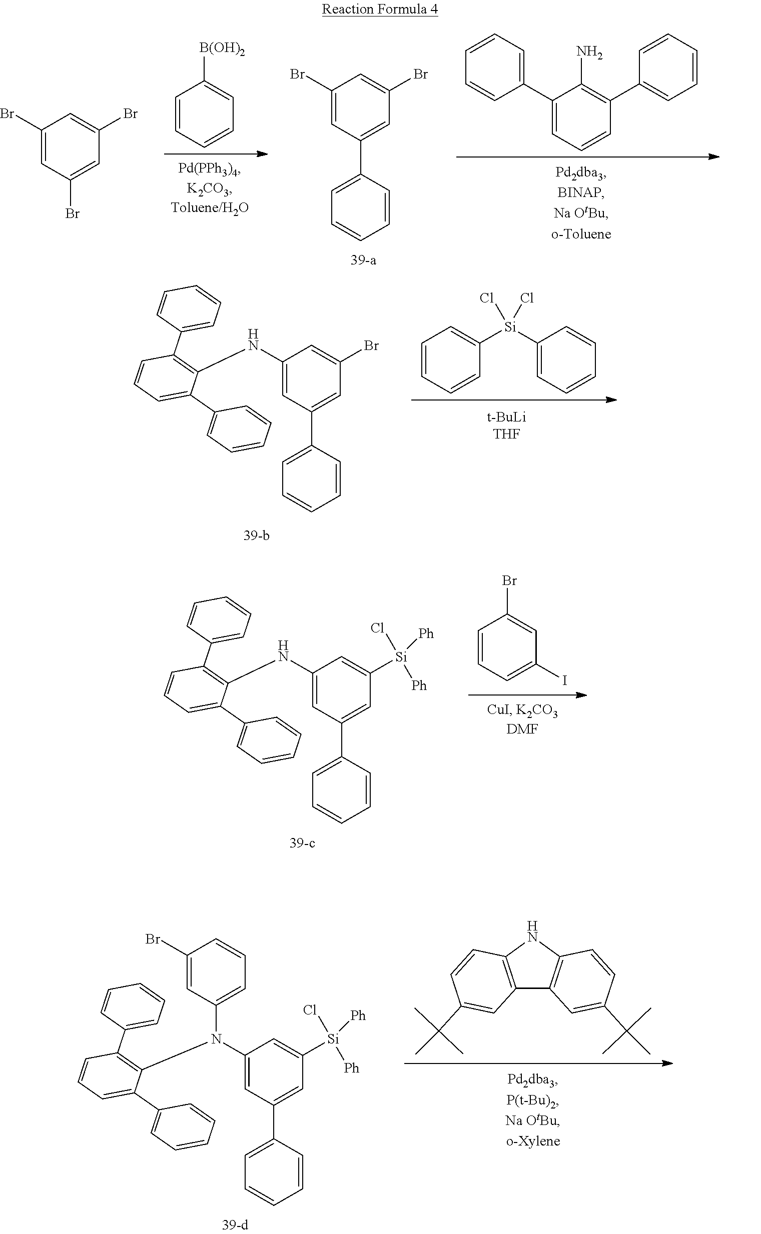

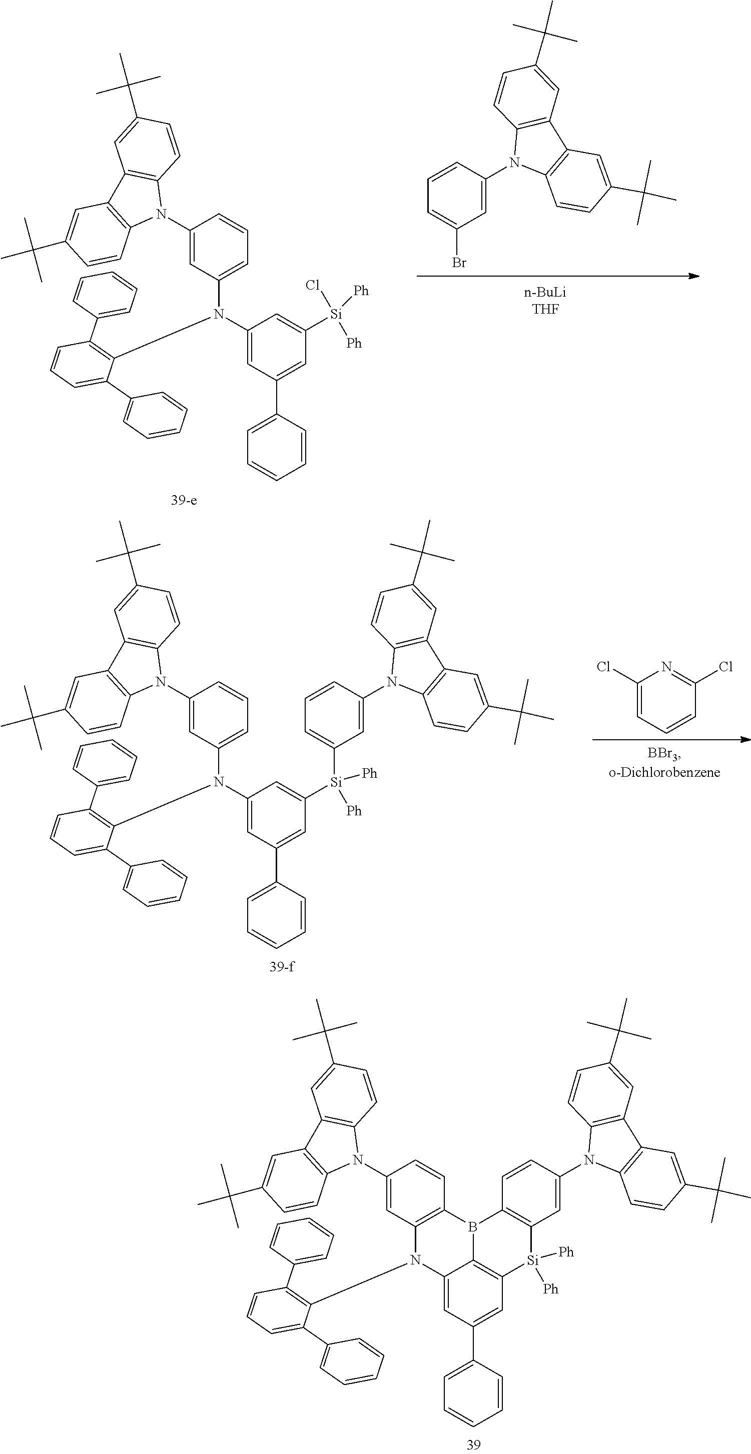

### (1) Synthesis of Intermediate 39-a

In an argon atmosphere, in a 2 L flask, phenyl boronic acid (0.8 eq), 1,3,5-tribromobenzene (3 eq), Pd(PPh₃)₄ (0.03 eq), and potassium carbonate (2 eq) were added and dissolved in toluene:H₂O (3:1), and then the reaction solution was stirred at 100° C. for 12 hours. After cooling the resultant product, water (1 L) and ethyl acetate (300 mL) were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 39-a (yield: 30%). It was confirmed that the obtained compound was Intermediate 39-a through ESI-LCMS.

ESI-LCMS: [M]⁺: C₁₂H₈Br₂. 309.8993.

### (2) Synthesis of Intermediate 39-b

In an argon atmosphere, in a 1 L flask, Intermediate 39-a (1 eq), [1,1′:3′,1″-terphenyl]-2′-amine (1 eq), Pd₂dba₃ (0.05 eq), tris-tert-butyl phosphine (0.1 eq), and sodium tert-butoxide (3 eq) were added and dissolved in toluene, and then the reaction solution was stirred at 140° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to synthesize Intermediate 39-b. (Yield: 64%). It was confirmed that the obtained solid was Intermediate 39-b through ESI-LCMS.

ESI-LCMS: [M]⁺: C₃₀H₂₂BrN. 475.0936.

### (3) Synthesis of Intermediate 39-c

In an argon atmosphere, in a 1 L flask, Intermediate 39-b (1 eq) was dissolved in THF. At −78° C., t-BuLi (2.5 eq) was slowly added dropwise. Thereafter, dichlorodiphenylsilane (1 eq.) was dissolved in THF and added dropwise, and the temperature was slowly raised to room temperature and the mixture was stirred for 1 hour. After 1 hour, an aqueous solution of ammonium chloride was added to terminate the reaction. Water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 39-c (yield: 51%). It was confirmed that the obtained compound was Compound 39-c through ESI-LCMS.

ESI-LCMS: [M]⁺: C₄₂H₃₂ClNSi. 613.1993.

### (4) Synthesis of Intermediate 39-d

In an argon atmosphere, in a 1 L flask, Intermediate 39-c (1 eq), 1-bromo-3-iodobenzene (1 eq), copper iodide (1 eq), 1,10-phenanthroline (1 eq), and potassium carbonate (3 eq) were added and dissolved in DMF, and then the reaction solution was stirred at 160° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to synthesize Intermediate 39-d. (Yield: 48%). It was confirmed that the obtained solid was Intermediate 39-d through ESI-LCMS.

ESI-LCMS: [M]⁺: C₄₈H₃₅BrClNSi. 767.1411.

### (5) Synthesis of Intermediate 39-e

Intermediate 39-e was synthesized in substantially the same manner as in the synthesis of Intermediate 29-a, utilizing Intermediate 39-d instead of Intermediate 24-a. (Yield: 68%). It was confirmed that the obtained solid was Intermediate 39-e through ESI-LCMS.

ESI-LCMS: [M]⁺: C₆₈H₅₉BrClN₂Si. 966.4136.

### (6) Synthesis of Intermediate 39-f

Intermediate 39-f was synthesized in substantially the same manner as in the synthesis of Intermediate 1-g, utilizing Intermediate 39-e instead of Intermediate 1-f, and 9-(3-bromophenyl)-3,6-di-tert-butyl-9H-carbazole instead of bromobenzene. (Yield: 38%). It was confirmed that the obtained solid was Intermediate 39-f through ESI-LCMS.

ESI-LCMS: [M]⁺: C₉₄H₈₇N₃Si. 1285.6669.

### (7) Synthesis of Compound 39

Compound 39 was synthesized in substantially the same manner as in the synthesis of Compound 24, utilizing Intermediate 39-f instead of Intermediate 24-e. (Yellow solid, yield: 4%). It was confirmed that the obtained yellow solid was Compound 39 through ¹H-NMR and ESI-LCMS.

¹H-NMR (400 MHz, CDCl₃): d=9.25 (d, 2H), 8.95-8.93 (s, 2H), 8.60-8.51 (m, 4H), 8.34-8.28 (m, 5H), 7.95-7.85 (m, 4H), 7.79-7.70 (m, 10H), 7.68-7.59 (m, 6H), 7.50-7.43 (m, 4H), 7.33-7.25 (m, 5H), 7.21-7.18 (m, 2H), 6.89-6.80 (m, 4H), 1.42 (s, 36H).

ESI-LCMS: [M]⁺: C₉₄H₈₄BN₃Si. 1293.6528.

### 5) Synthesis of Compound 41

Compound 41 according to an embodiment may be synthesized by, for example, a process of Reaction Formula 5.

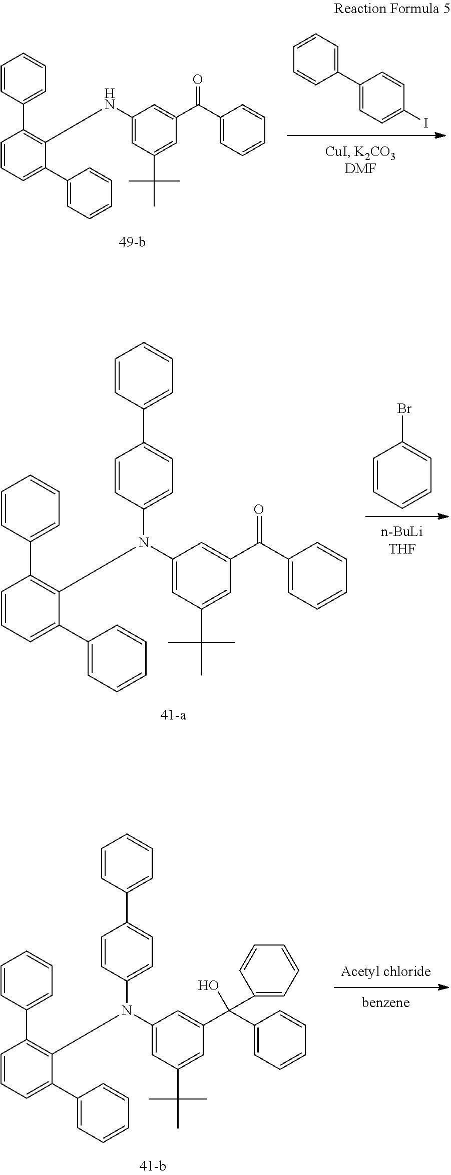 [SMILES: CC(C)(C)c1cc(Nc2c(-c3ccccc3)cccc2-c2ccccc2)cc(C(=O)c2ccccc2)c1 ; Ic1ccc(-c2ccccc2)cc1 ; CC(C)(C)c1cc(C(=O)c2ccccc2)cc(N(c2ccc(-c3ccccc3)cc2)c2c(-c3ccccc3)cccc2-c2ccccc2)c1 ; Brc1ccccc1 ; CC(C)(C)c1cc(N(c2ccc(-c3ccccc3)cc2)c2c(-c3ccccc3)cccc2-c2ccccc2)cc(C(O)(c2ccccc2)c2ccccc2)c1]

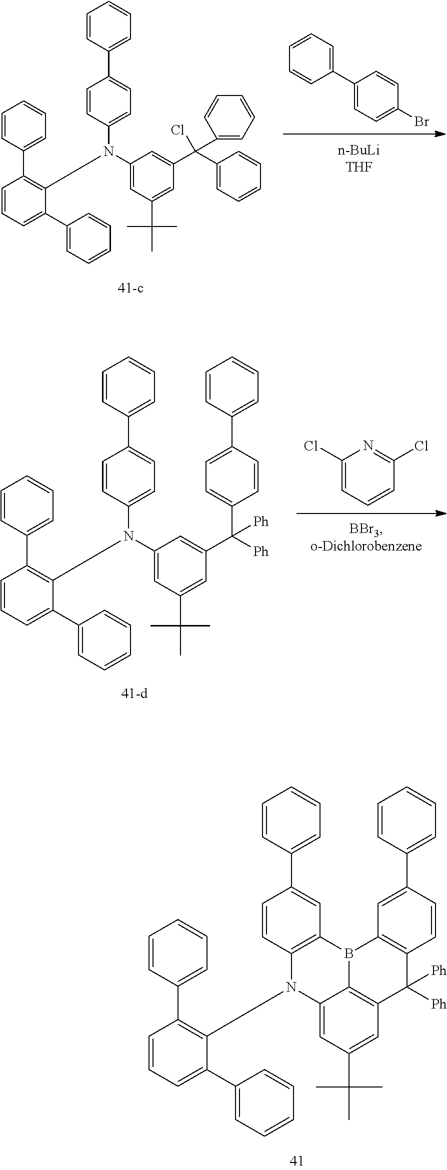 [SMILES: CC(C)(C)c1cc(N(c2ccc(-c3ccccc3)cc2)c2c(-c3ccccc3)cccc2-c2ccccc2)cc(C(Cl)(c2ccccc2)c2ccccc2)c1 ; Brc1ccc(-c2ccccc2)cc1 ; CC(C)(C)c1cc(N(c2ccc(-c3ccccc3)cc2)c2c(-c3ccccc3)cccc2-c2ccccc2)cc(C(c2ccccc2)(c2ccccc2)c2ccc(-c3ccccc3)cc2)c1 ; Clc1cccc(Cl)n1 ; CC(C)(C)c1cc2c3c(c1)C(c1ccccc1)(c1ccccc1)c1ccc(-c4ccccc4)cc1B3c1cc(-c3ccccc3)ccc1N2c1c(-c2ccccc2)cccc1-c1ccccc1]

### (1) Synthesis of Intermediate 41-a

Intermediate 41-a was synthesized in substantially the same manner as in the synthesis of Intermediate 49-c which will be described later, utilizing 4-iodo-1,1′-biphenyl instead of 1-bromo-3-iodobenzene. (Yield: 59%). It was confirmed that the obtained solid was Intermediate 41-a through ESI-LCMS.

ESI-LCMS: [M]⁺: C₄₇H₃₉NO. 633.3022.

### (2) Synthesis of Intermediate 41-b

Intermediate 41-b was synthesized in substantially the same manner as in the synthesis of Intermediate 1-e, utilizing Intermediate 41-a instead of Intermediate 1-d. (Yield: 43%). It was confirmed that the obtained solid was Intermediate 41-b through ESI-LCMS.

ESI-LCMS: [M]⁺: C₅₃H₄₅NO. 711.3501.

### (3) Synthesis of Intermediate 41-c

Intermediate 41-c was synthesized in substantially the same manner as in the synthesis of Intermediate 1-f, utilizing Intermediate 41-b instead of Intermediate 1-e. (Yield: 47%). It was confirmed that the obtained solid was Intermediate 41-c through ESI-LCMS.

ESI-LCMS: [M]⁺: C₅₃H₄₄ClN. 729.3162.

### (4) Synthesis of Intermediate 41-d

Intermediate 41-d was synthesized in substantially the same manner as in the synthesis of Intermediate 1-g, utilizing Intermediate 41-c instead of Intermediate 1-f, and 4-bromo-1,1′-biphenyl instead of bromobenzene. (Yield: 38%). It was confirmed that the obtained solid was Intermediate 41-d through ESI-LCMS.

ESI-LCMS: [M]⁺: C₆₅H₅₃N. 847.4178.

### (5) Synthesis of Compound 41

Compound 41 was synthesized in substantially the same manner as in the synthesis of Compound 24, utilizing Intermediate 41-d instead of Intermediate 24-e. (Yellow solid, yield: 13%). It was confirmed that the obtained yellow solid was Compound 41 through ¹H-NMR and ESI-LCMS.

¹H-NMR (400 MHz, CDCl₃): d=9.24 (d, 2H), 8.30 (m, 2H), 7.95-7.84 (m, 10H), 7.80-7.73 (m, 8H), 7.60-7.51 (m, 6H), 7.43-7.28 (m, 7H), 7.20 (m, 7H), 7.18 (m, 4H), 6.91 (m, 4H).

ESI-LCMS: [M]⁺: C₆₅H₅₀BN. 855.4036.

### 6) Synthesis of Compound 49

Compound 49 according to an embodiment may be synthesized by, for example, a process of Reaction Formula 6.

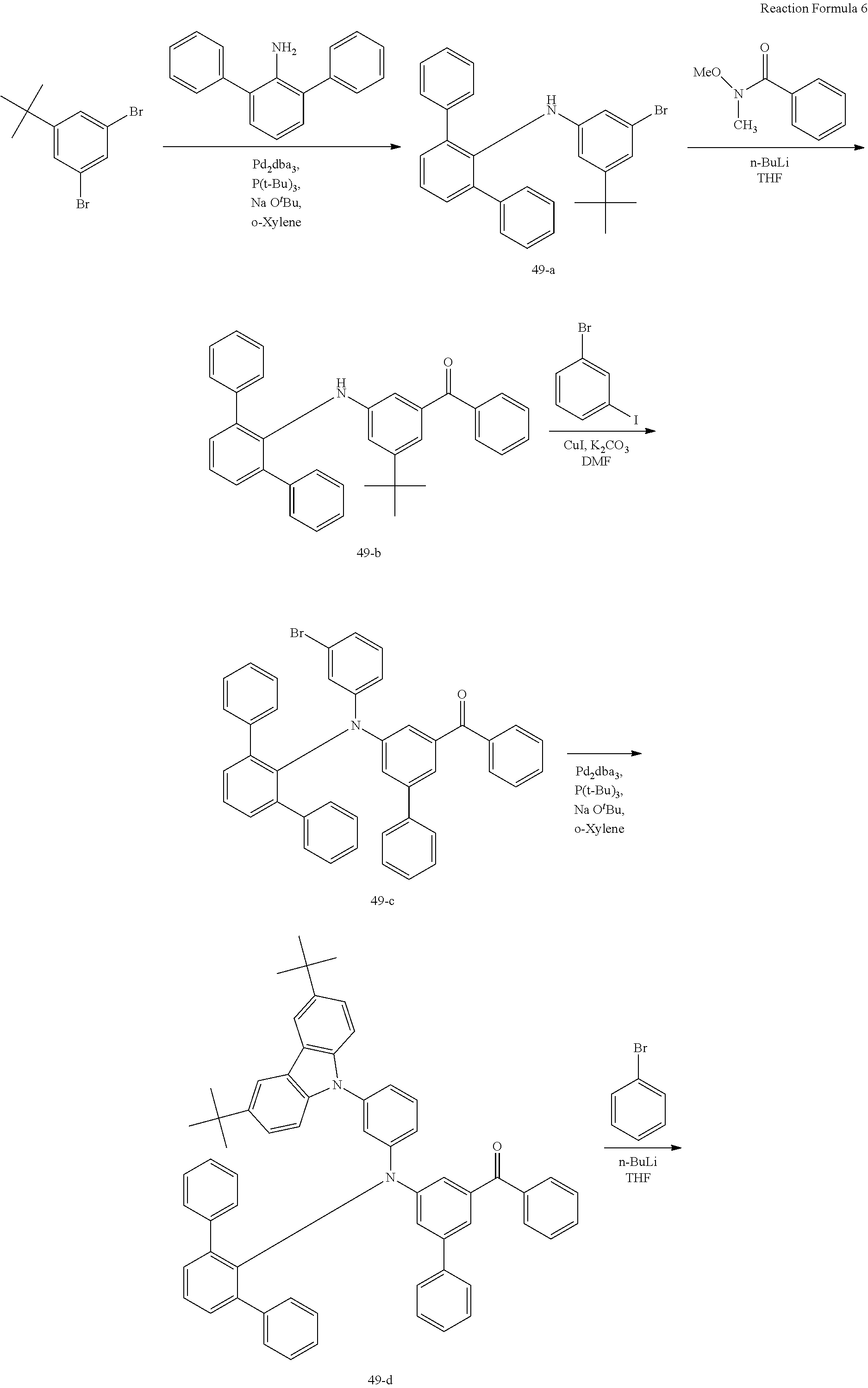

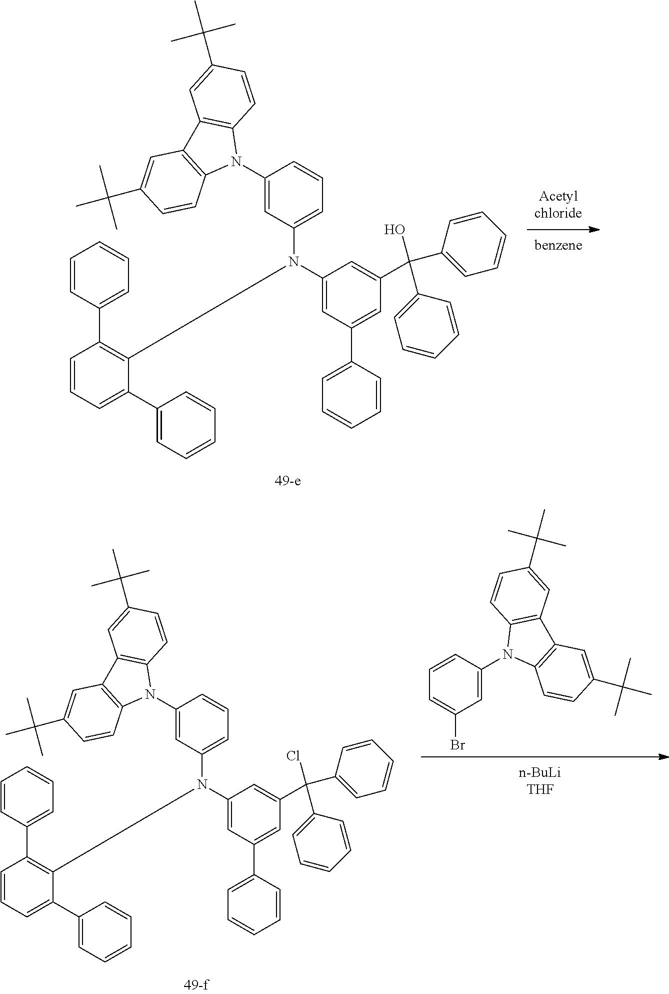 [SMILES: CC(C)(C)c1ccc2c(c1)c1cc(C(C)(C)C)ccc1n2-c1cccc(N(c2cc(-c3ccccc3)cc(C(O)(c3ccccc3)c3ccccc3)c2)c2c(-c3ccccc3)cccc2-c2ccccc2)c1 ; CC(C)(C)c1ccc2c(c1)c1cc(C(C)(C)C)ccc1n2-c1cccc(N(c2cc(-c3ccccc3)cc(C(Cl)(c3ccccc3)c3ccccc3)c2)c2c(-c3ccccc3)cccc2-c2ccccc2)c1 ; CC(C)(C)c1ccc2c(c1)c1cc(C(C)(C)C)ccc1n2-c1cccc(Br)c1]

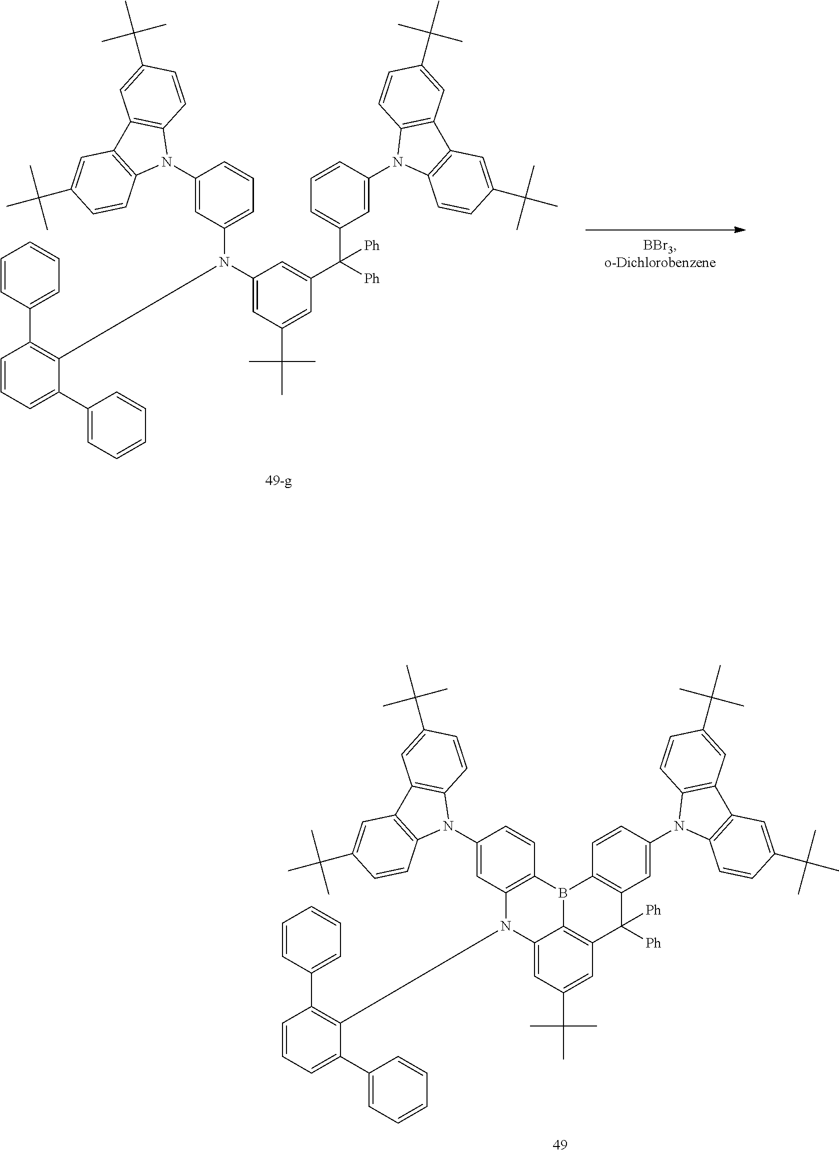 [SMILES: CC(C)(C)c1cc(N(c2cccc(-n3c4ccc(C(C)(C)C)cc4c4cc(C(C)(C)C)ccc43)c2)c2c(-c3ccccc3)cccc2-c2ccccc2)cc(C(c2ccccc2)(c2ccccc2)c2cccc(-n3c4ccc(C(C)(C)C)cc4c4cc(C(C)(C)C)ccc43)c2)c1 ; CC(C)(C)c1cc2c3c(c1)C(c1ccccc1)(c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1]

### (1) Synthesis of Intermediate 49-a

Intermediate 49-a was synthesized in substantially the same manner as in the synthesis of Intermediate 1-c, utilizing 1,3-dibromo-5-(tert-butyl)benzene instead of Intermediate 1-b (yield: 61%). It was confirmed that the obtained solid was Intermediate 49-a through ESI-LCMS.

ESI-LCMS: [M]⁺: C₂₈H₂₆BrN. 455.1249.

### (2) Synthesis of Intermediate 49-b

Intermediate 49-b was synthesized in substantially the same manner as in the synthesis of Intermediate 1-b, utilizing Intermediate 49-a instead of Intermediate 1-a (yield: 62%). It was confirmed that the obtained solid was Intermediate 49-b through ESI-LCMS.

ESI-LCMS: [M]⁺: C₃₅H₃₁ NO. 481.2406.

### (3) Synthesis of Intermediate 49-c

In an argon atmosphere, in a 1 L flask, Intermediate 49-b (1 eq), 1-bromo-3-iodobenzene (1 eq), copper iodide (1 eq), 1,10-phenanthroline (1 eq), and potassium carbonate (3 eq) were added and dissolved in DMF, and then the reaction solution was stirred at 160° C. for 12 hours. After cooling the resultant product, water and ethyl acetate were added thereto for extraction, and the organic layer was collected, dried over MgSO₄, and filtered. A solvent was removed at reduced pressure from the filtered solution, and CH₂Cl₂ and hexane were utilized as developing solvents to purify and separate the obtained solid through column chromatography utilizing silica gel to obtain Intermediate 49-c (5.4 g, 51%). It was confirmed that the obtained compound was Intermediate 49-c through ESI-LCMS.

ESI-LCMS: [M]⁺: C₄₃H₃₀BrNO. 655.1511.

### (4) Synthesis of Intermediate 49-d

Intermediate 49-d was synthesized in substantially the same manner as in the synthesis of Intermediate 1-c, utilizing Intermediate 49-c instead of Intermediate 1-b, and 3,6-di-tert-butyl-9H-carbazole instead of [1,1′:3′,1″-terphenyl]-2′-amine. (Yield: 76%). It was confirmed that the obtained solid was Intermediate 49-d through ESI-LCMS.

ESI-LCMS: [M]⁺: C₆₃H₅₄N₂O. 855.1380.

(5) Synthesis of Intermediate 49-e 10 [00361] Intermediate 49-e was synthesized in substantially the same manner as in the synthesis of Intermediate 1-e, utilizing Intermediate 49-d instead of Intermediate 1-d. (Yield: 68%). It was confirmed that the obtained solid was Intermediate 49-e through ESI-LCMS.

ESI-LCMS: [M]⁺: C₆₉H₆₀N₂O. 932.4706.

### (6) Synthesis of Intermediate 49-f

Intermediate 49-f was synthesized in substantially the same manner as in the synthesis of Intermediate 1-f, utilizing Intermediate 49-e instead of Intermediate 1-e. (Yield: 57%). It was confirmed that the obtained solid was Intermediate 49-f through ESI-LCMS.

ESI-LCMS: [M]⁺: C₆₉H₅₉N₂Cl. 950.4367.

### (7) Synthesis of Intermediate 49-g

Intermediate 49-g was synthesized in substantially the same manner as in the synthesis of Intermediate 1-g, utilizing Intermediate 49-f instead of Intermediate 1-f, and 9-(3-bromophenyl)-3,6-di-tert-butyl-9H-carbazole instead of bromobenzene. (Yield: 49%). It was confirmed that the obtained solid was Intermediate 49-g through ESI-LCMS.

ESI-LCMS: [M]⁺: C₉₃H₉₁N₃. 1249.7213.

### (8) Synthesis of Compound 49

Compound 49 was synthesized in substantially the same manner as in the synthesis of Compound 1, utilizing Intermediate 49-g instead of Intermediate 1-g. (Yellow solid, yield: 10%). It was confirmed that the obtained yellow solid was Compound 49 through ¹H-NMR and ESI-LCMS.

¹H-NMR (400 MHz, CDCl₃): d=9.24 (d, 2H), 8.55-8.48 (m, 8H), 8.40-8.32 (m, 4H), 8.20-8.15 (m, 4H), 7.87-7.80 (m, 2H), 7.77 (s, 2H), 7.50 (d, 3H), 7.43 (m, 8H), 7.19 (m, 4H), 7.08 (m, 4H), 6.89 (m, 2H), 1.42 (s, 9H), 1.38 (s, 36H).

ESI-LCMS: [M]⁺: C₉₃H₈₈BN₃. 1257.7071.

### 7) Synthesis of Compound 61

Compound 61 according to an embodiment may be synthesized by, for example, a process of Reaction Formula 7.

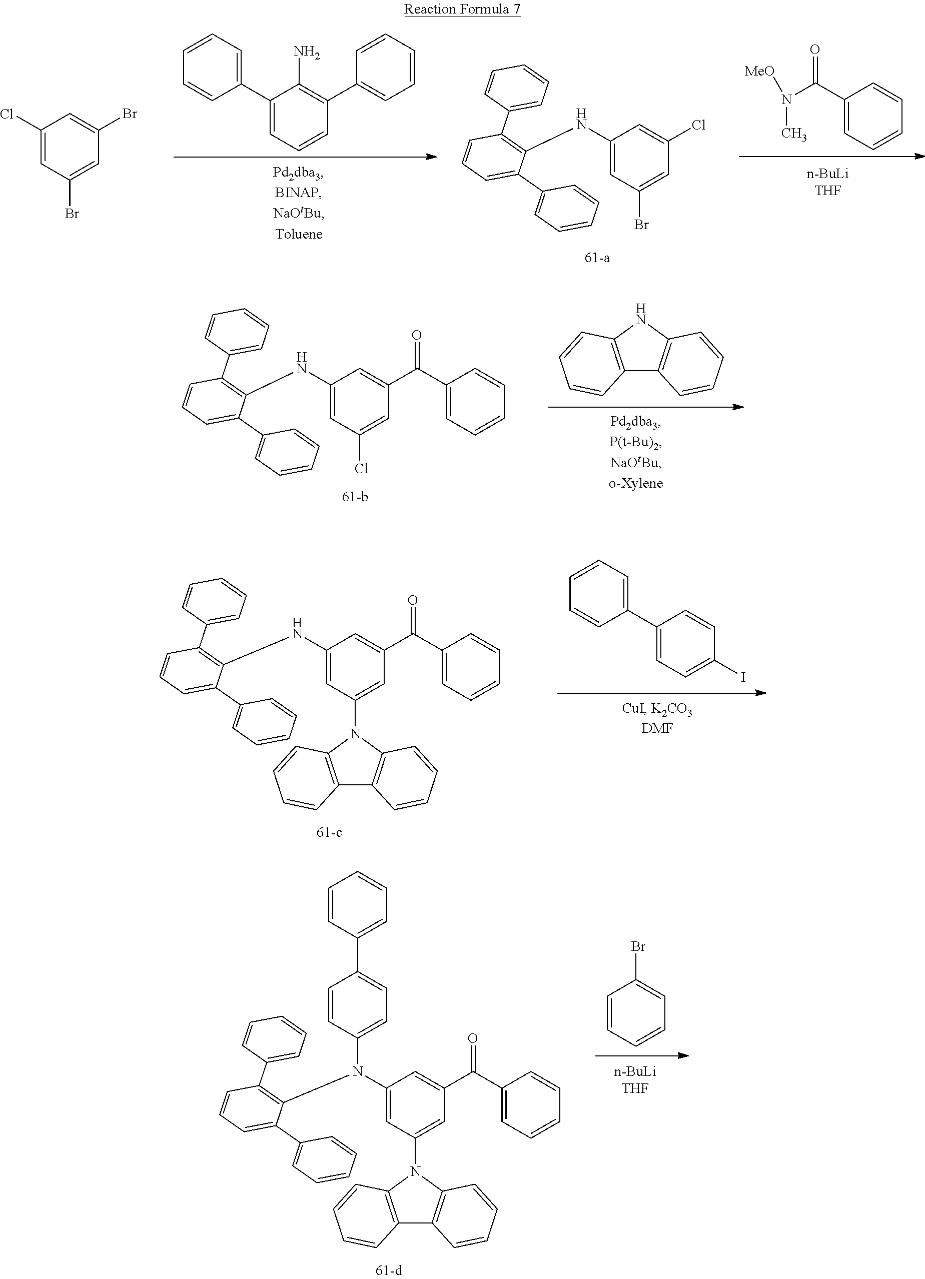

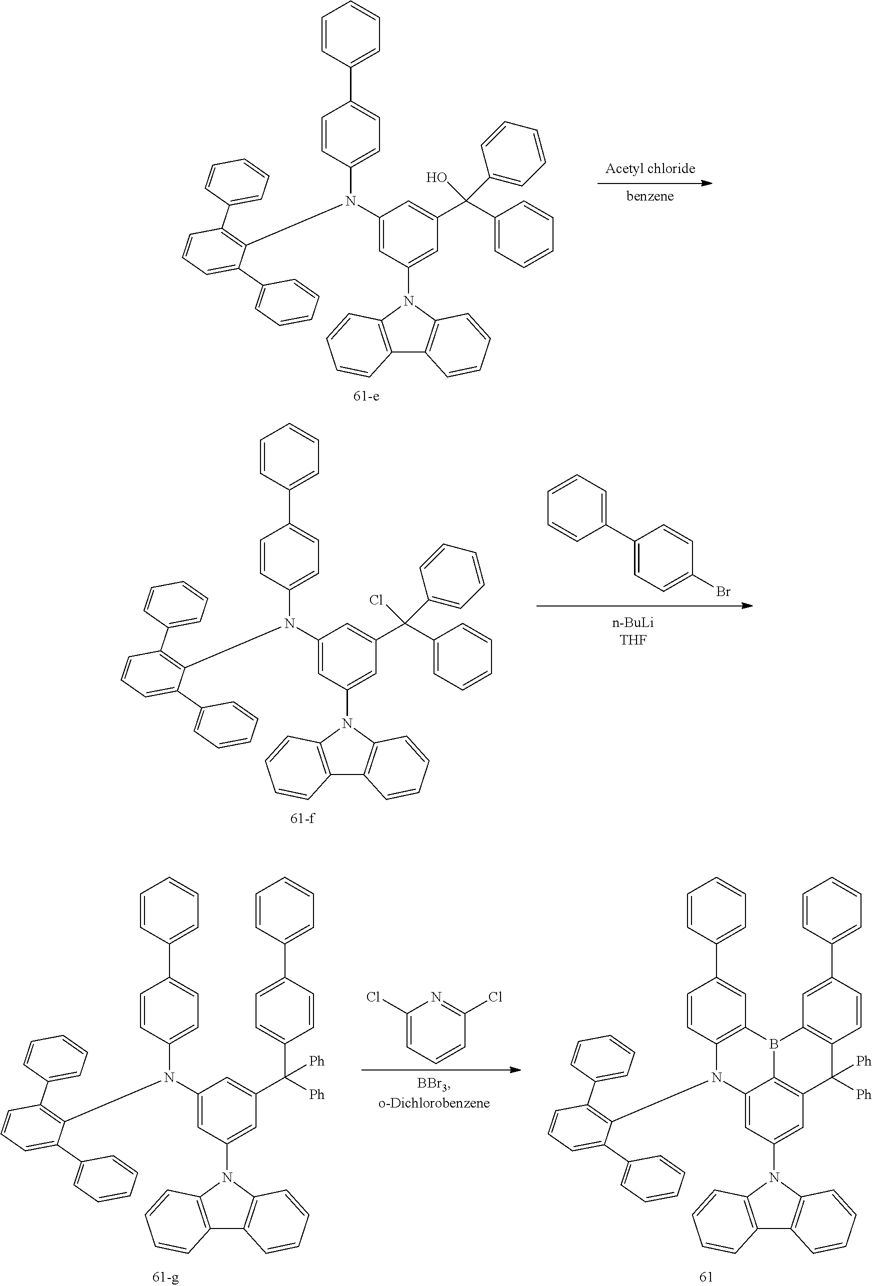

### (1) Synthesis of Intermediate 61-a

Intermediate 61-a was synthesized in substantially the same manner as in the synthesis of Intermediate 49-a, utilizing 1,3-dibromo-5-chlorobenzene instead of 1,3-dibromo-5-(tert-butyl)benzene (yield: 59%). It was confirmed that the obtained solid was Intermediate 61-a through ESI-LCMS.

ESI-LCMS: [M]⁺: C₂₄H₁₇BrClN. 433.0223.

### (2) Synthesis of Intermediate 61-b

Intermediate 61-b was synthesized in substantially the same manner as in the synthesis of Intermediate 1-b, utilizing Intermediate 61-a instead of Intermediate 1-a (yield: 52%). It was confirmed that the obtained solid was Intermediate 61-b through ESI-LCMS.

ESI-LCMS: [M]⁺: C₃₁H₂₂ClNO. 459.1390.

### (3) Synthesis of Intermediate 61-c

Intermediate 61-c was synthesized in substantially the same manner as in the synthesis of Intermediate 1-c, utilizing Intermediate 61-b instead of Intermediate 1-b, and 9H-carbazole instead of [1,1′:3′,1″-terphenyl]-2′-amine. (Yield: 76%). It was confirmed that the obtained solid was Intermediate 61-c through ESI-LCMS.

ESI-LCMS: [M]⁺: C₄₃H₃₀N₂O. 590.2358.

### (4) Synthesis of Intermediate 61-d

Intermediate 61-d was synthesized in substantially the same manner as in the synthesis of Intermediate 49-c, utilizing Intermediate 61-c instead of Intermediate 49-b, and 4-iodo-1,1′-biphenyl instead of 1-Bromo-3-iodobenzene (yield: 68%). It was confirmed that the obtained solid was Intermediate 61-d through ESI-LCMS.

ESI-LCMS: [M]⁺: C₅₅H₃₈N₂O. 742.2984.

### (5) Synthesis of Intermediate 61-e

Intermediate 61-e was synthesized in substantially the same manner as in the synthesis of Intermediate 1-e, utilizing Intermediate 61-d instead of Intermediate 1-d. (Yield: 72%). It was confirmed that the obtained solid was Intermediate 61-e through ESI-LCMS.

ESI-LCMS: [M]⁺: C₆₁H₄₄N₂O. 820.3454.

(6) Synthesis of Intermediate 61-f 10 [00381] Intermediate 61-f was synthesized in substantially the same manner as in the synthesis of Intermediate 1-f, utilizing Intermediate 61-e instead of Intermediate 1-e. (Yield: 53%). It was confirmed that the obtained solid was Intermediate 61-f through ESI-LCMS.

ESI-LCMS: [M]⁺: C₆₁H₄₃ClN₂. 838.3115.

### (7) Synthesis of Intermediate 61-g

Intermediate 61-g was synthesized in substantially the same manner as in the synthesis of Intermediate 1-g, utilizing Intermediate 61-f instead of Intermediate 1-f, and 4-bromo-1,1′-biphenyl instead of bromobenzene. (Yield: 58%). It was confirmed that the obtained solid was Intermediate 61-g through ESI-LCMS.

ESI-LCMS: [M]⁺: C₇₃H₅₂N₂. 956.4130.

### (8) Synthesis of Compound 61

Compound 61 was synthesized in substantially the same manner as in the synthesis of Compound 24, utilizing Intermediate 61-g instead of Intermediate 24-e. (Yellow solid, yield: 7%). It was confirmed that the obtained yellow solid was Compound 61 through ¹H-NMR and ESI-LCMS.

¹H-NMR (400 MHz, CDCl₃): d=9.34 (d, 2H), 8.55-8.51 (d, 2H), 8.20-8.15 (m, 4H), 7.94-7.88 (m, 4H), 7.82-7.75 (m, 6H), 7.71-7.60 (m, 12H), 7.58-7.52 (m, 6H), 7.48-7.42 (m, 4H), 7.19-7.14 (m, 5H), 7.08-7.01 (m, 4H).

ESI-LCMS: [M]⁺: C₇₃H₄₉BN₂. 964.3989.

### 8) Synthesis of Compound 69

Compound 69 according to an embodiment may be synthesized by, for example, a process of Reaction Formula 8.

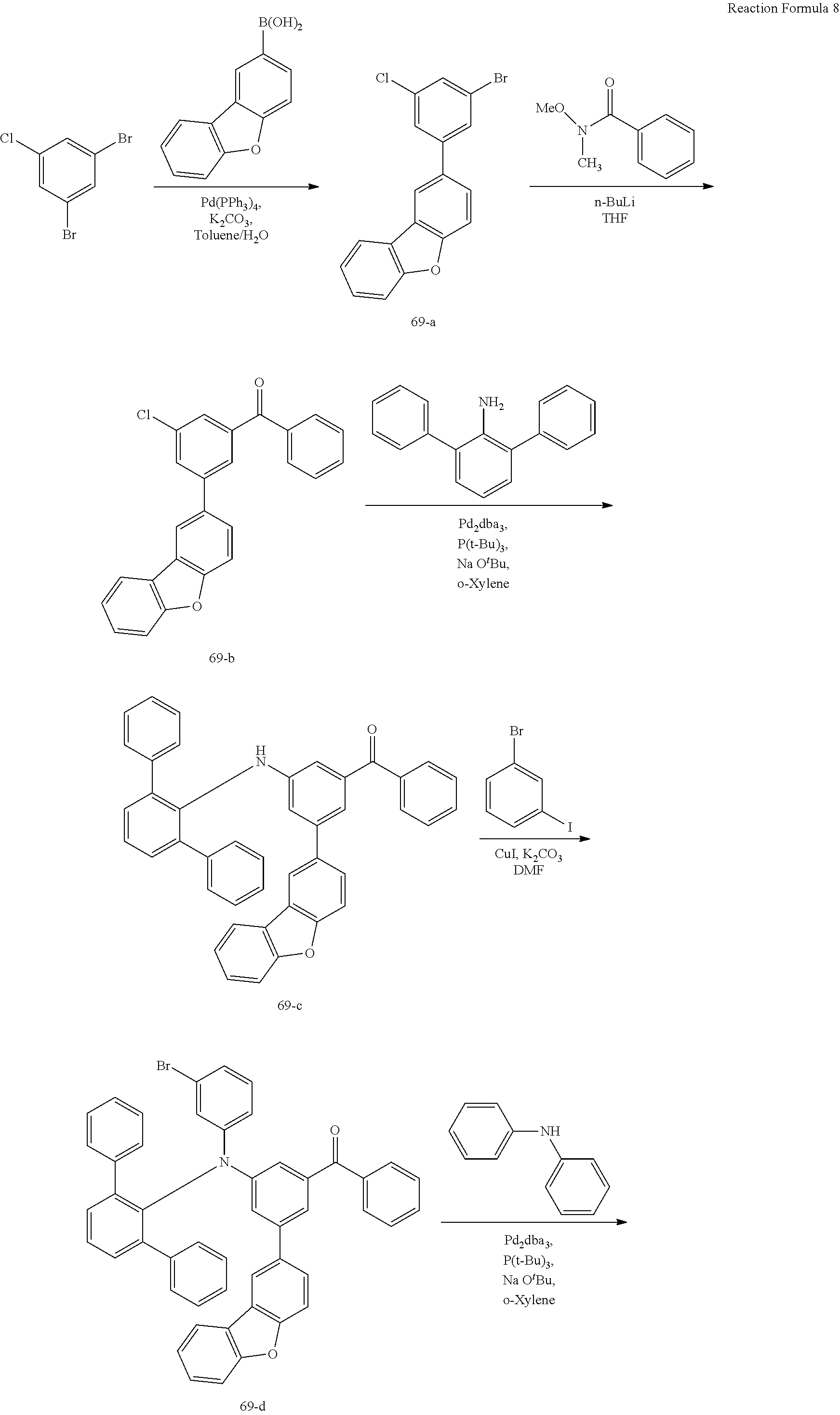

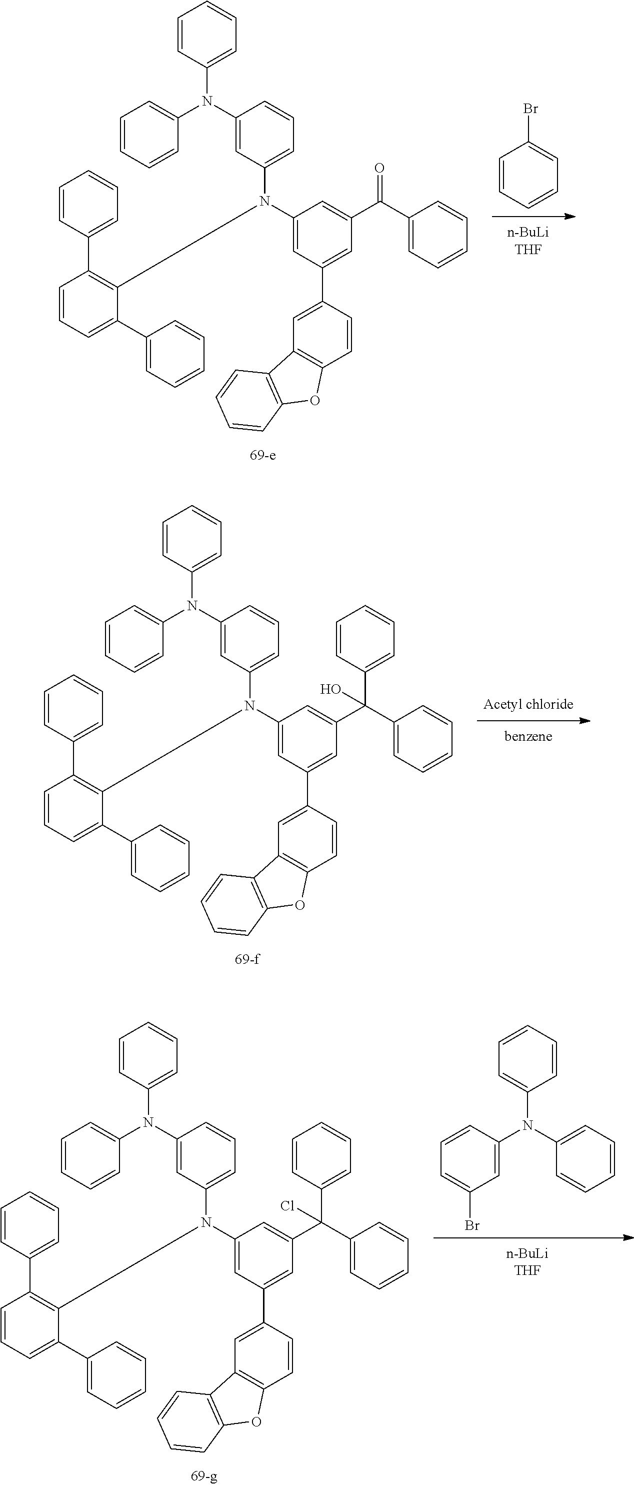

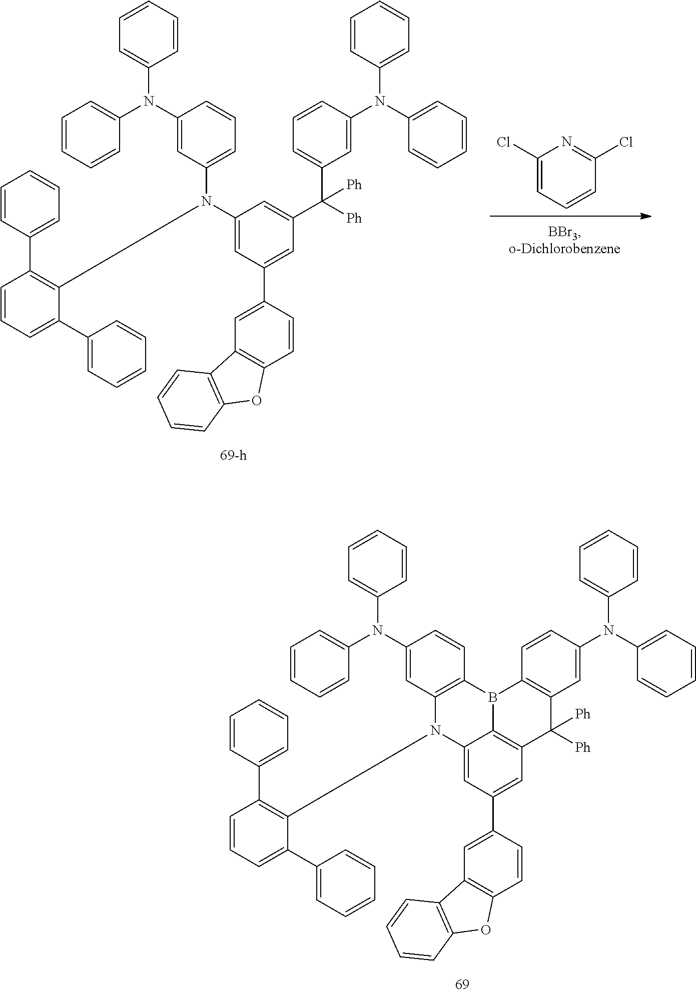

### (1) Synthesis of Intermediate 69-a

Intermediate 69-a was synthesized in substantially the same manner as in the synthesis of Intermediate 1-a, utilizing dibenzo[b,d]furan-2-ylboronic acid instead of phenyl boronic acid. (Yield: 53%) It was confirmed that the obtained solid was Intermediate 69-a through ESI-LCMS.

ESI-LCMS: [M]⁺: C₁₈H₁₀BrClO. 355.9604.

### (2) Synthesis of Intermediate 69-b

Intermediate 69-b was synthesized in substantially the same manner as in the synthesis of Intermediate 1-b, utilizing Intermediate 69-a instead of Intermediate 1-a (yield: 59%). It was confirmed that the obtained solid was Intermediate 69-b through ESI-LCMS.

ESI-LCMS: [M]⁺: C₂₅H₁₅ClO₂. 382.0761

### (3) Synthesis of Intermediate 69-c

Intermediate 69-c was synthesized in substantially the same manner as in the synthesis of Intermediate 1-c, utilizing Intermediate 69-b instead of Intermediate 1-b (yield: 72%). It was confirmed that the obtained solid was Intermediate 69-c through ESI-LCMS.

ESI-LCMS: [M]⁺: C₄₃H₂₉NO₂. 591.2198.

### (4) Synthesis of Intermediate 69-d

Intermediate 69-d was synthesized in substantially the same manner as in the synthesis of Intermediate 49-c, utilizing Intermediate 69-c instead of Intermediate 49-b (yield: 48%). It was confirmed that the obtained solid was Intermediate 69-d through ESI-LCMS.

ESI-LCMS: [M]⁺: C₄₉H₃₂BrNO₂. 745.1616.

(5) Synthesis of Intermediate 69-e 10 [00397] Intermediate 69-e was synthesized in substantially the same manner as in the synthesis of Intermediate 1-c, utilizing Intermediate 69-d instead of Intermediate 1-b, and diphenylamine instead of [1,1′:3′,1″-terphenyl]-2′-amine (yield: 81%). It was confirmed that the obtained solid was Intermediate 69-e through ESI-LCMS.

ESI-LCMS: [M]⁺: C₆₁H₄₂N₂O₂. 834.3246.

### (6) Synthesis of Intermediate 69-f

Intermediate 69-f was synthesized in substantially the same manner as in the synthesis of Intermediate 1-e, utilizing Intermediate 69-e instead of Intermediate 1-d. (Yield: 68%). It was confirmed that the obtained solid was Intermediate 69-f through ESI-LCMS.

ESI-LCMS: [M]⁺: C₆₇H₄₈N₂O₂. 912.3716.

### (7) Synthesis of Intermediate 69-g

Intermediate 69-g was synthesized in substantially the same manner as in the synthesis of Intermediate 1-f, utilizing Intermediate 69-f instead of Intermediate 1-e. (Yield: 51%). It was confirmed that the obtained solid was Intermediate 69-g through ESI-LCMS.

ESI-LCMS: [M]⁺: C₆₇H₄₇ClN₂O. 930.3377.

### (8) Synthesis of Intermediate 69-h

Intermediate 69-h was synthesized in substantially the same manner as in the synthesis of Intermediate 1-g, utilizing Intermediate 69-g instead of Intermediate 1-f, and 3-bromo-N,N-diphenylaniline instead of bromobenzene. (Yield: 58%). It was confirmed that the obtained solid was Intermediate 69-h through ESI-LCMS.

ESI-LCMS: [M]⁺: C₈₅H₆₁N₃O. 1139.4815.

### (9) Synthesis of Compound 69

Compound 69 was synthesized in substantially the same manner as in the synthesis of Compound 24, utilizing Intermediate 69-h instead of Intermediate 24-e. (Yellow solid, yield: 5%). It was confirmed that the obtained yellow solid was Compound 69 through ¹H-NMR and ESI-LCMS.

¹H-NMR (400 MHz, CDCl₃): d=9.25 (d, 2H), 8.21-8.18 (d, 2H), 7.98-7.95 (d, 4H), 7.88-7.73 (m, 8H), 7.70-7.62 (m, 6H), 7.60-7.48 (m, 14H), 7.45-7.32 (m, 8H), 7.30-7.25 (m, 6H), 7.19-7.12 (m, 4H), 7.08-7.01 (m, 4H).

ESI-LCMS: [M]⁺: C₈₅H₅₈BN₃O. 1147.4673.

### 2. Manufacture and Evaluation of Light Emitting Elements

Utilizing Compound 1, Compound 24, Compound 29, Compound 39, Compound 41, Compound 49, Compound 61, and Compound 69, and Comparative Examples Compounds C₁ to C₄ as dopant materials for emission layers, light emitting elements of Examples 1 to 8 and Comparative Examples 1 to 4 were manufactured.

### Example Compounds

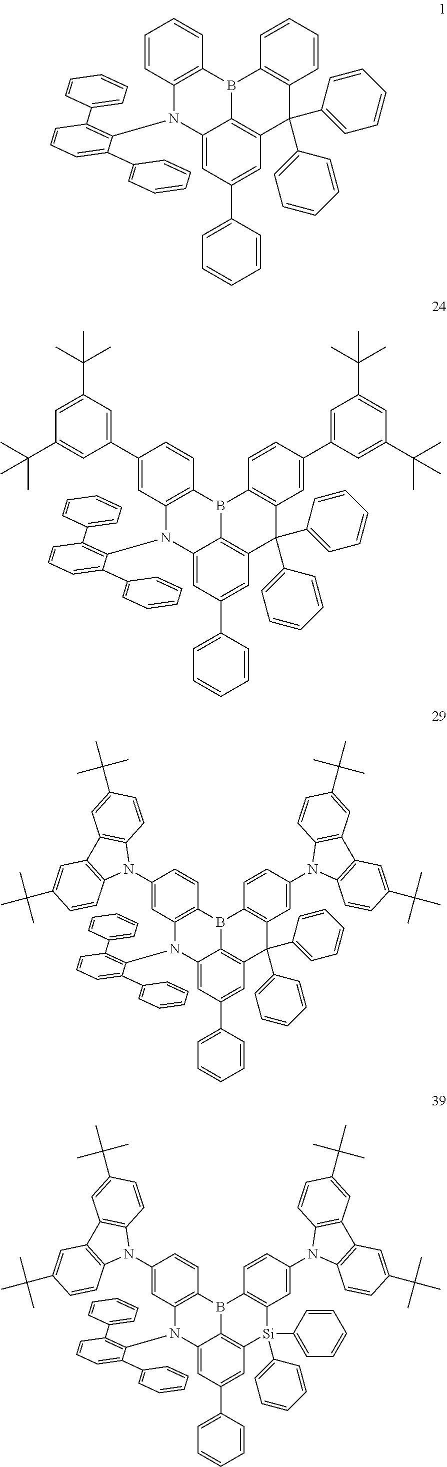

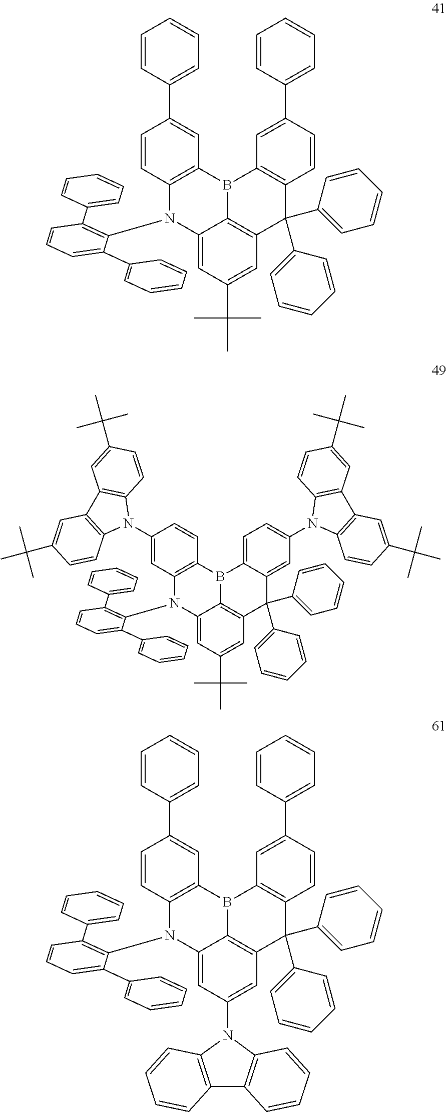 [SMILES: CC(C)(C)c1cc2c3c(c1)C(c1ccccc1)(c1ccccc1)c1ccc(-c4ccccc4)cc1B3c1cc(-c3ccccc3)ccc1N2c1c(-c2ccccc2)cccc1-c1ccccc1 ; CC(C)(C)c1cc2c3c(c1)C(c1ccccc1)(c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; c1ccc(-c2ccc3c(c2)B2c4cc(-c5ccccc5)ccc4C(c4ccccc4)(c4ccccc4)c4cc(-n5c6ccccc6c6ccccc65)cc(c42)N3c2c(-c3ccccc3)cccc2-c2ccccc2)cc1]

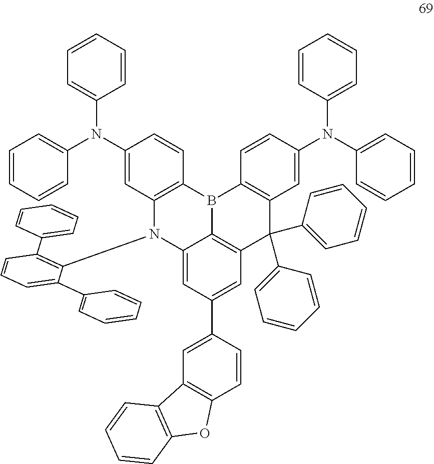 [SMILES: c1ccc(-c2cccc(-c3ccccc3)c2N2c3cc(N(c4ccccc4)c4ccccc4)ccc3B3c4ccc(N(c5ccccc5)c5ccccc5)cc4C(c4ccccc4)(c4ccccc4)c4cc(-c5ccc6oc7ccccc7c6c5)cc2c43)cc1]

### Comparative Example Compounds

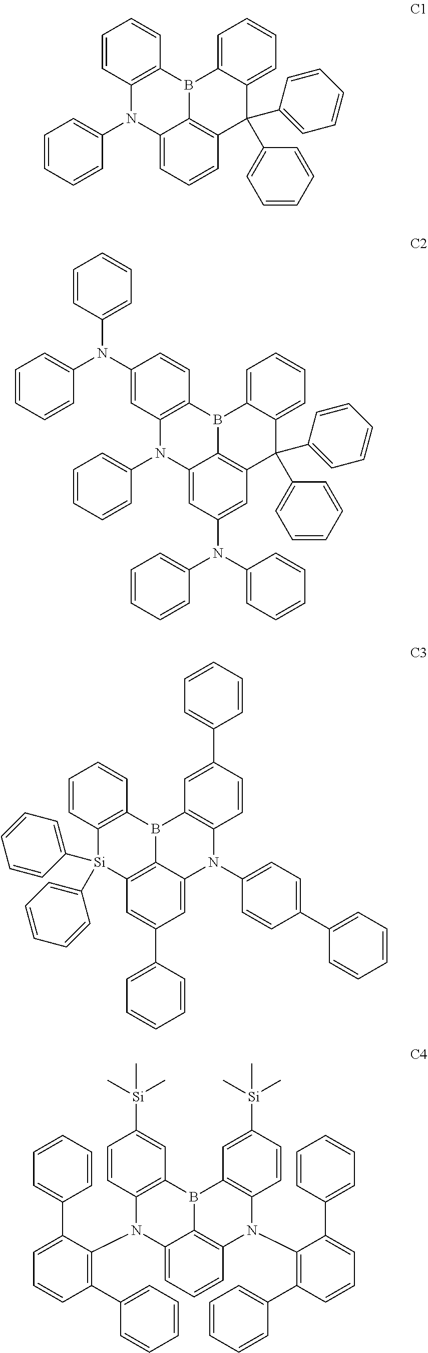

### Manufacture of Light Emitting Elements

A glass substrate on which an ITO having a thickness of 150 nm was patterned was subjected to ultrasonic cleaning utilizing (1) isopropyl alcohol and (2) (and then) pure water, each for 5 minutes, and then irradiated with UV for 30 minutes, and ozone-treated.

Thereafter, a hole injection layer having a thickness of 300 Å was formed utilizing NPD, and on the hole injection layer, a hole transport layer having a thickness of 200 Å was formed through deposition of HT6. On the hole transport layer, a light emitting auxiliary layer having a thickness of 100 Å was formed through deposition of a hole transporting compound CzSi.

Then, Example compounds or Comparative Example compounds, and mCP were co-deposited to form an emission layer having a thickness of 200 Å. Example compounds or Comparative Example compounds, and mCP were co-deposited at a weight ratio of 1:99. In the manufacture of light emitting elements, Example compounds or Comparative Example compounds were utilized as a dopant material.

Thereafter, on the emission layer, an electron transport layer having a thickness of 200 Å was formed through deposition of TSPO1, and on the electron transport layer, a buffer layer having a thickness of 300 Å was formed through deposition of a buffer electron transporting compound TPBi.

On the buffer layer, an electron injection layer having a thickness of 10 Å was formed through deposition of LiF, an alkali metal halide, and a LiF/Al electrode (second electrode) having a thickness of 3000 Å was formed through deposition of Al. On the electrode, a capping layer having a thickness of 700 Å was formed through deposition of HT28 to manufacture a light emitting element.

The hole transport region, the emission layer, the electron transport region, and the second electrode were formed utilizing a vacuum deposition apparatus.

The compounds utilized in the manufacture of the light emitting elements of Examples and Comparative Examples are disclosed below. The following materials were utilized for the manufacture of the elements after sublimation-purifying commercially available products.

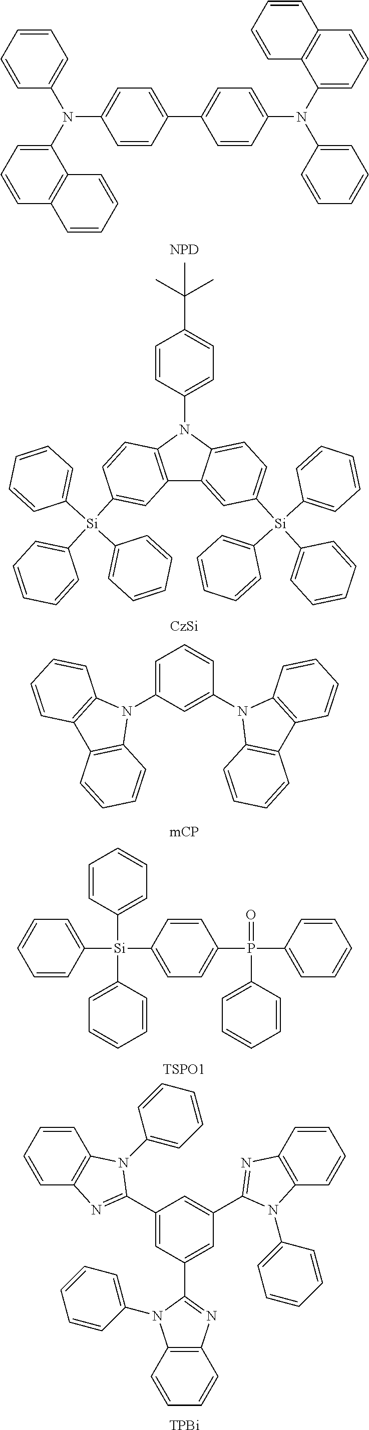

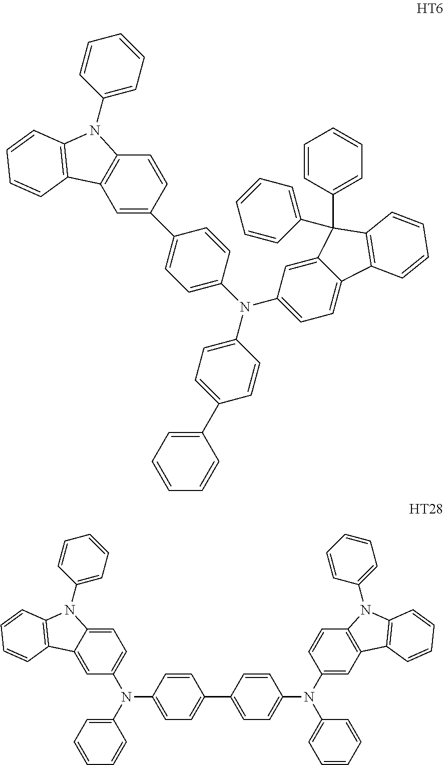 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Evaluation of Physical Properties of Compounds of Examples and Comparative Examples

In Tables 1 and 2, evaluation of the physical properties of Compound 1, Compound 24, Compound 29, Compound 39, Compound 41, Compound 49, Compound 61, and Compound 69, which are Example compounds, and Compounds C₁ to C₄, which are Comparative Example compounds, are shown.

In Table 1, for the compounds of Examples and Comparative Examples, lowest unoccupied molecular orbital (LUMO) energy level, highest occupied molecular orbital (HOMO) energy level, lowest singlet excitation energy level (S1), lowest triplet excitation energy level (T1), a difference between the lowest singlet excitation energy level (S1) and the lowest triplet excitation energy level (T1) (S1-T1, hereinafter LEST), and t (RISC transition time) are shown.

In Table 2, for the compounds of Examples and Comparative Examples, luminous efficiency (PLQY, photoluminescence quantum yield), maximum absorption wavelength (λ_{Abs}), maximum emission wavelength (λₑₘᵢ), maximum emission wavelength (λ_{film}), Stokes-shift (a difference between λ_{Abs} and λₑₘᵢ), and full width at quarter maximum (FWQM) were measured and shown. λₑₘᵢ indicates the maximum emission wavelength of the compounds of Examples or Comparative Examples in a solution state, and λ_{film} indicates the maximum emission wavelength of the compounds of Examples or Comparative Examples in a film state in the manufacture of elements.

TABLE 1

| | | HOMO | LUMO | S1 | T1 | ΔE_{ST} | t |
|---|---|---|---|---|---|---|---|
| Item | Dopant | (eV) | (eV) | (eV) | (eV) | (eV) | (ms) |
| Example | Compound | −5.21 | −2.05 | 2.83 | 2.54 | 0.21 | 122 |
| 1 | 1 | | | | | | |
| Example | Compound | −5.28 | −2.45 | 2.73 | 2.54 | 0.23 | 153 |
| 2 | 24 | | | | | | |
| Example | Compound | −5.41 | −2.05 | 2.80 | 2.63 | 0.22 | 101 |
| 3 | 29 | | | | | | |
| Example | Compound | −5.43 | −2.11 | 2.81 | 2.62 | 0.25 | 89 |
| 4 | 39 | | | | | | |
| Example | Compound | −5.18 | −2.09 | 2.83 | 2.62 | 0.21 | 146 |
| 5 | 41 | | | | | | |
| Example | Compound | −5.46 | −2.20 | 2.75 | 2.52 | 0.24 | 97 |
| 6 | 49 | | | | | | |
| Example | Compound | −5.35 | −2.21 | 2.71 | 2.55 | 0.22 | 116 |
| 7 | 61 | | | | | | |
| Example | Compound | −5.15 | −2.32 | 2.73 | 2.52 | 0.21 | 62 |
| 8 | 69 | | | | | | |
| Comparative | Compound | −5.12 | −1.84 | 2.82 | 2.54 | 0.33 | 148 |
| Example | C1 | | | | | | |
| 1 | | | | | | | |
| Comparative | Compound | −5.22 | −2.01 | 2.77 | 2.50 | 0.13 | 58 |
| Example | C2 | | | | | | |
| 2 | | | | | | | |
| Comparative | Compound | −5.15 | −2.32 | 2.80 | 2.55 | 0.25 | 72 |
| Example | C3 | | | | | | |
| 3 | | | | | | | |
| Comparative | Compound | −5.18 | −2.01 | 2.75 | 2.48 | 0.27 | 81 |
| Example | C4 | | | | | | |
| 4 | | | | | | | |

TABLE 2

| | | PLQY | λ_{Abs} | λₑₘᵢ | λ_{film} | Stokes- | FWQM |
|---|---|---|---|---|---|---|---|
| Item | Dopant | (%) | (nm) | (nm) | (nm) | shift | (nm) |
| Example 1 | Compound | 81 | 420 | 435 | 436 | 15 | 42 |
| | 1 | | | | | | |
| Example 2 | Compound | 93 | 437 | 450 | 451 | 13 | 43 |
| | 24 | | | | | | |
| Example 3 | Compound | 90 | 432 | 445 | 446 | 13 | 45 |
| | 29 | | | | | | |
| Example 4 | Compound | 87 | 440 | 452 | 453 | 12 | 42 |
| | 39 | | | | | | |
| Example 5 | Compound | 88 | 433 | 446 | 447 | 13 | 41 |
| | 41 | | | | | | |
| Example 6 | Compound | 92 | 429 | 441 | 442 | 13 | 42 |
| | 49 | | | | | | |
| Example 7 | Compound | 90 | 430 | 443 | 444 | 13 | 42 |
| | 61 | | | | | | |
| Example 8 | Compound | 86 | 429 | 442 | 443 | 13 | 43 |
| | 69 | | | | | | |
| Comparative | Compound | 71 | 405 | 422 | 427 | 17 | 46 |
| Example 1 | C1 | | | | | | |
| Comparative | Compound | 76 | 403 | 420 | 425 | 17 | 45 |
| Example 2 | C2 | | | | | | |
| Comparative | Compound | 72 | 426 | 442 | 447 | 18 | 45 |
| Example 3 | C3 | | | | | | |
| Comparative | Compound | 5 | 33 | 51 | 53 | 6 | 3 |
| Example 4 | C4 | | | | | | |

Referring to Table 1, it is seen that the compounds of Examples 1 to 8 and Comparative Examples 1 to 4 are applicable as TADF dopant materials with LEST of 0.27 eV or less, and t satisfying the range of 155 ms or less.

Referring to Table 2, it is seen that the compounds of Examples 1 to 8 have λ_{Abs}, λₑₘᵢ, and λ_{film} values closer to 450 nm than the compounds of Comparative Examples 1 and 2. For example, the compounds of Examples 1 to 8 may emit pure blue light compared to the compounds of Comparative Examples 1 and 2.

It is seen that the compounds of Examples 1 to 8 have greater luminous efficiency (PLQY), smaller Stokes-shift values, and smaller full width at quarter maximum than the compounds of Comparative Examples 1 to 4.

Accordingly, the light emitting elements of Examples 1 to 8 may exhibit greater luminous efficiency, greater element lifespan, and higher color purity than the light emitting elements of Comparative Examples 1 to 4.

### Property Evaluation of Light Emitting Elements

Property evaluation of the manufactured light emitting elements was performed utilizing a luminance orientation property measuring apparatus.

In Table 3, for the property evaluation of the light emitting elements according to Examples and Comparative Examples, driving voltage, luminous efficiency, emission wavelength, full width at quarter maximum (FMQW), lifespan ratio, colorimetric system (CIE), and quantum efficiency (Q.E) were measured.

Table 3 shows the evaluation results of the light emitting elements including hole transporting hosts, electron transporting hosts, sensitizers, and dopants in emission layers.

In Table 3, the driving voltage (V) and luminous efficiency (cd/A) at a current density of 10 10 mA/cm² were measured for the manufactured light emitting elements. The lifespan ratio was indicated as a relative value with respect to the lifespan ratio of Comparative Example 1 as 1 by comparing the time from the initial value to 50% luminance deterioration upon substantially continuous-driving at a current density of 10 mA/cm².

In Table 3, HT-1 was utilized as the hole transporting host, ET-1 was utilized as the electron transporting host, and PS-1 was utilized as the sensitizer.

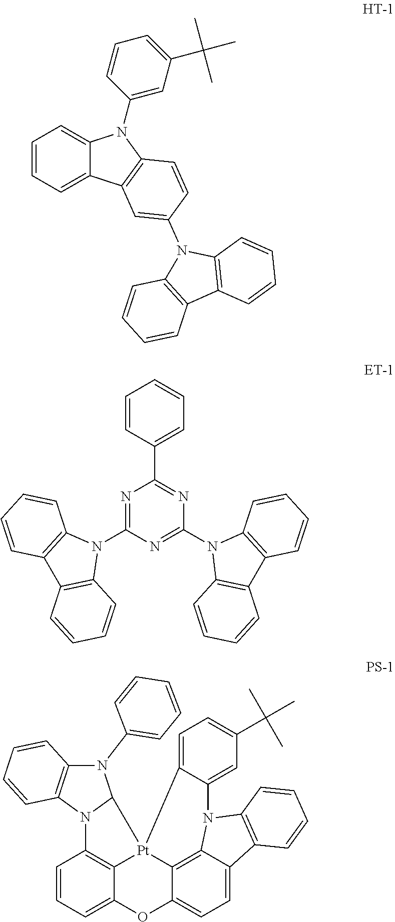

TABLE 3

| | | Driving | Luminous | Emission | | Lifespan | | |
|---|---|---|---|---|---|---|---|---|
| | | voltage | efficiency | wavelength | FMQW | ratio | CIE | |
| Item | Dopant | (V) | (cd/A) | (nm) | (nm) | (T95) | (x, y) | Q.E |
| Example | Compound | 4.2 | 4.1 | 436 | 44 | 3.3 | 0.141, | 6.5 |
| 1 | 1 | | | | | | 0.113 | |
| Example | Compound | 4.2 | 10.6 | 451 | 45 | 7.2 | 0.140, | 13.0 |
| 2 | 24 | | | | | | 0.133 | |
| Example | Compound | 4.3 | 8.8 | 446 | 47 | 9.3 | 0.141, | 9.3 |
| 3 | 29 | | | | | | 0.125 | |
| Example | Compound | 4.1 | 11.1 | 453 | 44 | 10.9 | 0.139, | 14.5 |
| 4 | 39 | | | | | | 0.135 | |
| Example | Compound | 4.2 | 8.3 | 447 | 43 | 8.5 | 0.135, | 9.1 |
| 5 | 41 | | | | | | 0.131 | |
| Example | Compound | 4.3 | 6.3 | 442 | 44 | 7.1 | 0.140, | 7.1 |
| 6 | 49 | | | | | | 0.123 | |
| Example | Compound | 4.3 | 7.6 | 444 | 44 | 8.4 | 0.138, | 8.6 |
| 7 | 61 | | | | | | 0.123 | |
| Example | Compound | 4.4 | 6.4 | 443 | 46 | 9.1 | 0.139, | 8.3 |
| 8 | 69 | | | | | | 0.124 | |
| Comparative | Compound | 5.5 | 1.3 | 427 | 52 | 1.0 | 0.133, | 2.2 |
| Example | C1 | | | | | | 0.102 | |
| 1 | | | | | | | | |
| Comparative | Compound | 4.9 | 3.2 | 425 | 51 | 1.2 | 0.134, | 4.5 |
| Example | C2 | | | | | | 0.108 | |
| 2 | | | | | | | | |
| Comparative | Compound | 4.8 | 2.9 | 447 | 51 | 1.0 | 0.135, | 3.7 |
| Example | C3 | | | | | | 0.131 | |
| 3 | | | | | | | | |
| Comparative | Compound | 4.9 | 3.2 | 453 | 49 | 3.2 | 0.140, | 3.6 |
| Example | C4 | | | | | | 0.133 | |
| 4 | | | | | | | | |

Referring to Table 3 above, the light emitting elements of Examples 1 to 8 may each exhibit lower driving voltage, greater luminous efficiency, smaller full width at quarter maximum, greater element lifespan, and higher quantum efficiency (Q.E) than the light emitting elements of Comparative Examples 1 to 4.

In some embodiments, the light emitting elements of Comparative Examples 1 and 2 have a light emitting wavelength in the range of 427 nm and 425 nm, and may thus exhibit a blue color having reduced color purity compared to the light emitting elements of Examples 1 to 8.

Compounds C₁ to C₃ of Comparative Examples include a C—C bond or a C—Si bond in a fused ring, but do not include a terphenyl group connected to the fused ring. Accordingly, the compounds C₁ to C₃ have more active intermolecular interactions, such as intermolecular aggregation, excimer formation, or exciplex formation, than the compounds of Examples, thereby reducing thermal stability of molecules and decreasing luminous efficiency and lifespan of elements. In some embodiments, in the compounds C₁ to C₃ of Comparative Examples, the p orbital of boron atoms in molecules is not protected by the terphenyl group, and accordingly, deterioration of elements may be caused as the boron atoms are combined with external nucleophiles. Accordingly, it is believed that the light emitting elements of Comparative Examples 1 to 3 exhibit higher driving voltages, lower luminous efficiencies, and shorter lifespans than the elements of Examples.

Compound C₄ of Comparative Example includes a terphenyl group connected to a fused ring, and includes a C—Si bond in molecules, but Si is connected to an alkyl group other than an aryl group, a heteroaryl group, or an aromatic ring, and thus it is believed that the compound has a greater deterioration in efficiency and lifespan of the element compared to the compounds of Examples.

The polycyclic compound of the present disclosure includes a C—C bond or a C—Si bond, including a fused ring skeleton containing carbon atoms, silicon atoms, boron atoms, and nitrogen atoms as ring-forming atoms to increase bond dissociation energy of molecules, and may thus exhibit greater molecular stability.

In some embodiments, the polycyclic compound of the present disclosure includes a structure in which an ortho-type or kind terphenyl group is connected to the fused ring skeleton having a plate structure, and may thus increase intermolecular distance, and reduce intermolecular interactions such as intermolecular aggregation, excimer formation, and exciplex formation, which may cause a decrease in luminous efficiency of elements. The terphenyl group may protect the p orbital of boron atoms, thereby preventing or reducing deformation of the trigonal bond structure of the boron atoms, which may cause deterioration of the elements. In some embodiments, the terphenyl group blocks high-energy radicals, excitons, and polarons from accessing the polycyclic compound, and inhibits Dexter energy transfer from hosts or sensitizers, thereby reducing deterioration of the elements and increasing element lifespan.

A light emitting element including a polycyclic compound of the present disclosure as a dopant of an emission layer may have a significant increase in lifespan and luminous efficiency.

A light emitting element according to an embodiment includes a polycyclic compound of an embodiment in an emission layer, and may thus exhibit high efficiency and long life characteristics.

A polycyclic compound of an embodiment includes a polycyclic group having a large steric effect, and may thus contribute to an increase in lifespan and luminous efficiency of a light emitting element.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting element comprising:
a first electrode;
a second electrode facing the first electrode; and
at least one functional layer between the first electrode and the second electrode,
wherein the at least one functional layer comprises:
a first compound represented by Formula 1; and
at least one of a second compound represented by Formula HT-1, a third compound represented by Formula ET-1, or a fourth compound represented by Formula M-b: 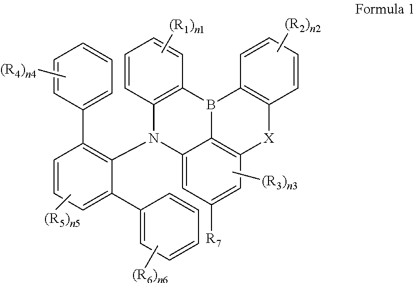
wherein in Formula 1,
X is CR₈R₉ or SiR₁₀R₁₁,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
R₈ to R₁₁ are each independently a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring,
n1 and n2 are each independently an integer from 0 to 4,
n3 is an integer from 0 to 2,
n4 is an integer from 0 to 5,
n5 is an integer from 0 to 3, and
n6 is an integer from 0 to 5; 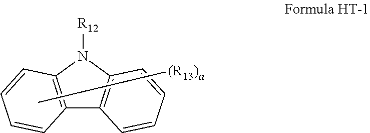
wherein in Formula HT-1,
R₁₂ and R₁₃ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
a is an integer from 0 to 8; 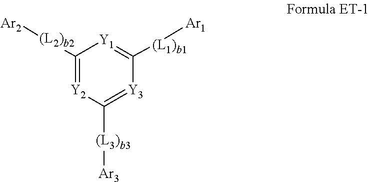
wherein in Formula ET-1,
Y₁ to Y₃ are each independently N or CRₐ, and at least one of Y₁ to Y₃ is N,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
b1 to b3 are each independently an integer from 0 to 10; and 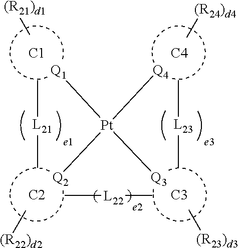
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocycle having 2 to 30 ring-forming carbon atoms,
L₂₁ to L₂₃ are each independently a direct linkage, 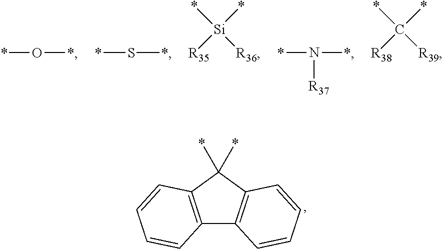
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4,
e1 to e3 are each independently 0 or 1, and
R₂₁ to R₂₄, and R₃₅ to R₃₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

2. The light emitting element of claim 1, wherein the at least one functional layer comprises an emission layer, a hole transport region between the first electrode and the emission layer, and an electron transport region between the emission layer and the second electrode,
the emission layer comprising:
the first compound; and
at least one of the second compound, the third compound, or the fourth compound.

3. The light emitting element of claim 2, wherein the emission layer is configured to emit delayed fluorescence.

4. The light emitting element of claim 2, wherein the emission layer is configured to emit light having a maximum emission wavelength of about 430 nm to about 490 nm.

5. The light emitting element of claim 1, wherein the at least one functional layer comprises the first compound, the second compound, and the third compound.

6. The light emitting element of claim 1, wherein the at least one functional layer comprises the first compound, the second compound, the third compound, and the fourth compound.

7. The light emitting element of claim 1, wherein the first compound represented by Formula 1 is represented by any one selected from among Formulas 1-1a to 1-1e: 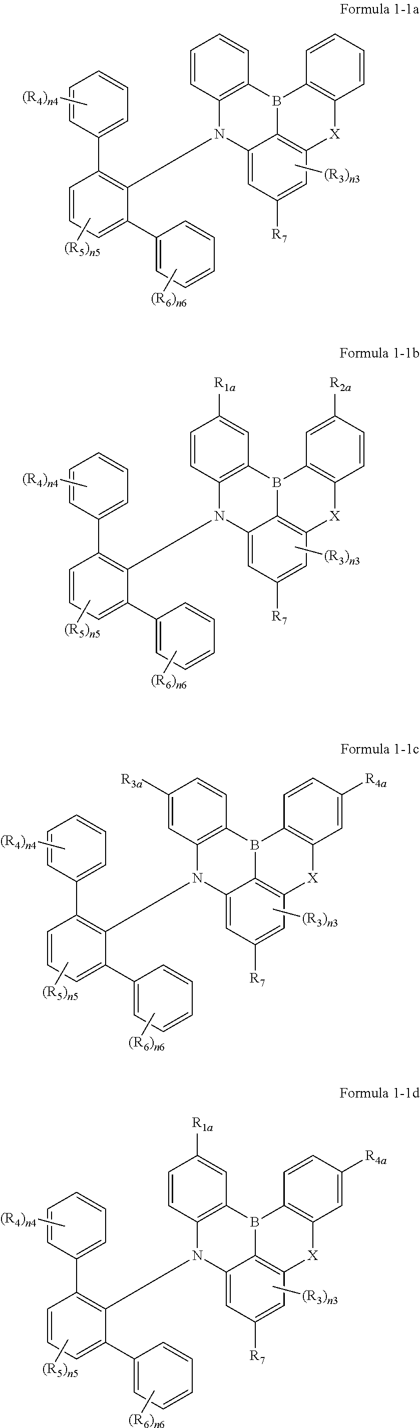 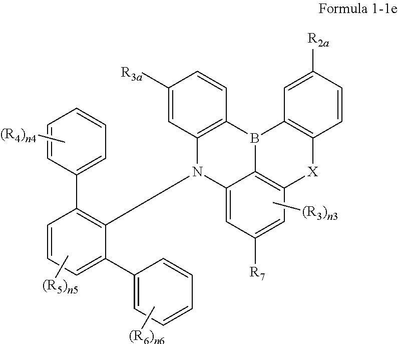
wherein in Formulas 1-1a to 1-1e,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
R₃ to R₇, X, and n3 to n6 are the same as defined in Formula 1.

8. The light emitting element of claim 7, wherein R₁ₐ to R₄ₐ are each independently a substituted or unsubstituted diphenylamine group, a substituted or unsubstituted phenyl group, or a substituted or unsubstituted carbazole group.

9. The light emitting element of claim 1, wherein R₁ and R₂ are each independently a hydrogen atom, a substituted or unsubstituted diphenylamine group, a substituted or unsubstituted phenyl group, or a substituted or unsubstituted carbazole group.

10. The light emitting element of claim 1, wherein R₃ is a hydrogen atom.

11. The light emitting element of claim 1, wherein R₄ and R₆ are each independently a hydrogen atom, a deuterium atom, a halogen atom, or a cyano group, and/or bonded to an adjacent group to form a ring.

12. The light emitting element of claim 1, wherein R₅ is a hydrogen atom.

13. The light emitting element of claim 1, wherein R₇ is a hydrogen atom, a substituted or unsubstituted t-butyl group, a substituted or unsubstituted diphenylamine group, a substituted or unsubstituted phenyl group, a substituted or unsubstituted biphenyl group, a substituted or unsubstituted terphenyl group, a substituted or unsubstituted carbazole group, a substituted or unsubstituted dibenzofuran group, a substituted or unsubstituted dibenzothiophene group, or a substituted or unsubstituted dibenzoselenophene group.

14. The light emitting element of claim 1, wherein R₈ to R₁₁ are each independently a substituted or unsubstituted phenyl group, and/or bonded to an adjacent group to form an aromatic ring.

15. The light emitting element of claim 1, wherein the first compound is represented by any one selected from among compounds of Compound Group 1: 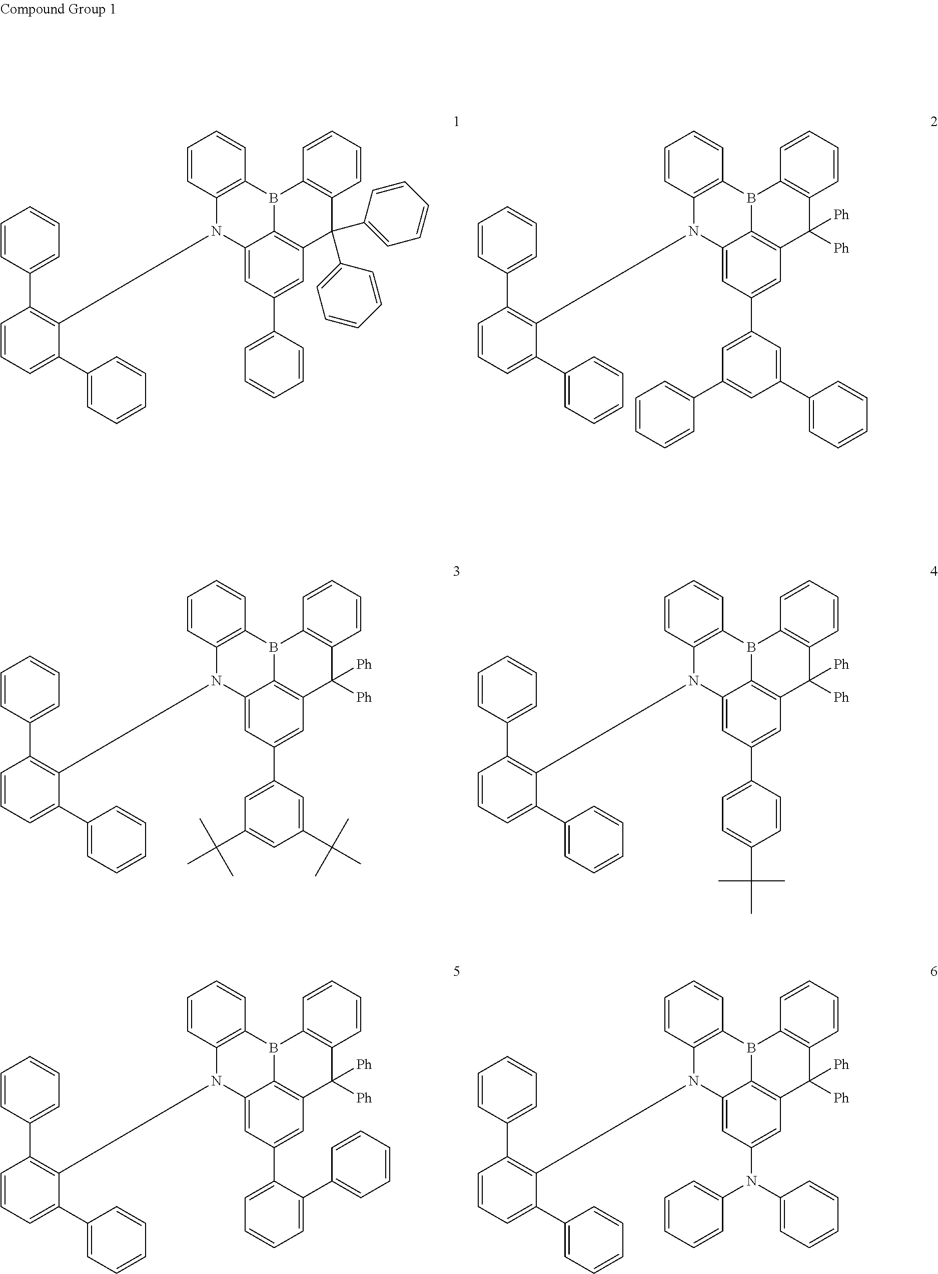 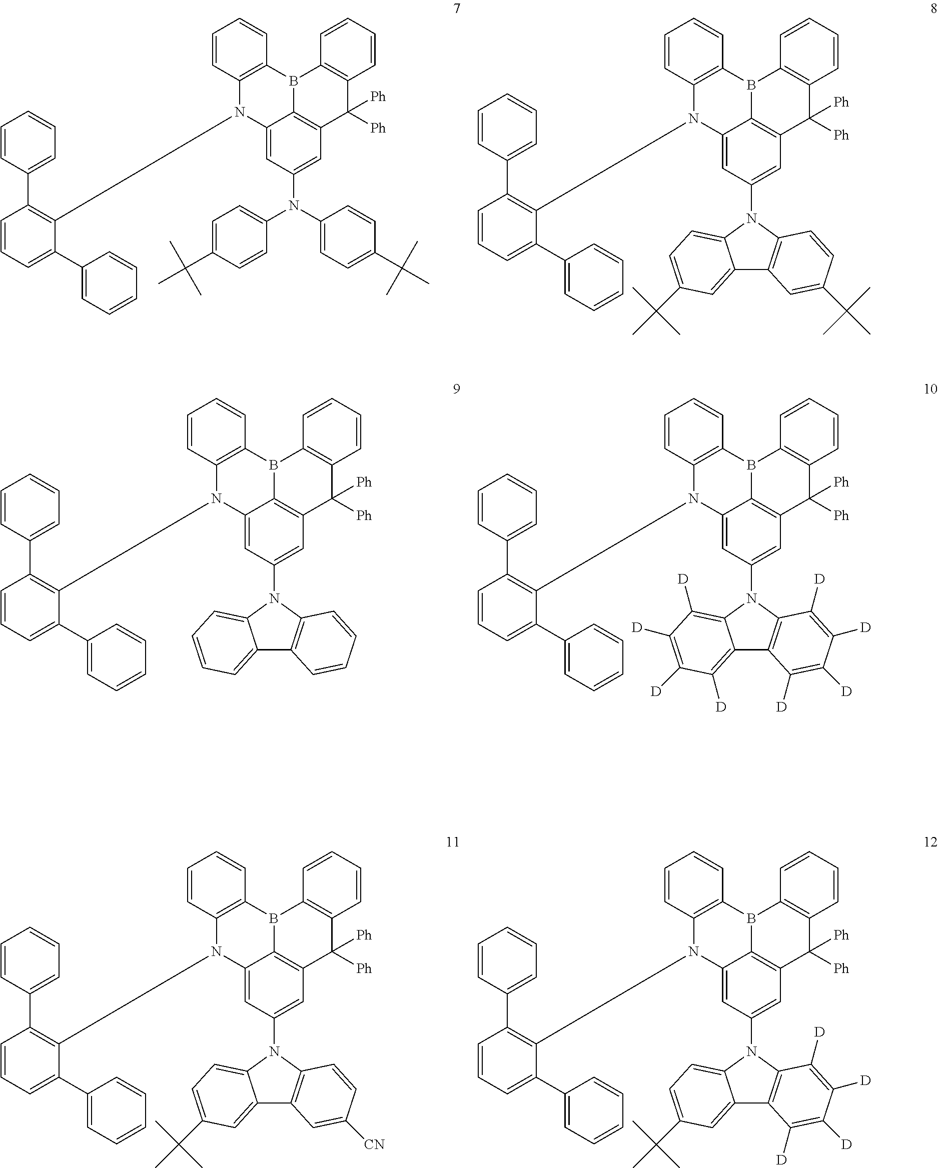 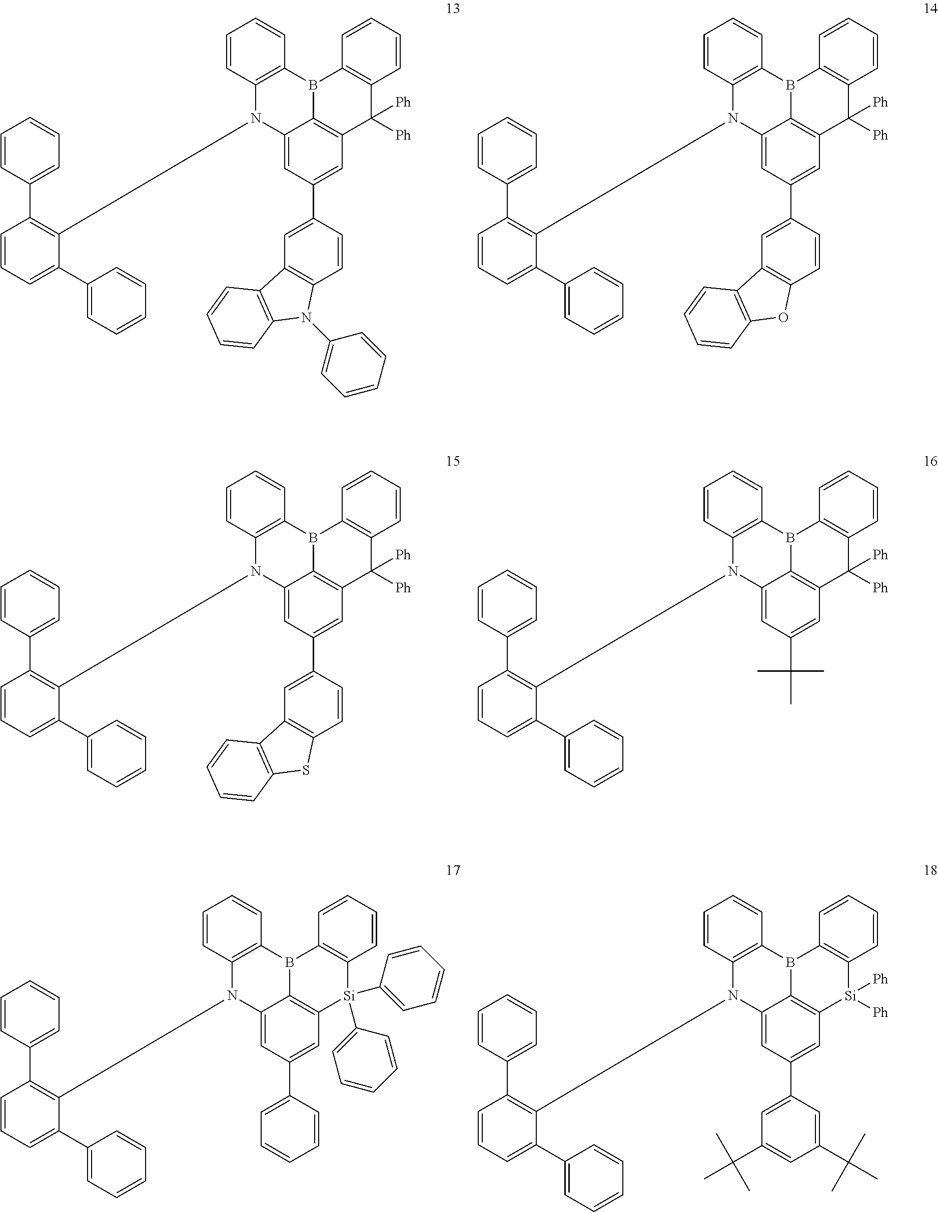 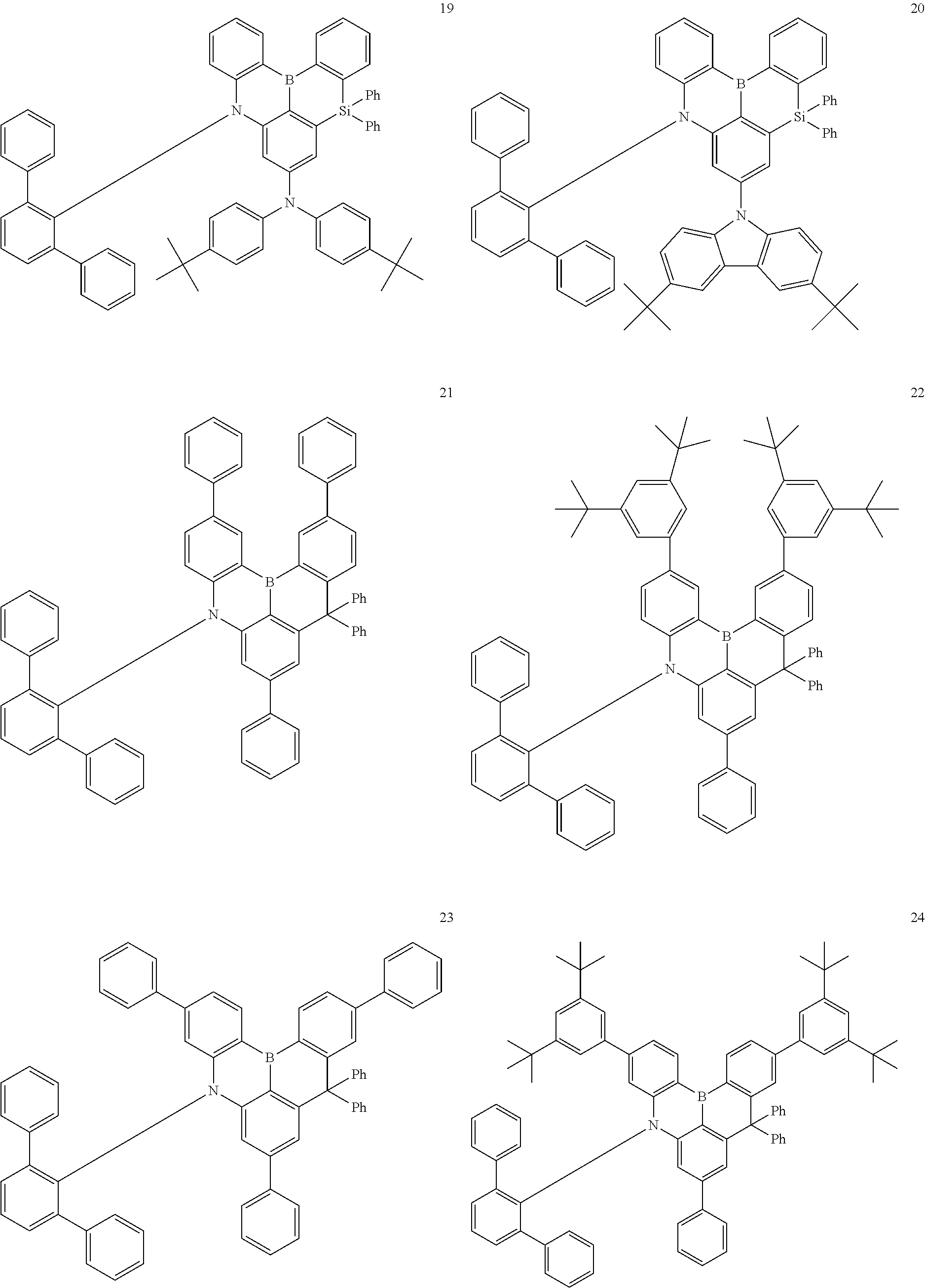 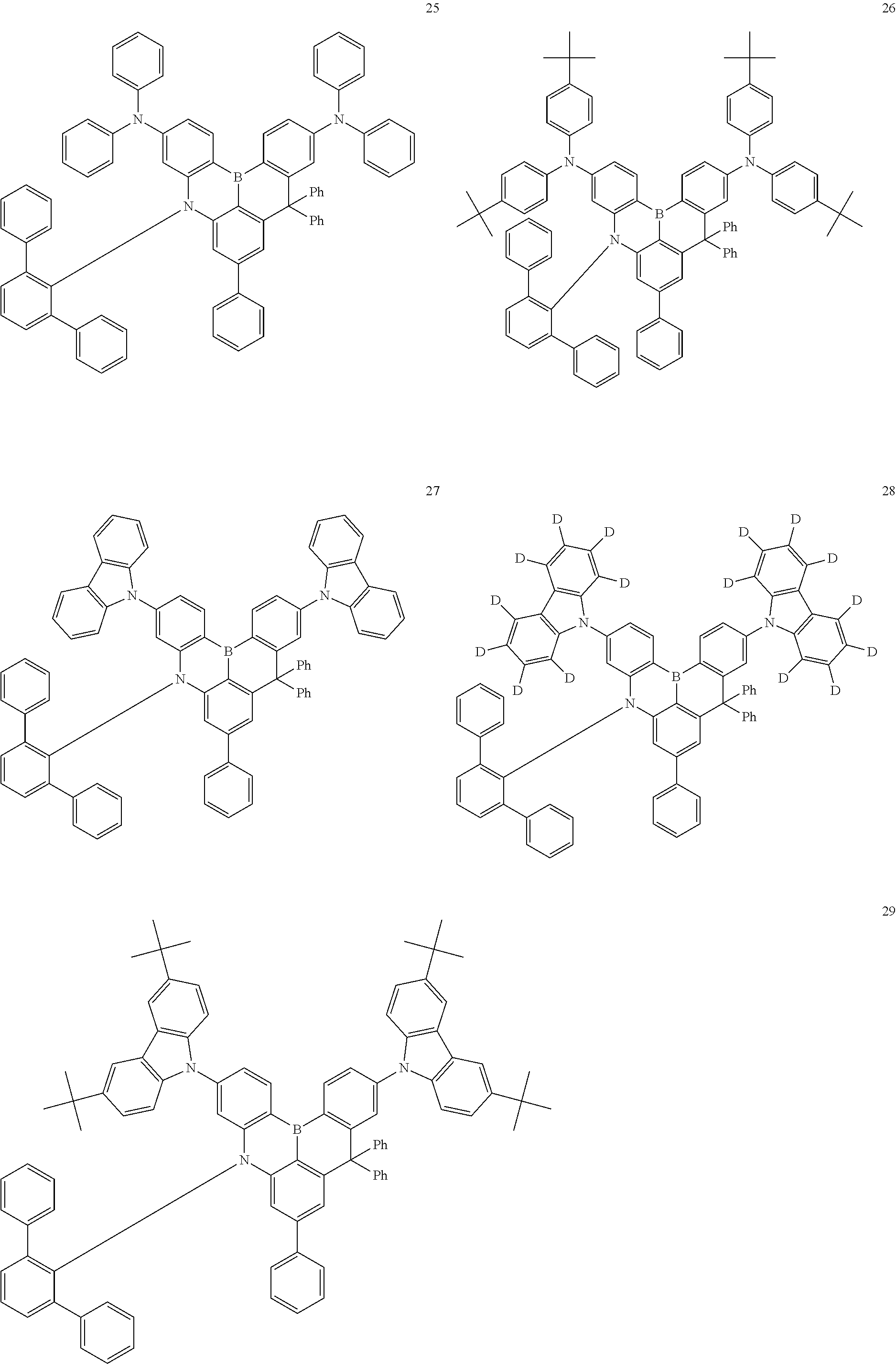 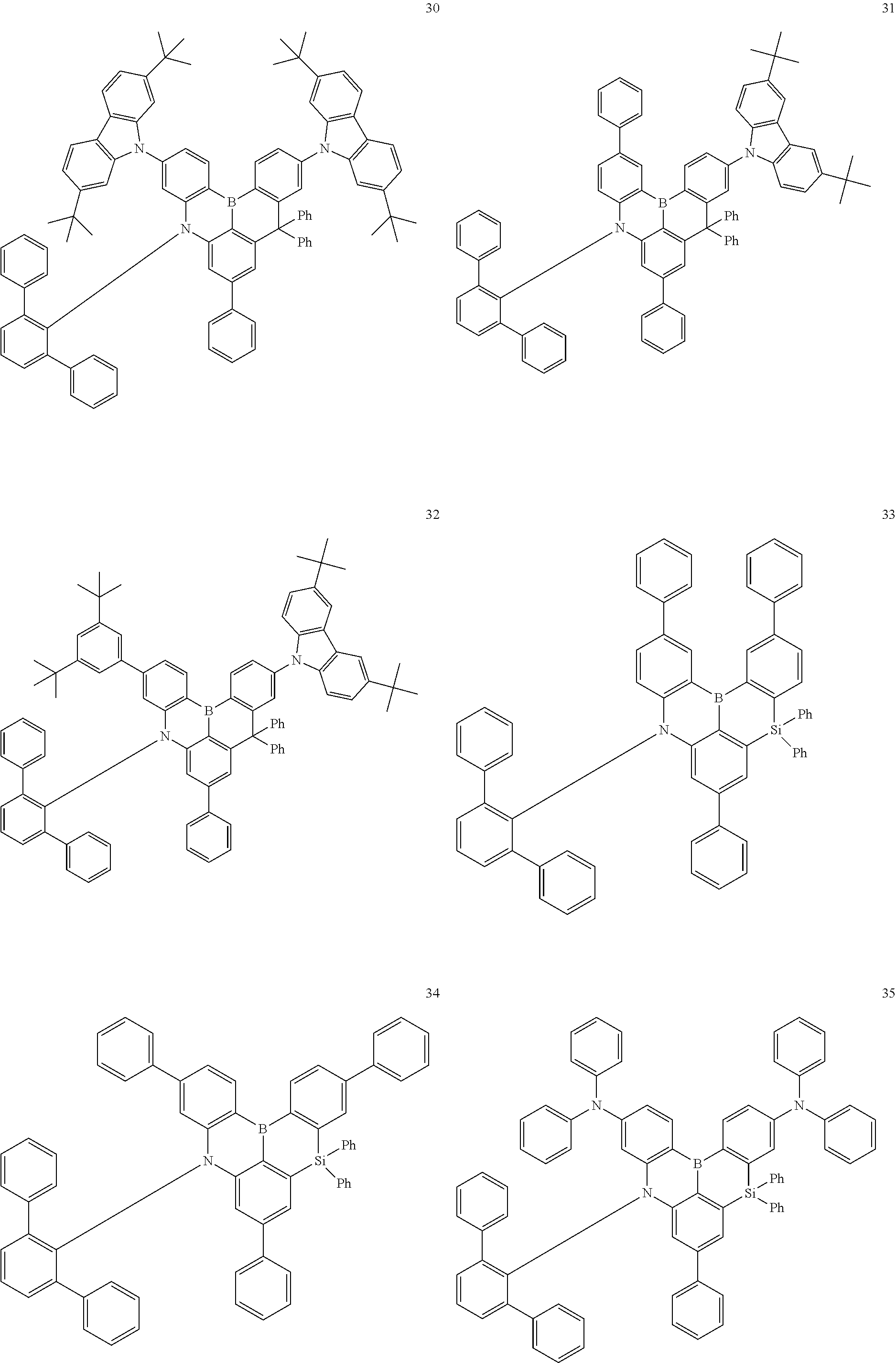 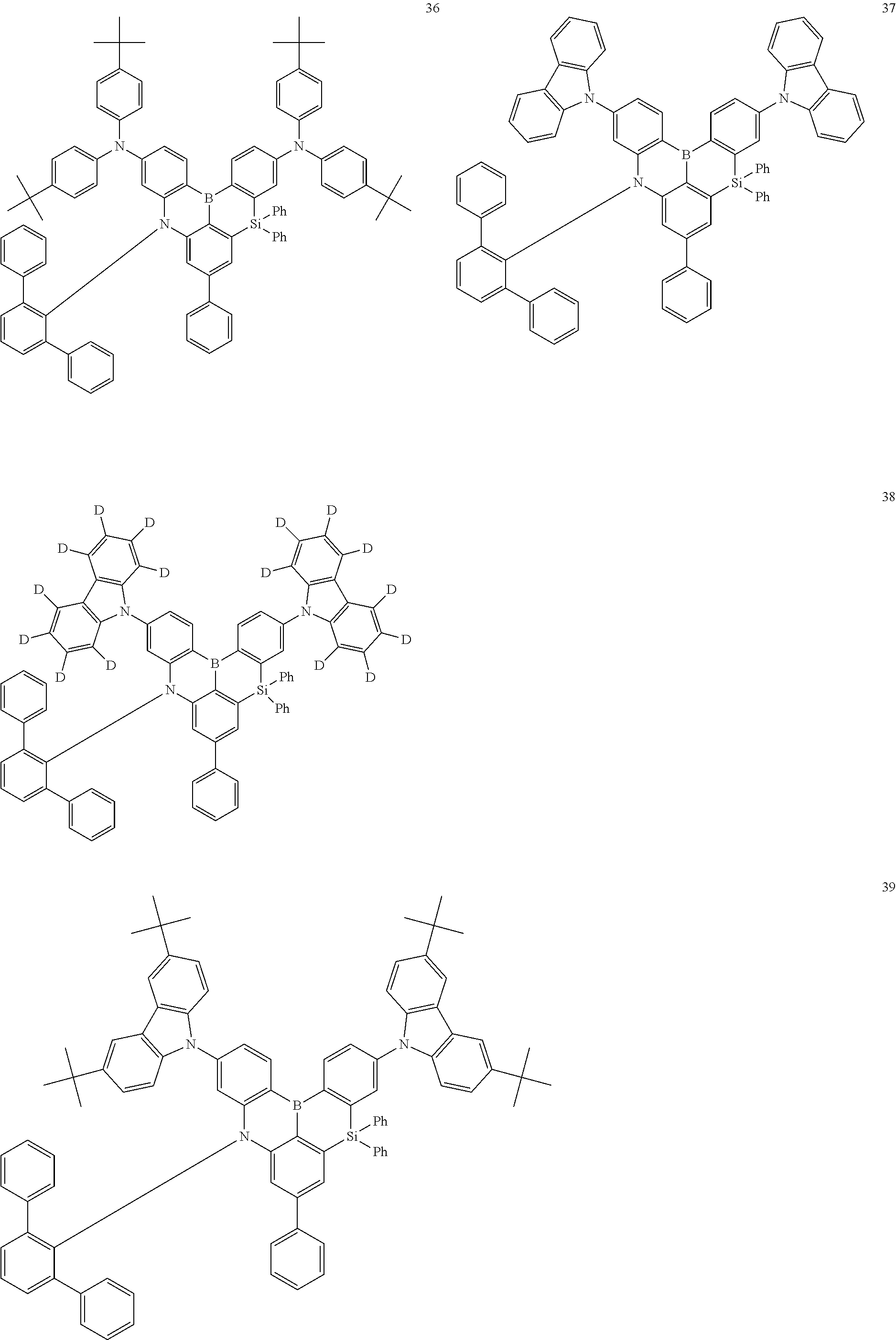 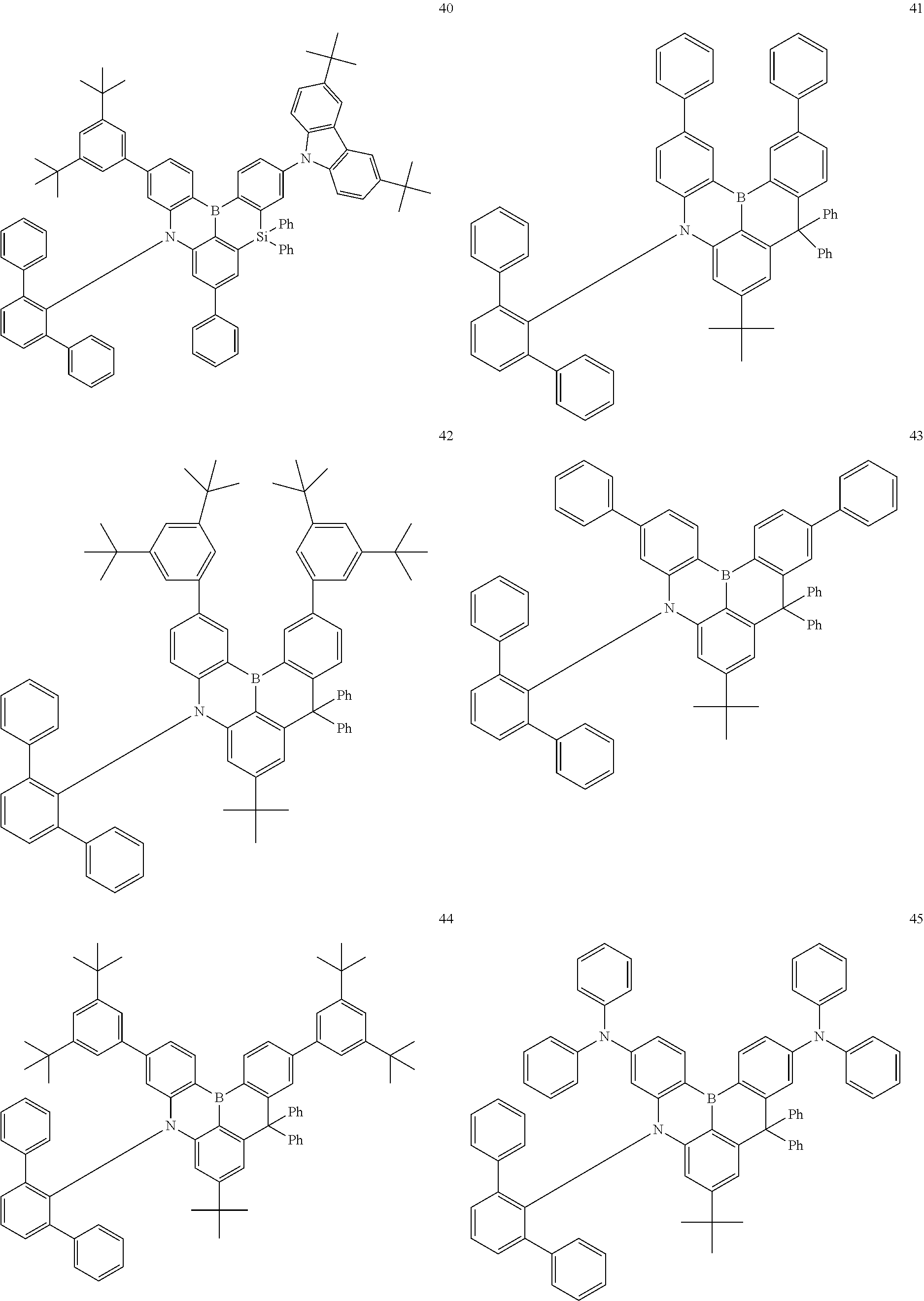 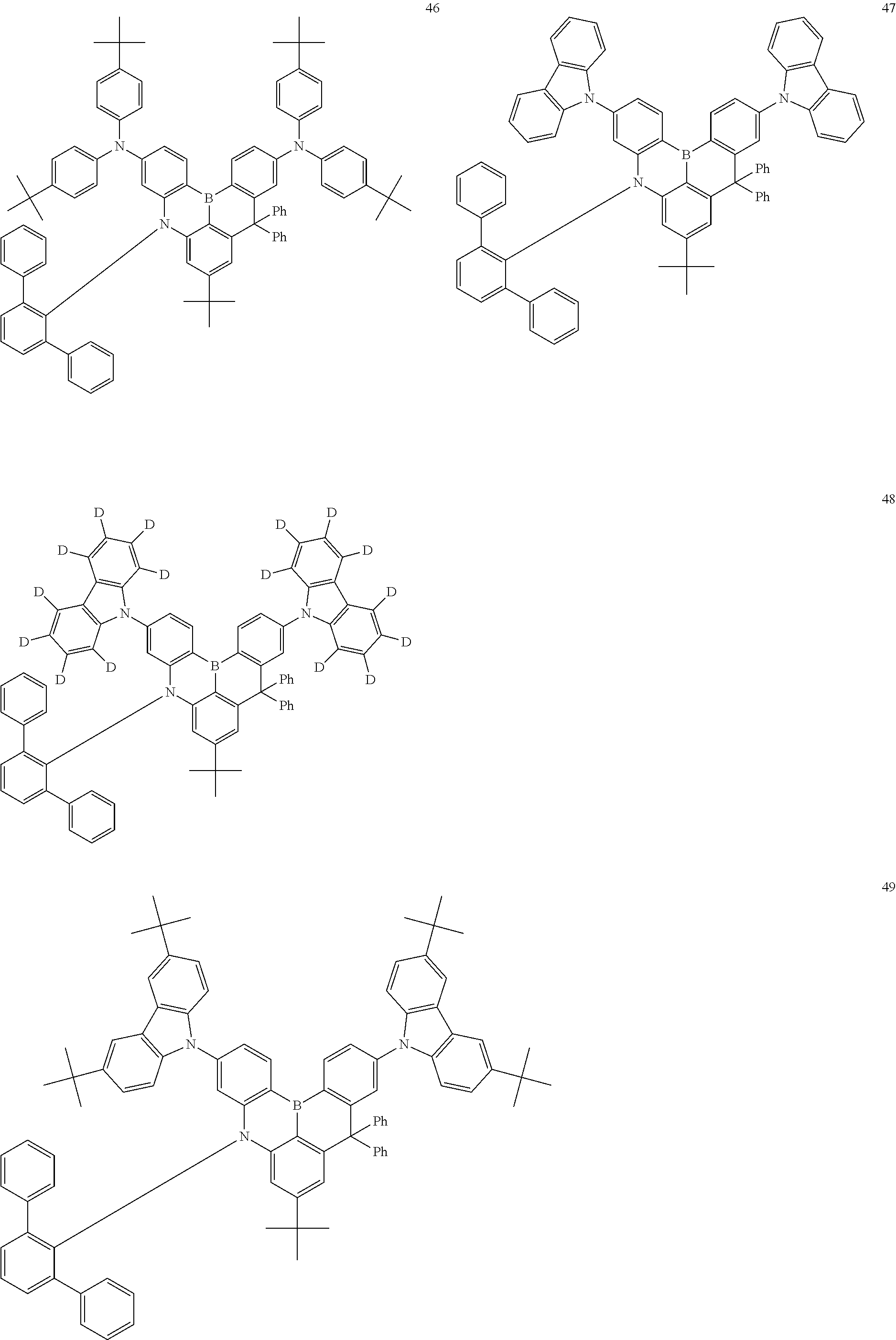 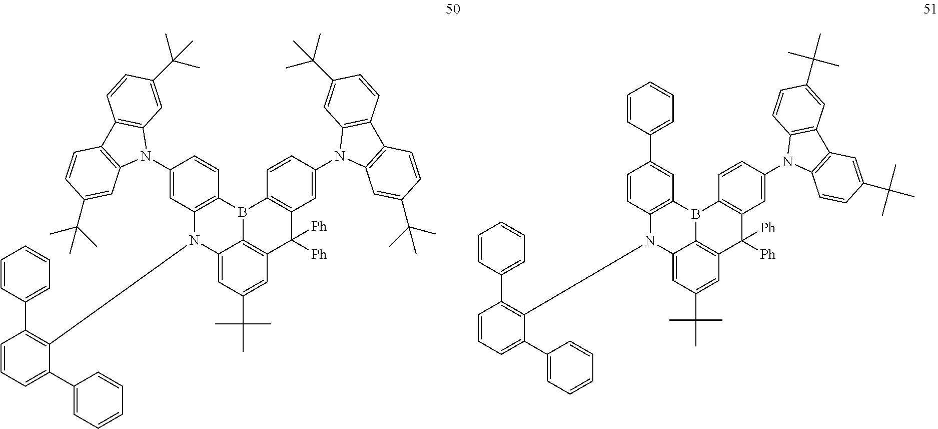 [SMILES: CC(C)(C)c1cc2c3c(c1)C(c1ccccc1)(c1ccccc1)c1cc(-n4c5cc(C(C)(C)C)ccc5c5ccc(C(C)(C)C)cc54)ccc1B3c1ccc(-n3c4cc(C(C)(C)C)ccc4c4ccc(C(C)(C)C)cc43)cc1N2c1c(-c2ccccc2)cccc1-c1ccccc1 ; CC(C)(C)c1cc2c3c(c1)C(c1ccccc1)(c1ccccc1)c1cc(-n4c5ccc(C(C)(C)C)cc5c5cc(C(C)(C)C)ccc54)ccc1B3c1cc(-c3ccccc3)ccc1N2c1c(-c2ccccc2)cccc1-c1ccccc1] 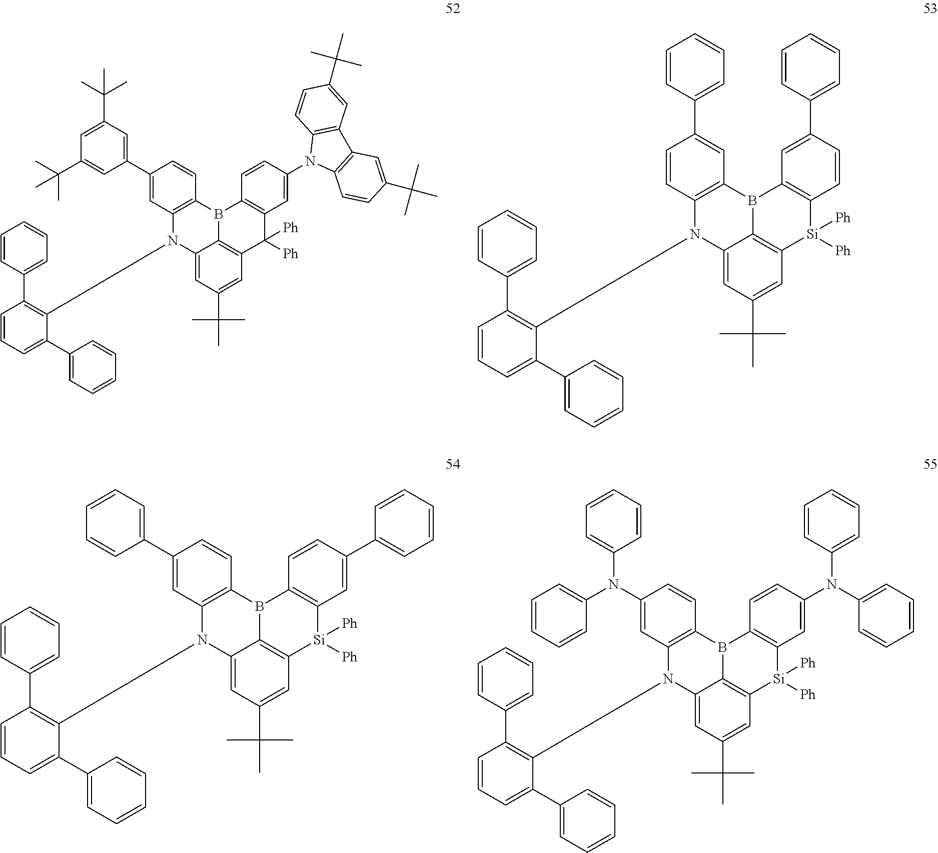 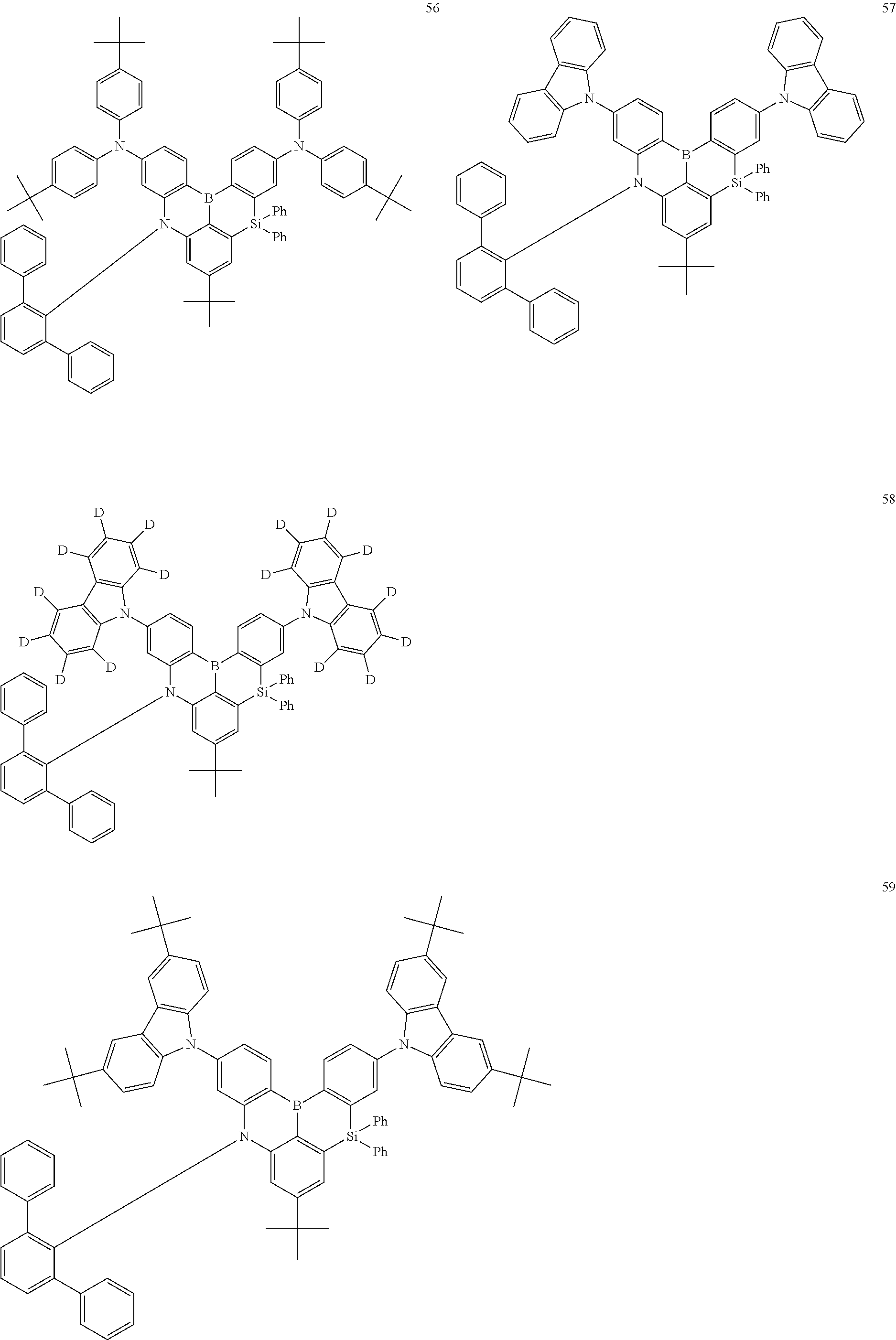 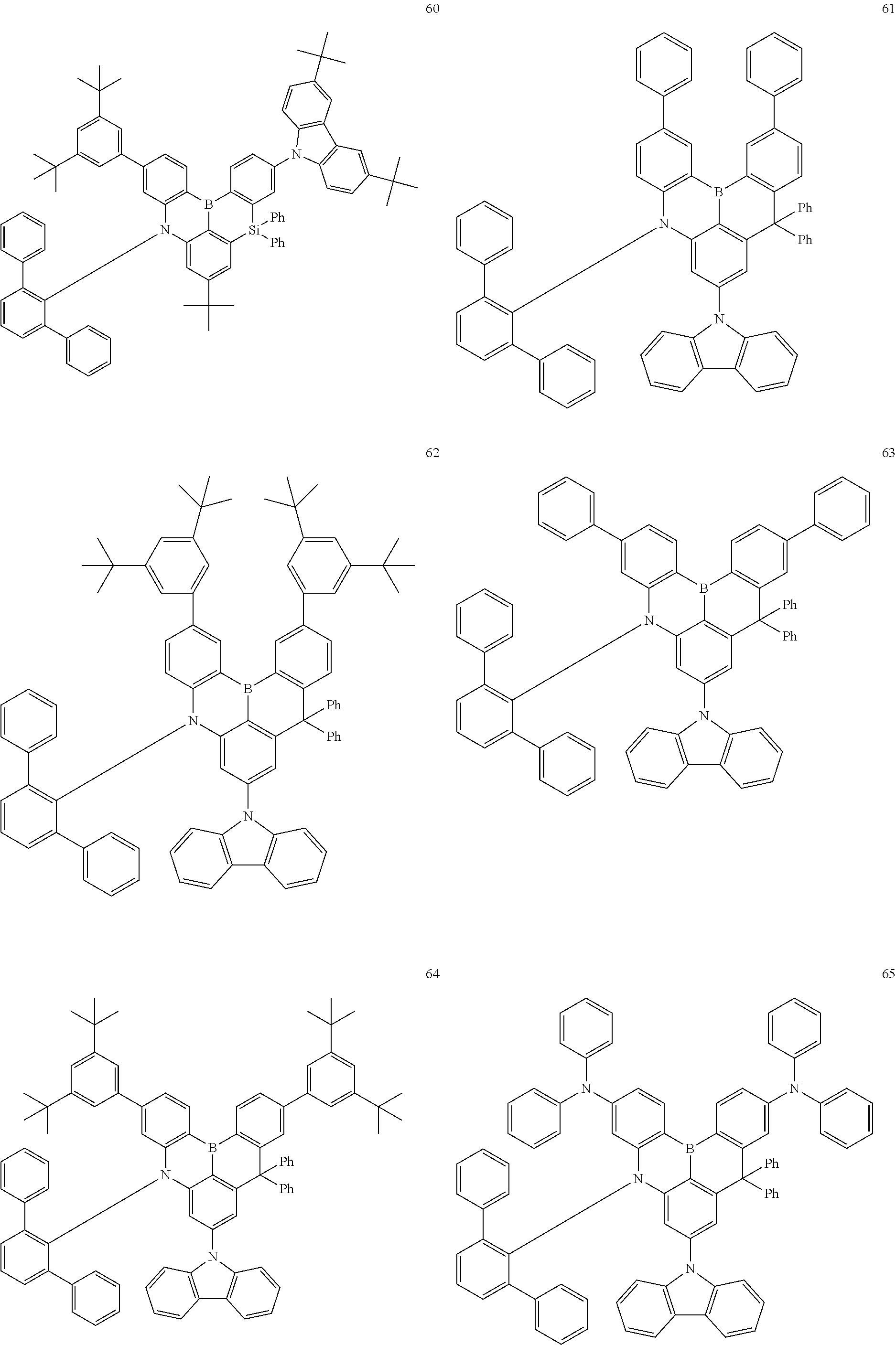 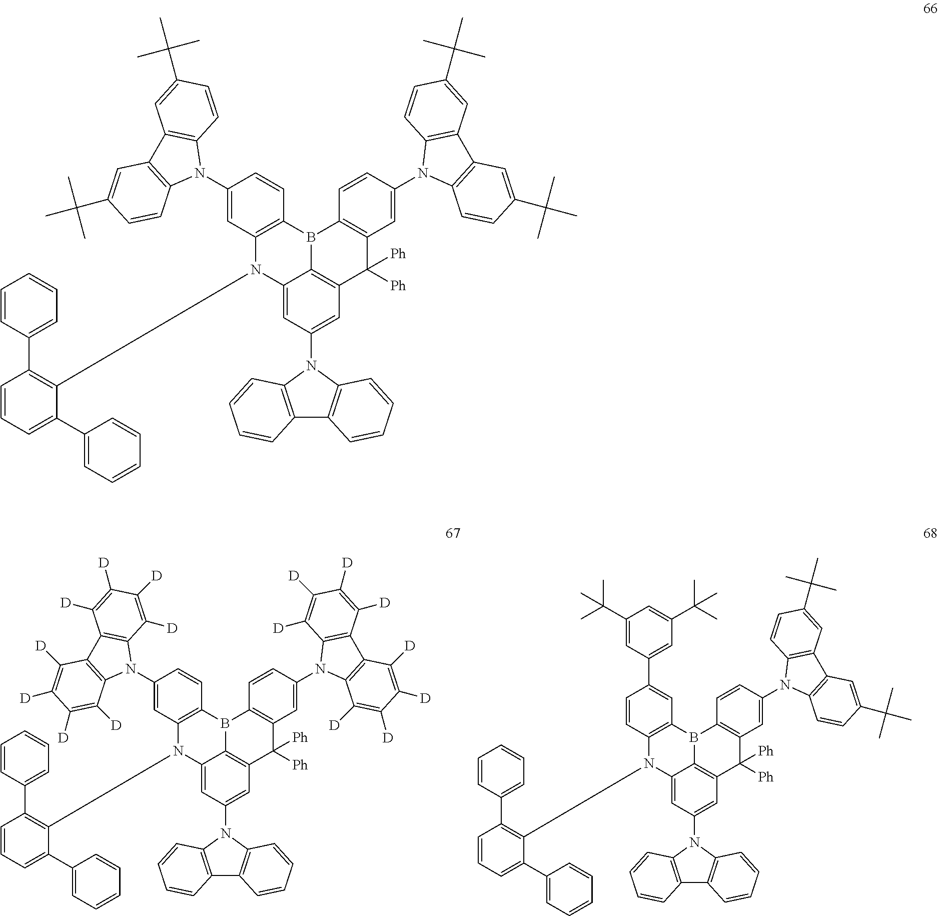 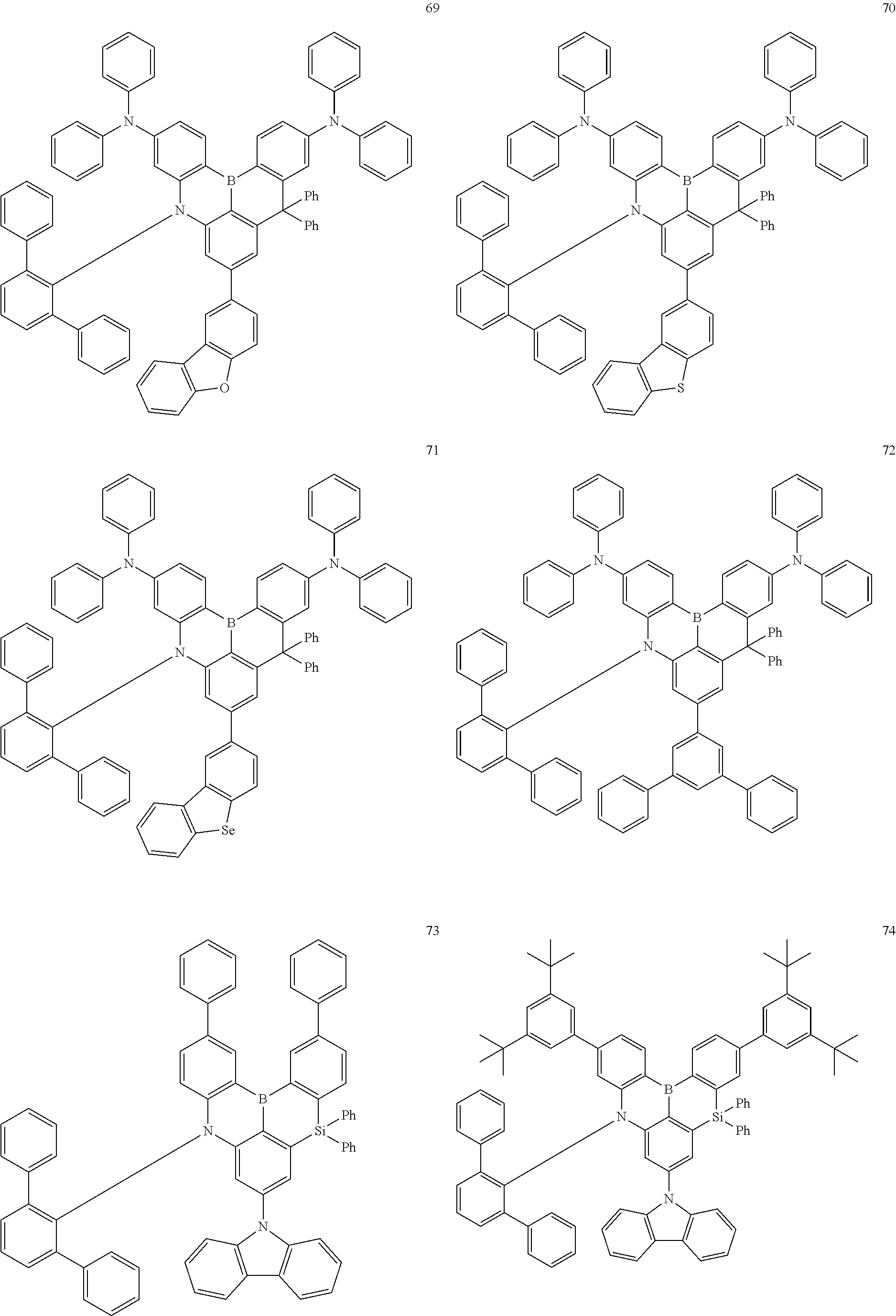 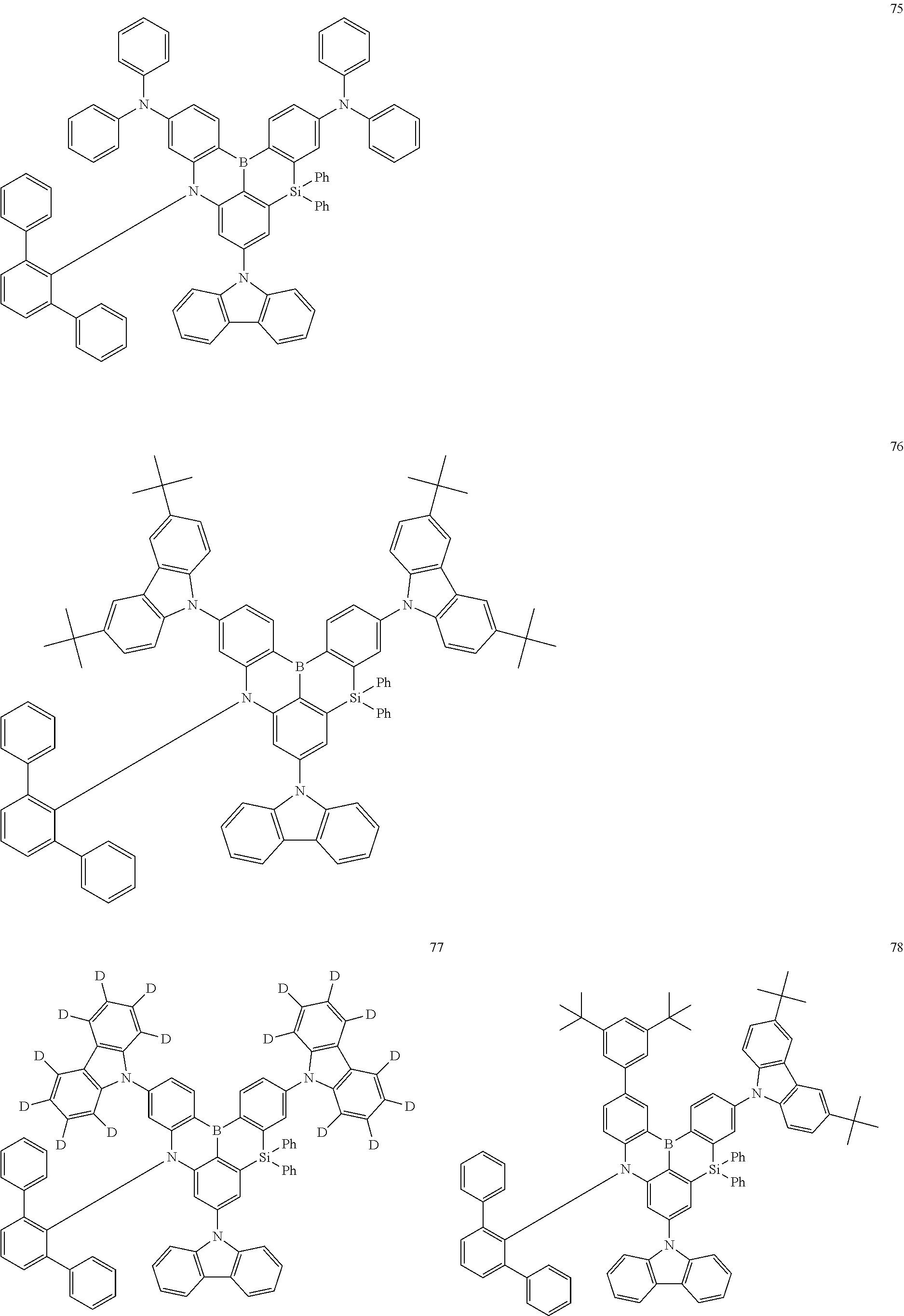 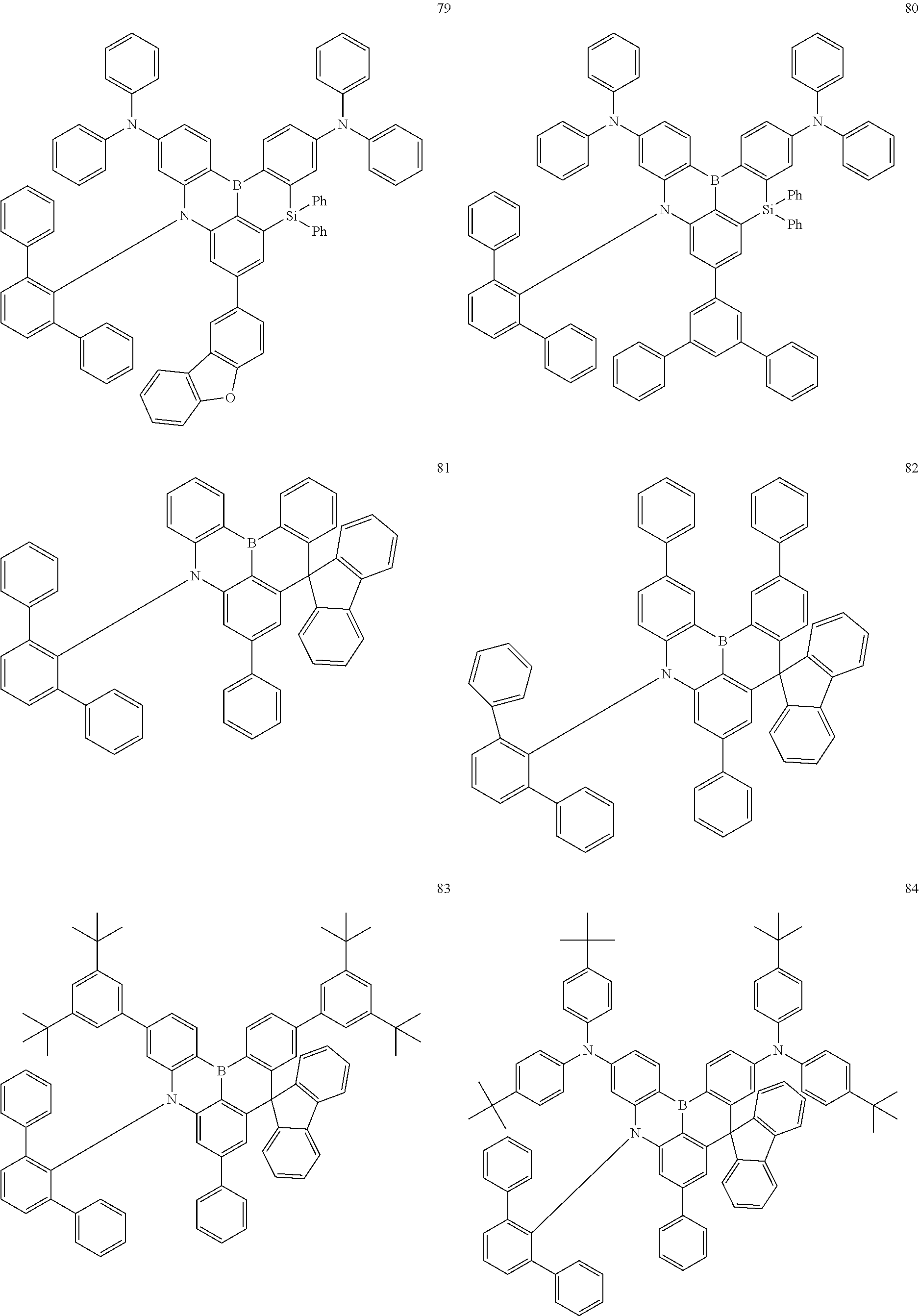 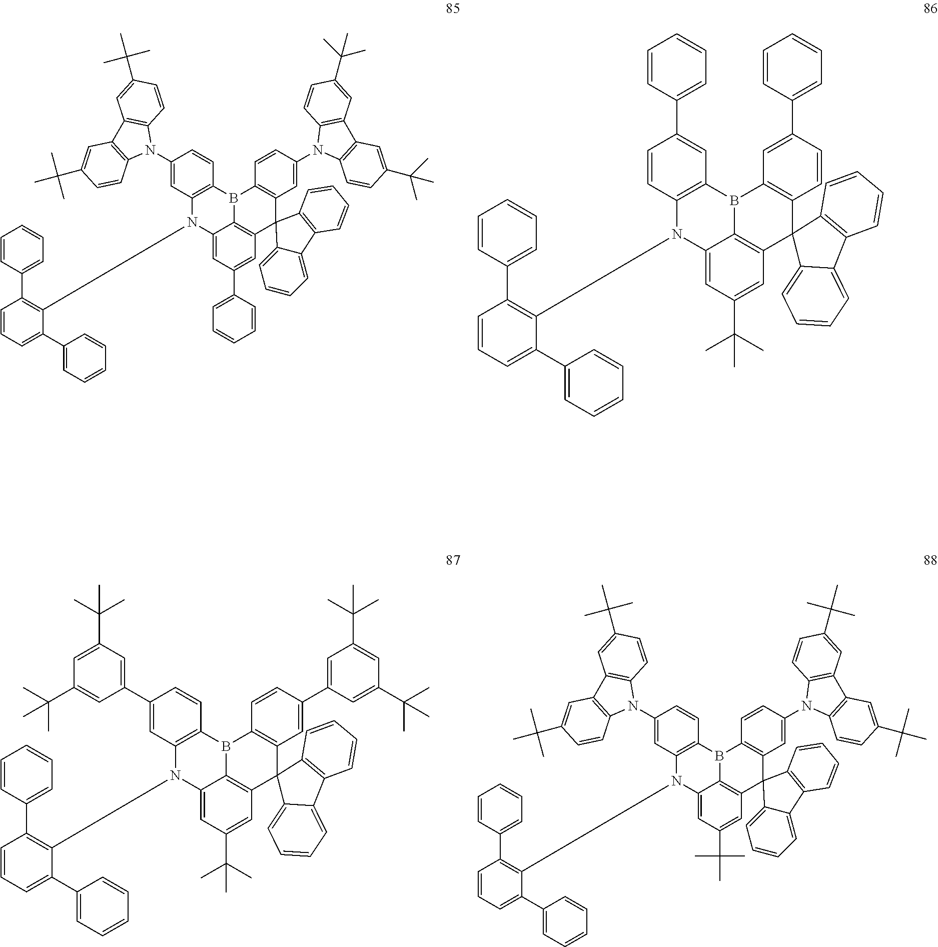 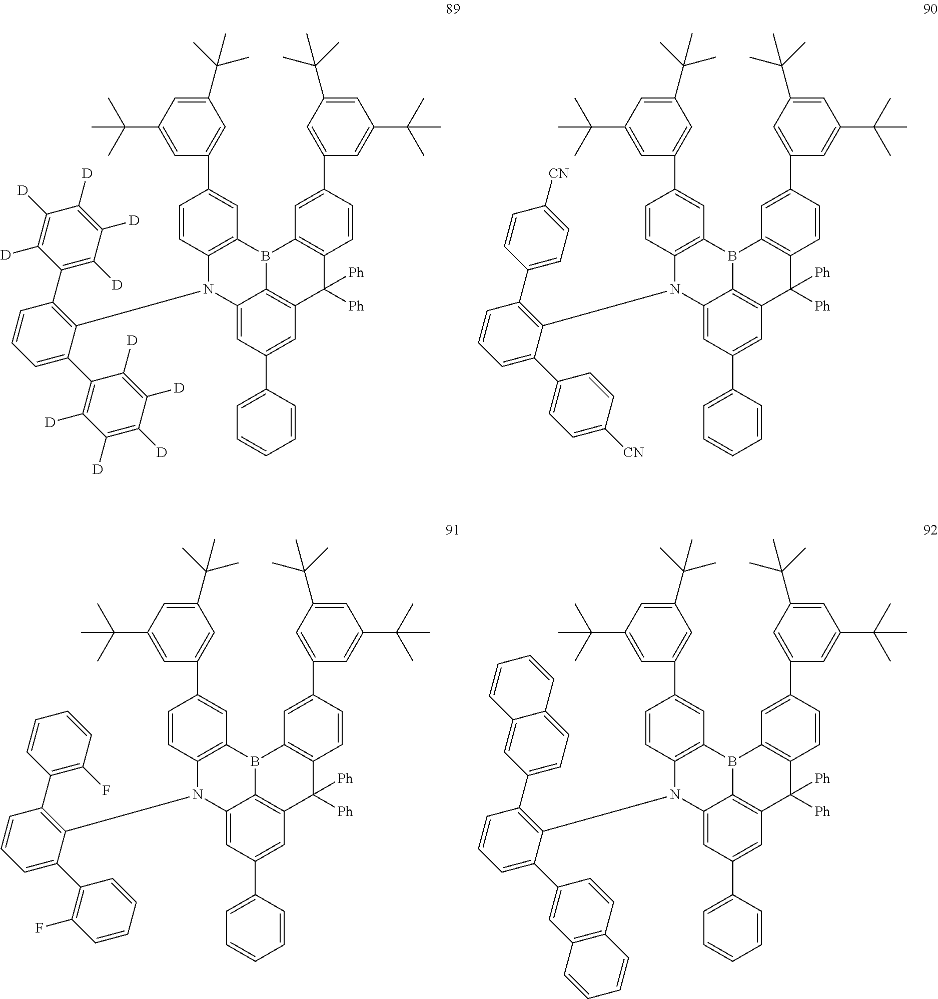
wherein in Compound Group 1, D is a deuterium atom.

16. A light emitting element comprising:
a first electrode;
a second electrode on the first electrode; and
an emission layer between the first electrode and the second electrode and comprising a polycyclic compound represented by Formula 1: 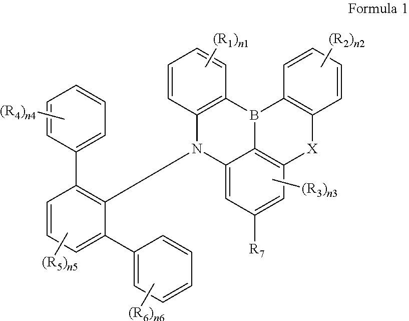
wherein in Formula 1,
X is CR₈R₉ or SiR₁₀R₁₁,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
R₈ to R₁₁ are each independently a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring,
n1 and n2 are each independently an integer from 0 to 4,
n3 is an integer from 0 to 2,
n4 is an integer from 0 to 5,
n5 is an integer from 0 to 3, and
n6 is an integer from 0 to 5.

17. The light emitting element of claim 16, wherein the polycyclic compound represented by Formula 1 is represented by any one selected from among Formulas 1-1a to 1-1e: 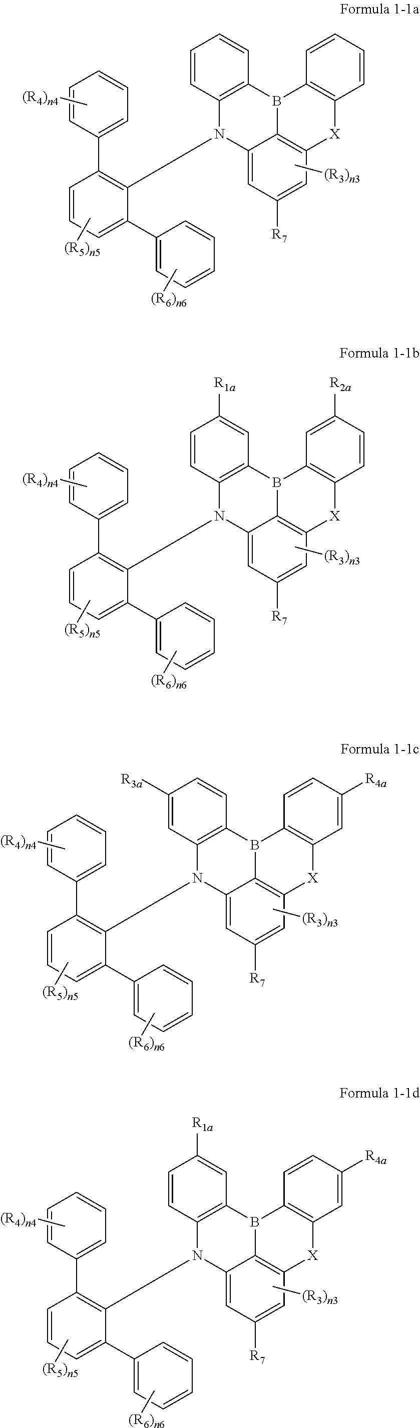 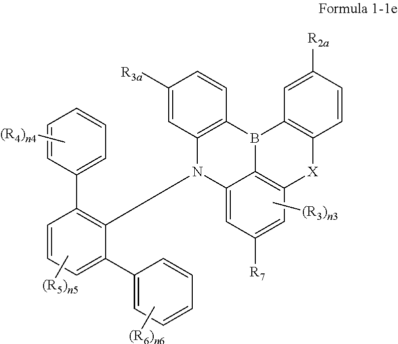
wherein in Formulas 1-1a to 1-1e,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
R₃ to R₇, X, and n3 to n6 are the same as defined in Formula 1.

18. A polycyclic compound represented by Formula 1: 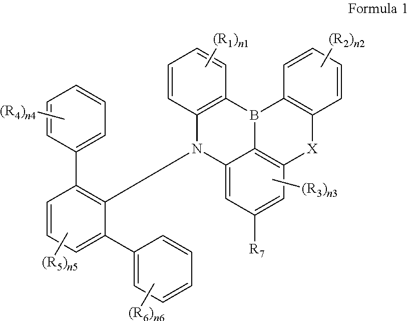
X is CR₈R₉ or SiR₁₀R₁₁,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
R₈ to R₁₁ are each independently a substituted or unsubstituted aryl group having 6 to 60 ring-forming carbon atoms, or a substituted or unsubstituted heteroaryl group having 2 to 60 ring-forming carbon atoms, and/or bonded to an adjacent group to form an aromatic ring,
n1 and n2 are each independently an integer from 0 to 4,
n3 is an integer from 0 to 2,
n4 is an integer from 0 to 5,
n5 is an integer from 0 to 3, and
n6 is an integer from 0 to 5.

19. The polycyclic compound of claim 18, wherein the polycyclic compound represented by Formula 1 is represented by any one selected from among Formulas 1-1a to 1-1e: 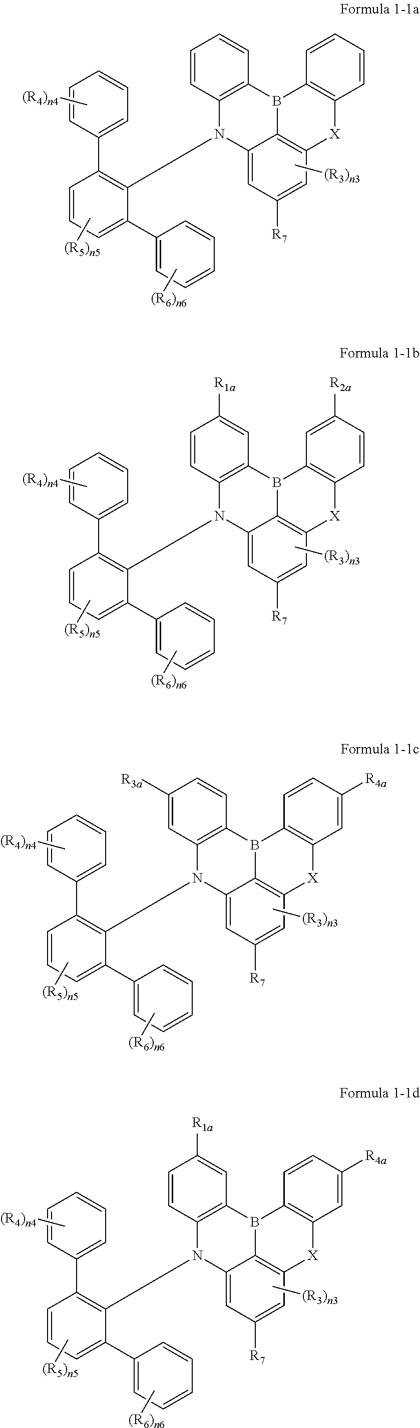 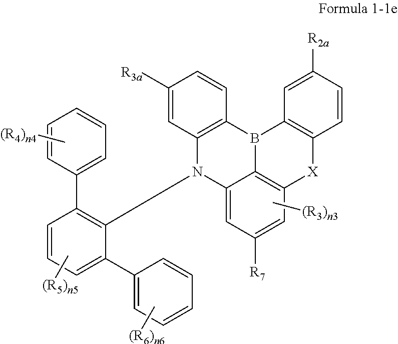
wherein in Formulas 1-1a to 1-1e,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
R₃ to R₇, X, and n3 to n6 are the same as defined in Formula 1.

20. The polycyclic compound of claim 18, wherein the polycyclic compound is represented by any one among compounds of Compound Group 1: 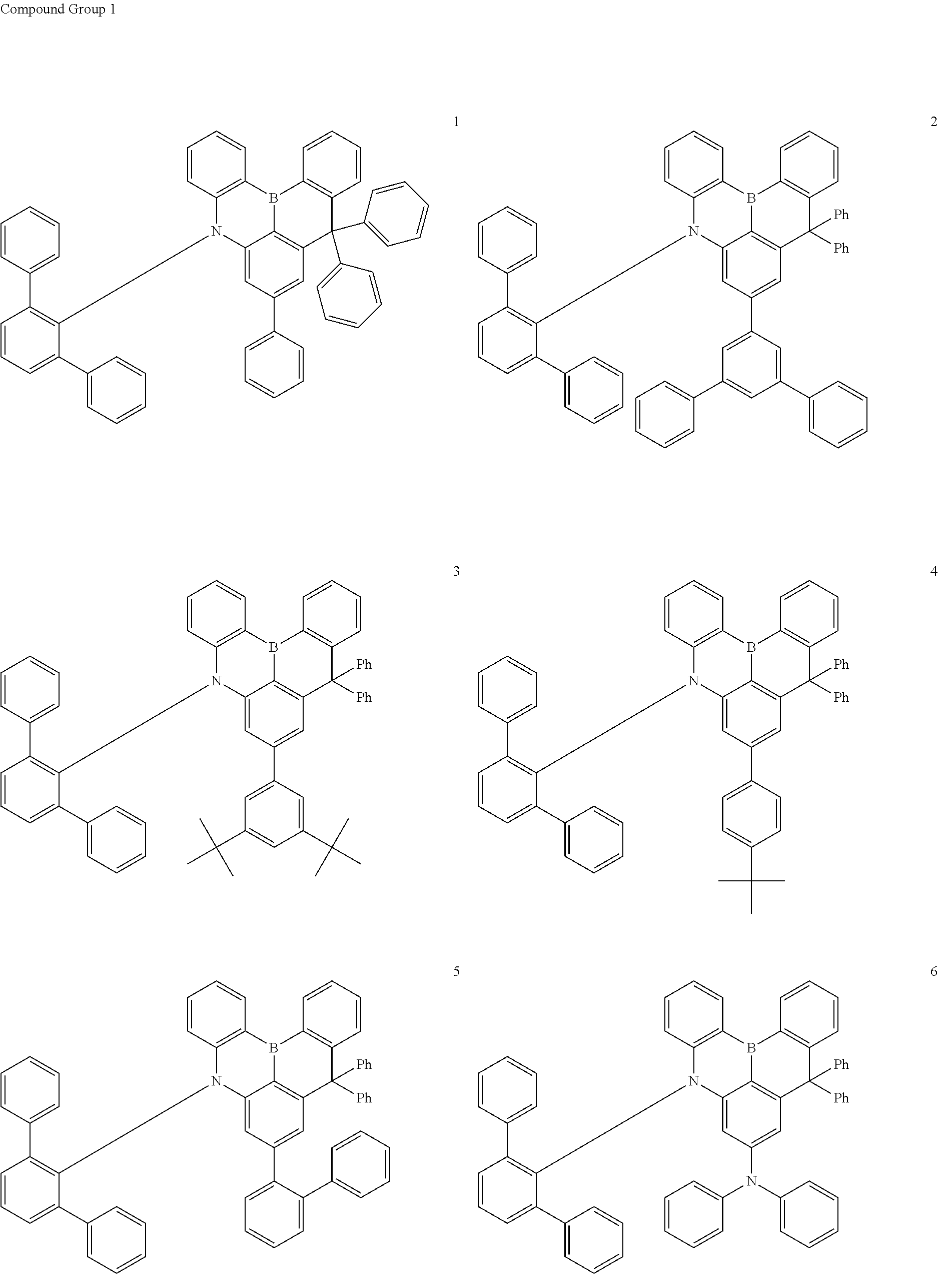 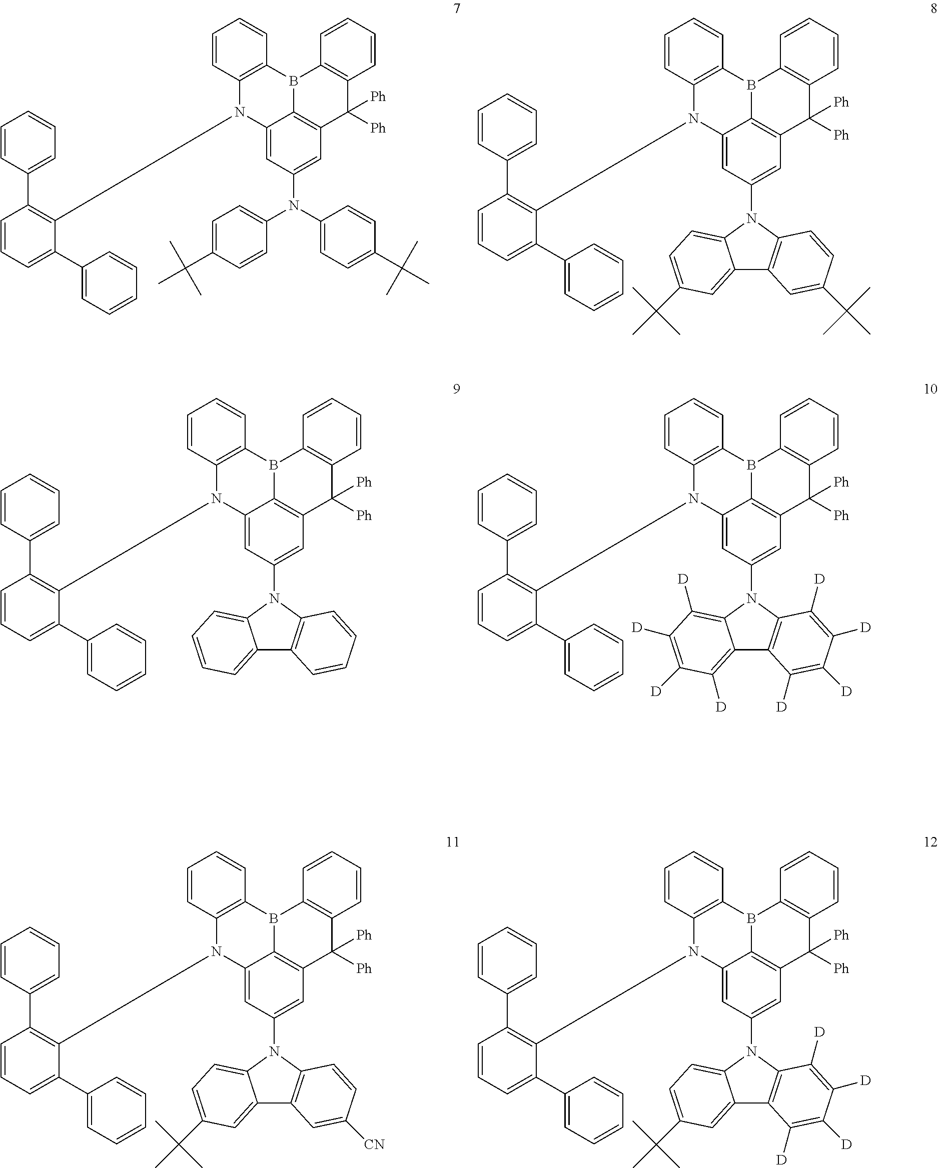 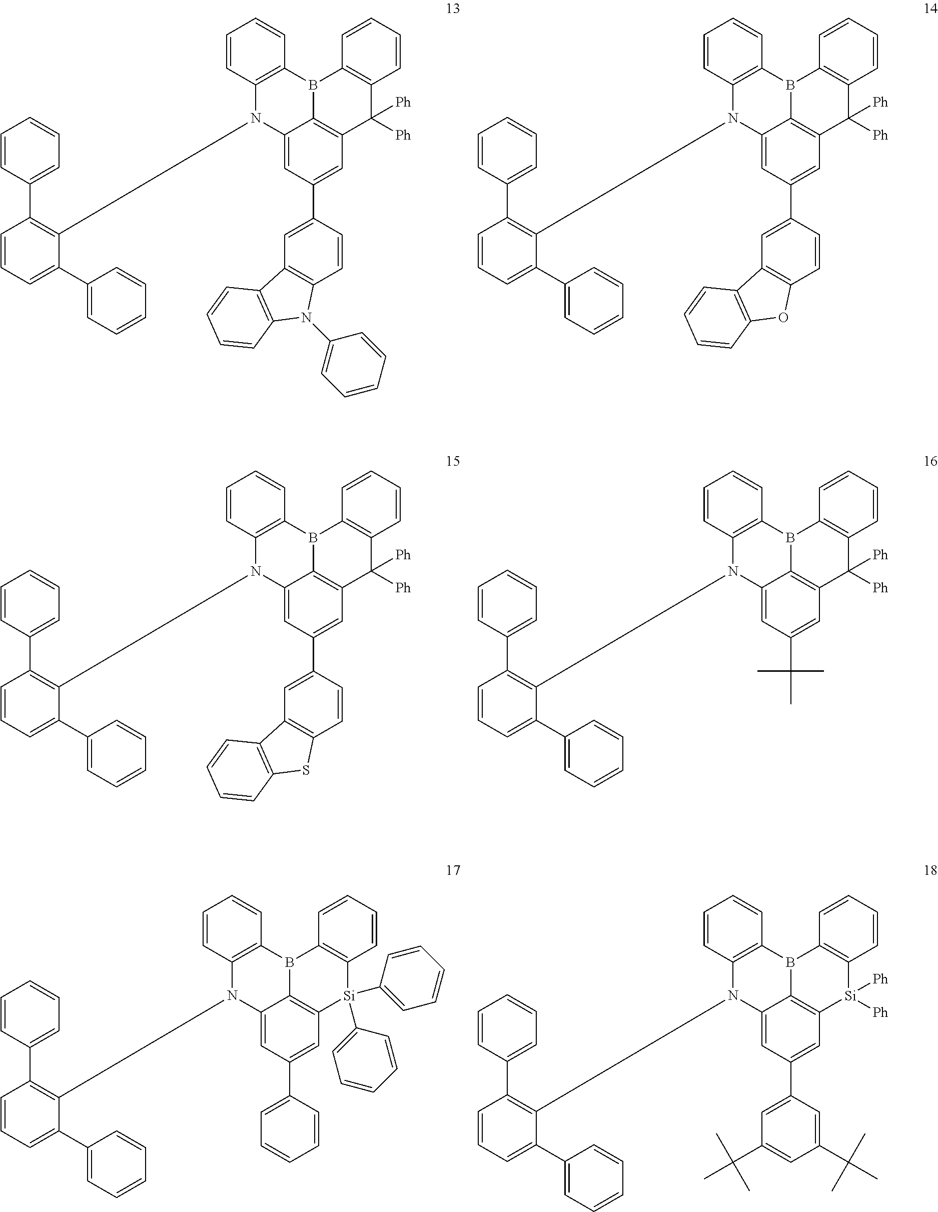 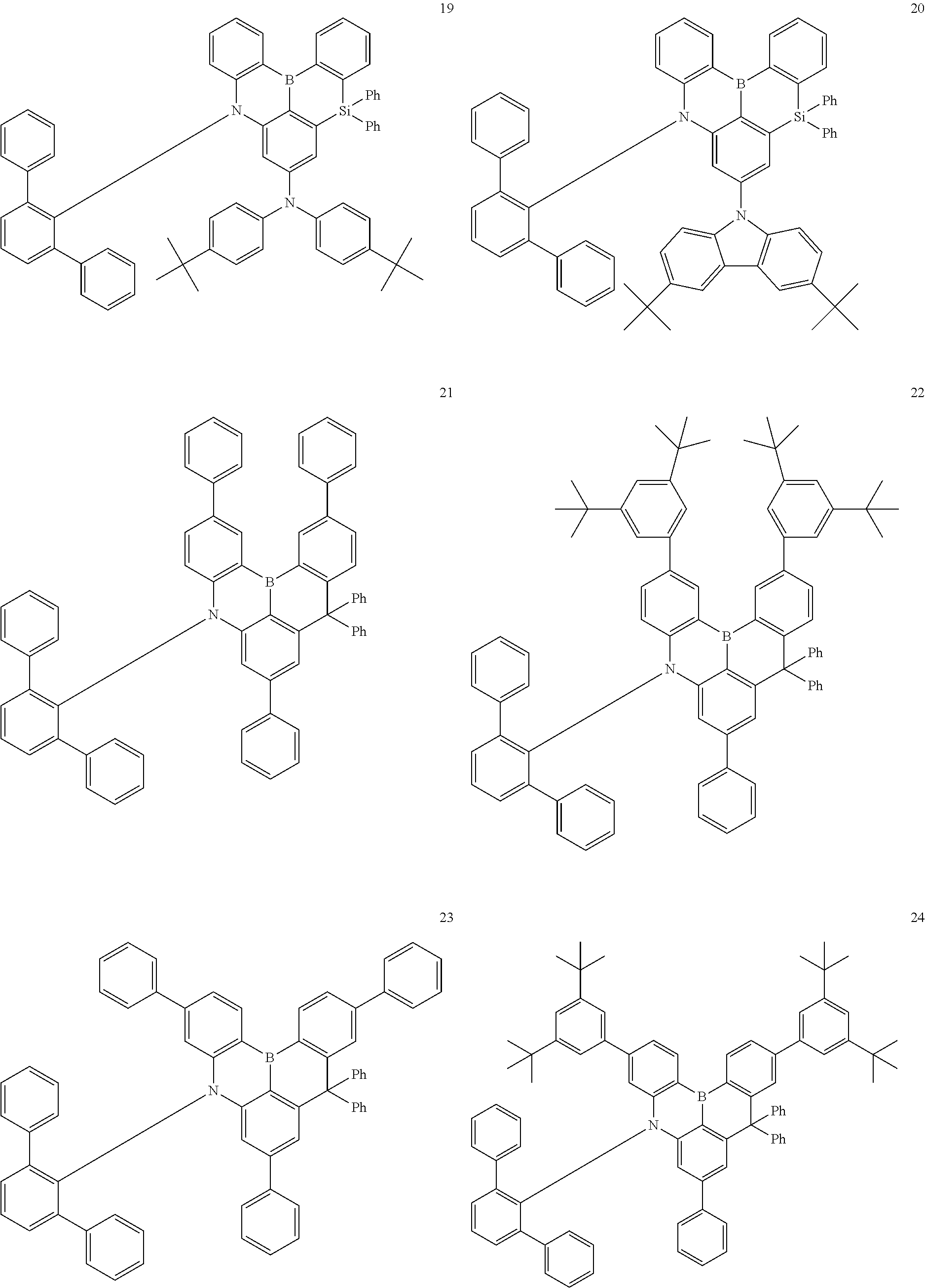 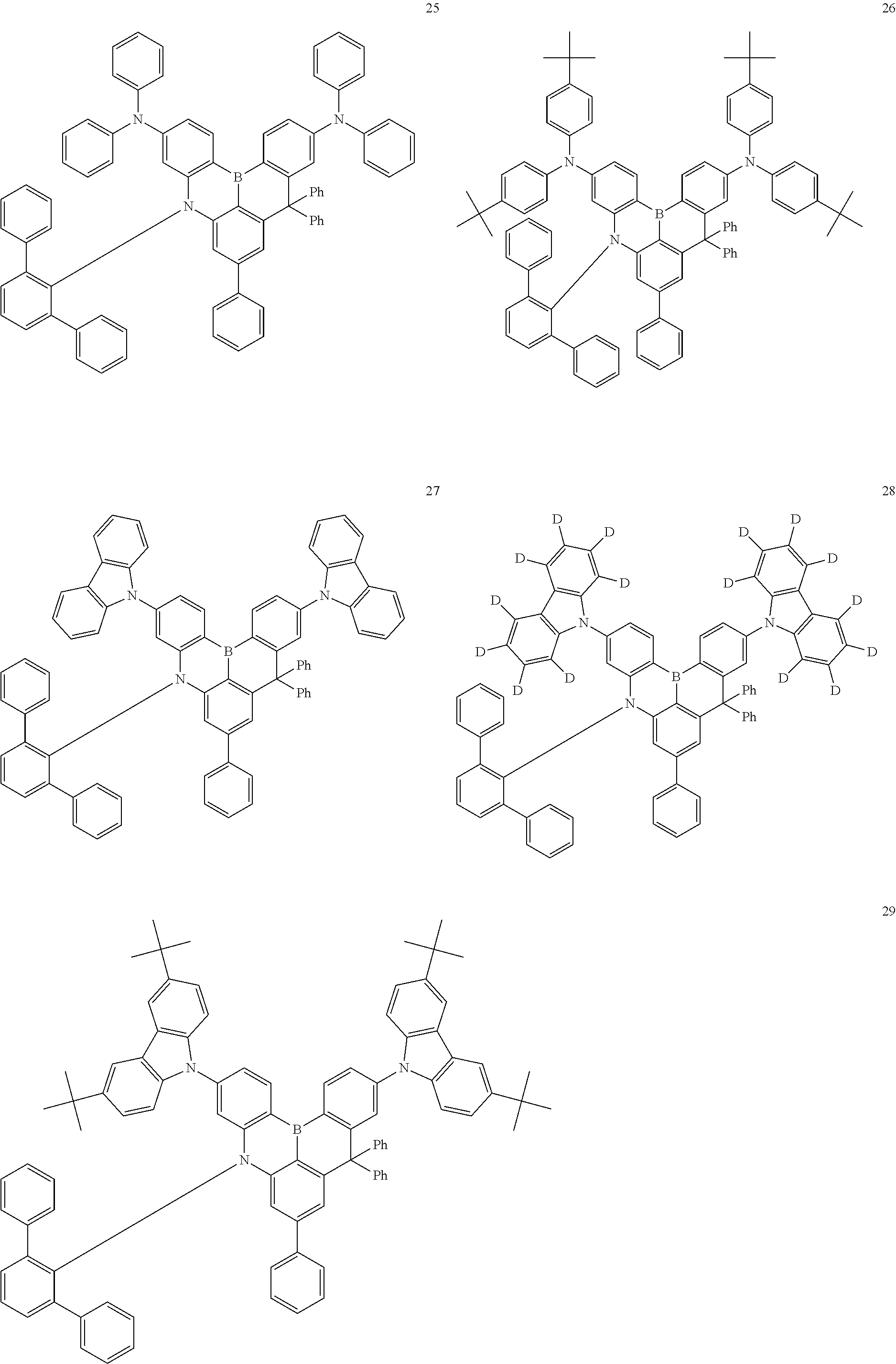 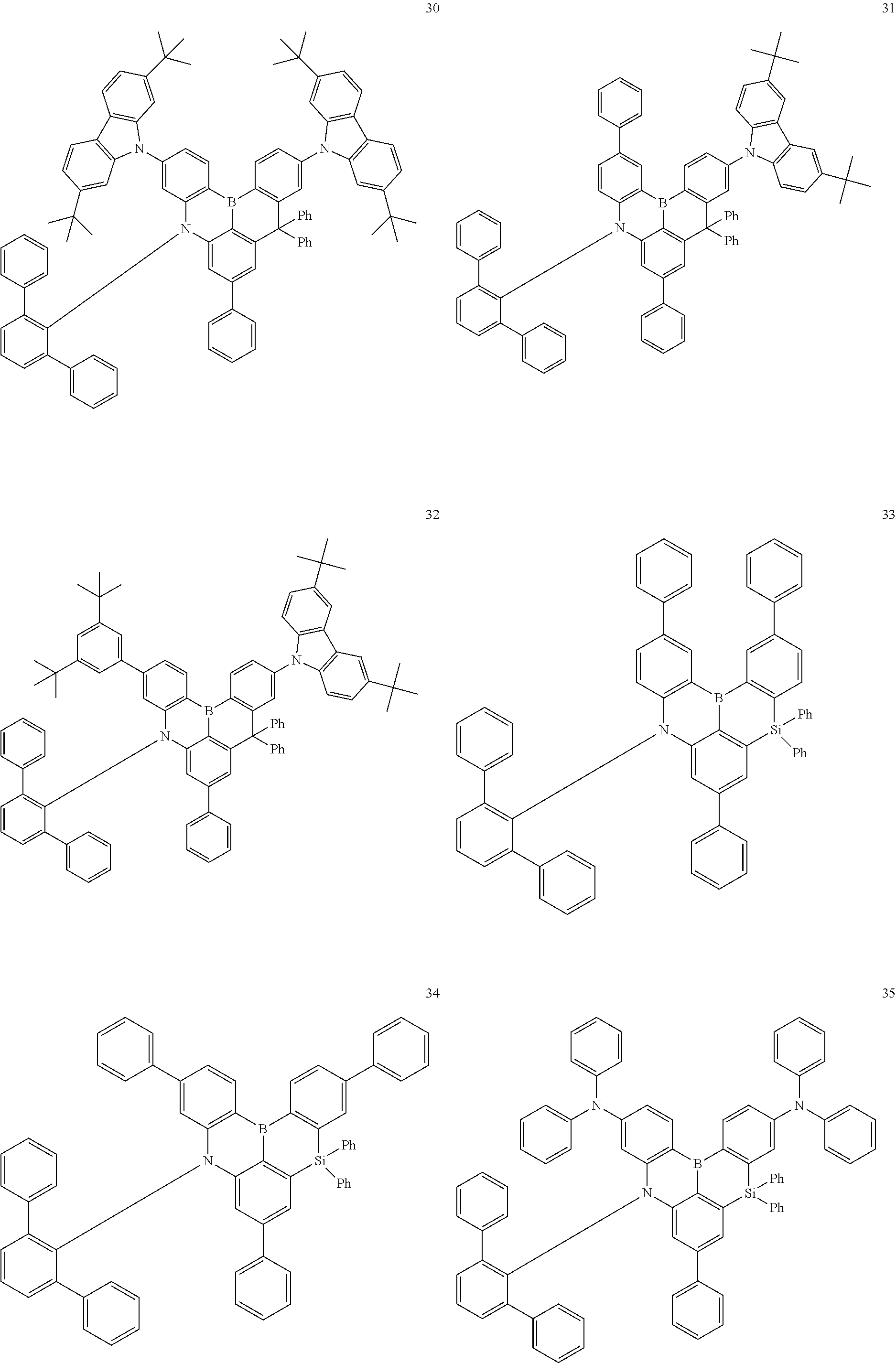 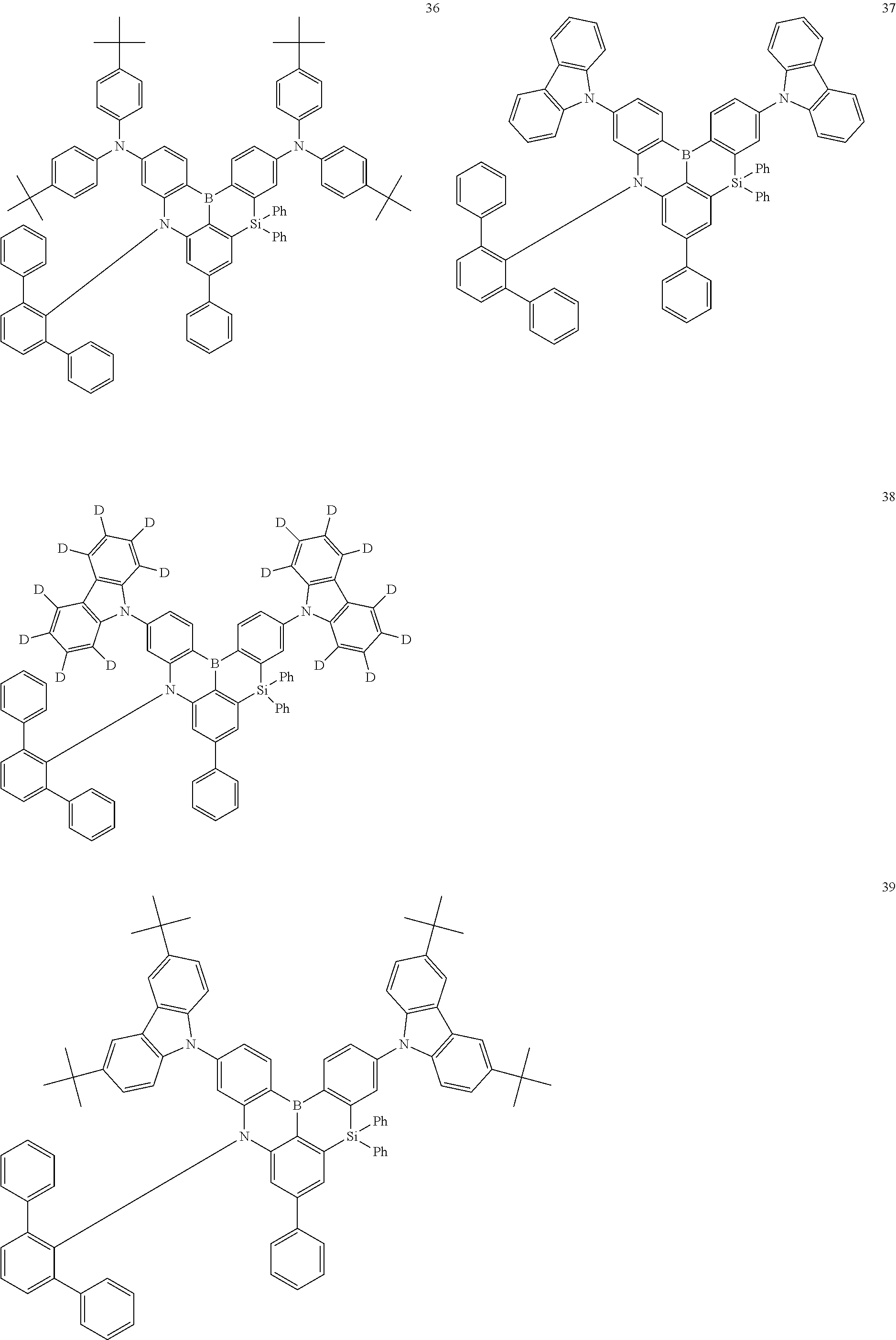 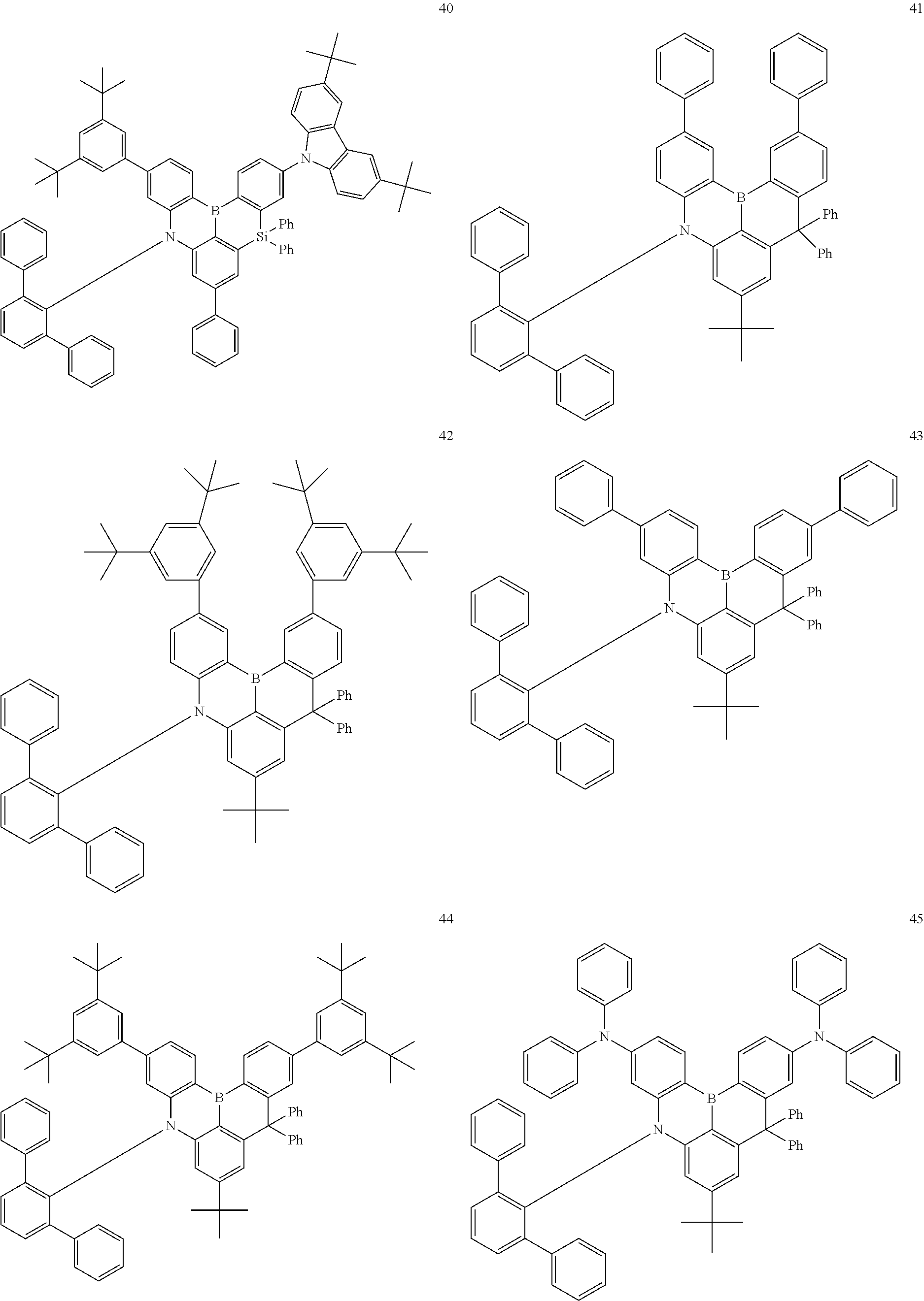 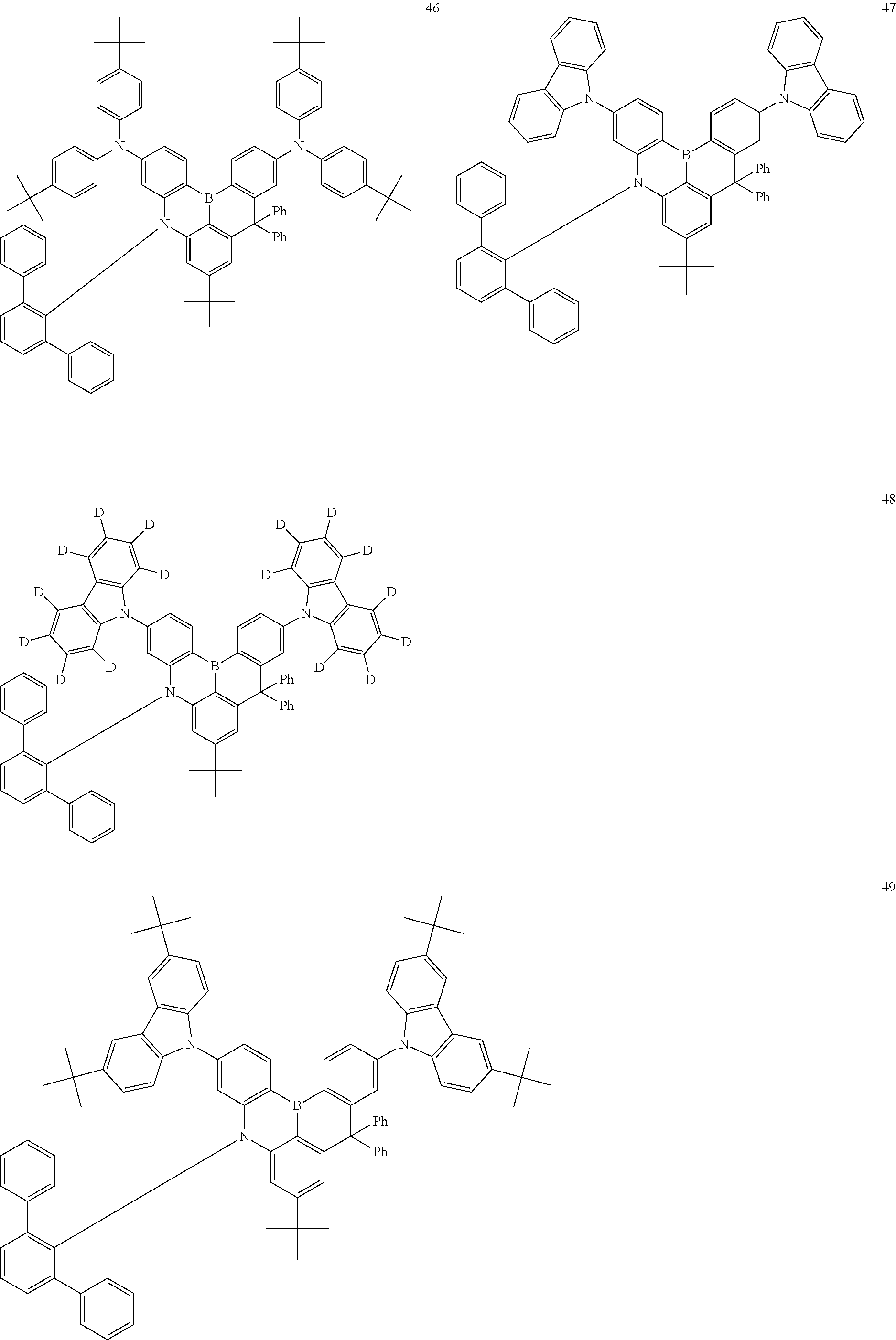 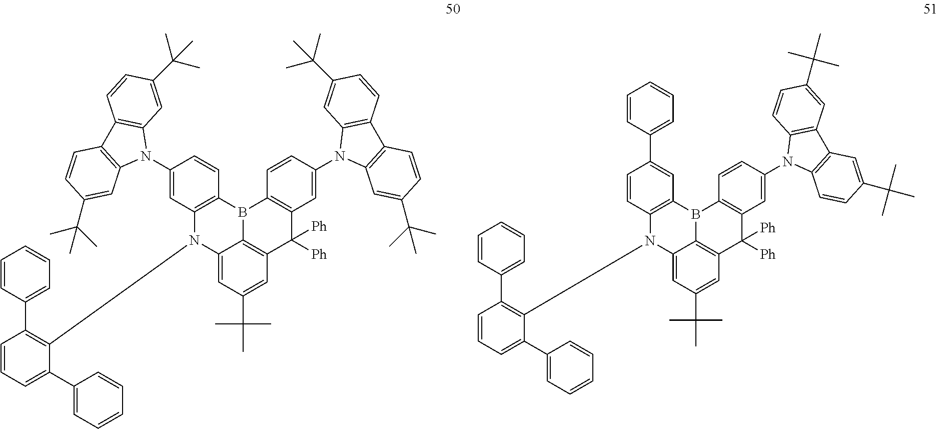 [SMILES: CC(C)(C)c1cc2c3c(c1)C(c1ccccc1)(c1ccccc1)c1cc(-n4c5cc(C(C)(C)C)ccc5c5ccc(C(C)(C)C)cc54)ccc1B3c1ccc(-n3c4cc(C(C)(C)C)ccc4c4ccc(C(C)(C)C)cc43)cc1N2c1c(-c2ccccc2)cccc1-c1ccccc1 ; CC(C)(C)c1cc2c3c(c1)C(c1ccccc1)(c1ccccc1)c1cc(-n4c5ccc(C(C)(C)C)cc5c5cc(C(C)(C)C)ccc54)ccc1B3c1cc(-c3ccccc3)ccc1N2c1c(-c2ccccc2)cccc1-c1ccccc1] 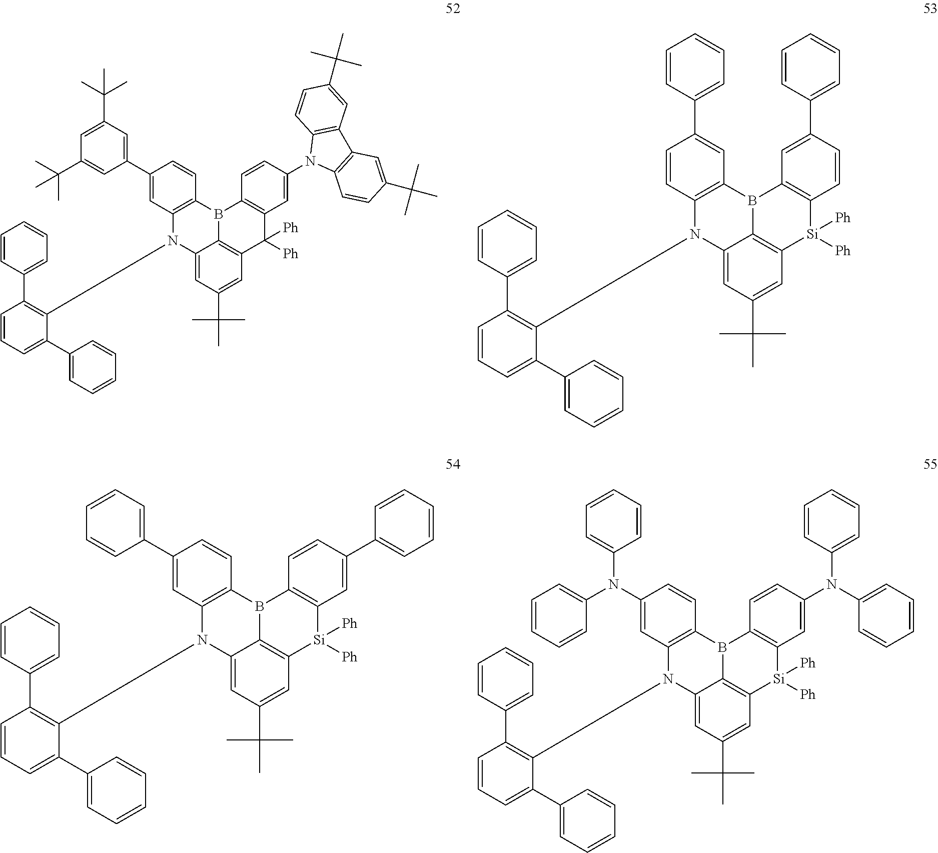 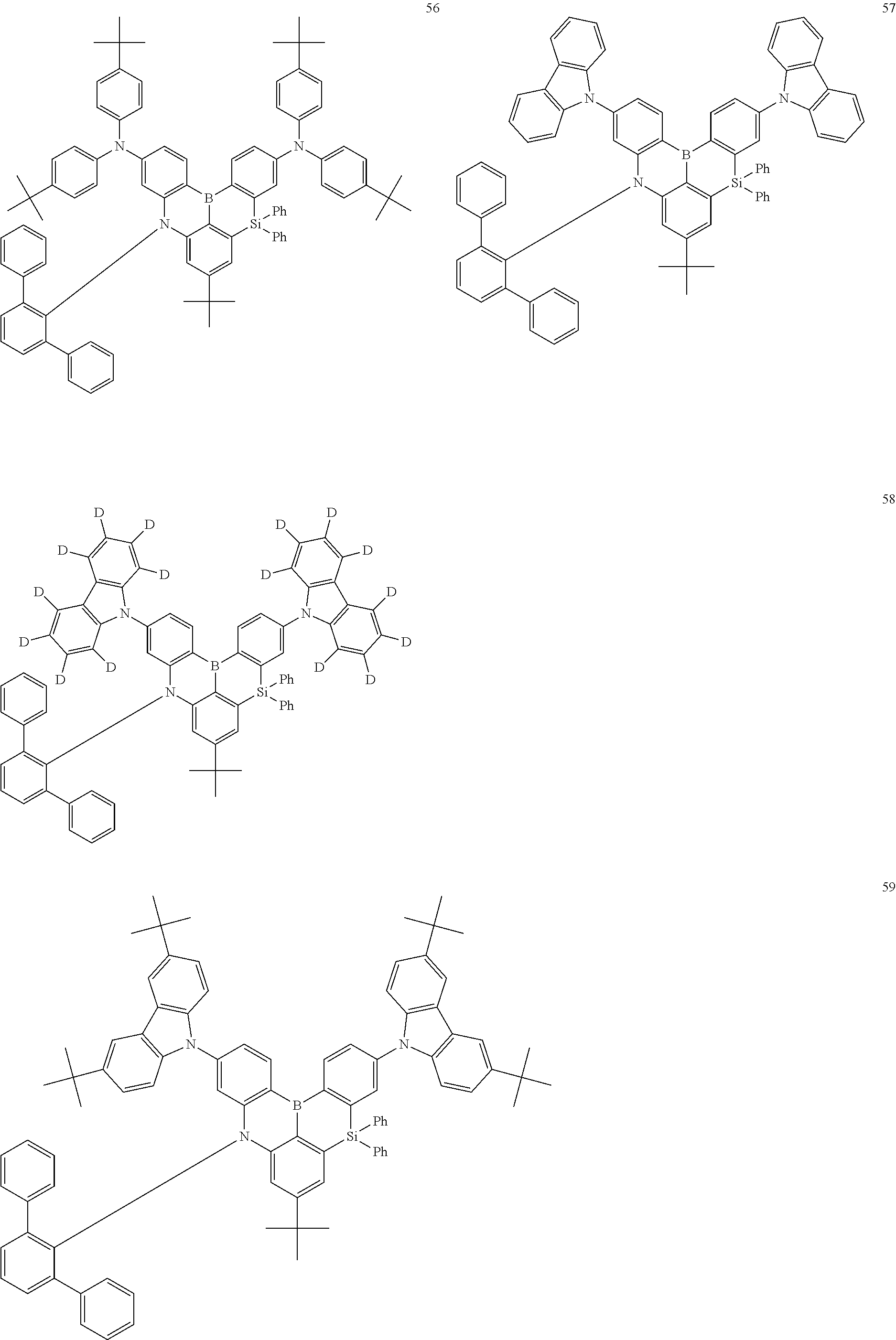 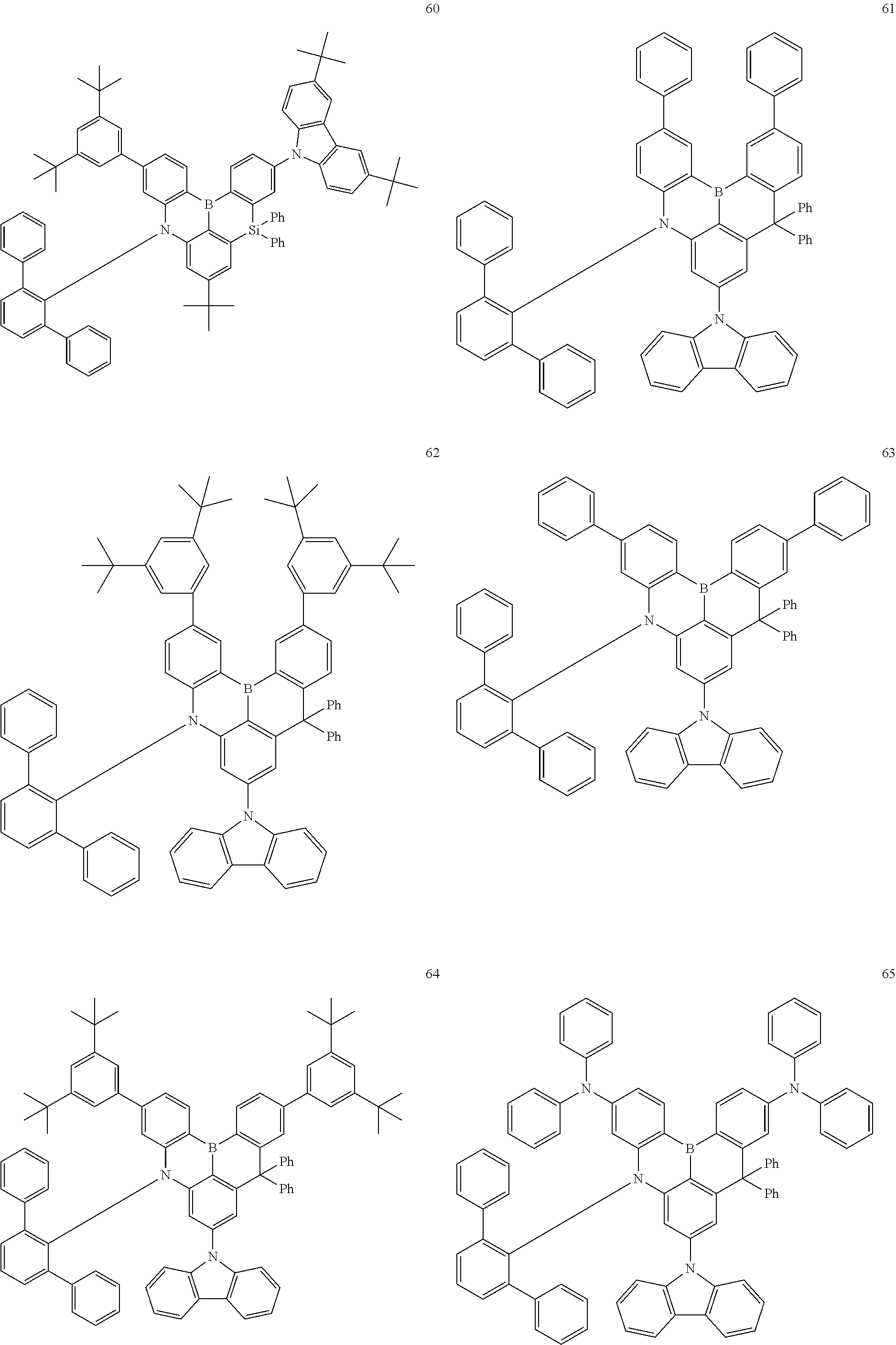 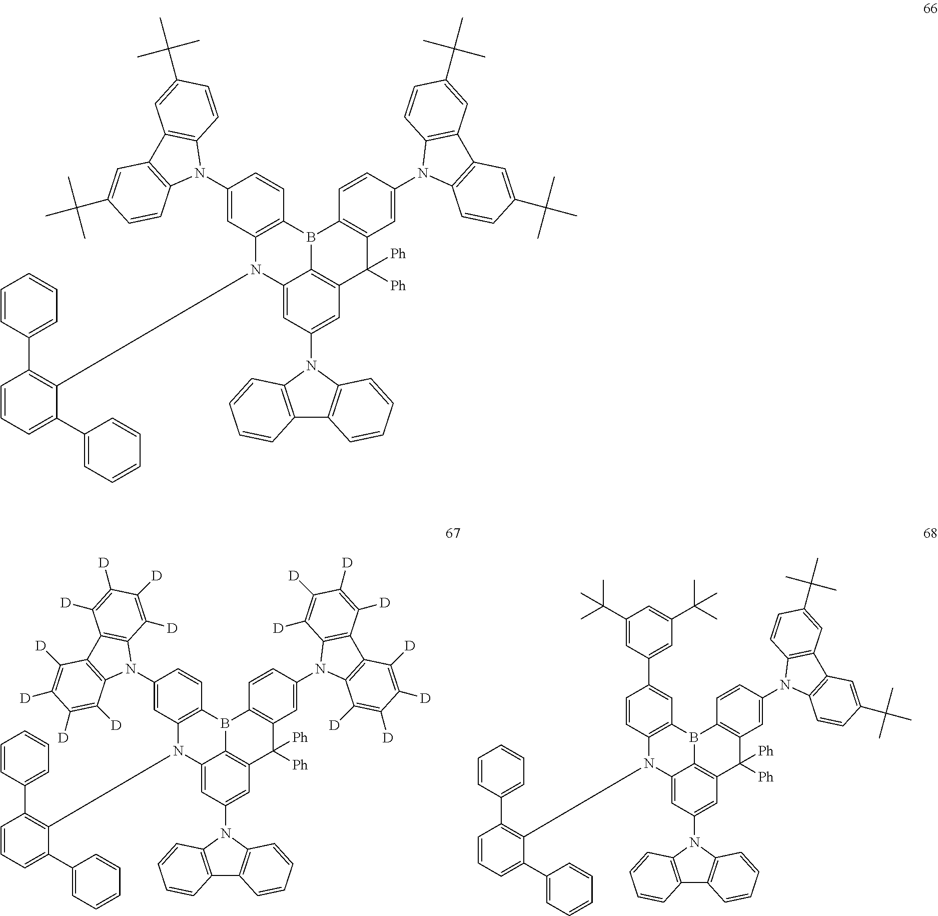 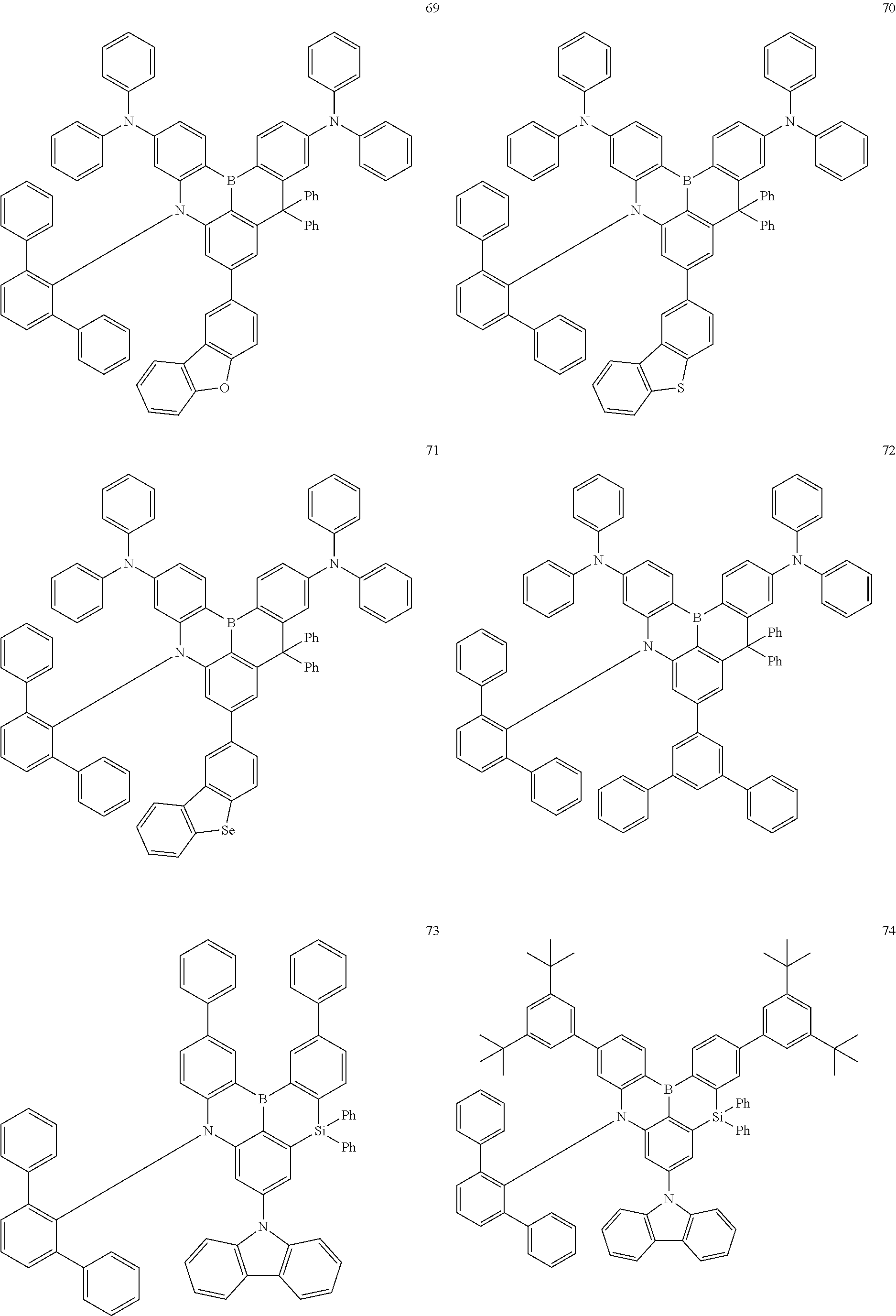 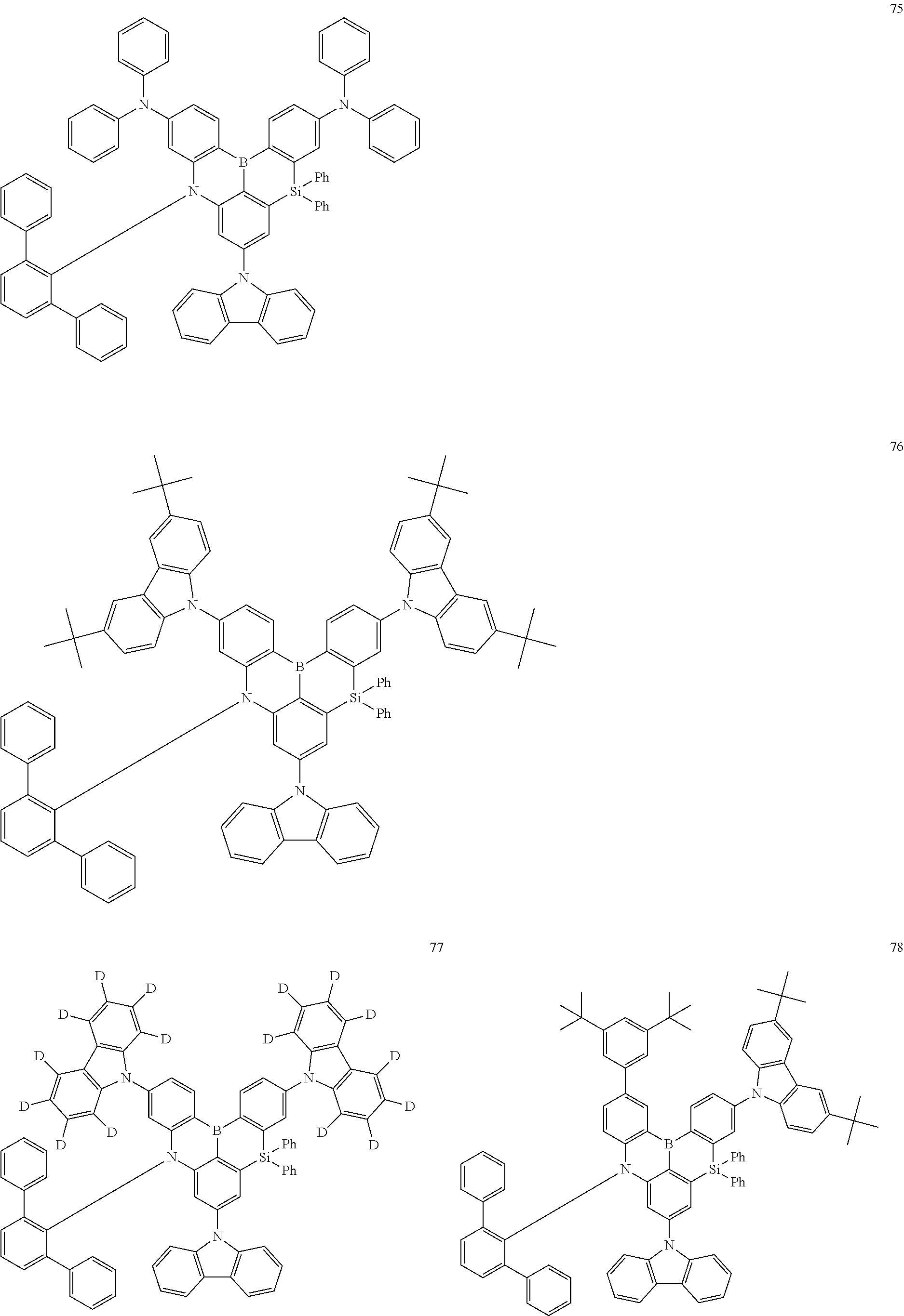 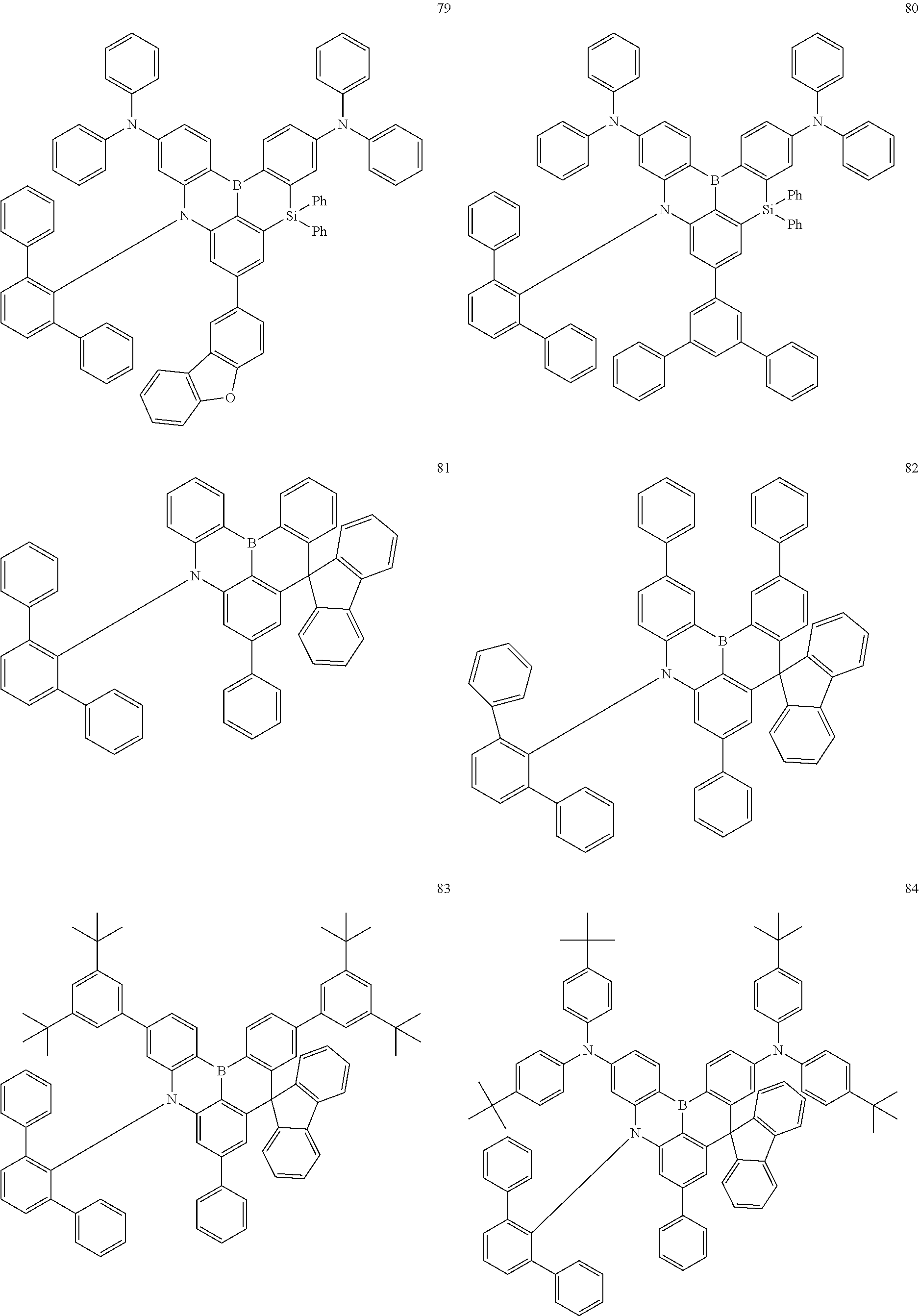 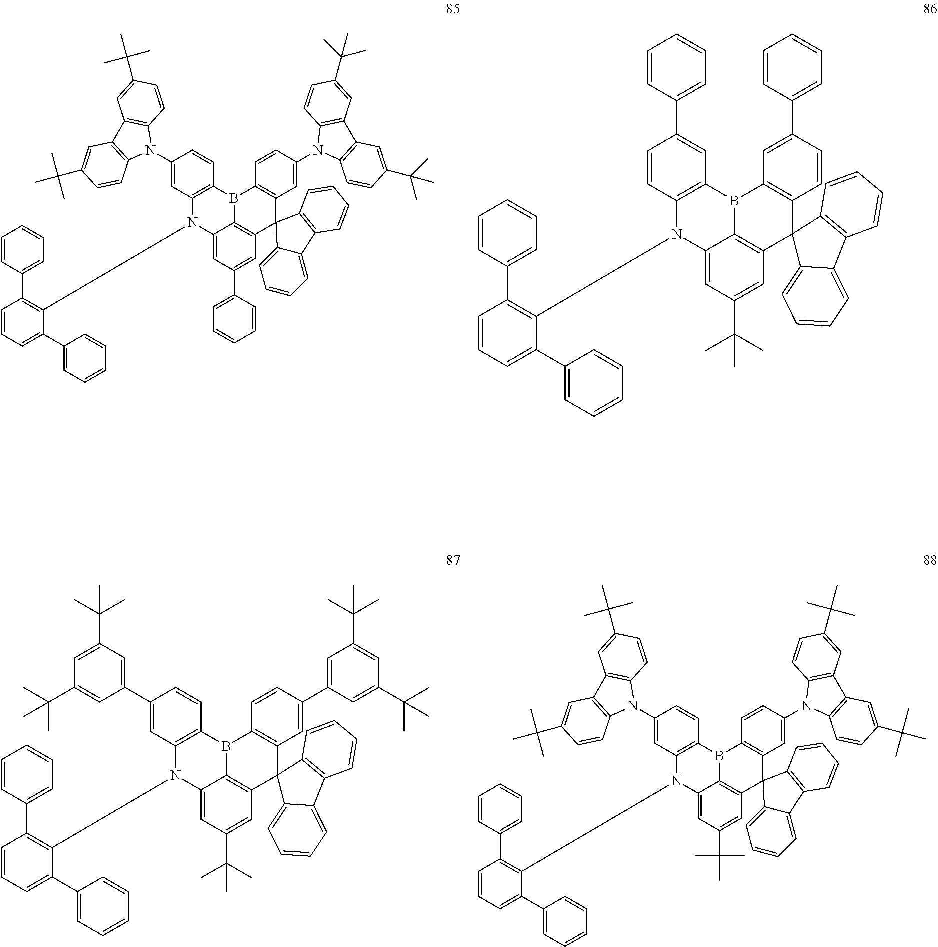 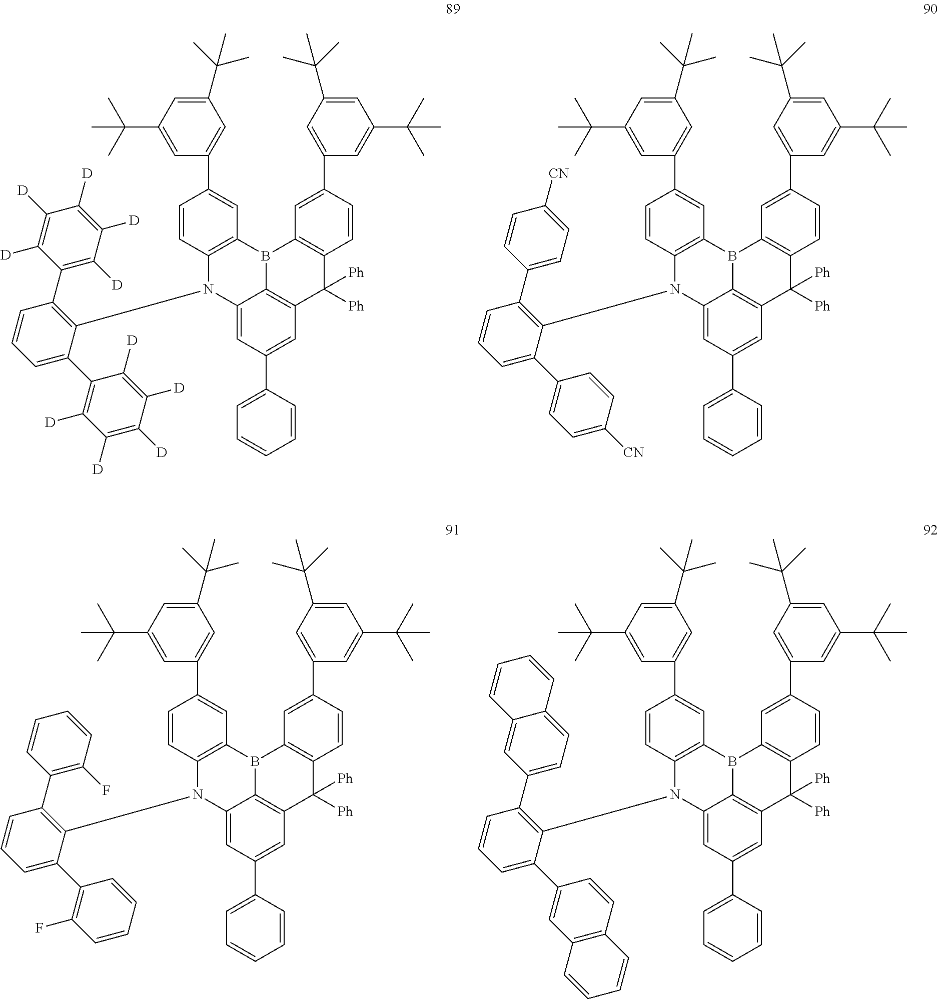
wherein in Compound Group 1, D is a deuterium atom.
